(19) United States
(12) Patent Application Publication
(10) Pub. No.: US 2014/0170564 A1
(43) Pub. Date: Jun. 19, 2014

(54) ACTINIC RAY-SENSITIVE OR RADIATION-SENSITIVE RESING COMPOSITION, ACTINIC RAY-SENSITIVE OR RADIATION-SENSITIVE FILM USING THE COMPOSITION, AND PATTERN FORMING METHOD

(71) Applicant: FUJIFILM Corporation, Tokyo (JP)

(72) Inventors: Tomoki MATSUDA, Shizuoka (JP); Yoko TOKUGAWA, Shizuoka (JP); Akinori SHIBUYA, Shizuoka (JP)

(73) Assignee: FUJIFILM Corporation, Tokyo (JP)

(21) Appl. No.: 14/184,854

(22) Filed: Feb. 20, 2014

Related U.S. Application Data
(63) Continuation of application No. PCT/JP2012/068622, filed on Jul. 23, 2012.

(30) Foreign Application Priority Data
Aug. 22, 2011 (JP) 2011-180895

(51) Int. Cl. G03F 7/004; G03F 7/20

(52) U.S. Cl. CPC G03F 7/0045; G03F 7/2041
USPC 430/285.1; 546/153; 549/72; 549/13; 549/70; 548/441; 548/468; 549/71; 549/78; 430/281.1; 430/270.1; 430/325

(57) ABSTRACT

There is provided an actinic ray-sensitive or radiation-sensitive resin composition containing (A) a compound represented by the following formula (1-1); an actinic ray-sensitive or radiation-sensitive film using the composition; and a pattern forming method:

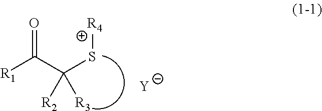

in the formula, R₁, R₂, R₃, R₄ and Y⁻ are the same as those in formula (1-1) set forth in the description.

### CROSS REFERENCE TO RELATED APPLICATION

This is a continuation of International Application No. PCT/JP2012/068622 filed on Jul. 23, 2012, and claims priority from Japanese Patent Application No. 2011-180895 filed on Aug. 22, 2011, the entire disclosures of which are incorporated therein by reference.

### TECHNICAL FIELD

The present invention relates to an actinic ray-sensitive or radiation-sensitive resin composition, an actinic ray-sensitive or radiation-sensitive film using the composition, and a pattern forming method. More specifically, the present invention relates to an actinic ray-sensitive or radiation-sensitive resin composition for use in the process of producing a semiconductor such as IC, in the production of a liquid crystal device or a circuit board such as thermal head, in other photo-fabrication processes, in a lithographic printing plate, and in an acid-curable composition; an actinic ray-sensitive or radiation-sensitive film using the composition; and a pattern forming method.

### BACKGROUND ART

A chemical amplification resist composition is a pattern forming material of forming a pattern on a substrate by producing an acid in the exposed area upon irradiation with radiation such as far ultraviolet light and through a reaction using the acid as a catalyst, causing a change in the solubility for developer of the area irradiated with an actinic ray and the non-irradiated area.

In the case of using a KrF excimer laser as the exposure light source, a resin having small absorption in the region of 248 nm and having a basic framework of poly(hydroxystyrene) is predominantly used as a main component and therefore, this is an excellent system capable of forming a good pattern with high sensitivity and high resolution compared with the conventional naphthoquinone diazide/novolak resin system.

On the other hand, in the case of using a light source of shorter wavelength, for example, an ArF excimer laser (193 nm), as the exposure light source, a satisfactory pattern cannot be formed even by the above-described chemical amplification system, because the compound having an aromatic group substantially exhibits a large absorption in the region of 193 nm. In order to solve this problem, a resist for ArF excimer laser, containing a resin having an alicyclic hydrocarbon structure, has been developed.

In addition, various compounds have been developed for a photoacid generator that is a main constituent component of the chemical amplification resist composition (see, for example, Patent Documents 1 to 8).

However, in view of the overall performance as a resist, it is very difficult to find out an appropriate combination of a resin, a photoacid generator, an additive, a solvent and the like, which are used in the composition, and the resist compositions developed so far are not sufficient yet. In particular, development of an actinic ray-sensitive or radiation-sensitive resin composition capable of satisfying both excellent exposure latitude (EL) and excellent line edge roughness (LER) performance at a high level is demanded.

### RELATED ART

### Patent Document

Patent Document 1: JP-A-2003-140332 (the term “JP-A” as used herein means an “unexamined published Japanese patent application”)
Patent Document 2: Unexamined Published European Patent Application No. 1270553
Patent Document 3: International Publication No. 02/042845
Patent Document 4: JP-A-2002-131897
Patent Document 5: JP-A-2002-214774
Patent Document 6: U.S. Patent Application Publication No. 2004/0087690
Patent Document 7: JP-A-2005-266766
Patent Document 8: JP-A-2002-255930

### SUMMARY OF THE INVENTION

### Problems that the Invention is to Solve

Under these circumstances, an object of the present invention is to provide an actinic ray-sensitive or radiation-sensitive resin composition capable of satisfying all of high sensitivity, excellent exposure latitude and excellent line edge roughness performance at a high level, an actinic ray-sensitive or radiation-sensitive film using the composition, and a pattern forming method.

### Means for Solving the Problems

The present invention includes the following configurations, and the above-described object of the present invention can be attained by these configurations.

[1] An actinic ray-sensitive or radiation-sensitive resin composition containing (A) a compound represented by the following formula (1-1):

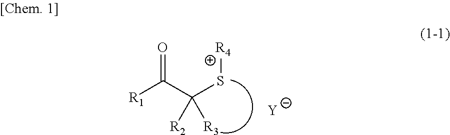

wherein R₁ represents an alkyl group, an alkenyl group, an alkoxy group, an aliphatic cyclic group, an aromatic hydrocarbon group or a heterocyclic group,

R₂ represents a hydrogen atom, an alkyl group, an alkoxy group, an alkenyl group, an aliphatic cyclic group, an aromatic hydrocarbon group, a heterocyclic group, a cyano group or an alkoxycarbonyl group,

R₃ represents an alkylene group where one or more —CH₂— groups may be substituted with an ether group, a carbonyl group, an ester group, an amide group, a urethane group or a urea group,

R₄ represents an alkyl group, an alkenyl group, an aliphatic cyclic group, an arylcarbonylalkyl group, an aryloxycarbonylalkyl group or an alkoxycarbonylalkyl group,

R₁ and R₂ may combine with each other to form a ring, and

Y⁻ represents an anion.

[2] The actinic ray-sensitive or radiation-sensitive resin composition as described in [1],

wherein in formula (1-1), R₁ is an aromatic hydrocarbon group or an aromatic heterocyclic group.

[3] The actinic ray-sensitive or radiation-sensitive resin composition as described in [2],

wherein in formula (1-1), R₁ is an aromatic hydrocarbon group.

[4] The actinic ray-sensitive or radiation-sensitive resin composition as described in any one of [1] to [3],

wherein in formula (1-1), R₃ is an unsubstituted alkylene group.

[5] The actinic ray-sensitive or radiation-sensitive resin composition as described in any one of [1] to [4],

wherein Y⁻ represents an organic acid anion.

[6] The actinic ray-sensitive or radiation-sensitive resin composition as described in any one of [1] to [5],

wherein Y⁻ represents a sulfonate anion, an imidate anion or a methidate anion.

[7] The actinic ray-sensitive or radiation-sensitive resin composition as described in any one of [1] to [6], containing (B) a resin capable of decomposing by an action of an acid to increase the solubility for an alkali developer.
[8] The actinic ray-sensitive or radiation-sensitive resin composition as described in any one of [1] to [7], further containing a hydrophobic resin.
[9] The actinic ray-sensitive or radiation-sensitive resin composition as described in any one of [1] to [8], further containing (F) a basic compound or (G) a low molecular compound having a group capable of leaving by an action of an acid, and increasing in the basicity upon leaving of the group.
[10] An actinic ray-sensitive or radiation-sensitive film formed using the actinic ray-sensitive or radiation-sensitive resin composition described in any one of [1] to [9].
[11]A pattern forming method comprising exposing the actinic ray-sensitive or radiation-sensitive film described in [10] and developing the exposed film.
[12] The pattern forming method as described in [11], wherein the exposure is performed through an immersion liquid.

### Advantage of the Invention

According to the present invention, an actinic ray-sensitive or radiation-sensitive resin composition capable of satisfying all of high sensitivity, excellent exposure latitude and excellent line edge roughness performance at a high level, an actinic ray-sensitive or radiation-sensitive film using the composition, and a pattern forming method can be provided.

### MODE FOR CARRYING OUT THE INVENTION

The mode for carrying out the present invention is described below.

In the description of the present invention, when a group (atomic group) is denoted without specifying whether substituted or unsubstituted, the group encompasses both a group having no substituent and a group having a substituent. For example, “an alkyl group” encompasses not only an alkyl group having no substituent (unsubstituted alkyl group) but also an alkyl group having a substituent (substituted alkyl group).

In the present invention, the term “actinic ray” or “radiation” indicates, for example, a bright line spectrum of mercury lamp, a far ultraviolet ray typified by excimer laser, an extreme-ultraviolet ray (EUV light), an X-ray or an electron beam (BB). Also, in the present invention, the “light” means an actinic ray or radiation.

In the description of the present invention, unless otherwise indicated, the “exposure” encompasses not only exposure to a mercury lamp, a far ultraviolet ray typified by excimer laser, an X-ray, EUV light or the like but also lithography with a particle beam such as electron beam and ion beam.

The actinic ray-sensitive or radiation-sensitive resin composition of the present invention contains a compound represented by formula (1-1) (hereinafter, sometimes referred to as “compound (A)”) described in detail below.

The actinic ray-sensitive or radiation-sensitive resin composition of the present invention is, for example, a positive composition and is typically a positive resist composition. Respective components of this composition are described below.

### [1] Compound (a) Represented by Formula (1-1)

The actinic ray-sensitive or radiation-sensitive resin composition of the present invention contains a compound represented by the following formula (1-1) (hereinafter, sometimes referred to as “compound (A)”) as described above. Here, the compound (A) decomposes upon irradiation with an actinic ray or radiation to generate an acid. That is, the compound (A) functions as an acid generator.

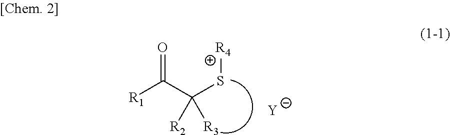

In the formula, R₁ represents an alkyl group, an alkenyl group, an alkoxy group, an aliphatic cyclic group, an aromatic hydrocarbon group or a heterocyclic group.

R₂ represents a hydrogen atom, an alkyl group, an alkoxy group, an alkenyl group, an aliphatic cyclic group, an aromatic hydrocarbon group, a heterocyclic group, a cyano group or an alkoxycarbonyl group.

R₃ represents an alkylene group where one or more —CH₂— groups may be substituted with an ether group, a carbonyl group, an ester group, an amide group, a urethane group or a urea group.

R₄ represents an alkyl group, an alkenyl group, an aliphatic cyclic group, an arylcarbonylalkyl group, an aryloxycarbonylalkyl group or an alkoxycarbonylalkyl group.

R₁ and R₂ may combine with each other to form a ring.

Y⁻ represents an anion.

The actinic ray-sensitive or radiation-sensitive resin composition of the present invention contains, as an acid generator, a compound represented by formula (1-1), whereby both excellent exposure latitude and excellent line edge roughness performance can be satisfied at a high level. The reason therefor is not clearly known, but it is considered that as in formula (1-1), an S—C bond moiety formed by combining a sulfur atom and a carbon atom adjacent to a carbonyl group forms a ring through an alkylene group of R₃, whereby the molecular weight of a residual material derived from the compound (A) (that is, a compound derived from the compound (A), in the state after an acid is generated from the compound (A) upon exposure) in the exposed area tends to become large compared with the case of using an acid generator not having the above-described ring, presumably because fragments after exposure remain connected due to the presence of an alkylene group of R₃, and this makes it possible to raise the glass transition temperature of the film in the exposed area and in turn, keep the acid generated in the exposed from excessively diffusing even into the unexposed area, as a result, an excellent exposure latitude can be achieved.

Also, it is considered that the compound represented by formula (1-1) is constrained from molecular movement due to the ring structure and this enables suppression of thermal deactivation in the excited state during exposure and efficient occurrence of decomposition, leading to an increase in the acid generation efficiency, as a result, the sensitivity and line edge roughness performance are enhanced.

As described above, R₁ represents an alkyl group, an allenyl group, an alkoxy group, an aliphatic cyclic group, an aromatic hydrocarbon group or a heterocyclic group. These groups may further have a substituent.

The alkyl group represented by R₁ may be linear or branched. The carbon umber of the alkyl group is preferably from 1 to 50, more preferably from 1 to 30, still more preferably from 1 to 20. This alkyl group includes, for example, a methyl group, an ethyl group, a propyl group, a butyl group, a hexyl group, an octyl group, a decyl group, a dodecyl group, an octadecyl group, an isopropyl group, an isobutyl group, a sec-butyl group, a tert-butyl group, a 1-ethylpentyl group, and a 2-ethylhexyl group.

The alkenyl group represented by R₁ may be linear or branched. The carbon number of the alkenyl group is preferably from 2 to 50, more preferably from 2 to 30, still more preferably from 3 to 20. This alkenyl group includes, for example, a vinyl group, an allyl group, and a styryl group.

As for the alkoxy group represented by R₁, the alkyl moiety in the alkoxy group may be linear, branched or cyclic. The carbon number of the alkoxy group is preferably from 1 to 10, and this alkoxy group includes, for example, a methoxy group, an ethoxy group, an n-propoxy group, an i-propoxy group, an n-butoxy group, a 2-methylpropoxy group, a 1-methylpropoxy group, a tert-butoxy group, an n-pentyloxy group, a neopentyloxy group, a cyclopentyloxy group, an n-hexyloxy group, a cyclohexyloxy group, an n-heptyloxy group, a cyclopentyloxy group, an n-hexyloxy group, a cyclohexyloxy group, an n-heptyloxy group, a cycloheptyloxy group, an n-octyloxy group, a 2-ethylhexyloxy group, an n-nonyloxy group, and an n-decyloxy group. Among these alkoxy groups, a methoxy group, an ethoxy group, a cyclopentyloxy group and a cyclohexyloxy group are preferred.

The aliphatic cyclic group represented by R₁ is, for example, a cycloalkyl group. The cycloalkyl group may be monocyclic or polycyclic. This aliphatic cyclic group is preferably a monocyclic cycloalkyl group having a carbon number of 3 to 8, such as cyclopropyl group, cyclopentyl group and cyclohexyl group.

As the aromatic hydrocarbon group represented by R1, those having a carbon number of 6 to 14 are preferred. Such a group includes, for example, an aryl group such as phenyl group, naphthyl group and anthryl group. The aromatic hydrocarbon group represented by R₁ is preferably a phenyl group.

The heterocyclic group represented by R₁ may have aromaticity or may not have aromaticity. This heterocyclic group preferably has aromaticity.

The heterocyclic ring contained in the group above may be monocyclic or polycyclic. This heterocyclic ring includes, for example, an imidazole ring, a pyridine ring, a pyrazine ring, a pyrimidine ring, a pyridazine ring, a 2H-pyrrole ring, a 3H-indole ring, 1H-indazole, a purine ring, an isoquinoline ring, a 4H-quinolidine ring, a quinoline ring, a phthalazine ring, a naphthylidine ring, a quinoxaline ring, a quinoxazoline ring, a cinnoline ring, a pteridine ring, a phenanthridine ring, an acridine ring, a phenanthroline ring, a phenazine ring, a perimidine ring, a triazine ring, a benzisoquinoline ring, a thiazole ring, a thiadiazine ring, an azepine ring, an azocine ring, an isothiazole ring, an isoxazole ring, a benzothiazole ring, a carbazole ring, a dibenzofuran ring, and a dibenzothiophene ring.

In view of having an appropriate absorption for the exposure light source, R₁ is preferably an aromatic hydrocarbon group or an aromatic heterocyclic group, more preferably an aromatic hydrocarbon group.

In the case where the group represented by R₁ further has a substituent, the substituent includes, for example, the followings. That is, examples of the substituent include a halogen atom (—F, —Br, —Cl or —I), a hydroxyl group, an alkoxy group, an alkoxycarbonyl group, an alkylcarbonyloxy group, an aryloxy group, an alkoxycarbonyl group, a mercapto group, an alkylthio group, an aryl group, an arylthio group, an amino group, an acyloxy group, a carbamoyloxy group, an alkylsulfoxy group, an arylsulfoxy group, an acylthio group, an acylamino group, a ureido group, an alkoxycarbonylamino group, an aryloxycarbonylamino group, an N-alkyl-N-alkoxycarbonylamino group, an N-alkyl-N-aryloxycarbonylamino group, an N-aryl-N-alkoxycarbonylamino group, an N-aryl-N-aryloxycarbonylamino group, a formyl group, an acyl group, a carboxyl group, a carbamoyl group, an alkylsulfinyl group, an arylsulfinyl group, an alkylsulfonyl group, an arylsulfonyl group, a sulfo group (—SO₃H) and a conjugate base group thereof (referred to as a “sulfonato group”), an alkoxysulfonyl group, an aryloxysulfonyl group, a sulfinamoyl group, a phosphono group (—PO₃H₂) and a conjugate base group thereof (referred to as “phosphonato group”), a phosphonoxy group (—OPO₃H₂) and a conjugate base group thereof (referred to as “phosphonatoxy group”), a cyano group, a nitro group, an aryl group, an alkenyl group, an alkynyl group, a heterocyclic group, a silyl group, a cycloalkyl group, and an alkyl group.

Among these substituents, a halogen atom, an alkyl group, an aliphatic cyclic group, an alkoxycarbonyl group and an alkoxy group are preferred. Examples of the alkyl group and aliphatic cyclic group here are the same as those described above for R₁.

R₂ represents a hydrogen atom, an alkyl group, an alkoxy group, an alkenyl group, an aliphatic cyclic group, an aromatic hydrocarbon group, a heterocyclic group, a cyano group or an alkoxycarbonyl group.

The alkyl group represented by R₂ may be linear or branched. The carbon umber of the alkyl group is preferably from 1 to 50, more preferably from 1 to 30, still more preferably from 1 to 20. This alkyl group includes, for example, a methyl group, an ethyl group, a propyl group, a butyl group, a hexyl group, an octyl group, a decyl group, a dodecyl group, an octadecyl group, an isopropyl group, an isobutyl group, a sec-butyl group, a tert-butyl group, a 1-ethylpentyl group, and a 2-ethylhexyl group.

The alkoxy group represented by R₂ is linear or branched and is preferably an alkoxy group having a carbon number of 1 to 10, and examples thereof include a methoxy group, an ethoxy group, an n-propoxy group, an i-propoxy group, an n-butoxy group, a 2-methylpropoxy group, a 1-methylpropoxy group, a tert-butoxy group, an n-pentyloxy group, a neopentyloxy group, an n-hexyloxy group, an n-heptyloxy group, an n-octyloxy group, a 2-ethylhexyloxy group, an n-nonyloxy group, and an n-decyloxy group. Among these alkoxy groups, a methoxy group and an ethoxy group are preferred.

The alkenyl group represented by R₂ may be linear or branched. The carbon number of the alkenyl group is preferably from 2 to 50, more preferably from 2 to 30, still more preferably from 3 to 20. This alkenyl group includes, for example, a vinyl group, an allyl group, and a styryl group.

The aliphatic cyclic group represented by R₂ is, for example, a cycloalkyl group. The cycloalkyl group may be monocyclic or polycyclic. This aliphatic cyclic group is preferably a monocyclic cycloalkyl group having a carbon number of 3 to 8, such as cyclopropyl group, cyclopentyl group and cyclohexyl group.

As the aromatic hydrocarbon group represented by R₂, those having a carbon number of 6 to 14 are preferred. Such a group includes, for example, an aryl group such as phenyl group and naphthyl group. The aromatic hydrocarbon group represented by R₁ is preferably a phenyl group.

The heterocyclic group represented by R₂ may have aromaticity or may not have aromaticity. This heterocyclic group preferably has aromaticity.

The heterocyclic ring contained in the group above may be monocyclic or polycyclic. This heterocyclic ring includes, for example, an imidazole ring, a pyridine ring, a pyrazine ring, a pyrimidine ring, a pyridazine ring, a 2H-pyrrole ring, a 3H-indole ring, a 1H-indazole ring, a purine ring, an isoquinoline ring, a 4H-quinolidine ring, a quinoline ring, a phthalazine ring, a naphthylidine ring, a quinoxaline ring, a quinoxazoline ring, a cinnoline ring, a pteridine ring, a phenanthridine ring, an acridine ring, a phenanthroline ring, a phenazine ring, a perimidine ring, a triazine ring, a benzisoquinoline ring, a thiazole ring, a thiadiazine ring, an azepine ring, an azocine ring, an isothiazole ring, an isoxazole ring, and a benzothiazole ring.

The alkoxycarbonyl group represented by R₂ includes, for example, a linear, branched or cyclic alkoxycarbonyl group having a carbon number of 2 to 21, such as methoxycarbonyl group, ethoxycarbonyl group, n-propoxycarbonyl group, i-propoxycarbonyl group, n-butoxycarbonyl group, 2-methylpropoxycarbonyl group, 1-methylpropoxycarbonyl group, tert-butoxycarbonyl group, cyclopentyloxycarbonyl group and cyclohexyloxycarbonyl.

R₂ is preferably a hydrogen atom or an alkyl group.

The groups represented by R₂ may further have a substituent and in this case, examples of the substituent are the same as those described above for Rₜ.

As described above, R₃ represents an alkylene group where one or more —CH₂— groups may be substituted with an ether group, a carbonyl group, an ester group, an amide group, a urethane group or a urea group, and the alkylene group preferably has a carbon number of 1 to 10, more preferably a carbon number of 2 to 6, still more preferably a carbon number of 3 or 4. This alkylene group includes a propylene group, a butylene group, an a pentylene group. Here, in the case where one or more —CH₂— groups in the alkylene group are substituted with an ether group, a carbonyl group, an ester group, an amide group, a urethane group or a urea group, the preferred carbon number above of the alkyl group is the carbon number in the state of one or more —CH₂— groups being substituted with the above-described group.

The groups represented by R₃ may further have a substituent and in this case, examples of the substituent are the same as those described above for R₁.

R₃ is preferably an unsubstituted alkylene group, among others.

As described above, R₄ represents an alkyl group, an alkenyl group, an aliphatic cyclic group, an arylcarbonylalkyl group, an aryloxycarbonylalkyl group or an alkoxycarbonylalkyl group.

The alkyl group represented by R₄ may be linear or branched. The carbon umber of the alkyl group is preferably from 1 to 50, more preferably from 1 to 30, still more preferably from 1 to 20. This alkyl group includes, for example, a methyl group, an ethyl group, a propyl group, a butyl group, a hexyl group, an octyl group, a decyl group, a dodecyl group, an octadecyl group, an isopropyl group, an isobutyl group, a sec-butyl group, a tert-butyl group, a 1-ethylpentyl group, and a 2-ethylhexyl group.

The alkenyl group represented by R₄ may be linear or branched. The carbon number of the alkenyl group is preferably from 2 to 50, more preferably from 2 to 30, still more preferably from 3 to 20. This alkenyl group includes, for example, a vinyl group, an allyl group, and a styryl group.

The aliphatic cyclic group represented by R₄ is, for example, a cycloalkyl group. The cycloalkyl group may be monocyclic or polycyclic. This aliphatic cyclic group is preferably a monocyclic cycloalkyl group having a carbon number of 3 to 8, such as cyclopropyl group, cyclopentyl group and cyclohexyl group.

The aryl group in the arylcarbonylalkyl group includes an aryl group having a carbon number of 6 to 14. Among others; a phenyl group and a naphthyl group are preferred. The alkyl group in the aryloxycarbonylalkyl group includes an alkyl group having a carbon number of 1 to 5. Among others, a methyl group and an ethyl group are preferred.

The aryl group in the aryloxycarbonylalkyl group includes an aryl group having a carbon number of 6 to 14. Among others, a phenyl group and a naphthyl group are preferred. The alkyl group in the aryloxycarbonylalkyl group includes an alkyl group having a carbon number of 1 to 5. Among others, a methyl group and an ethyl group are preferred.

As for the alkoxy group in the alkoxycarbonylalkyl group, the alkyl moiety in the alkoxy group may be linear, branched or cyclic. An alkoxy group having a carbon number of 1 to 10 is preferred. The alkyl group in the alkoxycarbonylalkyl group (that is, the alkyl group directly bonded to the carbonyl group) includes, for example, a linear, branched or cyclic alkyl group having a carbon number of 1 to 10 (preferably a carbon number of 1 to 6). Among others, a methyl group, an ethyl group, an isopropyl group and a cyclohexyl group are preferred.

The groups represented by R₄ may further have a substituent and in this case, examples of the substituent are the same as those described above for R₁.

R₄ is preferably an alkyl group, an aliphatic cyclic group or an alkoxycarbonylalkyl group (the carbon number of these groups is preferably from 1 to 12), more preferably an ethyl group, a propyl group or an alkoxycarbonylmethyl group.

The ring that may be formed by combining R₁ and R₂ with each other is preferably a 4-membered or higher ring, more preferably a 5- or 6-membered ring. Incidentally, the carbon atom constituting the ring (the carbon atom as a ring member) may be substituted with an oxo group (═O) (that is, may be a carbonyl carbon).

Y⁻ is preferably an organic acid anion and is preferably a sulfonate anion, an imidate anion or a methidate anion.

Also, Y⁻ is preferably a non-nucleophilic anion. Here, the non-nucleophilic anion is an anion having an extremely low ability of causing a nucleophilic reaction and is an anion capable of suppressing the decomposition with aging due to intramolecular nucleophilic reaction. Thanks to this anion, the aging stability of the composition according to the present invention is enhanced.

The non-nucleophilic anion as Y⁻ includes, for example, a sulfonate anion, a carboxylate anion, an imidate anion such as bis(alkylsulfonyl)imide anion, and a methidate anion such as tris(alkylsulfonyl)methyl anion.

The sulfonate anion includes, for example, an aliphatic sulfonate anion, an aromatic sulfonate anion, and a camphorsulfonate anion.

The carboxylate anion includes, for example, an aliphatic carboxylate anion, an aromatic carboxylate anion, and an aralkylcarboxylate anion.

The aliphatic moiety in the aliphatic sulfonate anion may be an alkyl group or a cycloalkyl group but is preferably an alkyl group having a carbon number of 1 to 30 or a cycloalkyl group having a carbon number of 3 to 30, and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group, and a bornyl group.

The aromatic group in the aromatic sulfonate anion is preferably an aryl group having a carbon number of 6 to 14, and examples thereof include a phenyl group, a tolyl group and a naphthyl group.

The alkyl group, cycloalkyl group and aryl group in the aliphatic sulfonate anion and aromatic sulfonate anion may have a substituent. The substituent on the alkyl group, cycloalkyl group and aryl group in the aliphatic sulfonate anion and aromatic sulfonate anion includes, for example, a nitro group, a halogen atom (fluorine atom, chlorine atom, bromine atom, iodine atom), a carboxy group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7), an alkylthio group (preferably having a carbon number of 1 to 15), an alkylsulfonyl group (preferably having a carbon number of 1 to 15), an alkyliminosulfonyl group (preferably having a carbon number of 1 to 15), an aryloxysulfonyl group (preferably having a carbon number of 6 to 20), an alkylaryloxysulfonyl group (preferably having a carbon number of 7 to 20), a cycloalkylaryloxysulfonyl group (preferably having a carbon number of 10 to 20), an alkyloxyalkyloxy group (preferably having a carbon number of 5 to 20), and a cycloalkylalkyloxyalkyloxy group (preferably having a carbon number of 8 to 20). As for the aryl group and ring structure in each group, the substituent thereon further includes an alkyl group (preferably having a carbon number of 1 to 15).

The aliphatic moiety in the aliphatic carboxylate anion includes the same alkyl groups and cycloalkyl groups as in the aliphatic sulfonate anion.

The aromatic group in the aromatic carboxylate anion includes the same aryl groups as in the aromatic sulfonate anion.

The aralkyl group in the aralkylcarboxylate anion is preferably an aralkyl group having a carbon number of 7 to 12, and examples thereof include a benzyl group, a phenethyl group, a naphthylmethyl group, a naphthylethyl group and a naphthylbutyl group.

The alkyl group, cycloalkyl group, aryl group and aralkyl group in the aliphatic carboxylate anion, aromatic carboxylate anion and aralkylcarboxylate anion may have a substituent. The substituent in the aliphatic carboxylate anion, aromatic carboxylate anion and aralkylcarboxylate anion includes, for example, the same halogen atoms, alkyl groups, cycloalkyl groups, alkoxy groups and alkylthio groups as in the aromatic sulfonate anion.

The sulfonylimide anion includes, for example, saccharin anion.

The alkyl group in the bis(alkylsulfonyl)imide anion and tris(alkylsulfonyl)methyl anion is preferably an alkyl group having a carbon number of 1 to 5, and examples thereof include a methyl group, an ethyl group, a propyl group, an isopropyl group, an n-butyl group, an isobutyl group, a sec-butyl group, a pentyl group and a neopentyl group. Examples of the substituent on this alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with a fluorine atom-substituted alkyl group being preferred. An embodiment where two alkyl groups in the bis(alkylsulfonyl)imide anion are combined with each other to form a cyclic structure, is also preferred. In this case, the cyclic structure formed is preferably a 5- to 7-membered ring.

Other non-nucleophilic anions include, for example, fluorinated phosphorus, fluorinated boron and fluorinated antimony.

The non-nucleophilic anion of Y⁻ is preferably an aliphatic sulfonate anion substituted with a fluorine atom at the α-position of the sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having a carbon number of 4 to 8 or a fluorine atom-containing benzenesulfonate anion, still more preferably nonafluorobutanesulfonate anion, perfluorooctanesulfonate anion, pentafluorobenzenesulfonate anion or 3,5-bis(trifluoromethyl)benzenesulfonate anion.

The non-nucleophilic anion of Y⁻ is preferably represented, for example, by the following formula (LD1):

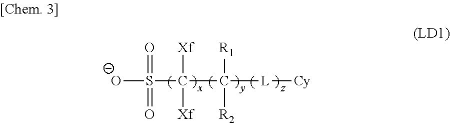

In the formula, each Xf independently represents a fluorine atom or an alkyl group substituted with at least one fluorine atom.

Each of R₁ and R₂ independently represents a hydrogen atom, a fluorine atom or an alkyl group, and when a plurality of R₁ or R₂ are present, each may be the same as or different from every other member.

L represents a divalent linking group, and when a plurality of L are present, each may be the same as or different from every other member.

Cy represents a cyclic organic group.

x represents an integer of 1 to 20.

y represents an integer of 0 to 10.

z represents an integer of 0 to 10.

Xf represents a fluorine atom or an alkyl group substituted with at least one fluorine atom. The carbon number of the alkyl group is preferably from 1 to 10, more preferably from 1 to 4. Also, the alkyl group substituted with at least one fluorine atom is preferably a perfluoroalkyrl group.

Xf is preferably a fluorine atom or a perfluoroalkyl group having a carbon number of 1 to 4. More specifically, Xf is preferably a fluorine atom, CF₃, C₂F₅, C₃F₇, CF₉, C₅F₁₁, C₆F₁₃, C₇F₁₅, C₅F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ or CH₂CH₂C₄F₉, preferably a fluorine atom or CF₃. In particular, it is preferred that both Xf are a fluorine atom.

Each of R₁ and R₂ independently represents a hydrogen atom, a fluorine atom or an alkyl group. This alkyl group may have a substituent (preferably a fluorine atom) and is preferably an alkyl group having a carbon number of 1 to 4, more preferably a perfluoroalkyl group having a carbon number of 1 to 4. Specific examples of the alkyl group having a substituent of R₁ and R₂ include CF₃, C₂F₅, C₃F₇, C₄F₉, C₅F₁₁, C₆F₁₃, C₇F₁₅, C₅F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, with CF₃ being preferred.

Each of R¹ and R² is preferably a fluorine atom or CF₃.

L represents a divalent linking group. The divalent linking group includes, for example, —COO—, —OCO—, —CONH—, —CO—, —O—, —S—, —SO—, —SO₂—, an alkylene group (preferably having a carbon number of 1 to 10), a cycloalkylene group (preferably having a carbon number of 3 to 30), an alkenylene group (preferably having a carbon number of 1 to 10), and a group formed by combining a plurality of these members. Among these, —COO-alkylene group-, —OCO-alkylene group-, —CONH-alkylene group-, —O-alkylene group-, —CONH—, —CO— and —SO₂— are preferred, and —COO-alkylene group-, —OCO-alkylene group-, —CONH— and —SO₂— are more preferred. The alkylene group in the —COO-alkylene group- and —OCO-alkylene group- is preferably a methylene group, among others. The groups above may have a substituent and in this case, examples of the substituent are the same as those described above for R₁.

Cy represents a cyclic organic group. The cyclic organic group includes, for example, an alicyclic group, an aryl group, and a heterocyclic group.

The alicyclic group may be monocyclic or polycyclic. The monocyclic alicyclic group includes, for example, a monocyclic cycloalkyl group such as cyclopentyl group, cyclohexyl group and cyclooctyl group. The polycyclic alicyclic group includes, for example, a polycyclic cycloalkyl group such as norbornyl group, tricyclodecanyl group, tetracyclodecanyl group, tetracyclododecanyl group and adamantyl group. Above all, an alicyclic group having a bulky structure with a carbon number of 7 or more, such as norbornyl group, tricyclodecanyl group, tetracyclodecanyl group, tetracyclododecanyl group and adamantyl group, is preferred from the standpoint of suppressing the in-film diffusion during PEB (post-exposure baking) and enhancing MEEF (Mask Error Enhancement Factor). Cy is preferably an adamantyl group, among others.

The aryl group may be monocyclic or polycyclic. This aryl group includes, for example, a phenyl group, a naphthyl group, a phenanthryl group, and an anthryl group. Among others, a naphthyl group having a relatively low absorbance at 193 nm is preferred.

The heterocyclic group may be monocyclic or polycyclic, but a polycyclic heterocyclic group can more suppress the diffusion of acid. Also, the heterocyclic group may have aromaticity or may not have aromaticity. The heterocyclic ring having aromaticity includes, for example, a furan ring, a thiophene ring, a benzofuran ring, a benzothiophene ring, a dibenzofuran ring, a dibenzothiophene ring, a pyridine ring, and a piperidine ring. The heterocyclic ring not having aromaticity includes, for example, a tetrahydropyran ring, a lactone ring, and a decahydroisoquinoline ring. The heterocyclic ring in the group having a heterocyclic structure is preferably a furan ring, a thiophene ring, a pyridine ring or a decahydroisoquinoline ring, among others. Examples of the lactone ring include lactone structures exemplified later in the resin (A).

The above-described cyclic organic group may have a substituent, and the substituent includes, for example, an alkyl group, a cycloalkyl group, an aryl group, a hydroxy group, an alkoxy group, an ester group, an amide group, a urethane group, a ureido group, a thioether group, a sulfonamide group, and a sulfonic acid ester group. The alkyl group may be linear or branched. Also, the alkyl group preferably has a carbon number of 1 to 12. The cycloalkyl group may be monocyclic or polycyclic. Also, the cycloalkyl group preferably has a carbon number of 3 to 12. The aryl group preferably has a carbon number of 6 to 14. Incidentally, the carbon constituting the cyclic organic group (the carbon contributing to ring formation) may be a carbonyl carbon.

x is preferably 1 to 8, more preferably 1 to 4, still more preferably 1. y is preferably 0 to 4, more preferably 0. z is preferably 0 to 8, more preferably 0 to 4.

The non-nucleophilic anion of Y⁻ is also preferably represented, for example, by the following formula (LD2):

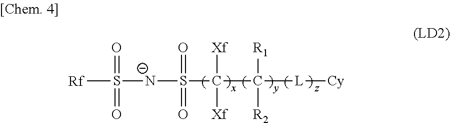

In formula (LD2), Xf, R₁, R₂, L, Cy, x, y and z have the same meanings as respective members in formula (LD1). Rf is a fluorine atom-containing group.

The fluorine atom-containing group represented by Rf includes, for example, an alkyl group having at least one fluorine atom, a cycloalkyl group having at least one fluorine atom, and an aryl group having at least one fluorine atom.

The alkyl group, cycloalkyl group and aryl group may be substituted with a fluorine atom or may be substituted with another fluorine atom-containing substituent. In the case where Rf is a cycloalkyl group having at least one fluorine atom or an aryl group having at least one fluorine atom, the another fluorine-containing substituent includes, for example, an alkyl group substituted with at least one fluorine atom.

Also, the alkyl group, cycloalkyl group and aryl group may be further substituted with a fluorine atom-free substituent. This substituent includes, for example, those not containing a fluorine atom out of the substituents described above for Cy.

Examples of the alkyl group having at least one fluorine atom represented by Rf are the same as those described above as the alkyl group substituted with at least one fluorine atom represented by Xf. The cycloalkyl group having at least one fluorine atom represented by Rf includes, for example, a perfluorocyclopentyl group and a perfluorocyclohexyl group. The aryl group having at least one fluorine atom represented by Rf includes, for example, a perfluorophenyl group.

Specific examples of the cation moiety in the compound (A) are illustrated below, but the present invention is not limited thereto.

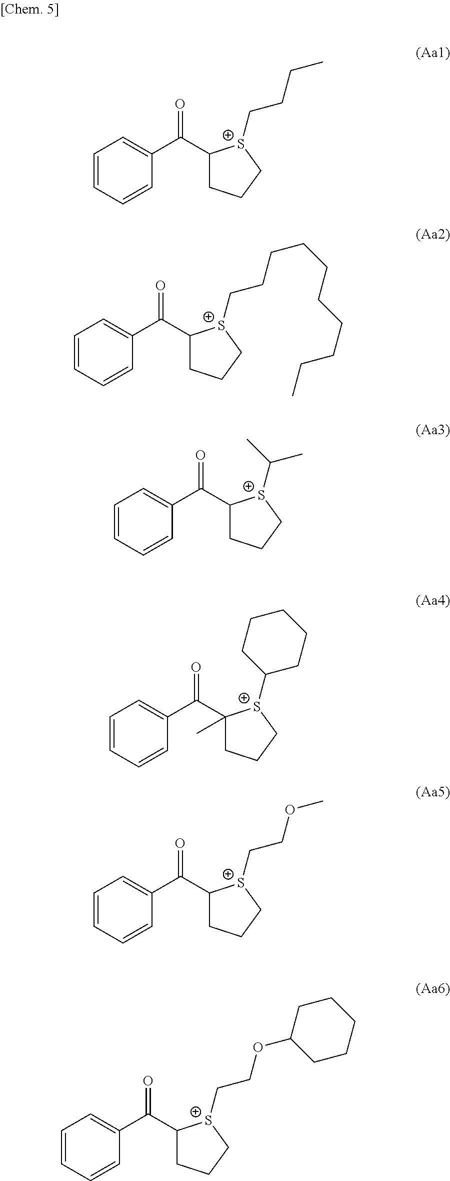 [SMILES: CCCC[S+]1CCCC1C(=O)c1ccccc1 ; CCCCCCCCCC[S+]1CCCC1C(=O)c1ccccc1 ; CC(C)[S+]1CCCC1C(=O)c1ccccc1 ; CC1(C(=O)c2ccccc2)CCC[S+]1C1CCCCC1 ; COCC[S+]1CCCC1C(=O)c1ccccc1 ; O=C(c1ccccc1)C1CCC[S+]1CCOC1CCCCC1]

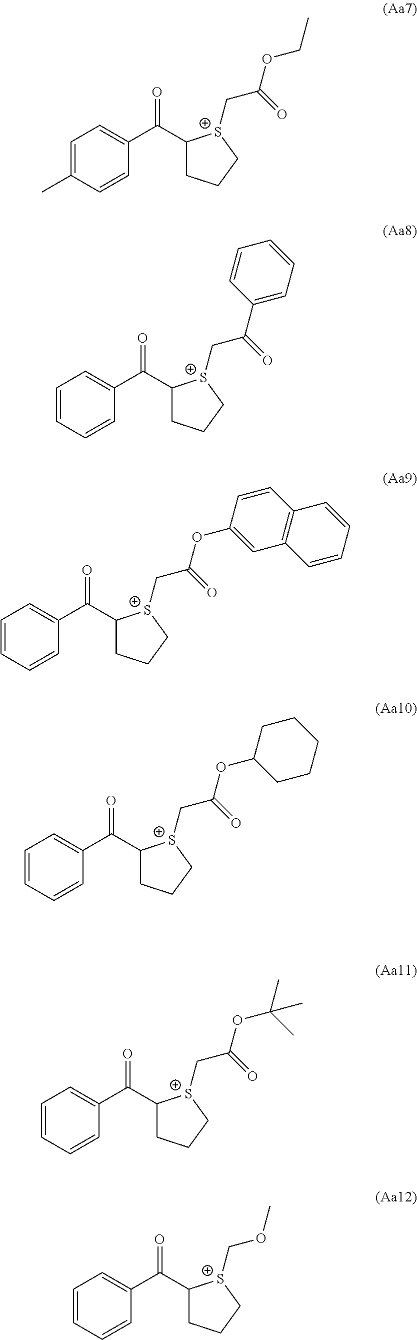 [SMILES: CCOC(=O)C[S+]1CCCC1C(=O)c1ccc(C)cc1 ; O=C(C[S+]1CCCC1C(=O)c1ccccc1)c1ccccc1 ; O=C(C[S+]1CCCC1C(=O)c1ccccc1)Oc1ccc2ccccc2c1 ; O=C(C[S+]1CCCC1C(=O)c1ccccc1)OC1CCCCC1 ; CC(C)(C)OC(=O)C[S+]1CCCC1C(=O)c1ccccc1 ; COC[S+]1CCCC1C(=O)c1ccccc1]

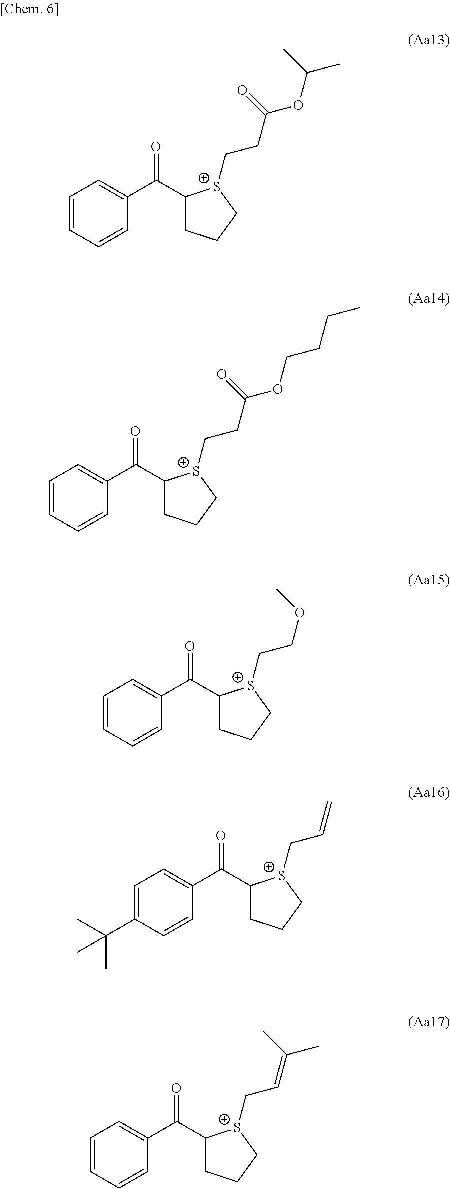

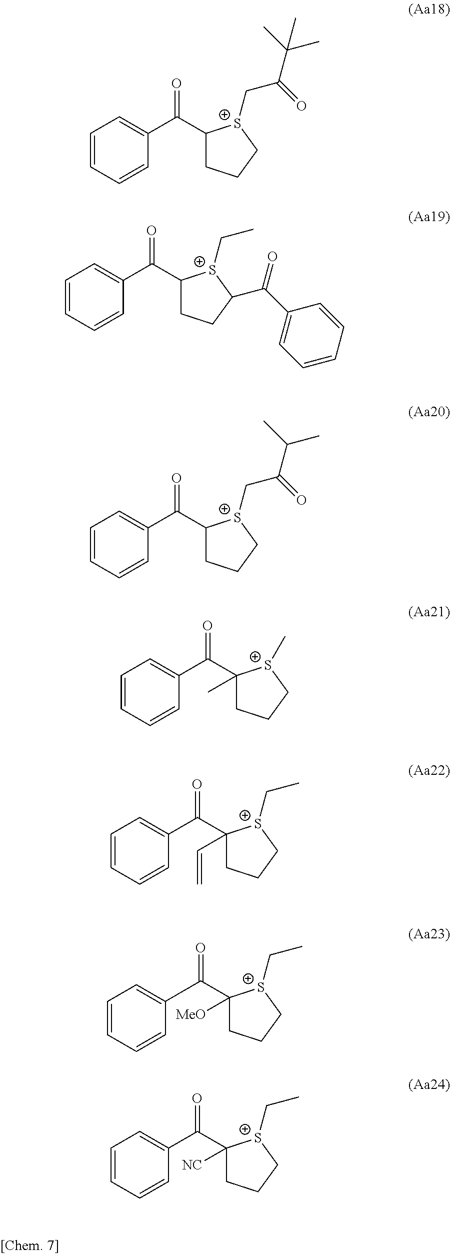

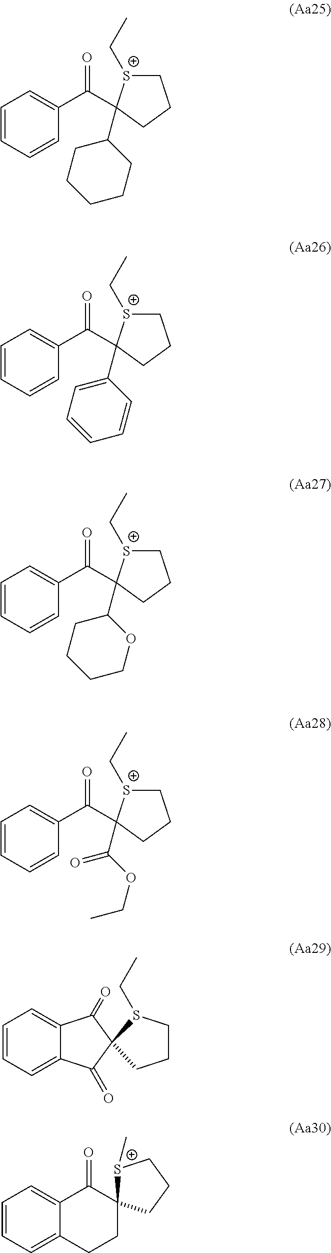

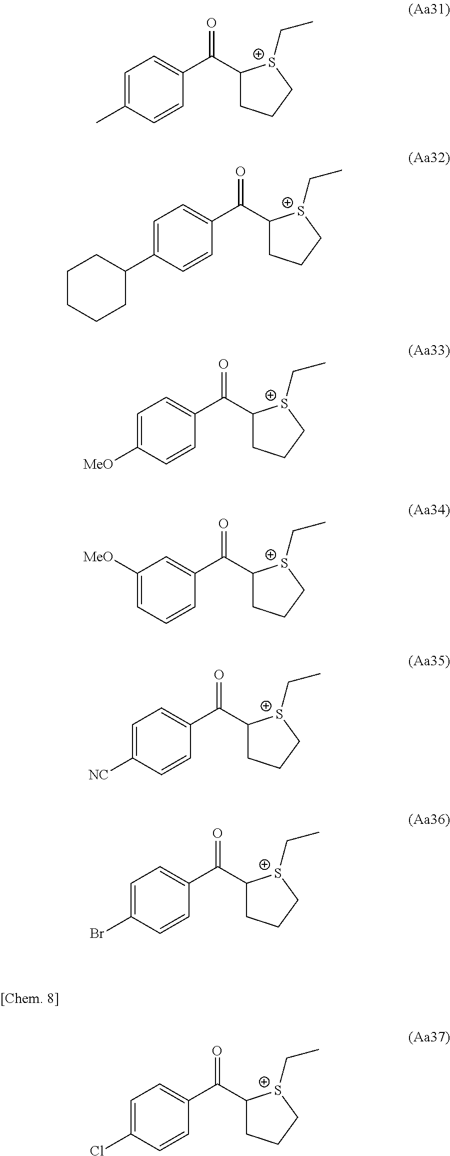

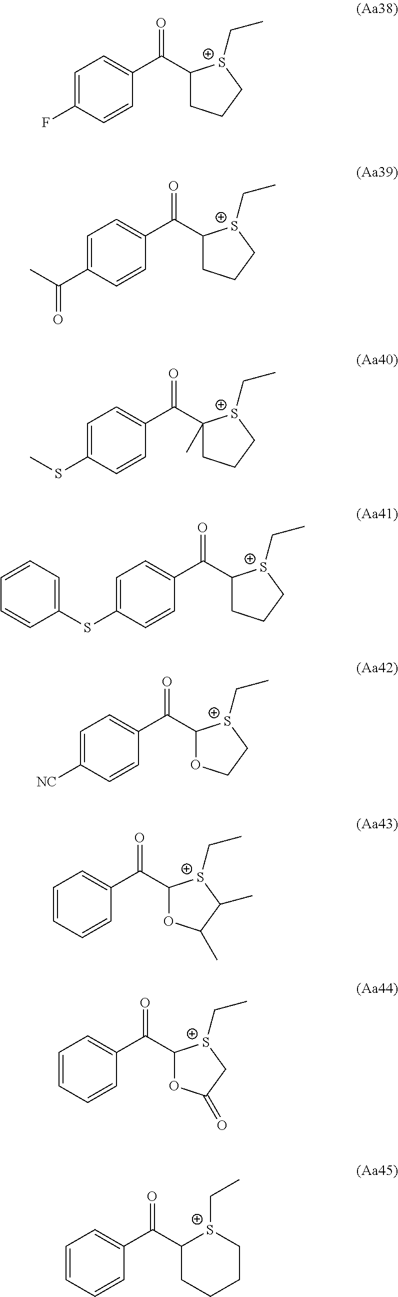

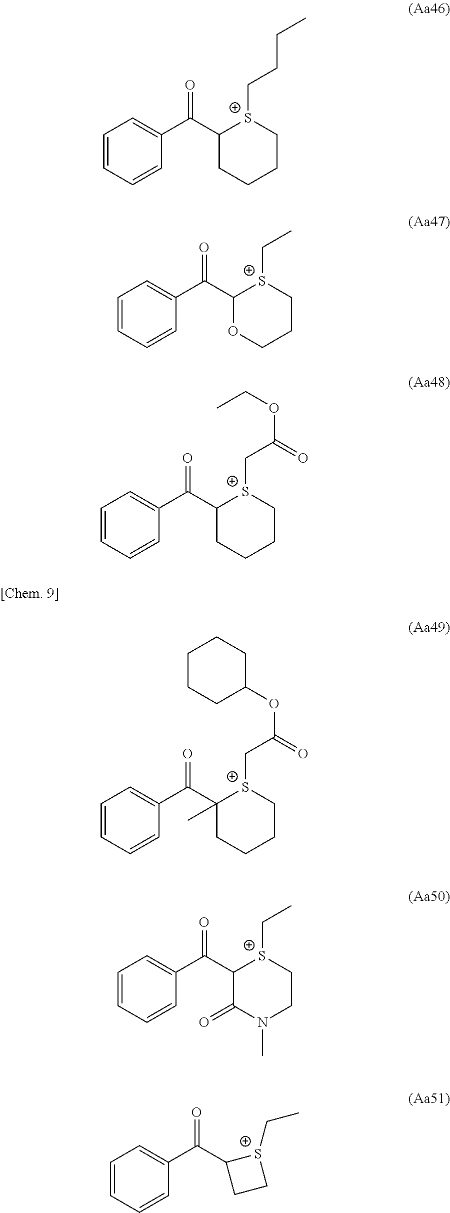 [SMILES: CCCC[S+]1CCCCC1C(=O)c1ccccc1 ; CC[S+]1CCCOC1C(=O)c1ccccc1 ; CCOC(=O)C[S+]1CCCCC1C(=O)c1ccccc1 ; CC1(C(=O)c2ccccc2)CCCC[S+]1CC(=O)OC1CCCCC1 ; CC[S+]1CCN(C)C(=O)C1C(=O)c1ccccc1 ; CC[S+]1CCC1C(=O)c1ccccc1]

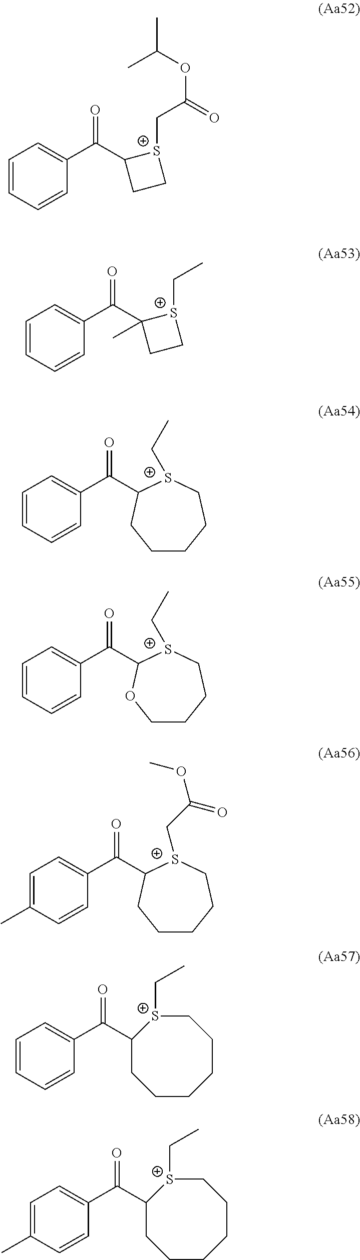

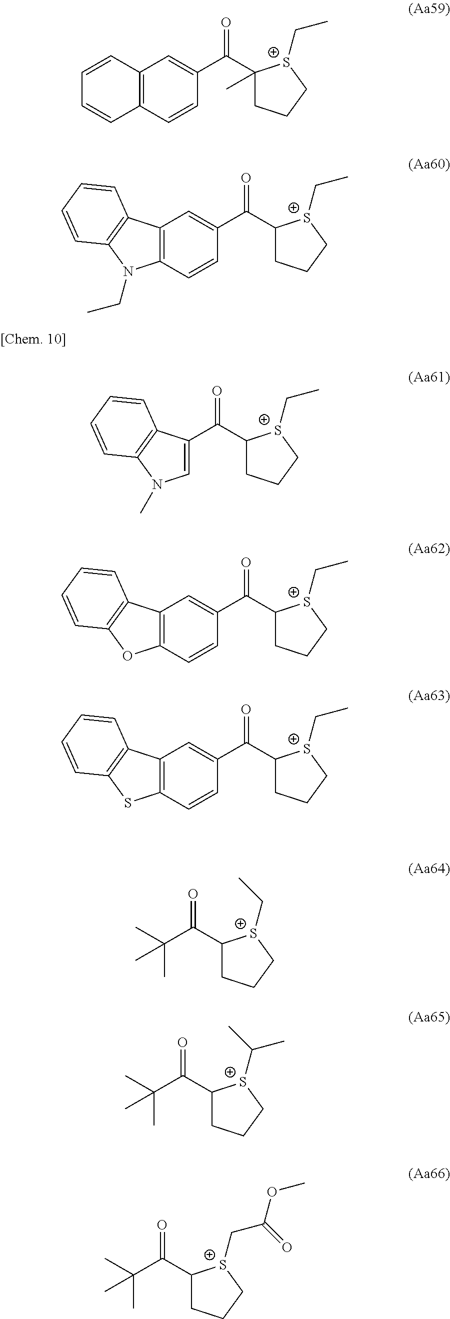

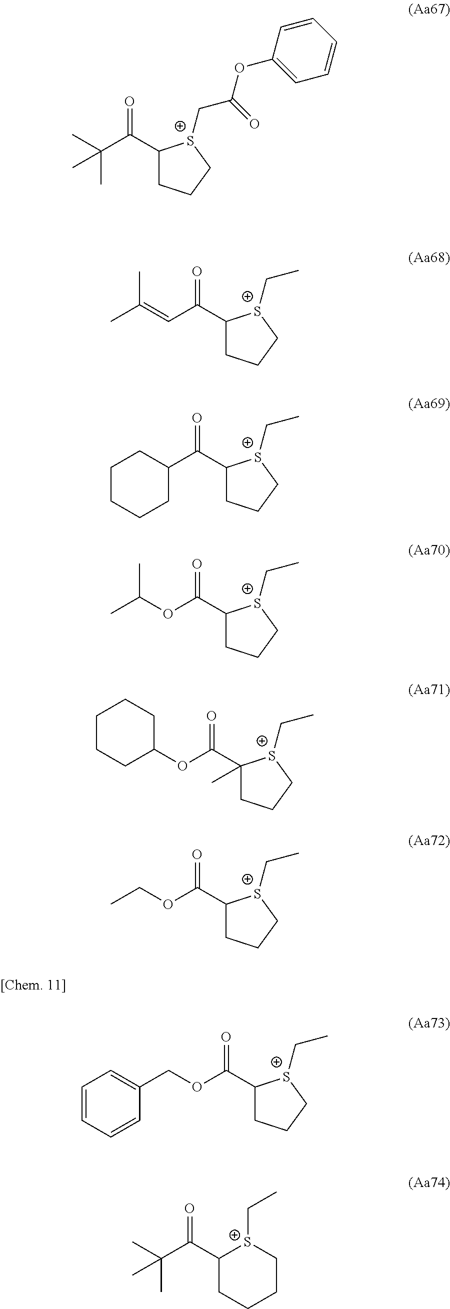

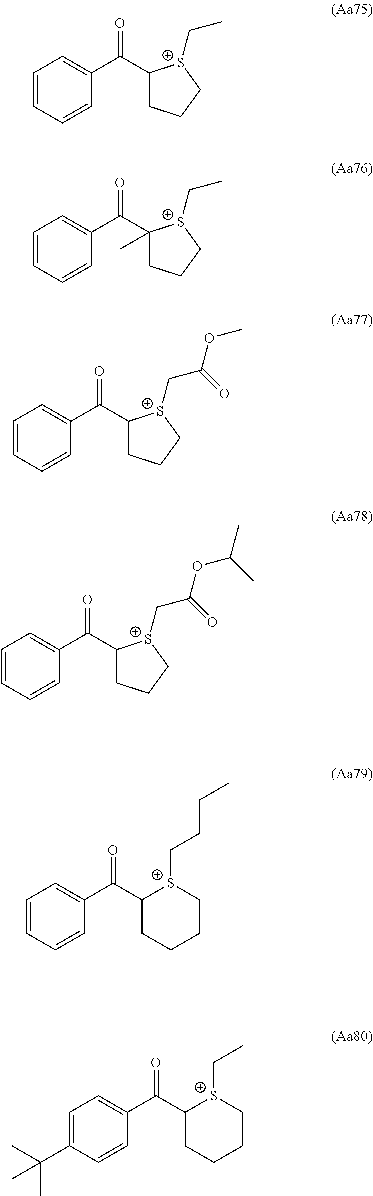

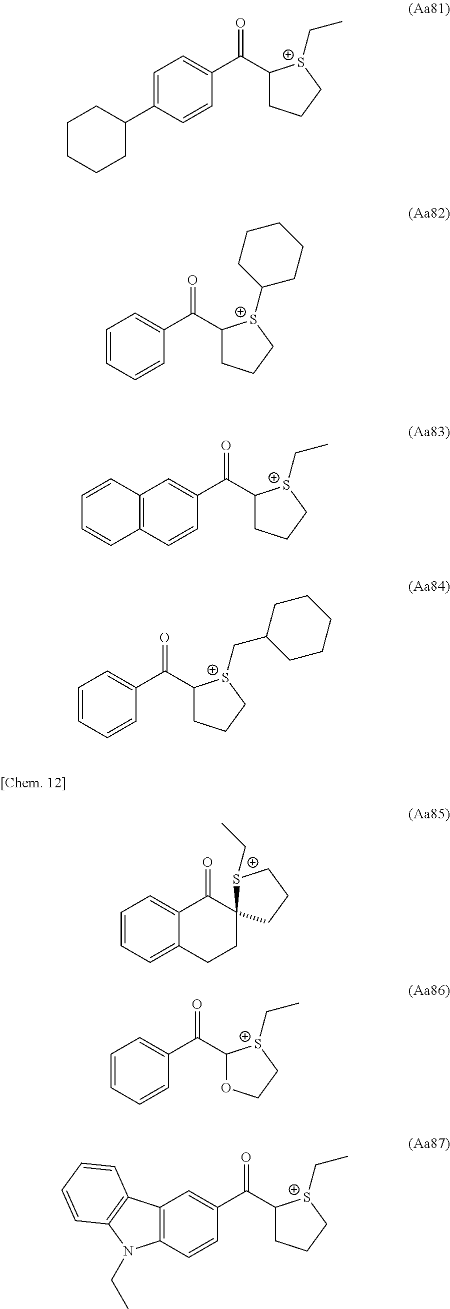

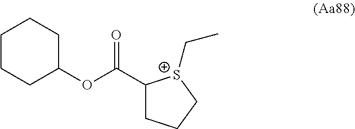 [SMILES: CC[S+]1CCCC1C(=O)OC1CCCCC1]

The production method for the compound represented by formula (1-1) is not particularly limited, but the compound is synthesized, for example, by reacting a compound represented by the following formula (2) and a compound represented by the following formula (3) as seen in the synthesis scheme below.

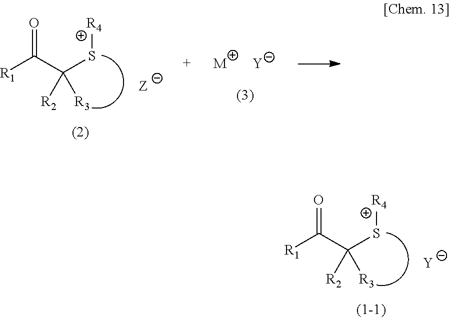

In formula (2), Z⁻ is, for example, bromine ion, chlorine ion, iodine ion, sulfonic acid ion, BF₄⁻, AsF₆⁻, SbF₆⁻, PF₆⁻ or ClO₄⁻, preferably bromine ion, chlorine ion, sulfonic acid ion or carboxylic acid ion.

The sulfonic acid ion in Z⁻ includes, for example, a p-toluenesulfonic acid ion, a methanesulfonic acid ion, and a trifluoromethanesulfonic acid ion.

The carboxylic acid ion in Z⁻ includes, for example, trifluoroacetic acid ion and acetic acid ion.

In formula (3), M⁺ is, for example, an alkali metal ion. The alkali metal ion includes, for example, sodium ion, lithium ion, and potassium ion.

R₁, R₂, R₃, R₄ and Y⁻ in formulae (2) and (3) have the same meanings as R₁, R₂, R₃, R₄ and Y⁻, respectively, in formula (1-1).

The production method for the compound represented by formula (2) is not particularly limited, but specifically, for example, in the case of a sulfide compound represented by formula (4), the compound represented by formula (2) can be synthesized by reacting a compound represented by formula (4) and an alkyl halide represented by formula (5) in the presence of an activator as seen in the synthesis scheme below.

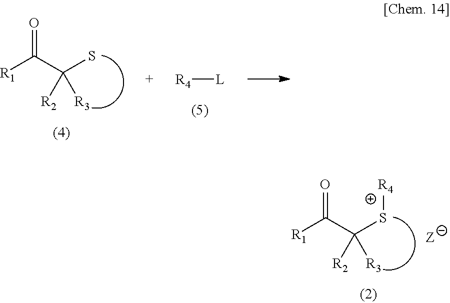

Here, the molar ratio of the compound represented by formula (5) to the compound represented by formula (4) is preferably from 1 to 100, more preferably from 1 to 10, still more preferably from 1 to 5.

The activating agent used for the reaction is preferably AgBF₄.

In formula (5), L represents a leaving group. The leaving group is preferably an iodine atom, a bromine atom, a chlorine atom, an arylsulfonyl group or an alkylsulfonyl group.

R₁, R₂, R₃ and R₄ in formulae (4) and (5) have the same meanings as R₁, R₂, R₃ and R₄, respectively, in formula (1-1).

This reaction is performed, for example, in an aprotic organic solvent such as tetrahydrofuran, acetonitrile, methylene chloride and chloroform. Among others, the reaction is preferably performed in acetonitrile or chloroform. The proportion of the organic solvent used is preferably from 2 to 100 parts by mass, more preferably from 5 to 100 parts by mass, still more preferably from 10 to 95 parts by mass, per 100 parts by mass of the total of the organic solvent and water.

The reaction temperature is preferably from −40° C. to 100° C., more preferably from −20° C. to 80° C., still more preferably from 0 to 80° C. Also, the reaction time is from 0.1 to 96 hours, more preferably from 0.5 to 24 hours.

The production method for the compound (4) represented by formula (4) is specifically described, for example, by referring to the case of using a sulfide compound represented by formula (6). In this case, the compound represented by formula (4) can be synthesized, for example, by reacting a compound represented by formula (6) in the presence of an appropriate base as seen in the synthesis scheme below.

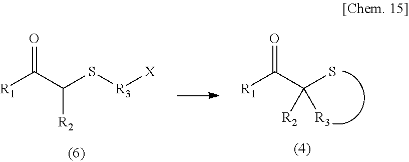

In formula (6), X represents a leaving group. The leaving group is preferably an iodine atom, a bromine atom, a chlorine atom, an arylsulfonyl group or an alkylsulfonyl group.

R₁, R₂ and R₃ in formula (6) have the same meanings as R₁, R₂ and R₃, respectively, in formula (1-1).

The base used for the reaction includes, for example, sodium hydride, tert-butoxy potassium, and lithium diisopropylamine. Among these, sodium hydride is preferred, because this has an appropriate basicity.

The reaction is performed, for example, in an aprotic organic solvent such as tetrahydrofuran, dimethylformamide, methylene chloride and NMP. Among others, the reaction is preferably performed in tetrahydrofuran or dimethylformamide. The proportion of the organic solvent used is preferably from 2 to 100 parts by mass, more preferably from 5 to 100 parts by mass, still more preferably from 10 to 95 parts by mass, per 100 parts by mass of the total of the organic solvent and water.

The reaction temperature is preferably from −40° C. to 100° C., more preferably from −20° C. to 80° C., still more preferably from 0 to 80° C. Also, the reaction time is from 0.1 to 96 hours, more preferably from 0.5 to 24 hours.

As a specific example of the production method for the compound represented by formula (6), the compound represented by formula (6) can be synthesized, for example, by reacting a compound represented by formula (7) and a compound represented by formula (8) in the presence of an appropriate base as seen in the synthesis scheme below.

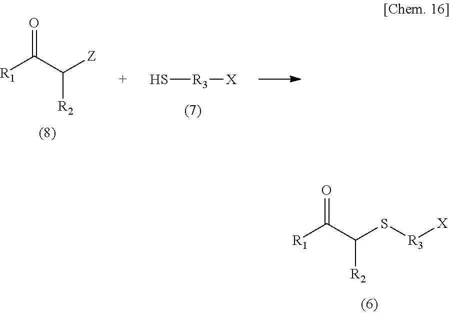

R₃ and X in formula (7) have the same meanings as R₃ and X, respectively, in formula (6).

In formula (8), Z represents a leaving group. The leaving group is preferably an iodine atom, a bromine atom or a chlorine atom.

R₁ and R₂ in formula (8) have the same meanings as R₁ and R₂, respectively, in formula (1-1).

Here, the molar ratio of the compound represented by formula (7) to the compound represented by formula (8) is preferably from 1 to 100, more preferably from 1 to 10, still more preferably from 1 to 5.

The base used for the reaction includes, for example, triethylamine, pyridine, sodium hydrogencarbonate, sodium carbonate, potassium carbonate, sodium hydride, and tert-butoxy potassium.

The reaction is performed, for example, in an aprotic organic solvent such as tetrahydrofuran, acetone, methyl ethyl ketone, acetonitrile, pyridine, NMP, methylene chloride and pyridine. Among others, the reaction is preferably performed in acetone, acetonitrile or tetrahydrofuran. The proportion of the organic solvent used is preferably from 2 to 100 parts by mass, more preferably from 5 to 100 parts by mass, still more preferably from 10 to 95 parts by mass, per 100 parts by mass of the total of the organic solvent and water.

The reaction temperature is preferably from −40° C. to 100° C., more preferably from −20° C. to 80° C., still more preferably from 0 to 80° C. Also, the reaction time is from 0.1 to 96 hours, more preferably from 0.5 to 24 hours.

As for the compound (A), one kind may be used alone, or two or more kinds may be used in combination.

The content of the compound (A) is preferably from 0.1 to 30.0 mass %, more preferably from 1.0 to 25.0 mass %, still more preferably from 2.0 to 25.0 mass %, based on the total solid content of the actinic ray-sensitive or radiation-sensitive resin composition.

Specific examples of the compound (A) are illustrated below, but the present invention is not limited thereto.

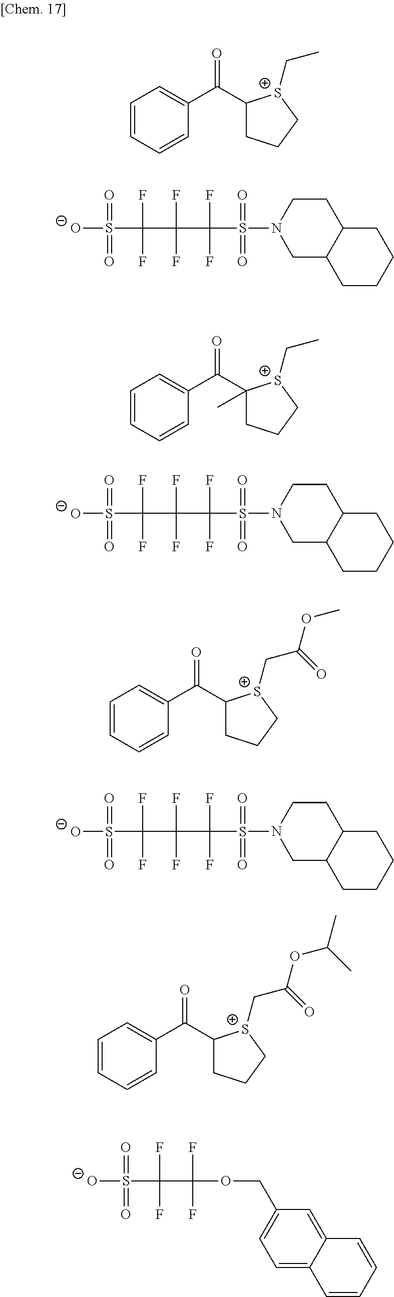

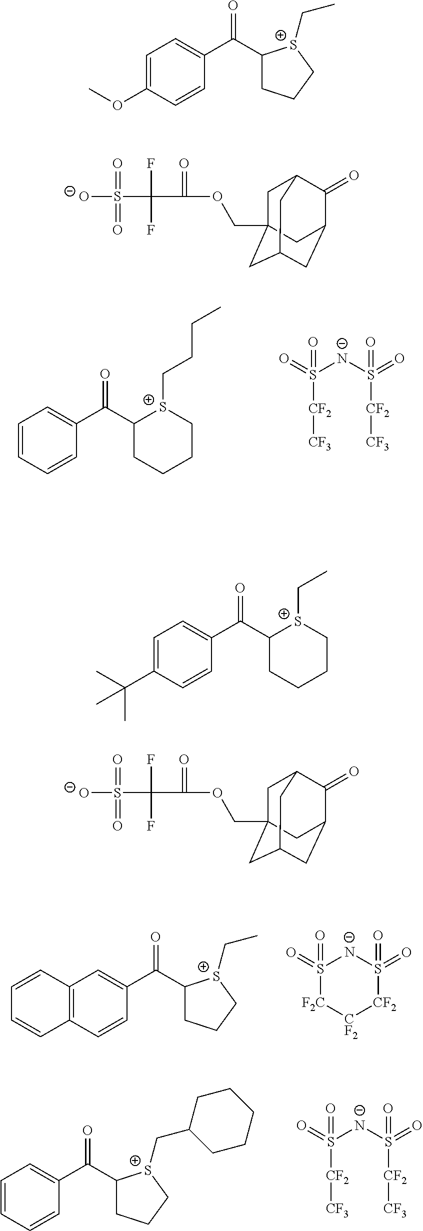

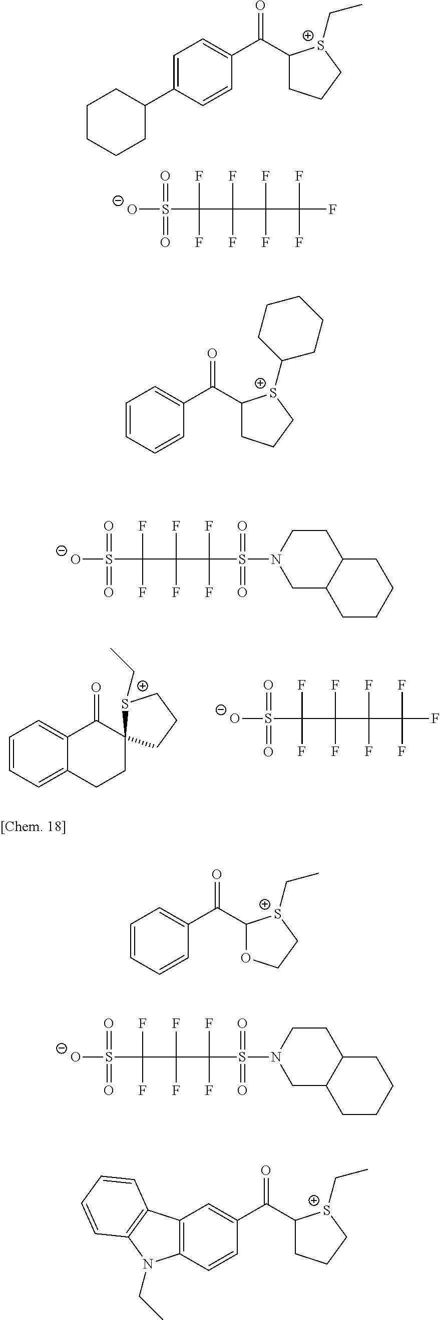

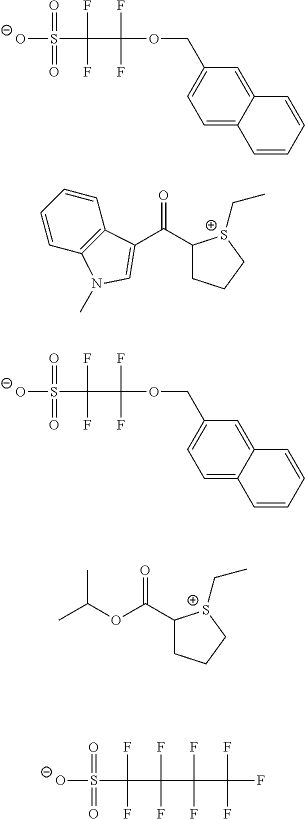

### [2](B) Resin Capable of Decomposing by an Action of an Acid to Increase the Solubility for an Alkali Developer

The actinic ray-sensitive or radiation-sensitive resin composition of the present invention preferably contains a resin capable of decomposing by an action of an acid to increase the solubility for an alkali developer (hereinafter, sometimes referred to as “acid-decomposable resin” or “resin (B)”).

The resin (B) has a group capable of decomposing by the action of an acid to produce an alkali-soluble group (hereinafter, sometimes referred to as an “acid-decomposable group”), in ether one or both of the main chain and the side chain of the resin.

The resin (B) is preferably insoluble or sparingly soluble in an alkali developer.

The acid-decomposable group preferably has a structure where an alkali-soluble group is protected by a group capable of decomposing and leaving by the action of an acid.

Examples of the alkali-soluble group include a phenolic hydroxyl group, a carboxyl group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Preferred alkali-soluble groups include a carboxyl group, a fluorinated alcohol group (preferably a hexafluoroisopropanol group), and a sulfonic acid group.

The group preferred as the acid-decomposable group is a group where a hydrogen atom of the alkali-soluble group above is substituted for by a group capable of leaving by the action of an acid.

The group capable of leaving by the action of an acid includes, for example, —C(R₃₆)(R₃₇)(R₃₈), —C(R₃₆)(R₃₇)(OR₃₉), and —C(R₀₁)(R₀₂)(OR₃₉).

In the formulae, each of R₃₆ to R₃₉ independently represents an alkyl group, a cycloalkyl group, an aryl group, an aralkyl group or an alkenyl group. R₃₆ and R₃₇ may combine with each other to form a ring.

Each of R₀₁ and R₀₂ independently represents a hydrogen atom, an alkyl group, a cycloalkyl group, an aryl group, an aralkyl group or an alkenyl group.

The acid-decomposable group is preferably a cumyl ester group, an enol ester group, an acetal ester group, a tertiary alkyl ester group or the like, more preferably a tertiary alkyl ester group.

The repeating unit having an acid-decomposable group, which may contained in the resin (B), is preferably a repeating unit represented by the following formula (AI):

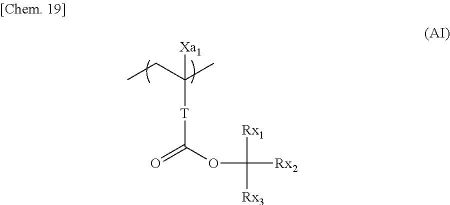

In formula (AI), Xa₁ represents a hydrogen atom, a methyl group which may have a substituent, or a group represented by —CH₂—R₉. R₉ represents a hydroxy group or a monovalent organic group and, for example, the monovalent organic group includes an alkyl group having a carbon number of 5 or less and an acyl group having a carbon number of 5 or less and is preferably an alkyl group having a carbon number of 3 or less, more preferably a methyl group. Xa₁ represents preferably a hydrogen atom, a methyl group, a trifluoromethyl group or a hydroxymethyl group.

T represents a single bond or a divalent linking group.

Each of Rx₁ to Rx₃ independently represents an alkyl group (linear or branched) or a cycloalkyl group (monocyclic or polycyclic).

Two members of Rx₁ to Rx₃ may combine to form a cycloalkyl group (monocyclic or polycyclic).

The divalent linking group of T includes an alkylene group, a —COO-Rt- group, a —O-Rt- group, and the like. In the formulae, Rt represents an alkylene group or a cycloalkylene group.

T is preferably a single bond or a —COO-Rt- group. Rt is preferably an alkylene group having a carbon number of 1 to 5, more preferably a —CH₂— group, —(CH₂)₂— group or a —(CH₂)₃— group.

The alkyl group of Rₓ₁ to Rx₃ is preferably an alkyl group having a carbon number of 1 to 4, such as methyl group, ethyl group, n-propyl group, isopropyl group, n-butyl group, isobutyl group and tert-butyl group.

The cycloalkyl group of Rx₁ to Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

The cycloalkyl group formed by combining two members of Rx₁ to Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group. A monocyclic cycloalkyl group having a carbon number of 5 to 6 is particularly preferred.

An embodiment where Rx₁ is a methyl group or an ethyl group and Rx₂ and Rx₃ are combined to form the above-described cycloalkyl group is preferred.

Each of the groups may have a substituent, and the substituent includes, for example, an alkyl group (having a carbon number of 1 to 4), a halogen atom, a hydroxyl group, an alkoxy group (having a carbon number of 1 to 4), a carboxyl group, and an alkoxycarbonyl group (having a carbon number of 2 to 6)). The carbon number is preferably 8 or less.

The total content of repeating units having an acid decomposable group is preferably from 15 to 70 mol %, more preferably from 20 to 60 mol %, based on all repeating units in the resin.

Specific preferred examples of the repeating unit having an acid-decomposable group are illustrated below, but the present invention is not limited thereto.

In specific examples, each of Rx and Xa₁ represents a hydrogen atom, CH₃, CF₃ or CH₂OH, and each of Rxa and Rxb represents an alkyl group having a carbon number of 1 to 4. Z represents a substituent containing a polar group, and when a plurality of Z are present, each may be the same as or different from every other member. p represents 0 or a positive integer. Specific examples and preferred examples of Z are the same as specific examples and preferred examples of R₁₀ in formula (II-1) described later.

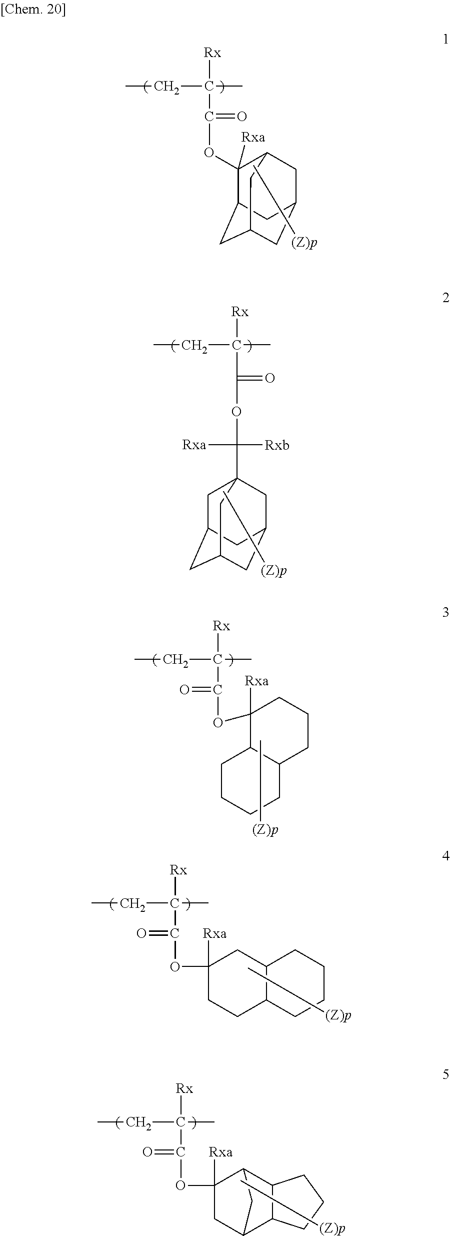

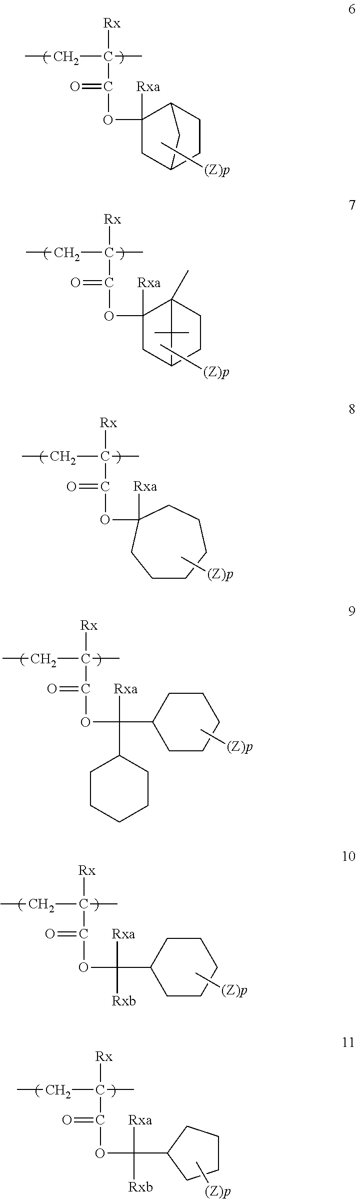

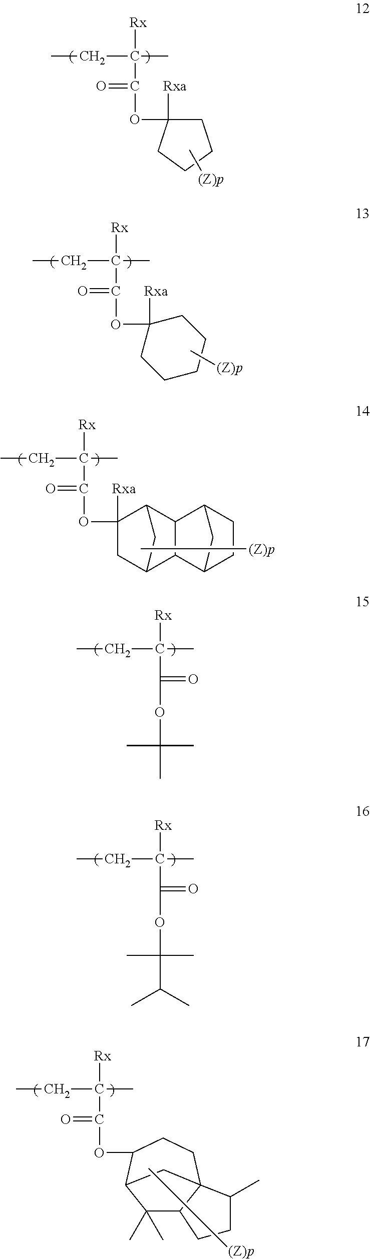

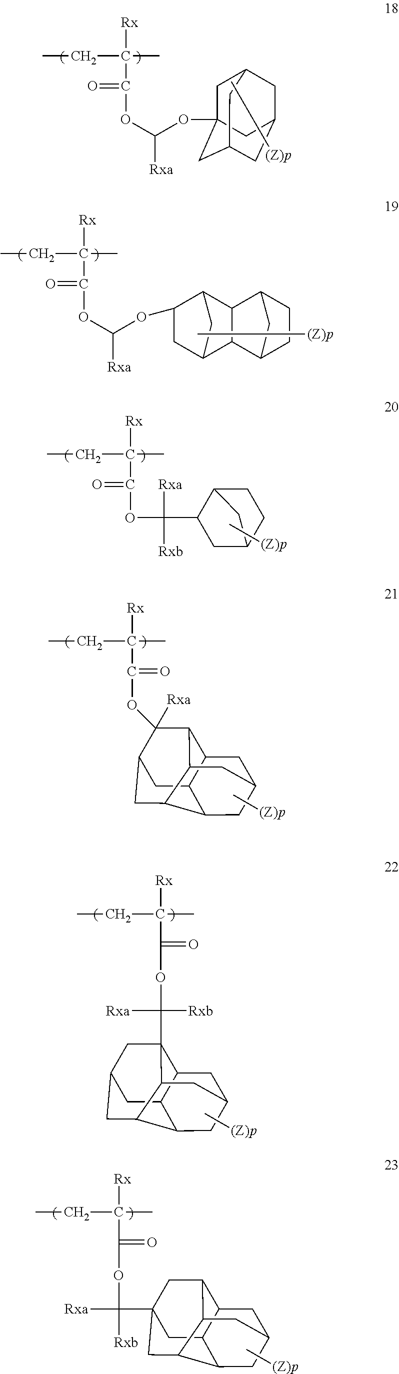

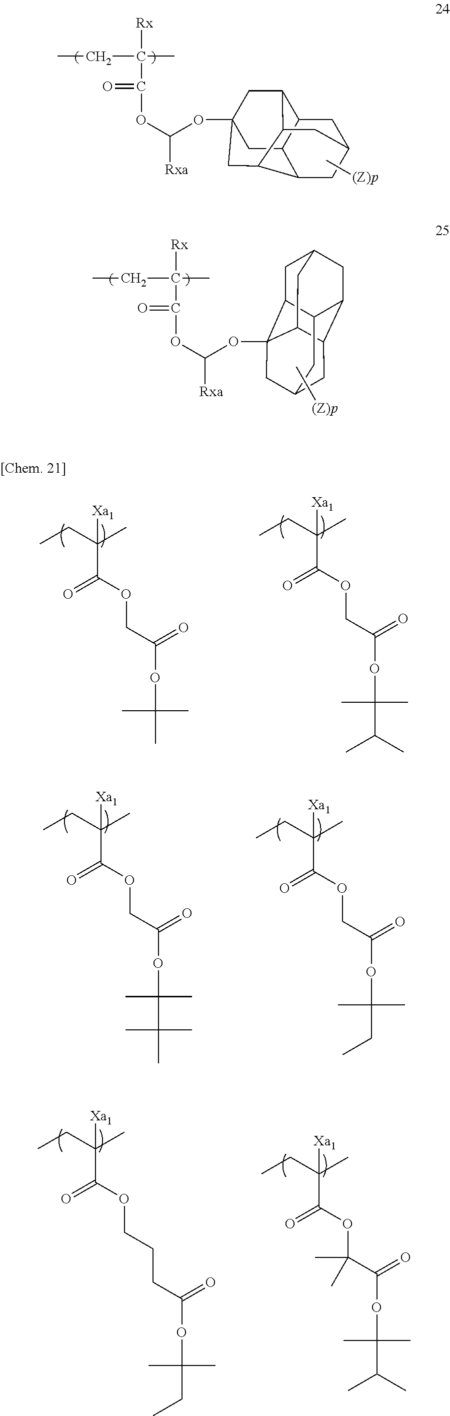

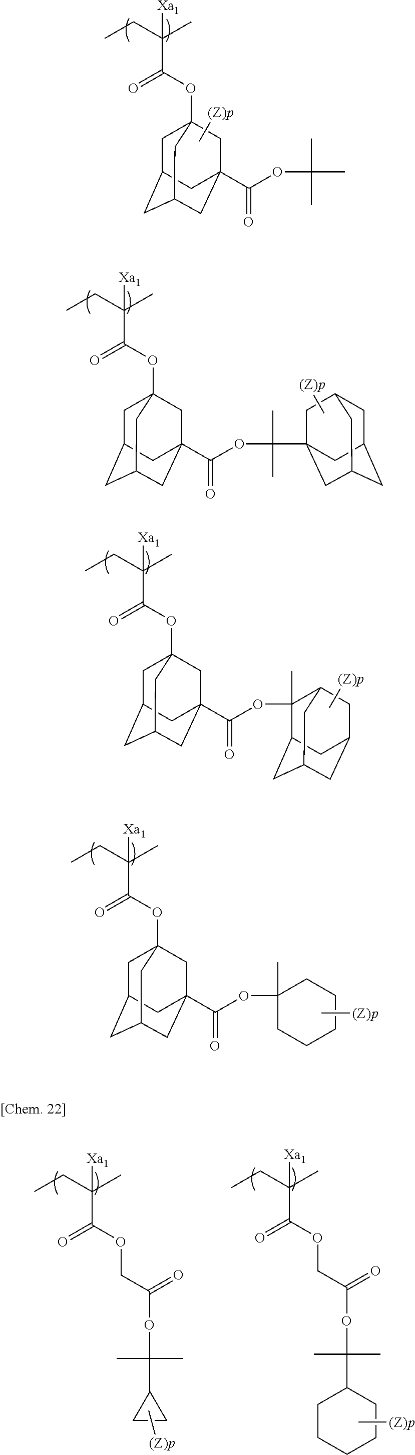

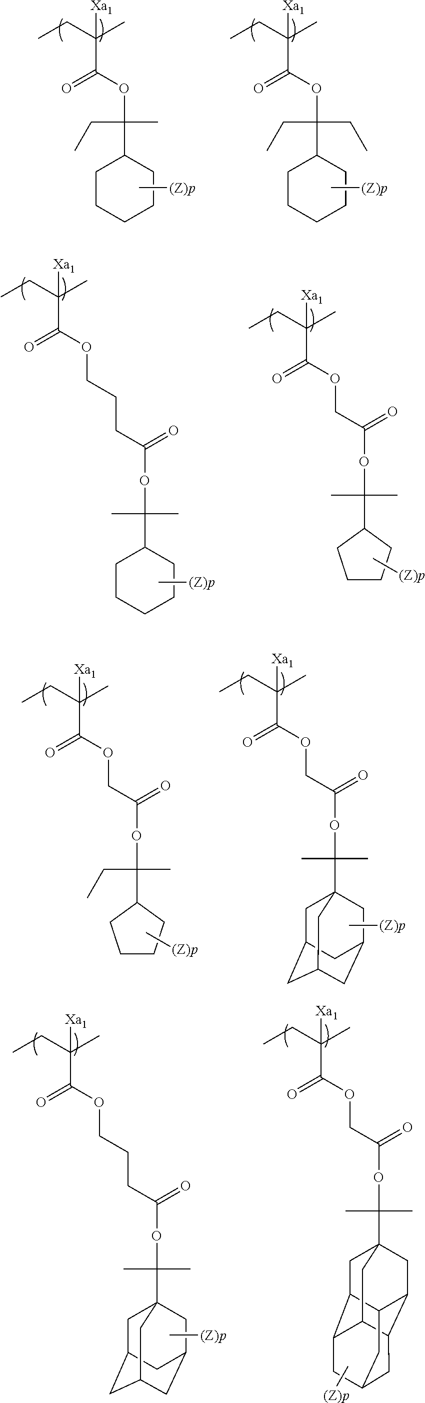

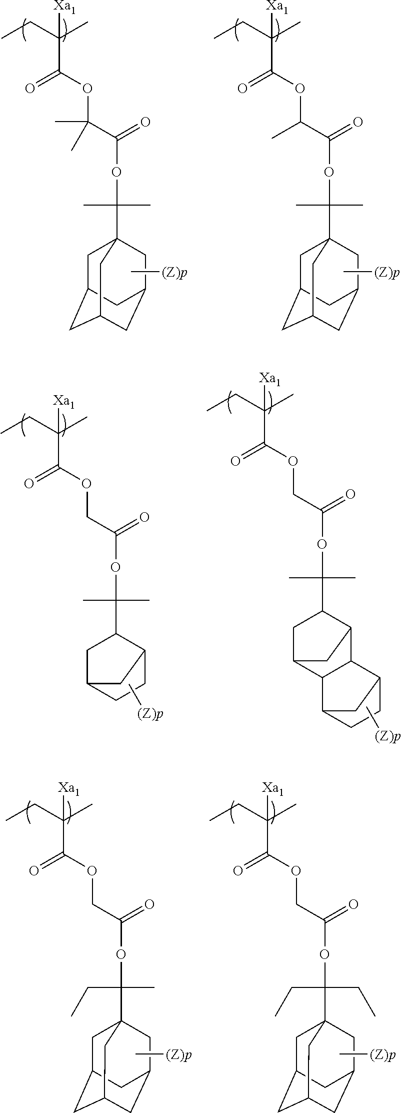

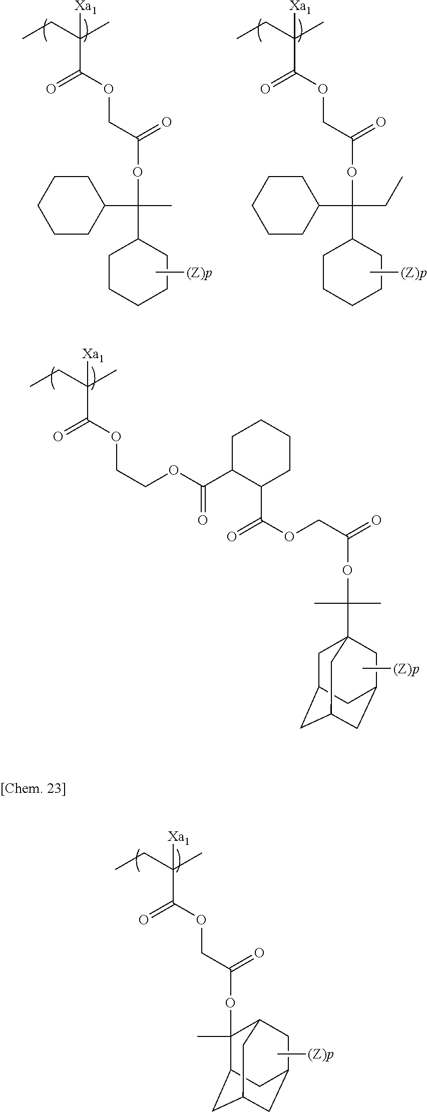

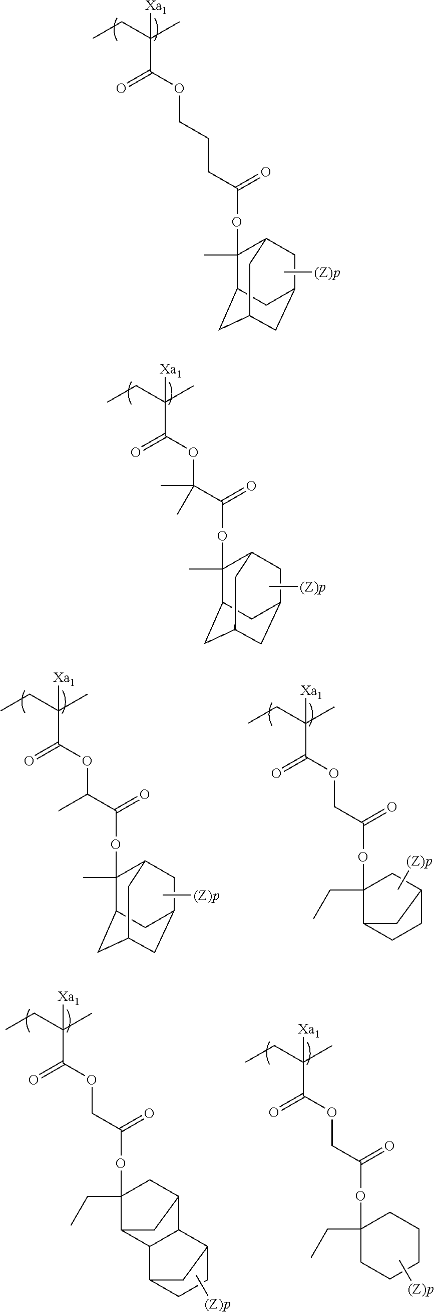

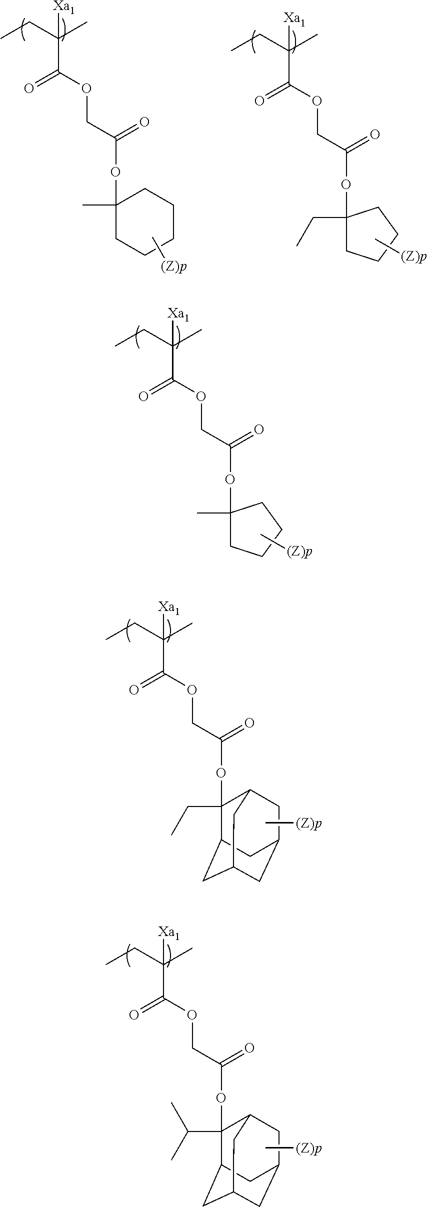

The resin (B) is more preferably a resin containing, as the repeating unit represented by formula (AI), at least either a repeating unit represented by formula (1) or a repeating unit represented by formula (II):

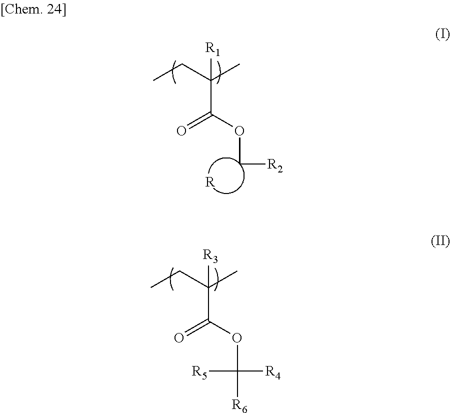

In formulae (1) and (II), each of R₁ and R₃ independently represents a hydrogen atom, a methyl group which may have a substituent, or a group represented by —CH₂—R₉. R₉ represents a hydroxyl group or a monovalent organic group.

Each of R₂, R₄, R₅ and R₆ independently represents an alkyl group or a cycloalkyl group.

R represents an atomic group necessary for forming an alicyclic structure together with the carbon atom.

Each of R₁ and R₃ preferably represents a hydrogen atom, a methyl group, a trifluoromethyl group or a hydroxymethyl group. Specific examples and preferred examples of the monovalent organic group in R₉ are the same as those described for R₉ in formula (AI).

The alkyl group in R₂ may be linear or branched and may have a substituent.

The cycloalkyl group in R₂ may be monocyclic or polycyclic and may have a substituent.

R₂ is preferably an alkyl group, more preferably an alkyl group having a carbon number of 1 to 10, still more preferably an alkyl group having a carbon number of 1 to 5, and examples thereof include a methyl group and an ethyl group.

R represents an atomic group necessary for forming an alicyclic structure together with the carbon atom. The alicyclic structure formed by R together with the carbon atom is preferably a monocyclic alicyclic structure, and the carbon number thereof is preferably from 3 to 7, more preferably 5 or 6.

R₃ is preferably a hydrogen atom or a methyl group, more preferably a methyl group.

The alkyl group in R₄, R₅ and R₆ may be linear or branched and may have a substituent. The alkyl group is preferably an alkyl group having a carbon number of 1 to 4, such as methyl group, ethyl group, n-propyl group, isopropyl group, n-butyl group, isobutyl group and tert-butyl group.

The cycloalkyl group in R₄, R₅ and R₆ may be monocyclic or polycyclic and may have a substituent. The cycloalkyl group is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

The repeating unit represented by formula (1) includes, for example, a repeating unit represented by the following formula (1-a):

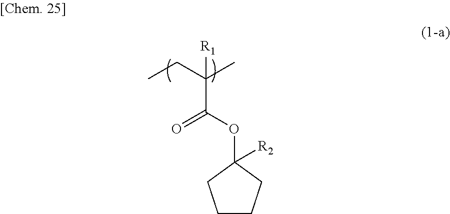

In the formula, R₁ and R have the same meanings as respective members in formula (1).

The repeating unit represented by formula (II) is preferably a repeating unit represented by the following formula (II-1):

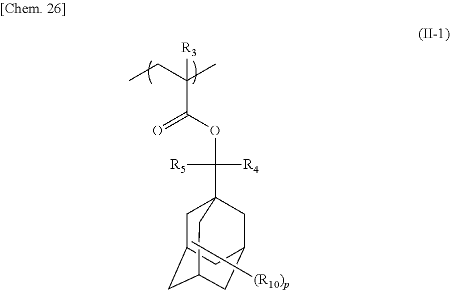

In formula (II-1), R₃ to R₅ have the same meanings as respective members in formula (II).

R₁₀ represents a substituent containing a polar group, and when a plurality of R₁₀ are present, each may be the same as or different from every other member. The substituent containing a polar group includes, for example, a hydroxyl group, a cyano group, an amino group, an alkylamide or sulfonamide group itself, and a linear or branched alkyl or cycloalkyl group having at least one of the groups above and is preferably an alkyl group having a hydroxyl group, more preferably a branched alkyl group having a hydroxyl group. The branched alkyl group is preferably an isopropyl group, among others.

p represents an integer of 0 to 15. p is preferably 0 to 2, more preferably 0 or 1.

The acid-decomposable resin is more preferably a resin containing, as the repeating unit represented by formula (AI), at least either a repeating unit represented by formula (1) or a repeating unit represented by formula (II). Also, in another embodiment, the acid-decomposable resin is more preferably a resin containing at least two repeating units represented by formula (I) as the repeating unit represented by formula (AI).

As for the repeating unit having an acid-decomposable group contained in the resin (B), one repeating unit may be used; or two or more repeating units may be used in combination.

In the case where the resin (A) contains acid-decomposable repeating units in combination, preferred combinations include the followings. In the following formulae, each R independently represents a hydrogen atom or a methyl group.

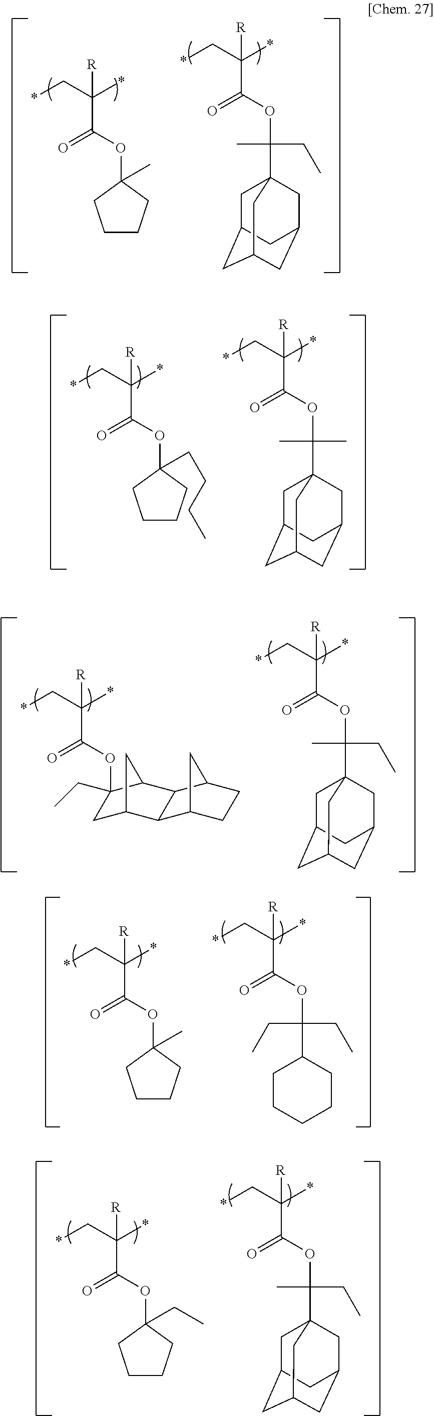

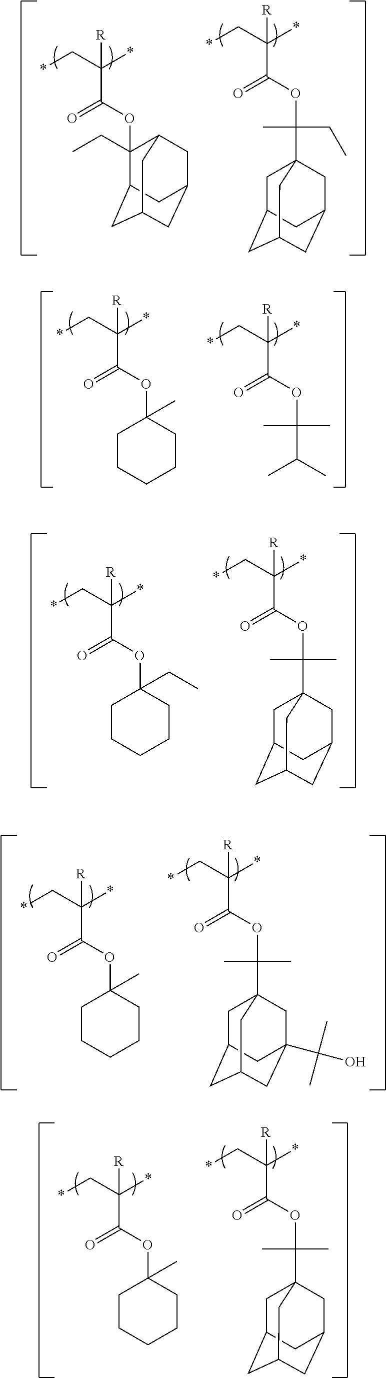

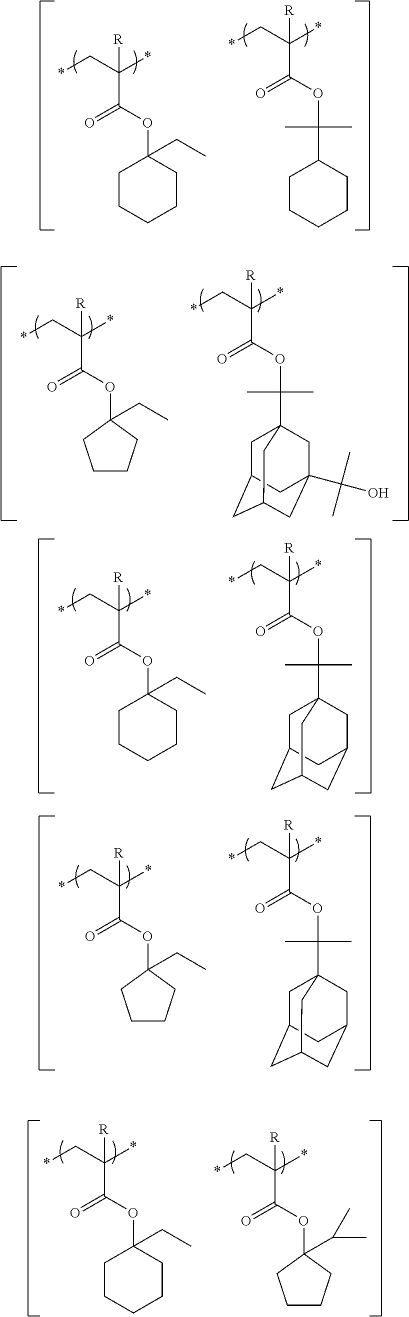

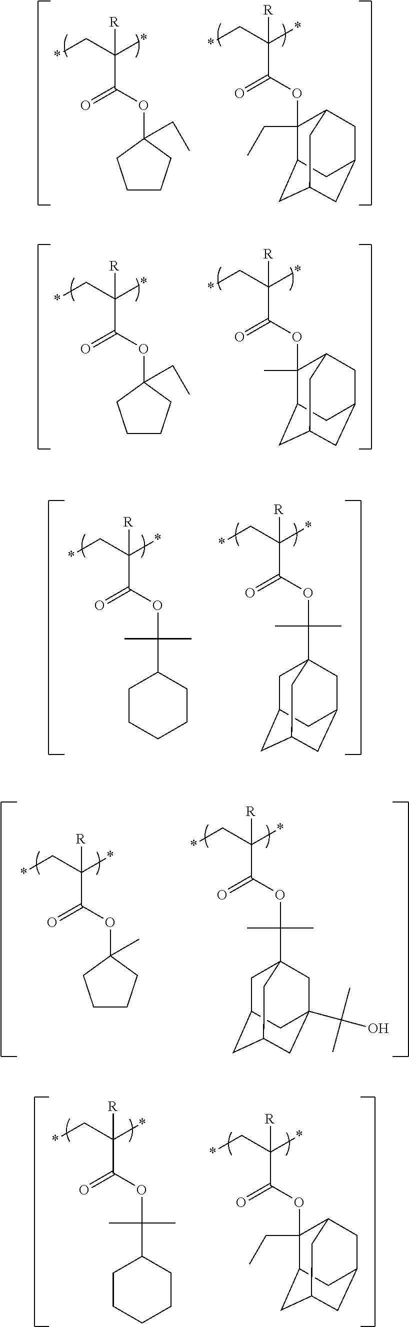

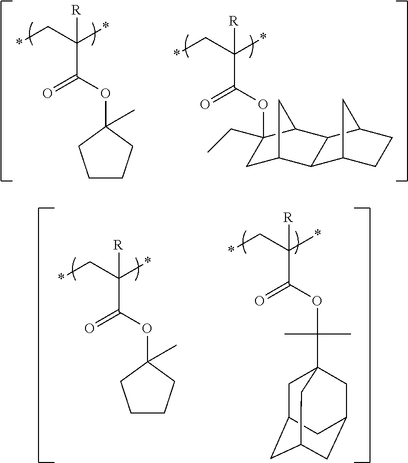

The resin (B) preferably contains a repeating unit having a lactone structure or a sultone (cyclic sulfonic acid ester) structure.

As the lactone structure or sultone structure, any structure may be used as long as it has a lactone structure or a sultone structure, but the structure is preferably a 5- to 7-membered ring lactone structure, and a 5- to 7-membered ring lactone structure to which another ring structure is fused in the form of forming a bicyclo structure or a spiro structure, is preferred. The resin more preferably contains a repeating unit having a lactone or sultone structure represented by any one of the following formulae (LC1-1) to (LC1-17), (SL1-1) and (SL1-2). Also, the lactone structure or sultone structure may be bonded directly to the main chain. Preferred lactone structures are (LC1-1), (LC1-4), (LC1-5), (LC1-6), (LC1-13), (LC1-14) and (LC1-17), and by using a specific lactone structure, LWR and development defect are improved.

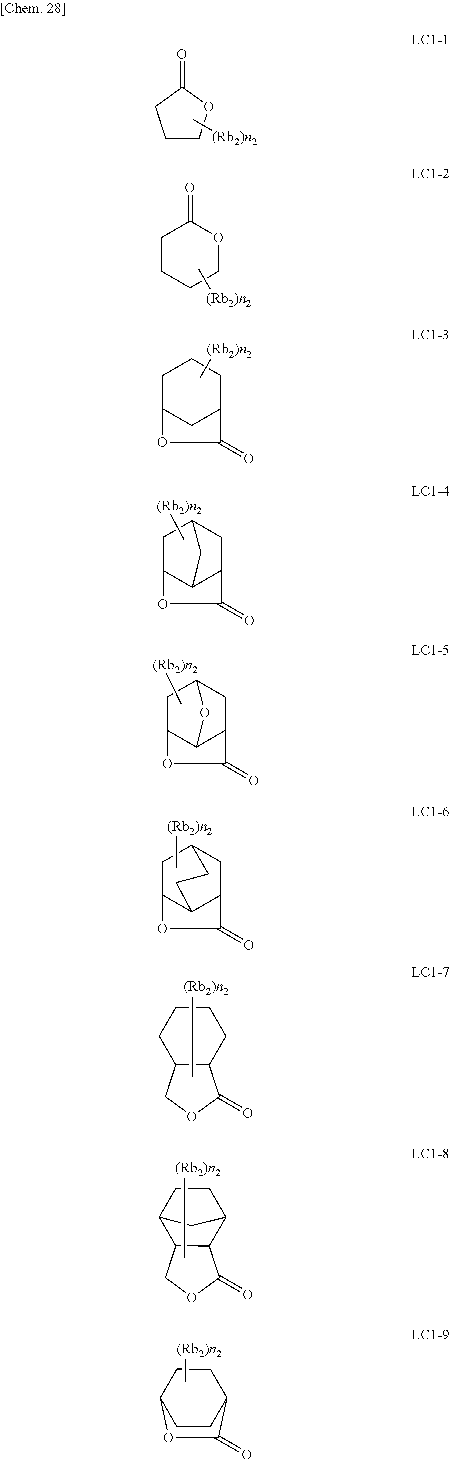

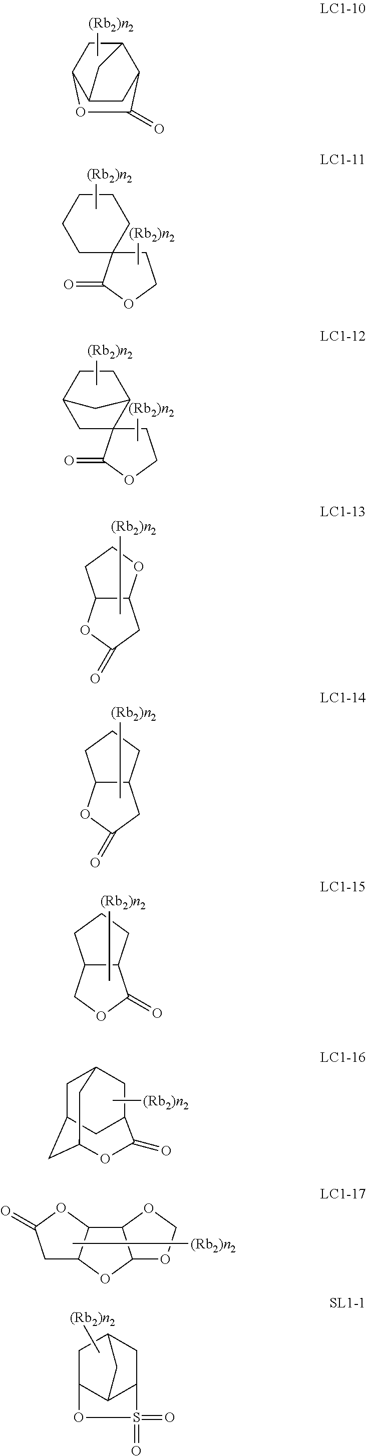

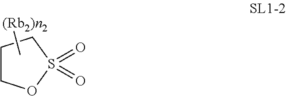

The lactone or sultone structure moiety may or may not have a substituent (Rb₂). Preferred examples of the substituent (Rb₂) include an alkyl group having a carbon number of 1 to 8, a cycloalkyl group having a carbon number of 4 to 7, an alkoxy group having a carbon number of 1 to 8, an alkoxycarbonyl group having a carbon number of 2 to 8, a carboxyl group, a halogen atom, a hydroxyl group, a cyano group, and an acid-decomposable group. An alkyl group having a carbon number of 1 to 4, a cyano group and an acid-decomposable group are more preferred. n₂ represents an integer of 0 to 4. When n₂ is 2 or more, each substituent (Rb₂) may be the same as or different from every other substituent and also, the plurality of substituents (Rb₂) may combine with each other to form a ring.

The resin (B) preferably contains a repeating unit having a lactone or sultone structure represented by the following formula (III):

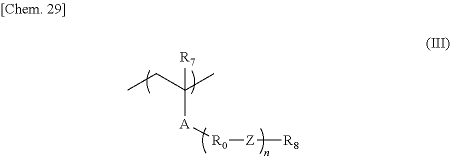

In formula (1), A represents an ester bond (a group represented by —COO—) or an amido bond (a group represented by —CONH—).

R₀ represents, when a plurality of R₀ are present, each independently represents, an alkylene group, a cycloalkylene group or a combination thereof.

Z represents, when a plurality of Z are present, each independently represents, a single bond, an ether bond, an ester bond, an amido bond, a urethane bond

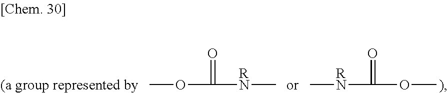

or a urea bond

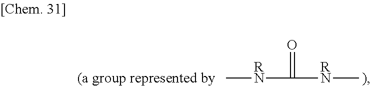

wherein each R independently represents a hydrogen atom, an alkyl group, a cycloalkyl group or an aryl group.

R₈ represents a monovalent organic group having a lactone structure or a sultone structure.

n is the repetition number of the structure represented by —R₀—Z— and represents an integer of 0 to 2, preferably 0 or 1. When n is 0, —R₀—Z— is not present, and a single bond is formed.

R₇ represents a hydrogen atom, a halogen atom or an alkyl group.

The alkylene group and cycloalkylene group of R₀ may have a substituent.

Z is preferably an ether bond or an ester bond, more preferably an ester bond.

The alkyl group of R₇ is preferably an alkyl group having a carbon number of 1 to 4, more preferably a methyl group or an ethyl group, still more preferably a methyl group. The alkyl group in the alkylene group and cycloalkylene group of R₀ and in R₇ may be substituted, and the substituent includes, for example, a halogen atom such as fluorine atom, chlorine atom and bromine atom, a mercapto group, a hydroxy group, an alkoxy group such as methoxy group, ethoxy group, isopropoxy group, tert-butoxy group and benzyloxy group, and an acyloxy group such as acetyloxy group and propionyloxy group. R₇ is preferably a hydrogen atom, a methyl group, a trifluoromethyl group or a hydroxymethyl group.

The chain alkylene group in R₀ is preferably a chain alkylene having a carbon number of 1 to 10, more preferably a carbon number of 1 to 5, and examples thereof include a methylene group, an ethylene group and a propylene group. The cycloalkylene group is preferably a cycloalkylene group having a carbon number of 3 to 20, and examples thereof include a cyclohexylene group, a cyclopentylene group, a norbornylene group and an adamantylene group. For bringing out the effects of the present invention, a chain alkylene group is more preferred, and a methylene group is still more preferred.

The monovalent organic group having a lactone or sultone structure represented by R₈ is not limited as long as it has a lactone or sultone structure. Specific examples of respective structures include lactone structures represented by formulae (LC1-1) to (LC1-17) and sultone structures represented by formulae (SL1-1) and (SL1-2). Among these, the structure represented by (LC1-4) is preferred. In (LC1-1) to (LC1-17), (SL-1-1) and (SL1-2), n₂ is preferably 2 or less.

R₈ is preferably a monovalent organic group having an unsubstituted lactone, or a monovalent organic group having a lactone structure containing a methyl group, a cyano group or an alkoxycarbonyl group as a substituent, more preferably a monovalent organic group having a lactone structure containing a cyano group as a substituent (cyanolactone).

Specific examples of the repeating unit containing a group having a lactone or sultone structure represented by formula (III) are illustrated below, but the present invention is not limited thereto.

In specific examples, R represents a hydrogen atom, an alkyl group which may have a substituent, or a halogen atom, preferably a hydrogen atom, a methyl group, a hydroxymethyl group or an acetyloxymethyl group.

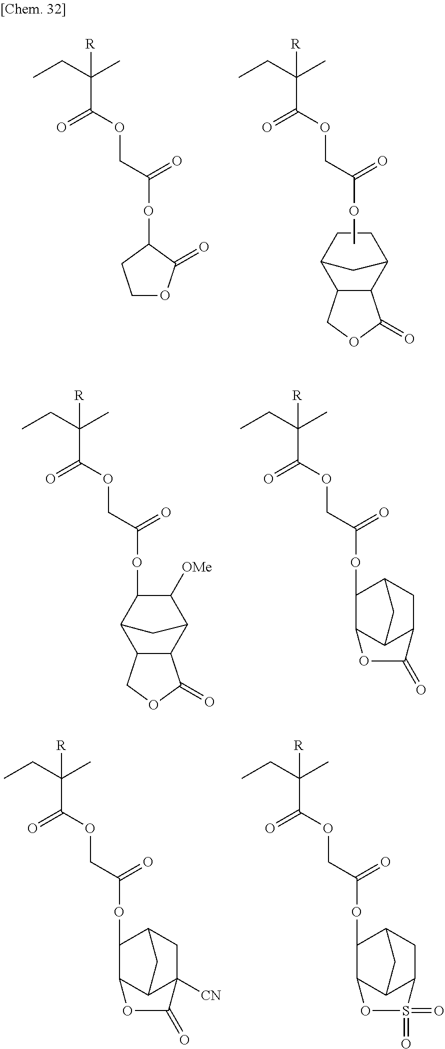

The repeating unit having a lactone structure or a sultone structure is more preferably a repeating unit represented by the following formula (III-1):

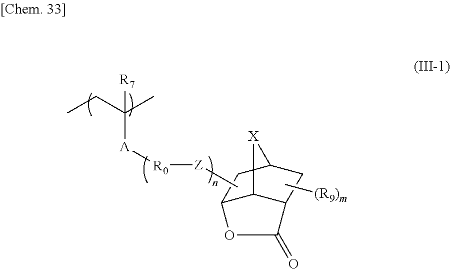

In formula (III-1), R₇, A, R₀, Z and n have the same meanings as in formula (III).

R₉ represents, when a plurality of R₉ are present, each independently represents, an alkyl group, a cycloalkyl group, an alkoxycarbonyl group, a cyano group, a hydroxyl group or an alkoxy group, and when a plurality of R are present, two members thereof may combine to form a ring.

X represents an alkylene group, an oxygen atom or a sulfur atom.

m is the number of substituents and represents an integer of 0 to 5. m is preferably 0 or 1.

The alkyl group of R₉ is preferably an alkyl group having a carbon number of 1 to 4, more preferably a methyl group or an ethyl group, and most preferably a methyl group. The cycloalkyl group includes a cyclopropyl group, a cyclobutyl group, a cyclopentyl group, and a cyclohexyl group. The alkoxycarbonyl group includes a methoxycarbonyl group, an ethoxycarbonyl group, an n-butoxycarbonyl group, a tert-butoxycarbonyl group, and the like. The alkoxy group includes a methoxy group, an ethoxy group, a propoxy group, an isopropoxy group, a butoxy group, and the like. These groups may have a substituent, and the substituent includes a hydroxy group, an alkoxy group such as methoxy group and ethoxy group, a cyano group, and a halogen atom such as fluorine atom. R₁ is preferably a methyl group, a cyano group or an alkoxycarbonyl group, more preferably a cyano group.

The alkylene group of X includes a methylene group, an ethylene group, and the like. X is preferably an oxygen atom or a methylene group, more preferably a methylene group.

When m is 1 or more, at least one R₉ is preferably substituted on the α- or β-position, more preferably the α-position, of the carbonyl group of lactone.

Specific examples of the repeating unit having a lactone structure-containing group represented by formula (III-1) are illustrated below, but the present invention is not limited thereto. In specific examples, R represents a hydrogen atom, an alkyl group which may have a substituent, or a halogen atom, preferably a hydrogen atom, a methyl group, a hydroxymethyl group or an acetyloxymethyl group.

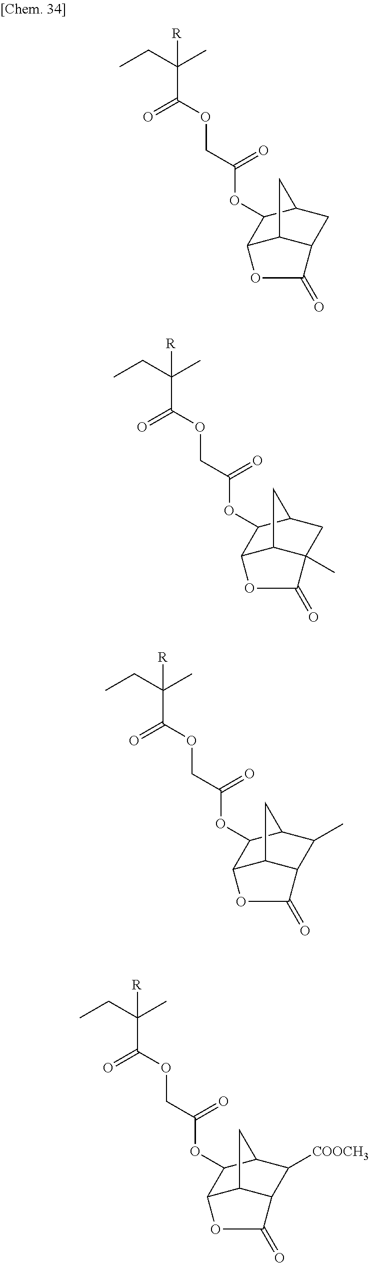

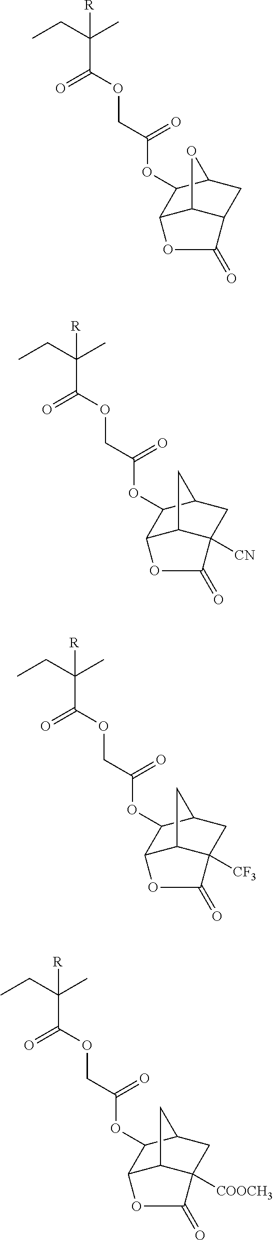

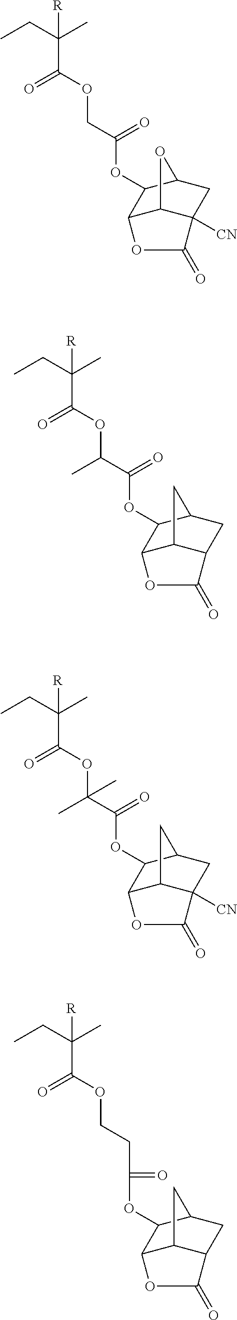

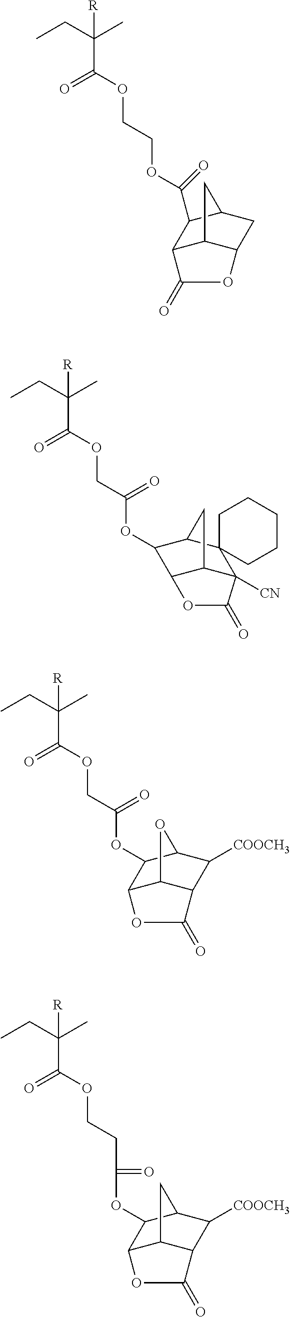

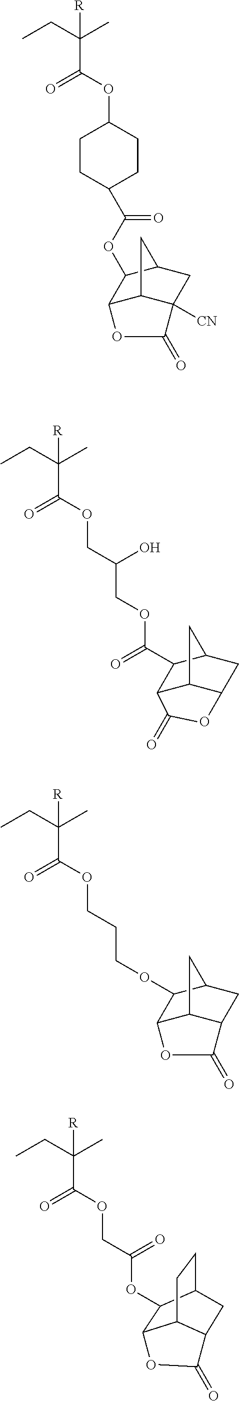

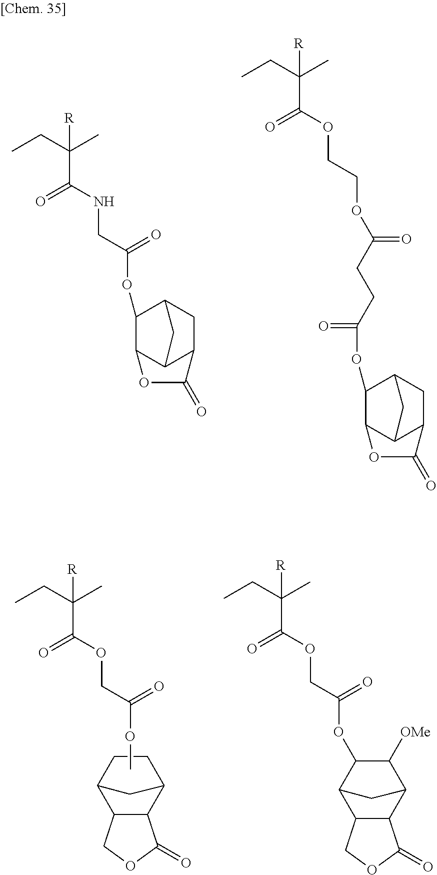

In one embodiment, the unit represented by formula (III) may be a repeating unit represented by the following formula (AII′):

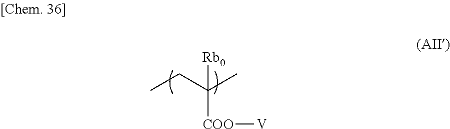

In formula (AII′), Rb₀ represents a hydrogen atom, a halogen atom or an alkyl group having a carbon number of 1 to 4. Preferred substituents which may be substituted on the alkyl group of Rb₀ include a hydroxyl group and a halogen atom. The halogen atom of Rb₀ includes a fluorine atom, a chlorine atom, a bromine atom, and an iodine atom. Rb₀ is preferably a hydrogen atom, a methyl group, a hydroxymethyl group or a trifluoromethyl group, more preferably a hydrogen atom or a methyl group.

V represents a group having a structure represented by any one of formulae (LC1-1) to (LC1-17).

The resin (B) may contain a repeating unit having the above-described lactone structure, in addition to the unit represented by formula (II).

Specific examples of the repeating unit having a lactone structure or a sultone structure include the followings, in addition to specific examples illustrated above, but the present invention is not limited thereto.

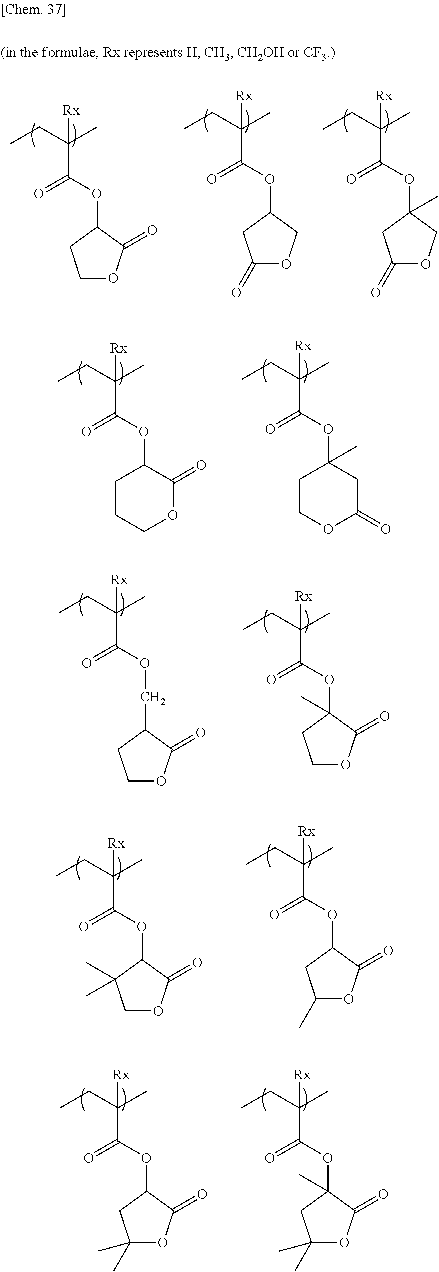

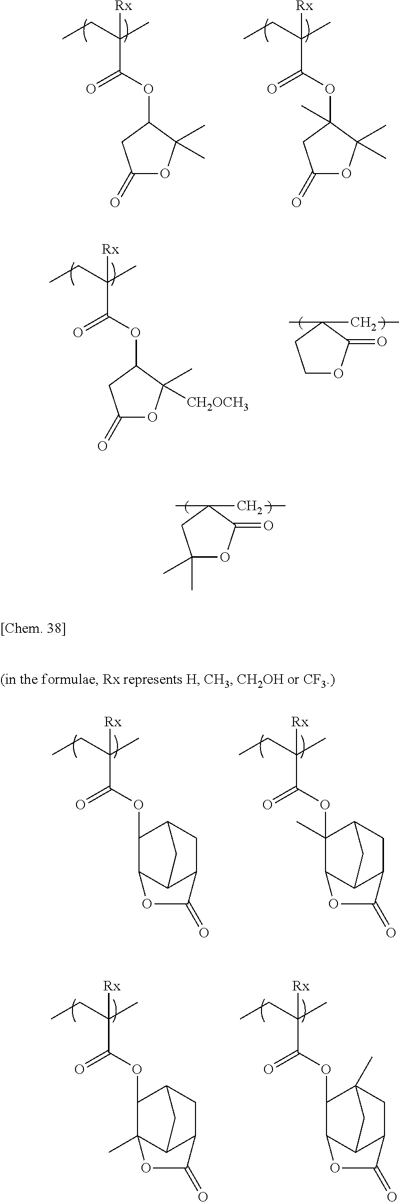

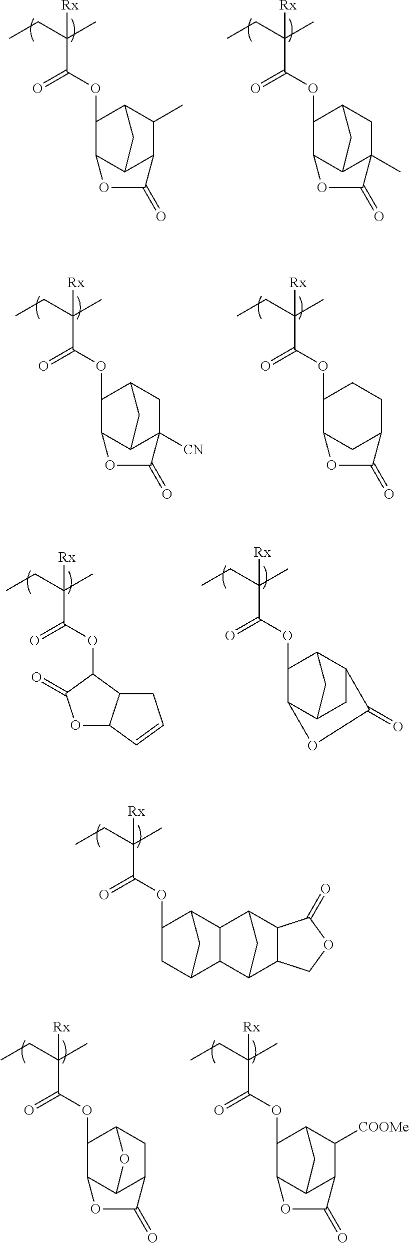

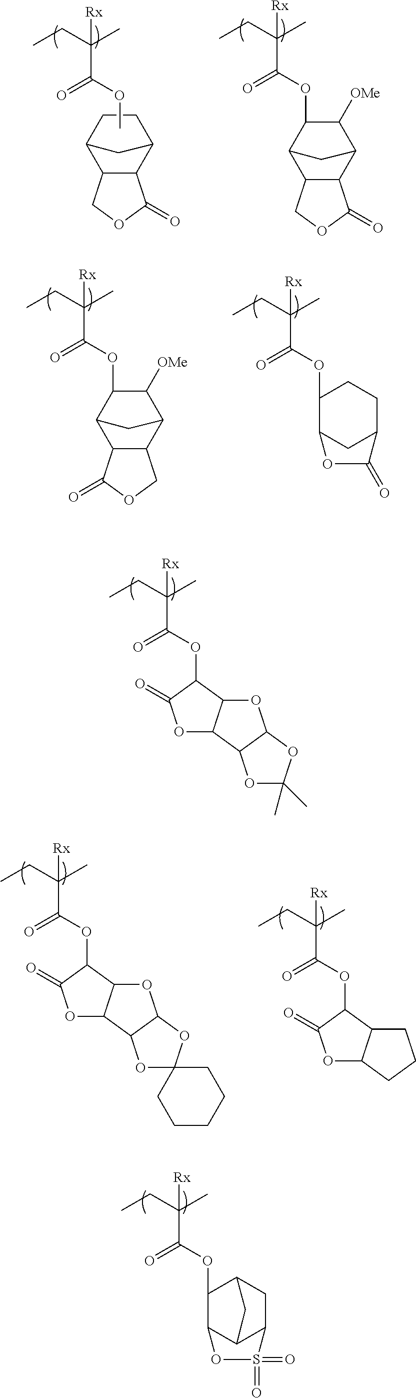

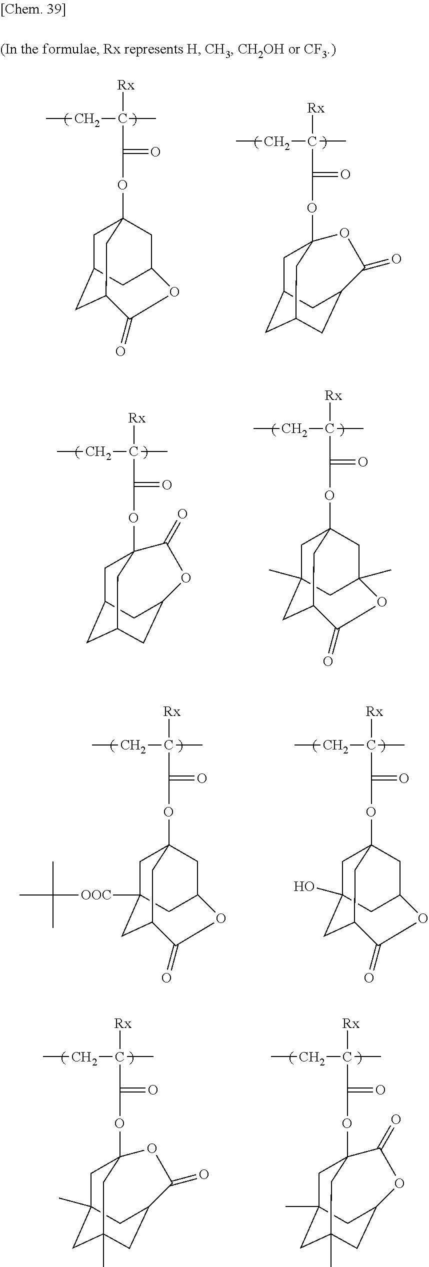

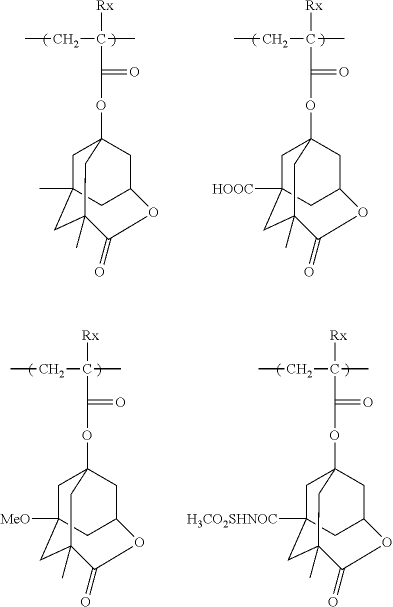

Of these specific examples, particularly preferred repeating units include the following repeating units. By selecting an optimal lactone group, the pattern profile and the iso/dense bias are improved.

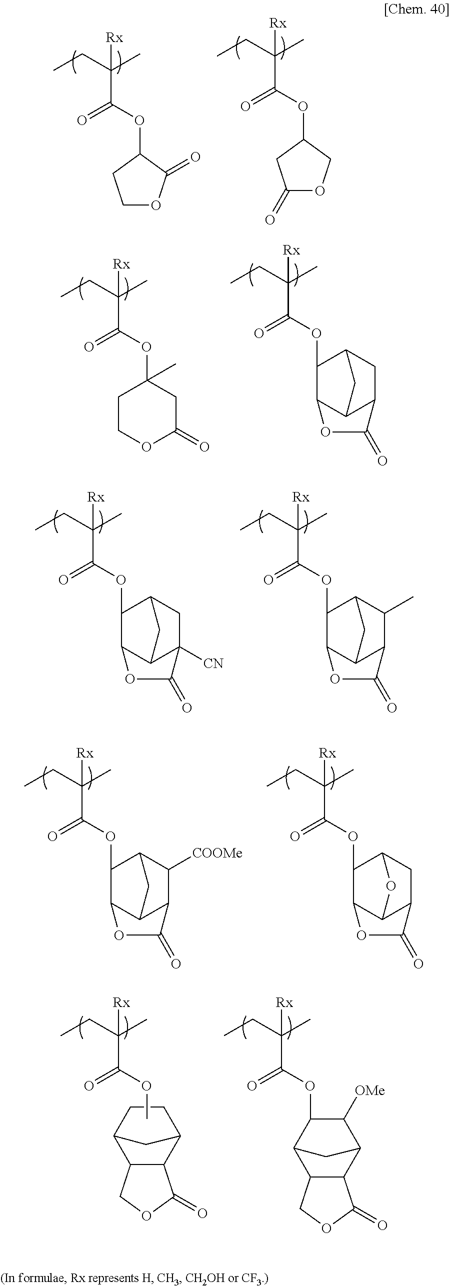

The repeating unit having a lactone group or a sultone structure usually has an optical isomer, but any optical isomer may be used. One optical isomer may be used alone, or a plurality of optical isomers may be mixed and used. In the case of mainly using one optical isomer, the optical purity (ee) thereof is preferably 90% or more, more preferably 95% or more.

The resin (B) may contain two or more repeating units having a lactone structure or a sultone structure. In particular, out of formula (III), two or more lactone repeating units where n is 1 are preferably selected and used in combination.

The content ratio of the repeating unit having a lactone group or a sultone structure, in the case of containing a plurality of kinds of repeating units, the total thereof, is preferably from 15 to 70 mol %, more preferably from 20 to 65 mol %, still more preferably from 30 to 60 mol %, based on all repeating units in the resin.

The resin (B) preferably contains a repeating unit having a hydroxyl group or a cyano group, other than formulae (AI) and (III). Thanks to this repeating unit, the adherence to substrate and the affinity for developer are enhanced. The repeating unit having a hydroxyl group or a cyano group is preferably a repeating unit having an alicyclic hydrocarbon structure substituted with a hydroxyl group or a cyano group and preferably has no acid-decomposable group. The alicyclic hydrocarbon structure in the alicyclic hydrocarbon structure substituted with a hydroxyl group or a cyano group is preferably an adamantyl group, a diamantyl group or a norbornyl group. As for the preferred alicyclic hydrocarbon structure substituted with a hydroxyl group or a cyano group, partial structures represented by the following formulae (VIIa) to (VIId) are preferred.

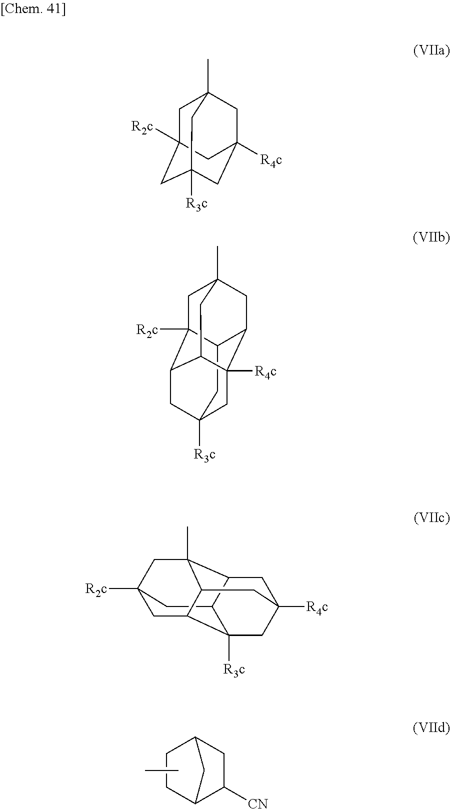

In formulae (VIIa) to (VIIc), each of R₂c to R₄c independently represents a hydrogen atom, a hydroxyl group or a cyano group, provided that at least one of R₂c to R₄c represents a hydroxyl group or a cyano group. A structure where one or two members out of R₂c to R₄c are a hydroxyl group with the remaining being a hydrogen atom is preferred. In formula (VIIa), it is more preferred that two members out of R₂c to R₄c are a hydroxyl group and the remaining is a hydrogen atom.

The repeating unit having a partial structure represented by formulae (VIIa) to (VIId) includes repeating units represented by the following formulae (AIIa) to (AIId):

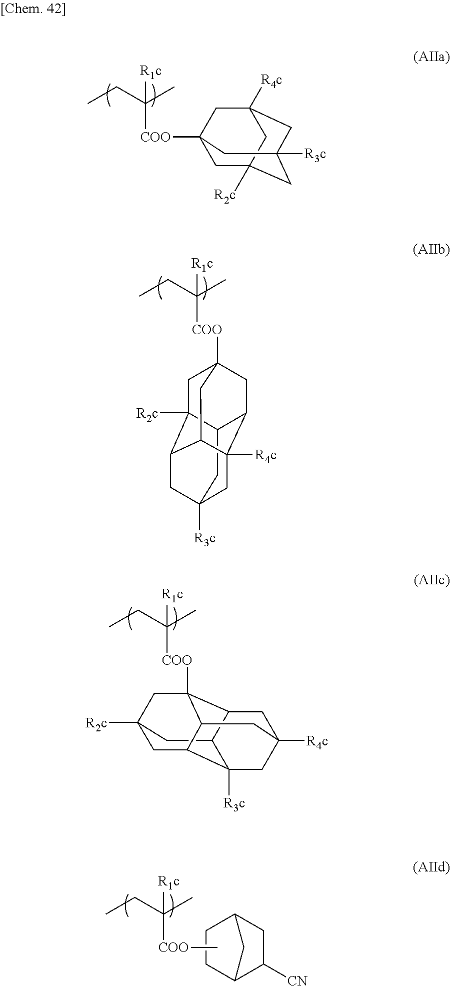

In formulae (AIIa) to (AIId), R₁c represents a hydrogen atom, a methyl group, a trifluoromethyl group or a hydroxymethyl group.

R₂c to R₄c have the same meanings as R₂c to R₄c in formulae (VIIa) to (VIIc).

The content ratio of the repeating unit having a hydroxyl group or a cyano group is preferably from 5 to 40 mol %, more preferably from 5 to 30 mol %, still more preferably from 10 to 30 mol %, based on all repeating units in the resin (B).

Specific examples of the repeating unit having a hydroxyl group or a cyano group are illustrated below, but the present invention is not limited thereto.

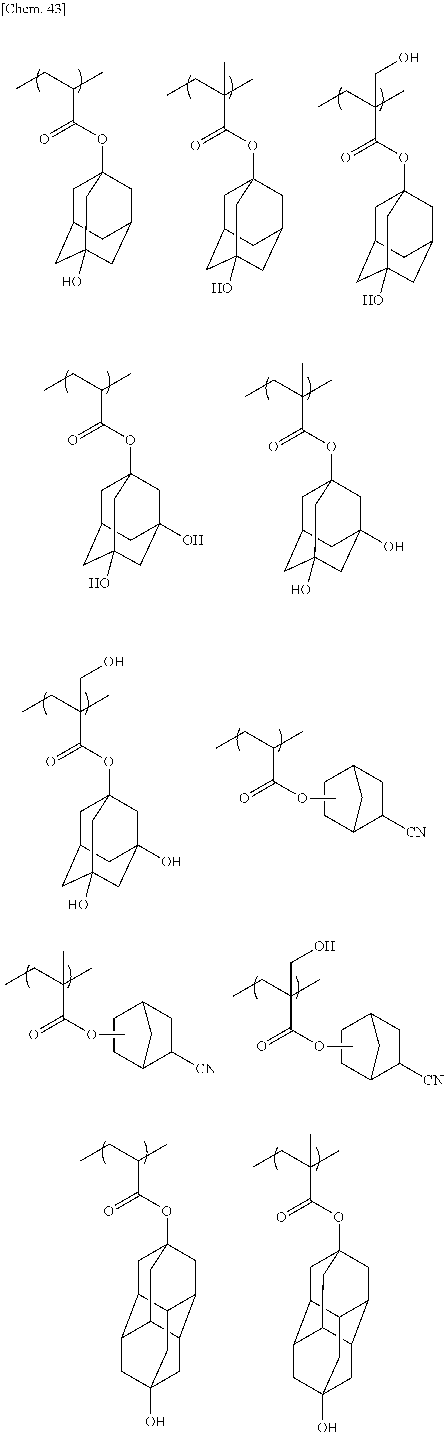

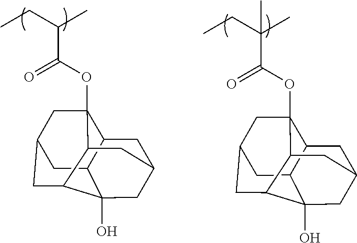

The resin used in the actinic ray-sensitive or radiation-sensitive resin composition of the present invention may contain a repeating unit having an alkali-soluble group. The alkali-soluble group includes a carboxyl group, a sulfonamide group, a sulfonylimide group, a bis-sulfonylimide group, and an aliphatic alcohol substituted with an electron-withdrawing group at the α-position (e.g., hexafluoroisopropanol). It is preferred to contain a repeating unit having a carboxyl group. By virtue of containing an alkali-soluble group-containing repeating unit, the resolution increases in the usage of forming contact holes. As for the repeating unit having an alkali-soluble group, all of a repeating unit where an alkali-soluble group is directly bonded to the main chain of the resin, such as repeating unit by an acrylic acid or a methacrylic acid, a repeating unit where an alkali-soluble group is bonded to the main chain of the resin through a linking group, and a repeating unit where an alkali-soluble group is introduced into the polymer chain terminal by using an alkali-soluble group-containing polymerization initiator or chain transfer agent at the polymerization, are preferred. The linking group may have a monocyclic or polycyclic hydrocarbon structure. A repeating unit by an acrylic acid or a methacrylic acid is preferred, among others.

The resin (B) for use in the present invention may or may not contain the repeating unit having an alkali-soluble group, but in the case of containing the repeating unit having an alkali-soluble group, the content ratio thereof is preferably from 1 to 20 mol %, more preferably from 3 to 15 mol %, still more preferably from 5 to 10 mol %, based on all repeating units in the resin (B).

Specific examples of the repeating unit having an alkali-soluble group are illustrated below, but the present invention is not limited thereto.

In specific examples, Rx represents H, CH₃, CH₂OH or CF₃.

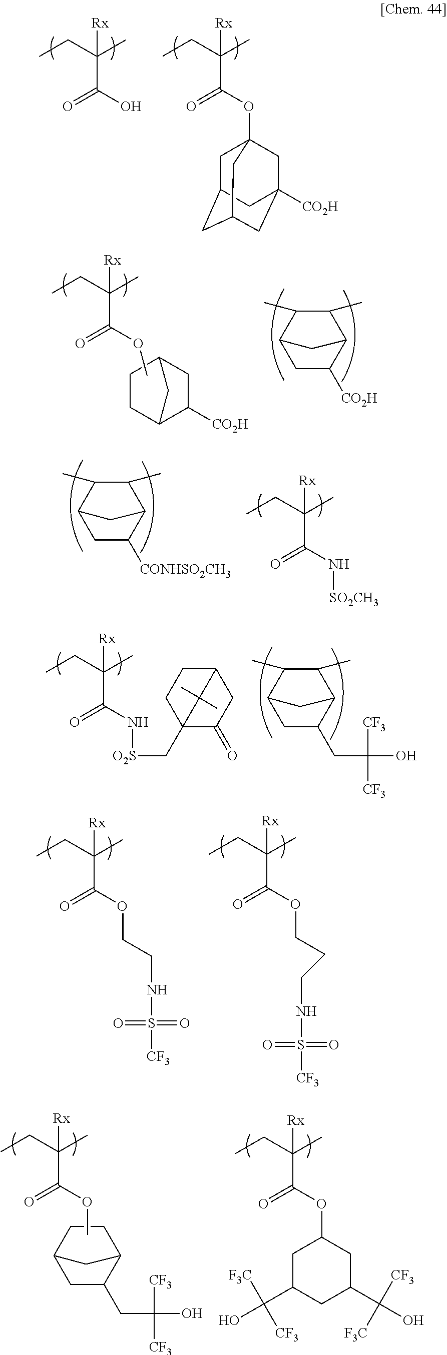

The resin (B) for use in the present invention may further contain a repeating unit having an alicyclic hydrocarbon structure free from a polar group (for example, the above-described alkali-soluble group, hydroxyl group or cyano group) and not exhibiting acid decomposability. Such a repeating unit includes a repeating unit represented by formula

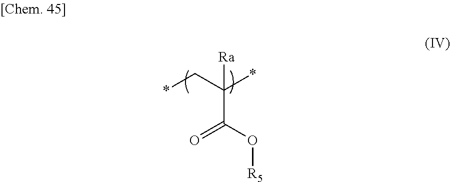

In formula (IV), R₅ represents a hydrocarbon group having at least one cyclic structure and having no polar group.

Ra represents a hydrogen atom, an alkyl group or a —CH₂—O-Ra₂ group, wherein Ra₂ represents a hydrogen atom, an alkyl group or an acyl group. Ra is preferably a hydrogen atom, a methyl group, a hydroxymethyl group or a trifluoromethyl group, more preferably a hydrogen atom or a methyl group.

The cyclic structure contained in R₅ includes a monocyclic hydrocarbon group and a polycyclic hydrocarbon group. The monocyclic hydrocarbon group includes, for example, a cycloalkyl group having a carbon number of 3 to 12, such as cyclopentyl group, cyclohexyl group, cycloheptyl group and cyclooctyl group, and a cycloalkenyl group having a carbon number of 3 to 12, such as cyclohexenyl group. The monocyclic hydrocarbon group is preferably a monocyclic hydrocarbon group having a carbon number of 3 to 7, more preferably a cyclopentyl group or a cyclohexyl group.

The polycyclic hydrocarbon group includes a ring assembly hydrocarbon group and a crosslinked cyclic hydrocarbon group. Examples of the ring assembly hydrocarbon group include a bicyclohexyl group and a perhydronaphthalenyl group. The crosslinked cyclic hydrocarbon ring includes, for example, a bicyclic hydrocarbon ring such as pinane ring, bornane ring, norpinane ring, norbornane ring and bicyclooctane ring (e.g., bicyclo[2.2.2]octane ring, bicyclo[3.2.1]octane ring), a tricyclic hydrocarbon ring such as homobledane ring, adamantane ring, tricyclo[5.2.1.0^{2,6}]decane ring and tricyclo[4.3.1.1^{2,5}]undecane ring, and a tetracyclic hydrocarbon ring such as tetracyclo[4.4.0.1^{2,5}.1^{7,10}]dodecane ring and perhydro-1,4-methano-5,8-methanonaphthalene ring. The crosslinked cyclic hydrocarbon ring also includes a condensed cyclic hydrocarbon ring, for example, a condensed ring formed by fusing a plurality of 5- to 8-membered cycloalkane rings, such as perhydronaphthalene (decalin) ring, perhydroanthracene ring, perhydrophenathrene ring, perhydroacenaphthene ring, perhydrofluorene ring, perhydroindene ring and perhydrophenalene ring.

Preferred crosslinked cyclic hydrocarbon rings include a norbornyl group, an adamantyl group, a bicyclooctanyl group, a tricyclo[5,2,1,0^{2,6}]decanyl group, and the like. More preferred crosslinked cyclic hydrocarbon rings include a norbornyl group and an adamantyl group.

These alicyclic hydrocarbon groups may have a substituent, and preferred substituents include a halogen atom, an alkyl group, a hydroxyl group with a hydrogen atom being substituted for, and an amino group with a hydrogen atom being substituted for. Preferred halogen atoms include bromine atom, chlorine atom and fluorine atom, and preferred alkyl groups include a methyl group, an ethyl group, a butyl group and a tert-butyl group. This alkyl group may further have a substituent, and the substituent which may be further substituted on the alkyl group includes a halogen atom, an alkyl group, a hydroxyl group with a hydrogen atom being substituted for, and an amino group with a hydrogen atom being substituted for.

The group substituted for the hydrogen atom includes, for example, an alkyl group, a cycloalkyl group, an aralkyl group, a substituted methyl group, a substituted ethyl group, an alkoxycarbonyl group, and an aralkyloxycarbonyl group. The alkyl group is preferably an alkyl group having a carbon number of 1 to 4; the substituted methyl group is preferably a methoxymethyl group, a methoxythiomethyl group, a benzyloxymethyl group, a tert-butoxymethyl group or a 2-methoxyethoxymethyl group; the substituted ethyl group is preferably 1-ethoxyethyl group or 1-methyl-1-methoxyethyl; the acyl group is preferably an aliphatic acyl group having a carbon number of 1 to 6, such as formyl group, acetyl group, propionyl group, butyryl group, isobutyryl group, valeryl group and pivaloyl group; and the alkoxycarbonyl group is an alkoxycarbonyl group having a carbon number of 1 to 4, or the like.

The resin (B) may or may not contain a repeating unit having an alicyclic hydrocarbon structure free from a polar group and not exhibiting acid decomposability, but in the case of containing this repeating unit, the content ratio thereof is preferably from 1 to 40 mol %, more preferably from 2 to 20 mol %, based on all repeating units in the resin (B).

Specific examples of the repeating unit having an alicyclic hydrocarbon structure free from a polar group and not exhibiting acid decomposability are illustrated below, but the present invention is not limited thereto. In the formulae, Ra represents H, CH₃, CH₂OH or CF₃.

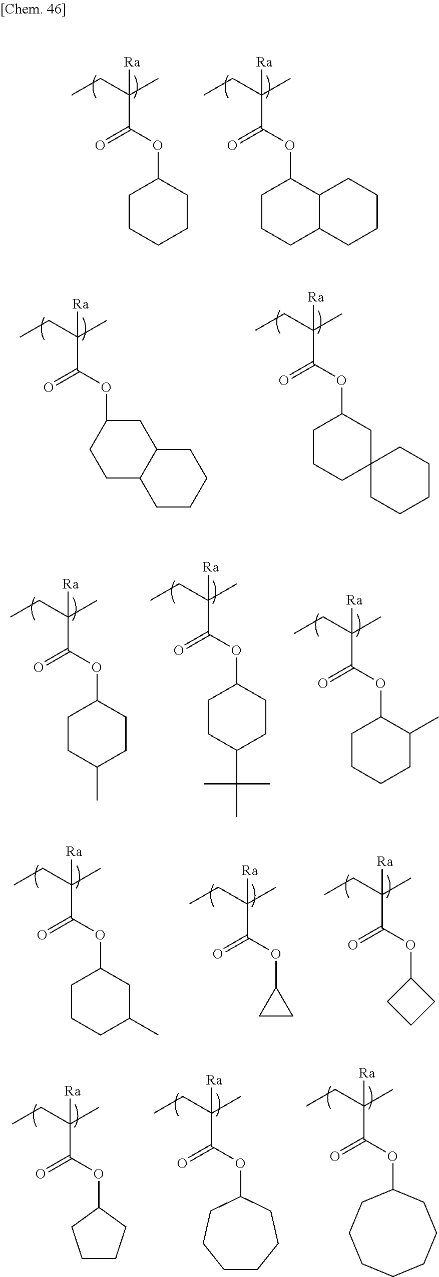

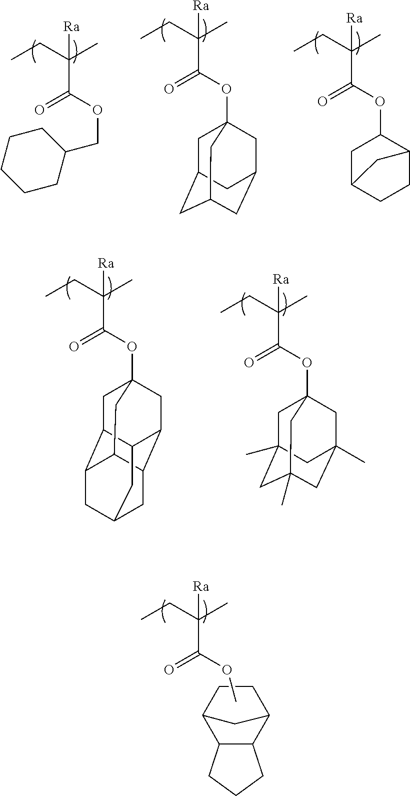

The resin (B) for use in the actinic ray-sensitive or radiation-sensitive resin composition of the present invention may contain, in addition to the above-described repeating structural units, various repeating structural units for the purpose of adjusting the dry etching resistance, suitability for standard developer, adherence to substrate, resist profile and properties generally required of a resist composition, such as resolution, heat resistance and sensitivity.

Such a repeating structural unit includes, but is not limited to, repeating structural units corresponding to the monomers described below.

Thanks to such a repeating structural unit, the performance required of the resin used in the actinic ray-sensitive or radiation-sensitive resin composition of the present invention, particularly, (1) solubility for coating solvent, (2) film-forming property (glass transition point), (3) alkali developability, (4) film loss (selection of hydrophilic, hydrophobic or alkali-soluble group), (5) adherence of unexposed area to substrate, (6) dry etching resistance, and the like can be subtly controlled.

The monomer includes, for example, a compound having one addition-polymerizable unsaturated bond selected from acrylic acid esters, methacrylic acid esters, acrylamides, methacrylamides, allyl compounds, vinyl ethers and vinyl esters.

Other than these compounds, an addition-polymerizable unsaturated compound copolymerizable with monomers corresponding to the above-described various repeating structural units may be copolymerized.

In the resin (B) for use in the actinic ray-sensitive or radiation-sensitive resin composition of the present invention, the molar ratio of respective repeating structural units contained is appropriately set to adjust the dry etching resistance of resist composition, suitability for standard developer, adherence to substrate, resist profile and performances generally required of a resist composition, such as resolution, heat resistance and sensitivity.

In the case where the actinic ray-sensitive or radiation-sensitive resin composition of the present invention is used for ArF exposure, in view of transparency to ArF light, the resin (B) for use in the actinic ray-sensitive or radiation-sensitive resin composition of the present invention preferably has substantially no aromatic group. More specifically, the percentage of an aromatic group-containing repeating unit in all repeating units of the resin (B) is preferably 5 mol % or less, more preferably 3 mol % or less, and ideally 0 mol %, that is, the resin does not contain a repeating unit having an aromatic group. Also, the resin (B) preferably has a monocyclic or polycyclic alicyclic hydrocarbon structure.

Incidentally, in view of compatibility with the later-described hydrophobic resin, the resin (B) preferably contains no fluorine atom and no silicon atom.

The resin (B) for use in the actinic ray-sensitive or radiation-sensitive resin composition of the present invention is preferably a resin where all repeating units are composed of a (meth)acrylate-based repeating unit. In this case, any of a resin where all repeating units are a methacrylate-based repeating unit, a resin where all repeating units are an acrylate-based repeating unit, and a resin where all repeating units are composed of a methacrylate-based repeating unit and an acrylate-based repeating unit, may be used, but the percentage of the acrylate-based repeating unit is preferably 50 mol % or less based on all repeating units. A copolymerized polymer containing from 20 to 50 mol % of an acid decomposable group-containing (meth)acrylate-based repeating unit, from 20 to 50 mol % of a lactone group-containing (meth)acrylate-based repeating unit, from 5 to 30 mol % of a (meth)acrylate-based repeating unit having an alicyclic hydrocarbon structure substituted with a hydroxyl group or a cyano group, and from 0 to 20 mol % of other (meth)acrylate-based repeating units is also preferred.

In the case of irradiating the actinic ray-sensitive or radiation-sensitive resin composition of the present invention with KrF excimer laser light, electron beam, X-ray or high-energy beam with a wavelength of 50 nm or less (e.g., EUV), the resin (B) preferably further contains a hydroxystyrene-based repeating unit. It is more preferred to contain a hydroxystyrene-based repeating unit, a hydroxystyrene-based repeating unit protected by an acid-decomposable group, and an acid-decomposable repeating unit such as tertiary alkyl(meth)acrylate.

The hydroxystyrene-based repeating unit having a preferred acid-decomposable group includes, for example, repeating units composed of a tert-butoxycarbonyloxystyrene, a 1-alkoxyethoxystyrene and a tertiary alkyl(meth)acrylate. Repeating units composed of a 2-alkyl-2-adamantyl(meth)acrylate and a dialkyl(1-adamantyl)methyl(meth)acrylate are more preferred.

When the resin (B) for use in the present invention is available on the market, a commercial product may be used, but the resin can be synthesized according to a conventional method (for example, radical polymerization). The general synthesis method includes, for example, a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. The reaction solvent includes, for example, tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and the later-described solvent capable of dissolving the actinic ray-sensitive or radiation-sensitive resin composition of the present invention, such as propylene glycol monomethyl ether acetate, propylene glycol monomethyl ether and cyclohexanone. The polymerization is more preferably performed using the same solvent as the solvent used in the actinic ray-sensitive or radiation-sensitive resin composition of the present invention. By the use of the same solvent, production of particles during storage can be suppressed.

The polymerization reaction is preferably performed in an inert gas atmosphere such as nitrogen or argon. As for the polymerization initiator, the polymerization is started using a commercially available radical initiator (e.g., azo-based initiator, peroxide). The radical initiator is preferably an azo-based initiator, and an azo-based initiator having an ester group, a cyano group or a carboxyl group is preferred. Preferred initiators include azobisisobutyronitrile, azobisdimethylvaleronitrile, dimethyl 2,2′-azobis(2-methylpropionate), and the like. The initiator is added additionally or in parts, if desired. After the completion of reaction, the reaction solution is poured in a solvent, and the desired polymer is collected by powder or solid recovery or other methods. The concentration at the reaction is from 5 to 50 mass %, preferably from 10 to 30 mass %, and the reaction temperature is usually from 10 to 150° C., preferably from 30 to 120° C., more preferably from 60 to 100° C.

The weight average molecular weight of the resin (B) for use in the present invention is preferably from 1,000 to 200,000, more preferably from 2,000 to 20,000, still more preferably from 3,000 to 15,000, yet still more preferably from 3,000 to 10,000, in terms of polystyrene by the GPC method. When the weight average molecular weight is from 1,000 to 200,000, reduction in the heat resistance and dry etching resistance can be avoided and at the same time, the film-forming property can be prevented from deteriorating due to degradation of developability or increase in the viscosity.

The polydispersity (molecular weight distribution) is usually from 1.0 to 3.0, preferably from 1.0 to 2.6, more preferably from 1.0 to 2.0, still more preferably from 1.4 to 2.0. As the molecular weight distribution is smaller, the resolution and pattern profile are more excellent, the side wall of resist pattern is smoother, and the roughness is more improved.

In the present invention, the content of the resin (B) is preferably from 30 to 99 mass %, more preferably from 60 to 95 mass %, based on the total solid content of the actinic ray-sensitive or radiation-sensitive resin composition.

As for the resin (B) of the present invention, one kind may be used or a plurality of kinds may be used in combination.

The actinic ray-sensitive or radiation-sensitive resin composition of the present invention may further contain other components, in addition to the above-described compound (A) and compound (B). These optional components are described below.

[3](C) Compound Capable of Generating an Acid Upon Irradiation with an Actinic Ray or Radiation, which is Different from the Compound (A)

The actinic ray-sensitive or radiation-sensitive resin composition of the present invention may further contain (C) a compound capable of generating an acid upon irradiation with an actinic ray or radiation, which is different from the compound (A) (hereinafter, sometimes referred to as “compound (C)” or “other acid generator”).

As the other acid generator, a photo-initiator for cationic photopolymerization, a photo-initiator for radical photopolymerization, a photo-decoloring agent for dyes, a photo-discoloring agent, a known compound capable of generating an acid upon irradiation with an actinic ray or radiation, which is used for microresist or the like, or a mixture thereof may be appropriately selected and used.

The other acid generator includes, for example, a diazonium salt, a phosphonium salt, a sulfonium salt, an iodonium salt, imidosulfonate, oxime sulfonate, diazodisulfone, disulfone and o-nitrobenzyl sulfonate.

Also, a compound where such a group or compound capable of generating an acid upon irradiation with an actinic ray or radiation is introduced into the main or side chain of the polymer, for example, compounds described in U.S. Pat. No. 3,849,137, German Patent 3,914,407, JP-A-63-26653, JP-A-55-164824, JP-A-62-69263, JP-A-63-146038, JP-A-63-163452, JP-A-62-153853 and JP-A-63-146029, may be used.

Furthermore, compounds capable of generating an acid by the action of light described, for example, in U.S. Pat. No. 3,779,778 and European Patent 126,712 may also be used.

Out of the acid generators, preferred compounds include compounds represented by the following formulae (ZI), (ZII) and (ZIII):

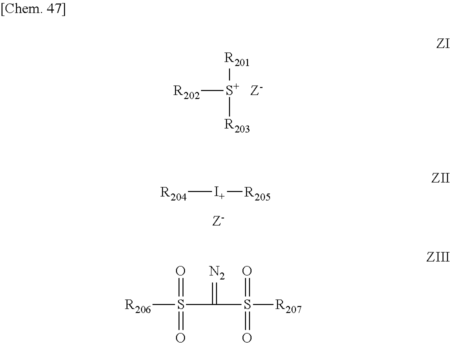

In formula (ZI), each of R₂₀₁, R₂₀₂ and R₂₀₃ independently represents an organic group.

The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain an oxygen atom, a sulfur atom, an ester bond, an amide bond or a carbonyl group. The group formed by combining two members out of R₂₀₁ to R₂₀₃ includes an alkylene group (e.g., butylenes group, pentylene group).

Z⁻ represents a non-nucleophilic anion.

Z⁻ includes, for example, the same anions as those descried above for Y⁻ in formula (1-1). Z⁻ and Y⁻ may be the same as or different from each other. However, from the standpoint of suppressing a salt exchange reaction with the compound (A) and the compound (C), the former configuration is preferably employed.

In formulae (ZII) and (ZIII), each of R₂₀₄ to R₂₀₇ independently represents an aryl group, an alkyl group or a cycloalkyl group.

The aryl group of R₂₀₄ to R₂₀₇ is preferably a phenyl group or a naphthyl group, more preferably a phenyl group. The aryl group of R₂₀₄ to R₂₀₇ may be an aryl group having a heterocyclic structure containing an oxygen atom, a nitrogen atom, a sulfur atom or the like. The heterocyclic structure includes, for example, pyrrole, furan, thiophene, indole, benzofuran and benzothiophene.

The alkyl group and cycloalkyl group in R₂₀₄ to R₂₀₇ is preferably a linear or branched alkyl group having a carbon number of 1 to 10 (for example, a methyl group, an ethyl group, a propyl group, a butyl group or a pentyl group) and a cycloalkyl group having a carbon number of 3 to 10 (a cyclopentyl group, a cyclohexyl group or a norbornyl group).

The aryl group, alkyl group and cycloalkyl group of R₂₀₄ to R₂₀₇ may have a substituent. The substituent which may be substituted on the aryl group, alkyl group and cycloalkyl group of R₂₀₄ to R₂₀₇ includes, for example, an alkyl group (for example, having a carbon number of 1 to 15), a cycloalkyl group (for example, having a carbon number of 3 to 15), an aryl group (for example, having a carbon number of 6 to 15), an alkoxy group (for example, having a carbon number of 1 to 15), a halogen atom, a hydroxyl group, and a phenylthio group.

Z⁻ represents a non-nucleophilic anion and includes the same anions as those for the non-nucleophilic anion of Z⁻ in formula (ZI).

Specific examples of the compound (C) are illustrated below, but the present invention is not limited thereto.

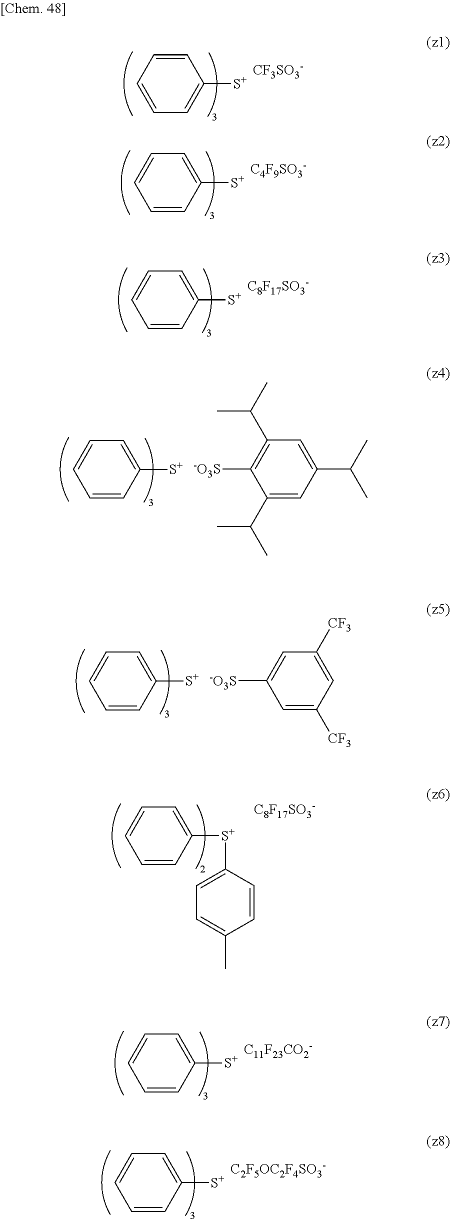

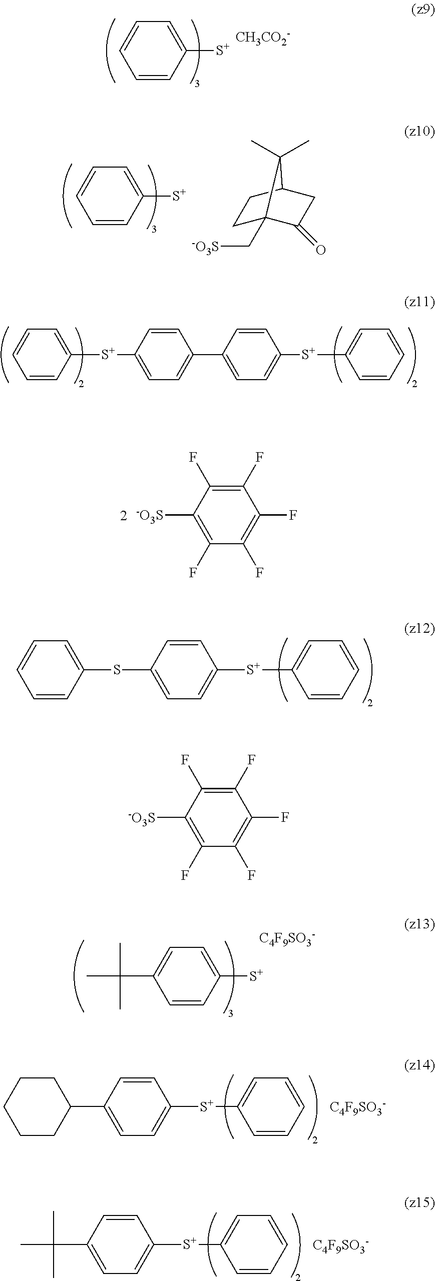

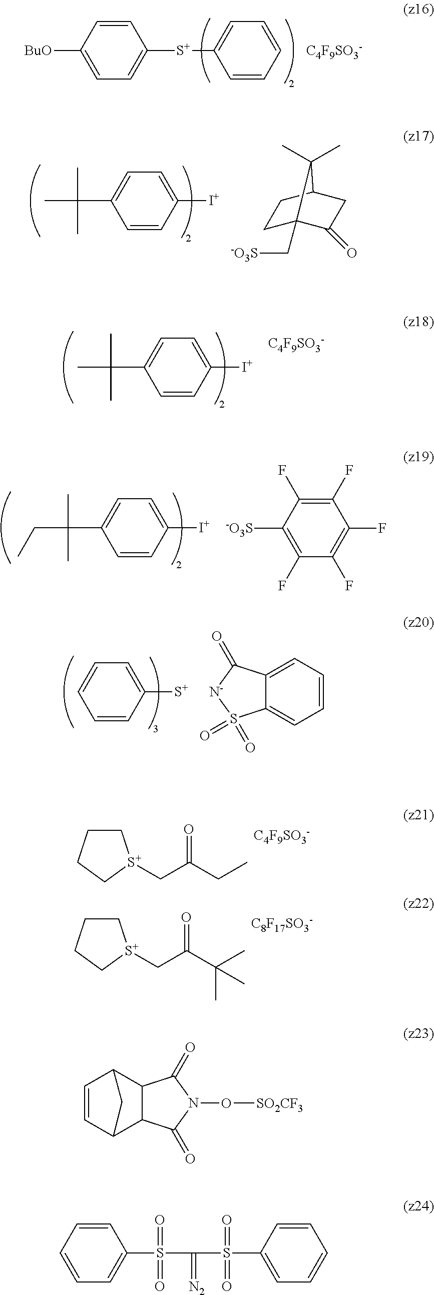

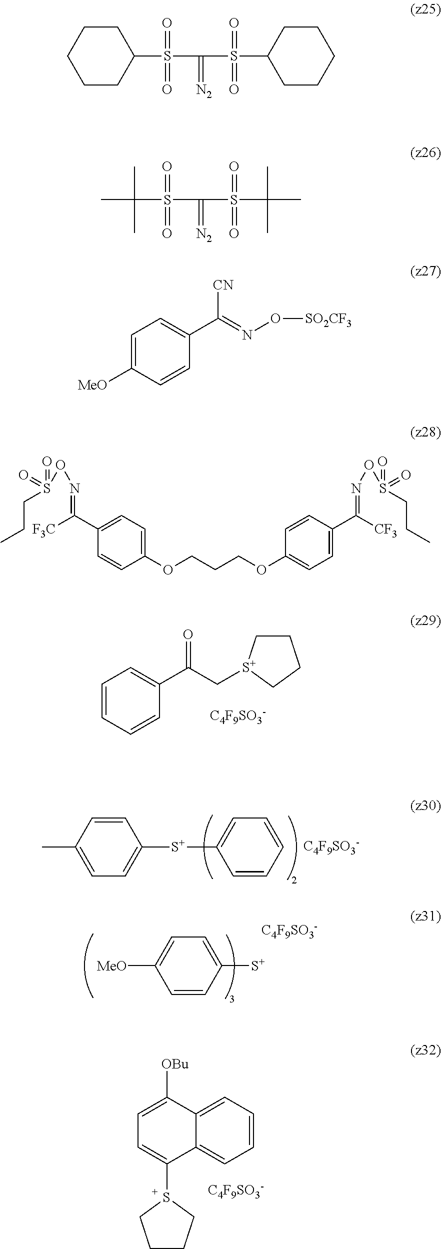

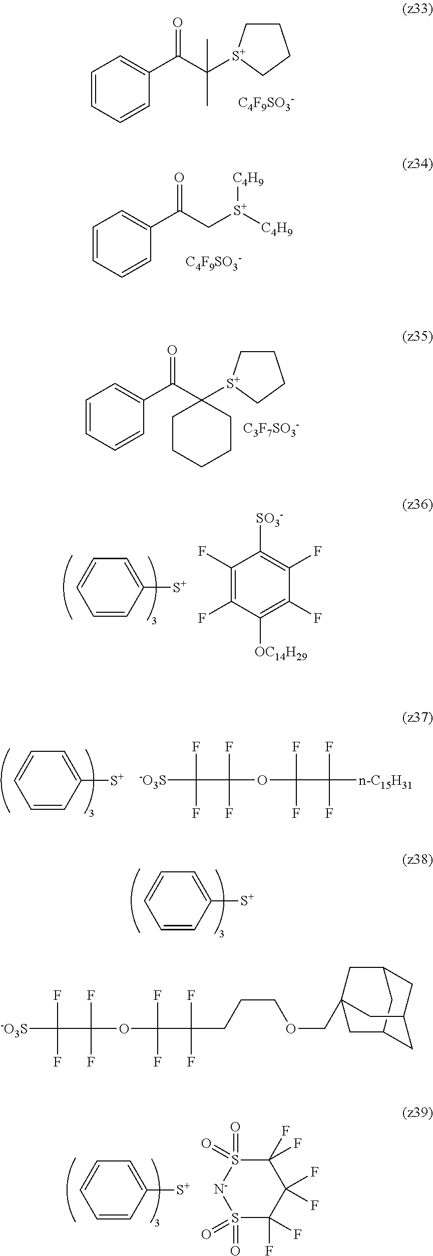

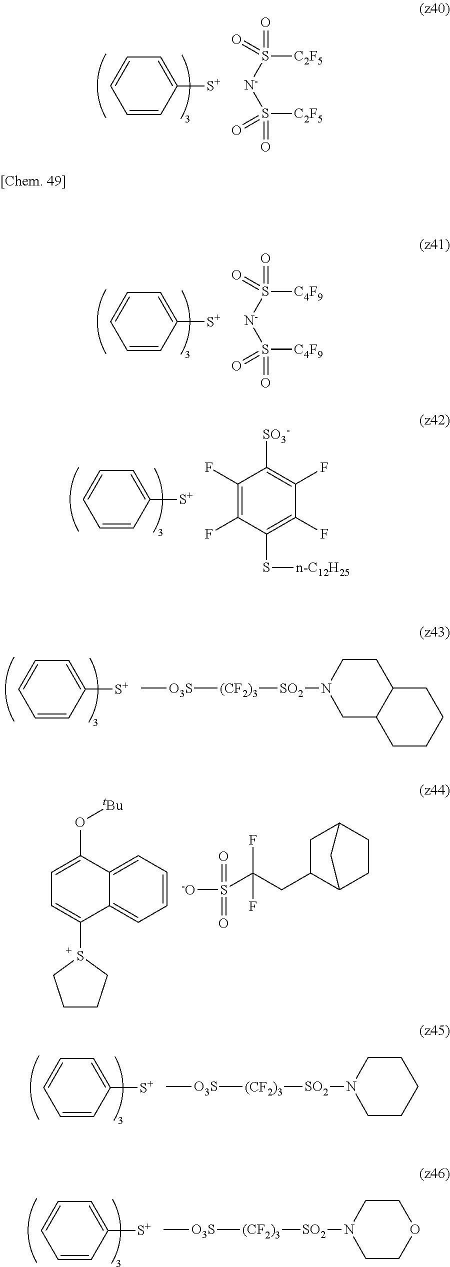

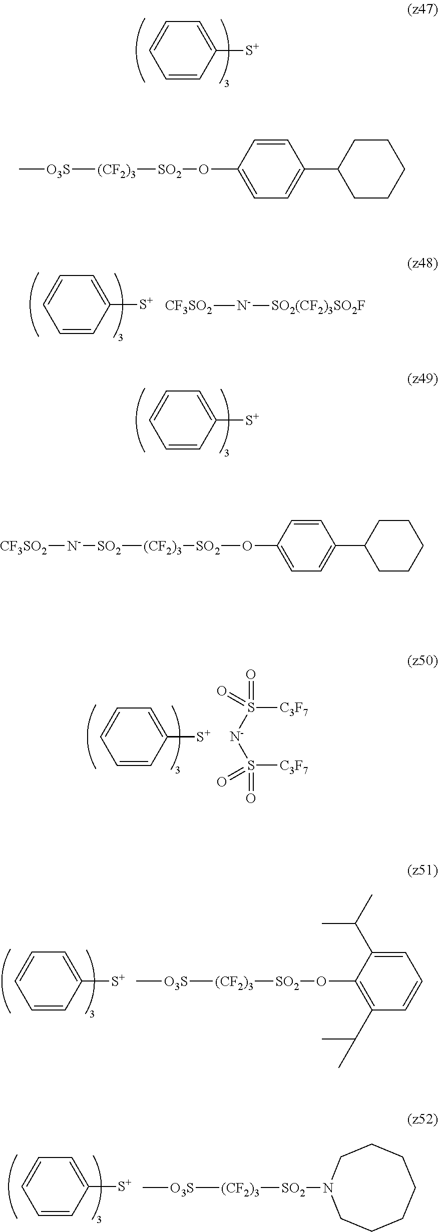

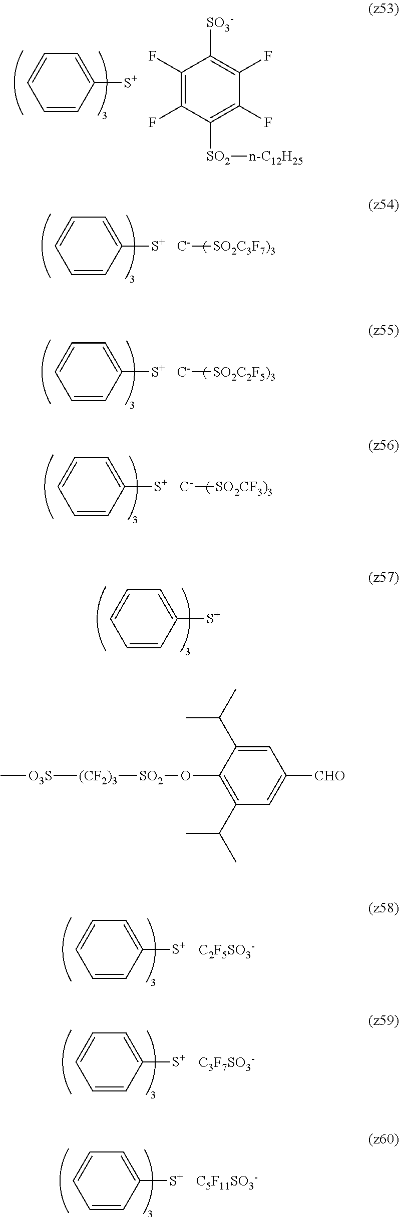

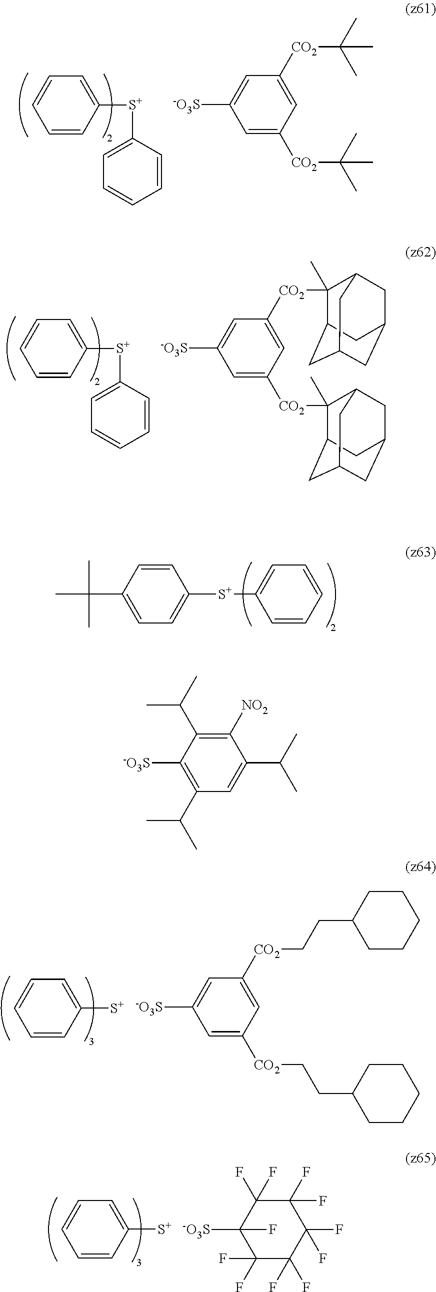

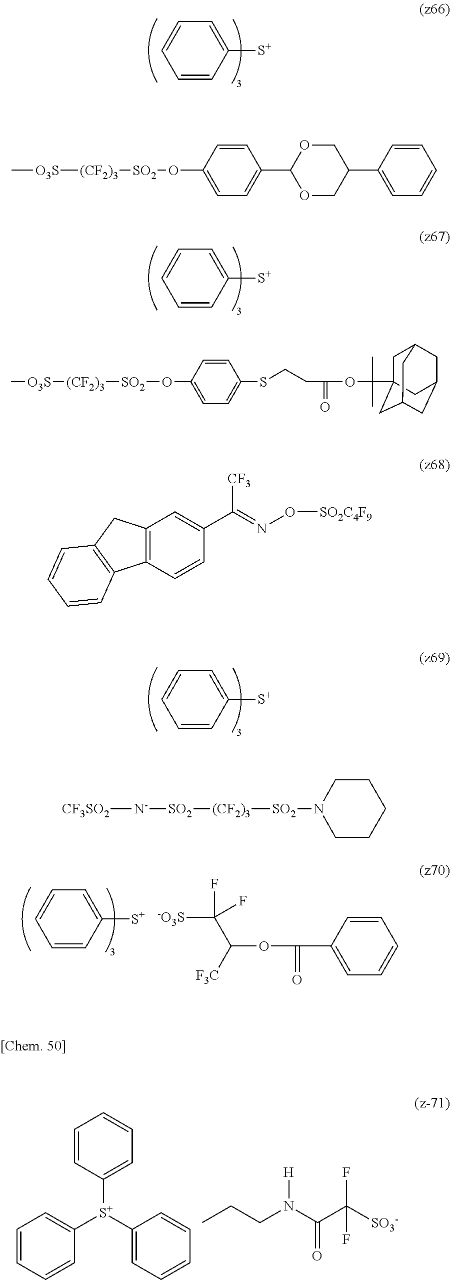

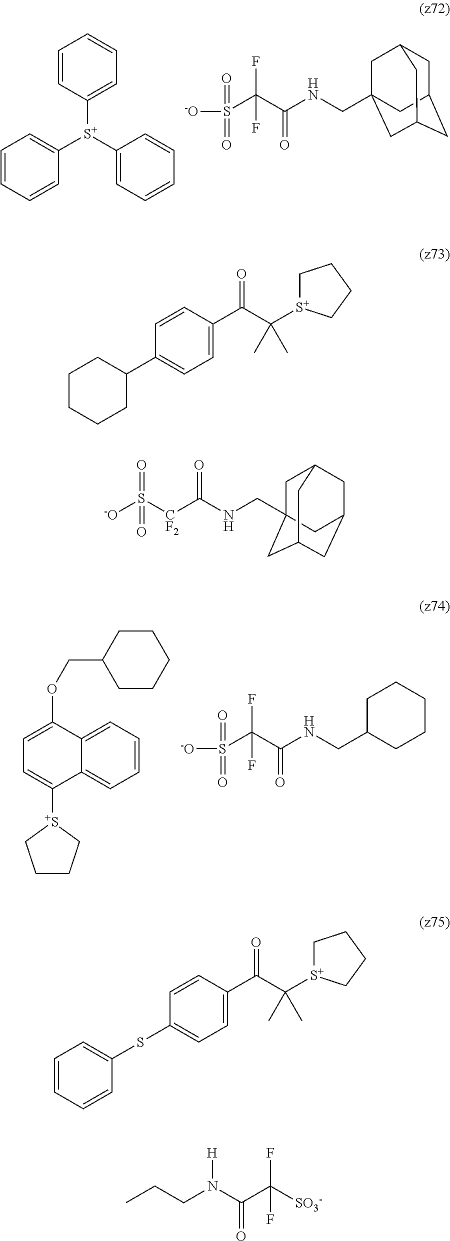

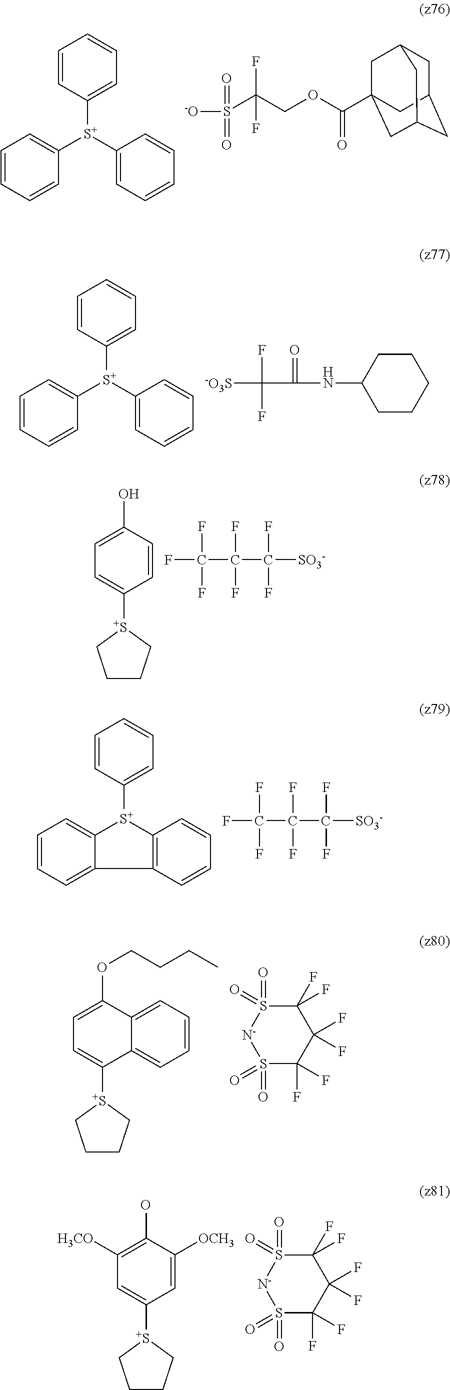

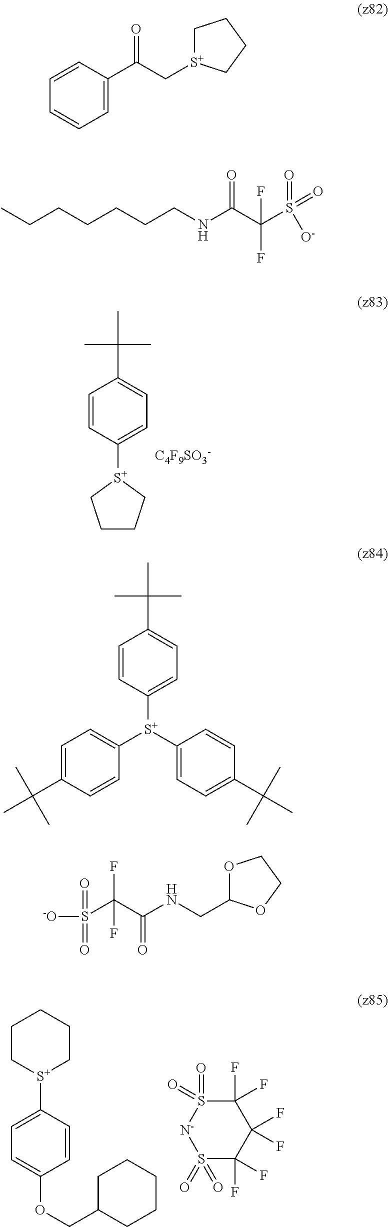

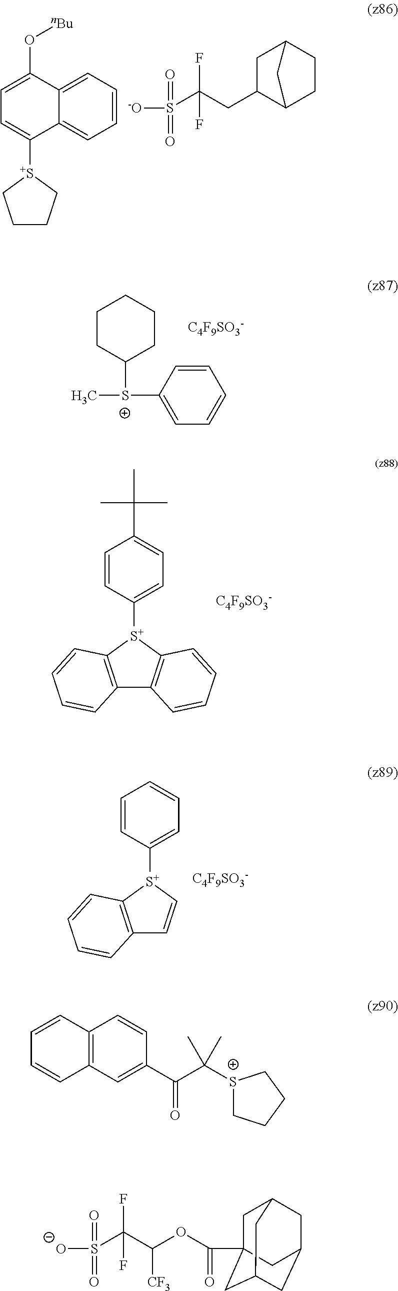

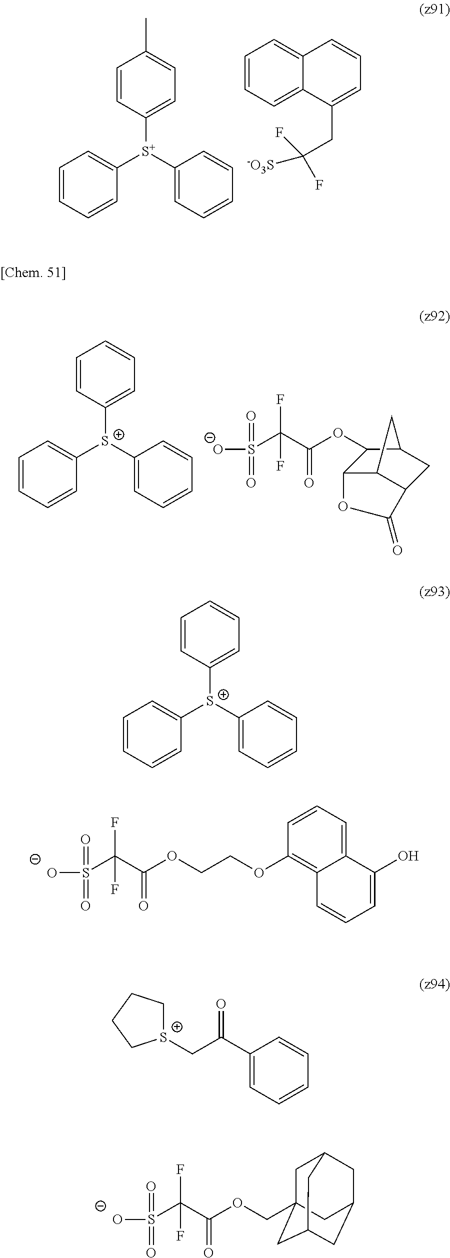

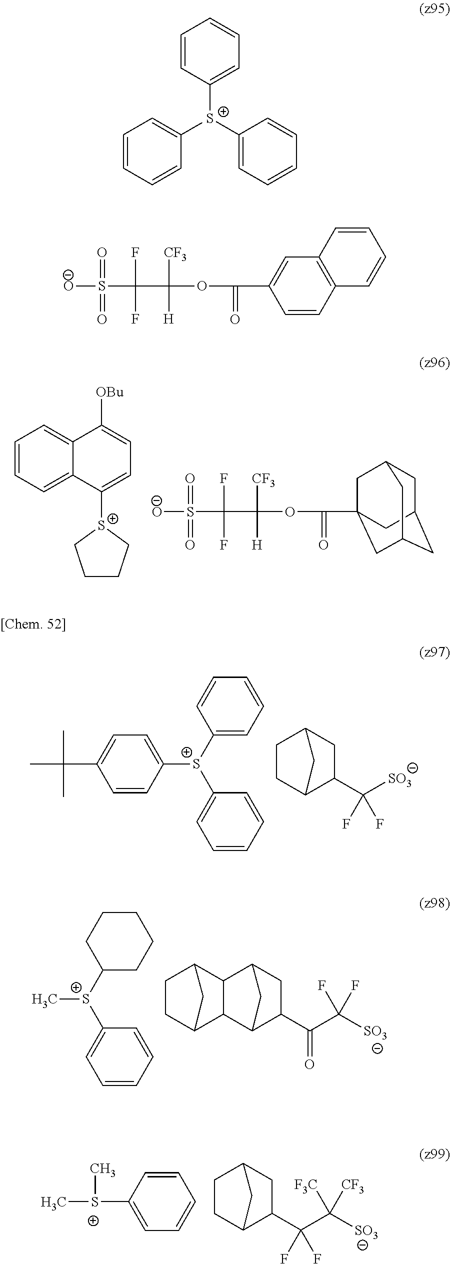

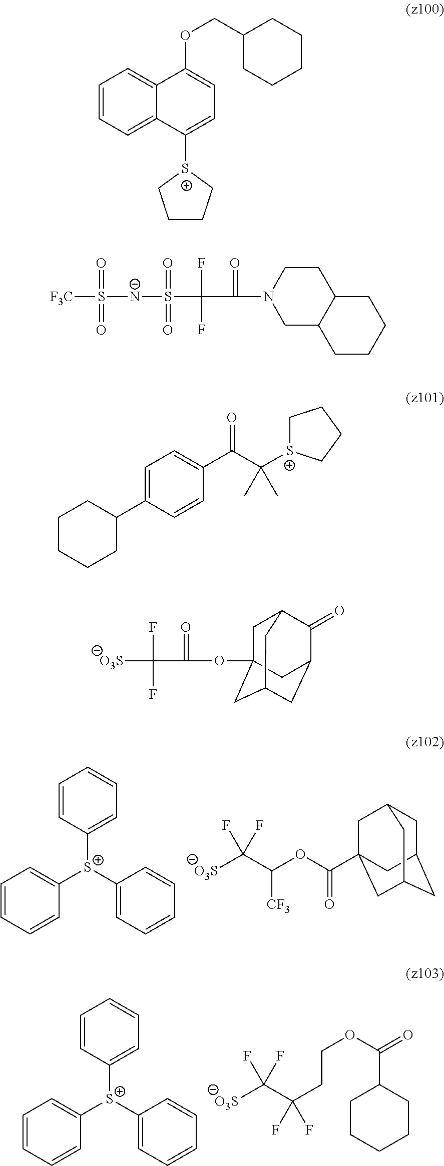

In the case where the actinic ray-sensitive or radiation-sensitive resin composition according to the present invention contains the compound (C), the content thereof is preferably from 0.1 to 25 mass %, more preferably from 0.5 to 20 mass %, still more preferably from 1 to 15 mass %, yet still more preferably from 2 to 10 mass %, based on the total solid content of the actinic ray-sensitive or radiation-sensitive resin composition.

Also, the mass ratio of the compound (C) to the compound (A) is preferably from 0.1 to 10.

### [4](D) Hydrophobic Resin

The actinic ray-sensitive or radiation-sensitive resin composition of the present invention may further contain a hydrophobic resin (hereinafter sometimes referred to as “resin (D)”) particularly when applying the composition to immersion exposure. The hydrophobic resin is unevenly distributed to the surface layer of the film and when the immersion medium is water, the static/dynamic contact angle on the resist film surface for water as well as the followability of immersion liquid can be enhanced.

The resin (D) is unevenly distributed to the interface but unlike a surfactant, need not have necessarily a hydrophilic group in the molecule and may not contribute to uniform mixing of polar/nonpolar substances.

The hydrophobic resin typically contains at least either one of a fluorine atom and a silicon atom.

The at least either a fluorine atom or a silicon atom in the hydrophobic resin may be contained in the main chain of resin or may be contained in the side chain.

In the case where the hydrophobic resin contains a fluorine atom, the hydrophobic resin is preferably a resin having a fluorine atom-containing alkyl group, a fluorine atom-containing cycloalkyl group or a fluorine atom-containing aryl group, as a fluorine atom-containing partial structure.

The fluorine atom-containing alkyl group is a linear or branched alkyl group with at least one hydrogen atom being substituted for by a fluorine atom and preferably has a carbon number of 1 to 10, more preferably a carbon number of 1 to 4. This alkyl group may further have another.

The fluorine atom-containing cycloalkyl group is a monocyclic or polycyclic cycloalkyl group with at least one hydrogen atom being substituted for by a fluorine atom and may further have another substituent.

The fluorine atom-containing aryl group is an aryl group such as phenyl group and naphthyl group, with at least one hydrogen atom being substituted for by a fluorine atom and may further have another substituent.

The fluorine atom-containing alkyl group, fluorine atom-containing cycloalkyl group and fluorine atom-containing aryl group are preferably a group represented by any one of the following formulae (F2) to (F4), but the present invention is not limited thereto:

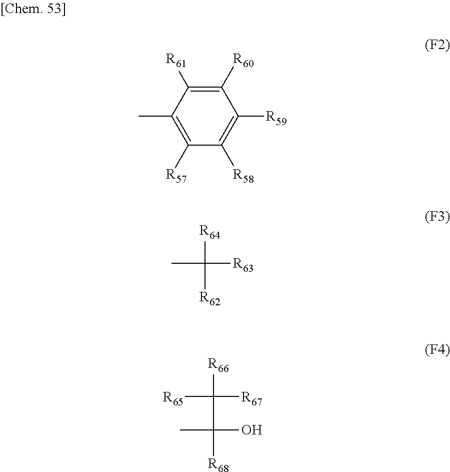

In formulae (F2) to (F4), each of R₅₇ to R₆₈ independently represents a hydrogen atom, a fluorine atom or an alkyl group (linear or branched), provided that at least one of R₅₇ to R₆₁, at least one of R₆₂ to R₆₄ and at least one of R₆₅ to R₆₈ represent a fluorine atom or an alkyl group (preferably having a carbon number of 1 to 4) with at least one hydrogen atom being substituted for by a fluorine atom.

It is preferred that all of R₅₇ to R₆₁ and R₆₅ to R₆₇ are a fluorine atom. Each of R₆₂, R₆₃ and R₆₈ is preferably a fluoroalkyl group (preferably having a carbon number of 1 to 4), more preferably a perfluoroalkyl group having a carbon number of 1 to 4. When R₆₂ and R₆₃ are a perfluoroalkyl group, R₆₄ is preferably a hydrogen atom. R₆₂ and R₆₃ may combine with each other to form a ring.

Specific examples of the group represented by formula (F2) include a p-fluorophenyl group, a pentafluorophenyl group, and a 3,5-di(trifluoromethyl)phenyl group.

Specific examples of the group represented by formula (F3) include a trifluoroethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-tert-butyl group, a perfluoroisopentyl group, a perfluorooctyl group, a perfluoro(trimethyl)hexyl group, a 2,2,3,3-tetrafluorocyclobutyl group, and a perfluorocyclohexyl group. A hexafluoroisopropyl group, a heptafluoroisopropyl group, a hexafluoro(2-methyl)isopropyl group, an octafluoroisobutyl group, a nonafluoro-tert-butyl group and a perfluoroisopentyl group are preferred, and a hexafluoroisopropyl group and a heptafluoroisopropyl group are more preferred.

Specific examples of the group represented by formula (F4) include —C(CF₃)₂OH, —C(C₂F₅)₂OH, —C(CF₃)(CH₃)OH and —CH(CF₃)OH, with —C(CF₃)₂OH being preferred.

The fluorine-containing partial structure may be directly bonded to the main chain or may be bonded to the main chain through a group selected from the group consisting of an alkylene group, a phenylene group, an ether bond, a thioether bond, a carbonyl group, an ester bond, an amide bond, a urethane bond and a ureylene bond, or a group formed by combining two or more thereof.

Preferred repeating units having a fluorine atom include the followings.

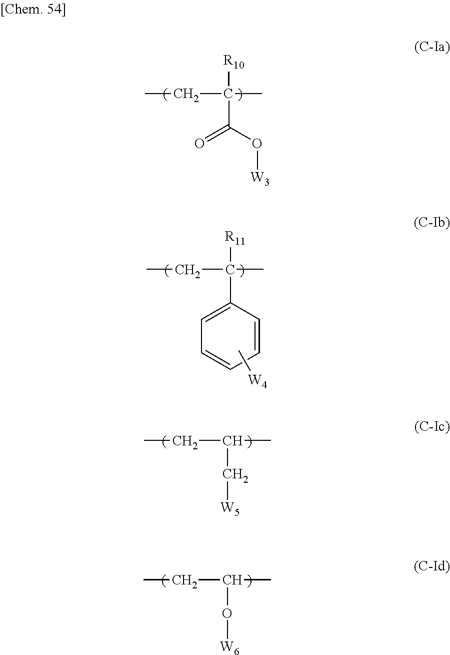

In the formulae, each of R₁₀ and R₁₁ independently represents a hydrogen atom, a fluorine atom or an alkyl group. The alkyl group is preferably a linear or branched alkyl group having a carbon number of 1 to 4 and may have a substituent. The alkyl group having a substituent includes a fluorinated alkyl group, among others.

Each of W₃ to W₆ independently represents an organic group having at least one or more fluorine atoms, and specific examples thereof include the atomic groups of (F2) to (F4).

In addition to these units, the hydrophobic resin may contain a unit shown below, as the repeating unit having a fluorine atom.

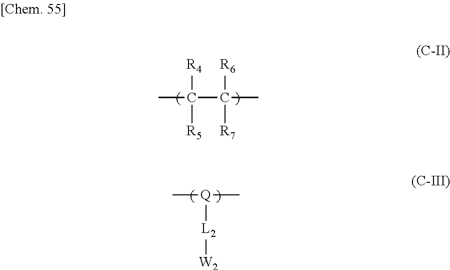

In the formulae, each of R₄ to R₇ independently represents a hydrogen atom, a fluorine atom or an alkyl group. The alkyl group is preferably a linear or branched alkyl group having a carbon number of 1 to 4 and may have a substituent, and the alkyl group having a substituent includes a fluorinated alkyl group, among others.

However, at least one of R₄ to R₇ represents a fluorine atom. A pair of R₄ and R₅ or a pair of R₆ and R₇ may form a ring.

W₂ represents an organic group containing at least one fluorine atom. Specific examples thereof include the atomic groups of (F2) to (F4).

L₂ represents a single bond or a divalent linking group. The divalent linking group is a substituted or unsubstituted arylene group, a substituted or unsubstituted alkylene group, a substituted or unsubstituted cycloalkylene group, —O—, —SO₂—, —CO—, —N(R)— (wherein R represents a hydrogen atom or an alkyl group), —NHSO₂ —, or a divalent linking group formed by combining a plurality of these members.

Q represents an alicyclic structure. The alicyclic structure may have a substituent and may be monocyclic or polycyclic, and in the case of a polycyclic structure, the structure may be crosslinked. The monocyclic structure is preferably a cycloalkyl group having a carbon number of 3 to 8, and examples thereof include a cyclopentyl group, a cyclohexyl group, a cyclobutyl group, and a cyclooctyl group. The polycyclic structure includes a group having a bicyclo, tricyclo or tetracyclo structure or the like with a carbon number of 5 or more. A cycloalkyl group having a carbon number of 6 to 20 is preferred, and examples thereof include an adamantyl group, a norbornyl group, a dicyclopentyl group, a tricyclodecanyl group, and a tetracyclododecyl group. Incidentally, a part of carbon atoms in the cycloalkyl group may be substituted with a heteroatom such as oxygen atom. Q is preferably a norbornyl group, a tricyclodecanyl group, a tetracyclododecyl group or the like, among others.

The hydrophobic resin may contain a silicon atom.

The resin preferably has an alkylsilyl structure (preferably a trialkylsilyl group) or a cyclic siloxane structure as the silicon atom-containing partial structure.

The alkylsilyl structure and cyclic siloxane structure specifically include, for example, the groups represented by the following formulae (CS-1) to (CS-3):

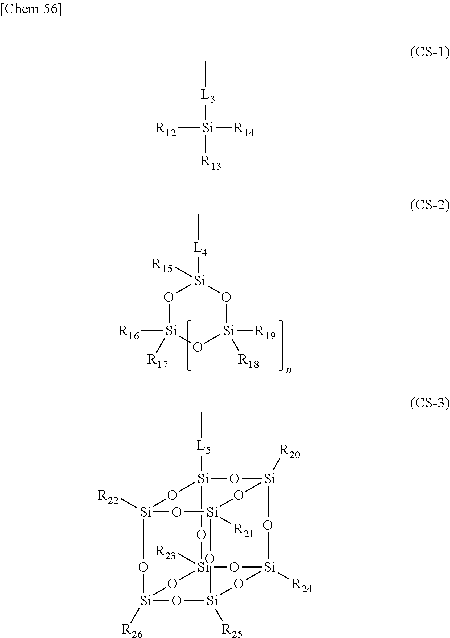

In formulae (CS-1) to (CS-3), each of R₁₂ to R₂₆ independently represents a linear or branched alkyl group (preferably having a carbon number of 1 to 20) or a cycloalkyl group (preferably having a carbon number of 3 to 20).

Each of L₃ to L₅ represents a single bond or a divalent linking group. The divalent linking group is a single member selected from the group consisting of an alkylene group, a phenylene group, an ether bond, a thioether bond, a carbonyl group, an ester bond, an amide bond, a urethane bond and a urea bond, or a combination of two or more thereof.

n represents an integer of 1 to 5. n is preferably an integer of 2 to 4.

The repeating unit having at least either a fluorine atom or a silicon atom is preferably a (meth)acrylate-based repeating unit.

Specific examples of the repeating unit having at least either a fluorine atom or a silicon atom are illustrated below, but the present invention is not limited thereto. In specific examples, X₁ represents a hydrogen atom, —CH₃, —F or —CF₃, and X₂ represents —F or —CF₃.

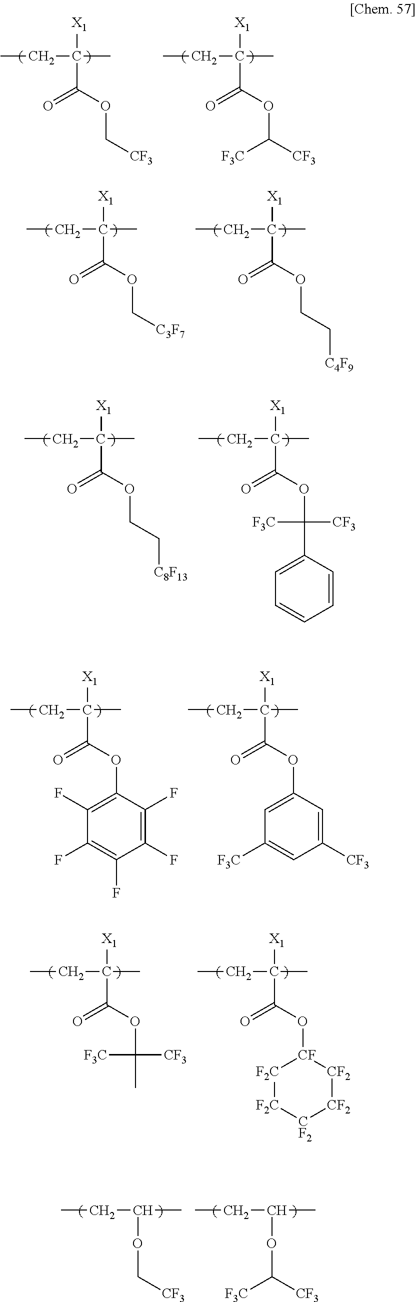

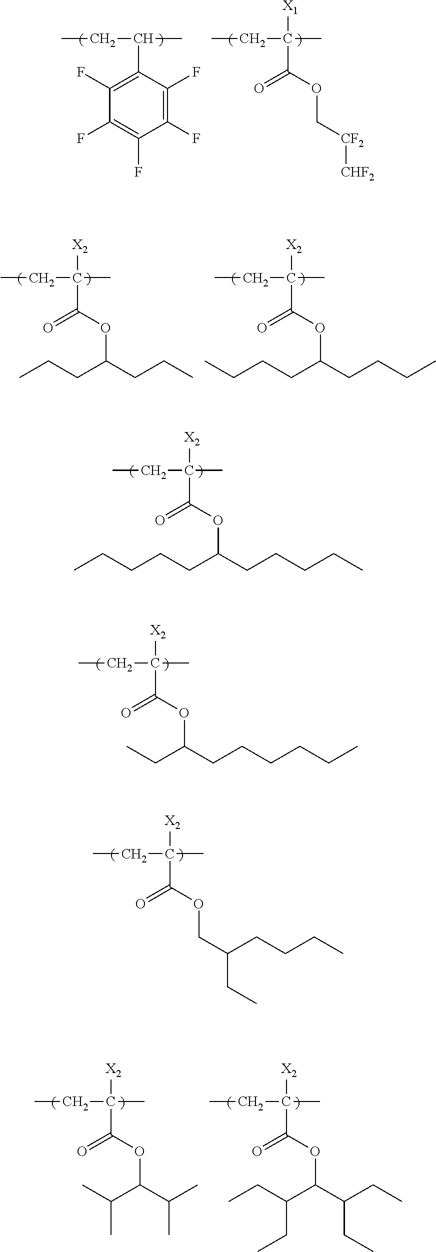

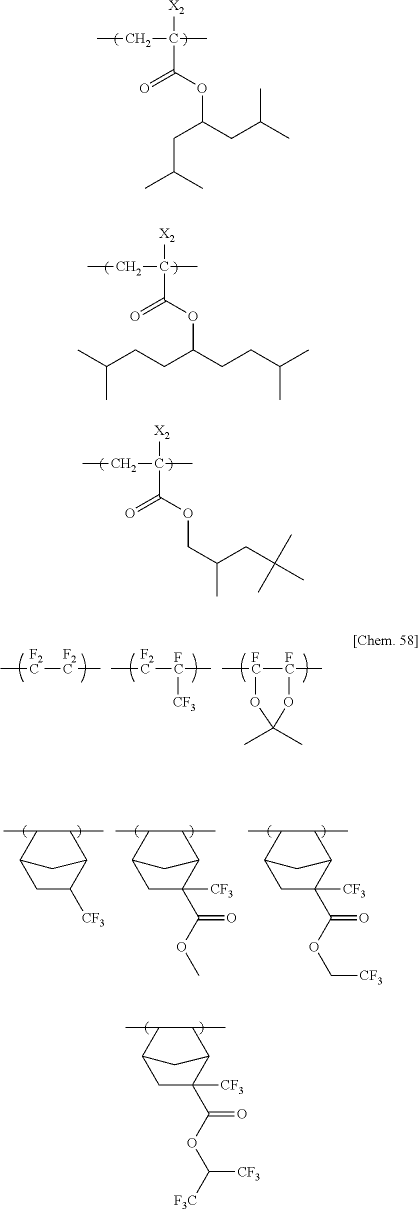

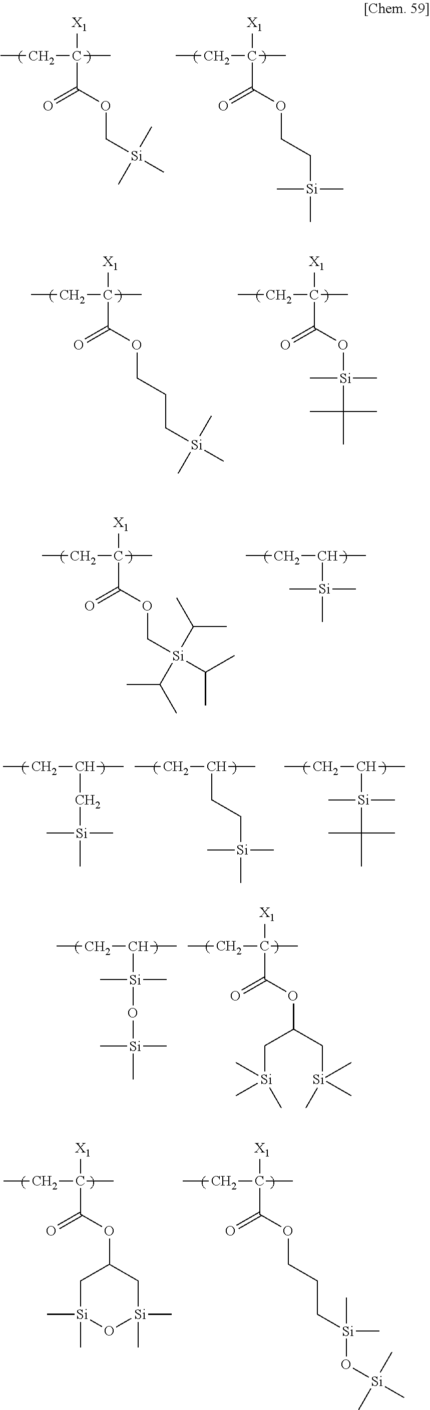

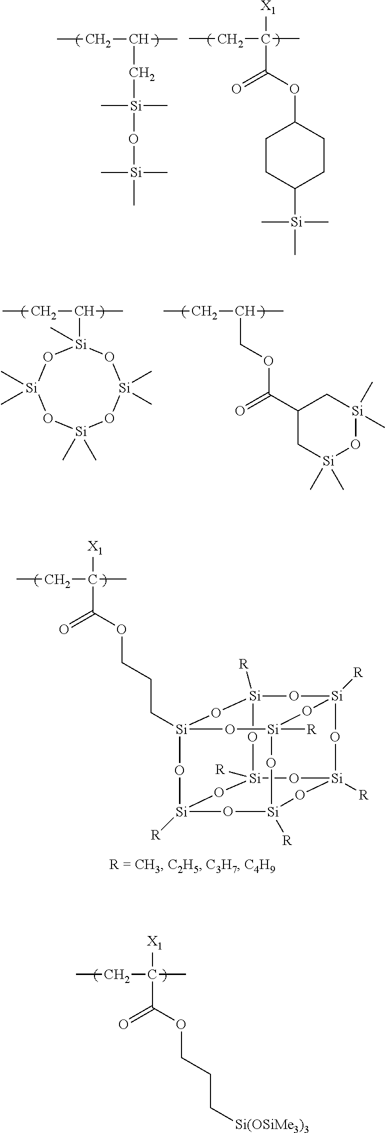

The hydrophobic resin preferably contains (b) a repeating unit having at least one group selected from the group consisting of the following (x) to (z):

(x) an alkali-soluble group,

(y) a group capable of decomposing by the action of an alkali developer to increase the solubility for an alkali developer (hereinafter, sometimes referred to as a polarity converting group), and

(z) a group capable of decomposing by the action of an acid to increase the solubility for an alkali developer.

The repeating unit (b) includes the following types:

(b′) a repeating unit having at least either a fluorine atom or a silicon atom and at least one group selected from the group consisting of (x) to (z), on one side chain,

(b*) a repeating unit having at least one group selected from the group consisting of (x) to (z) and at the same time, having neither a fluorine atom nor a silicon atom, and

(b″) a repeating unit having at least one group selected from the group consisting of (x) to (z) on one side chain and at the same time, having at least either a fluorine atom or a silicon atom on a side chain different from the side chain above in the same repeating unit

The hydrophobic resin more preferably contains the repeating unit (b) as the repeating unit (b). In other words, it is more preferred that the repeating unit (b) having at least one group selected from the group consisting of (x) to (z) has at least either a fluorine atom or a silicon atom.

In the case where the hydrophobic resin contains the repeating unit (b*), the resin is preferably a copolymer with a repeating unit having at least either a fluorine atom or a silicon atom (a repeating unit different from the repeating units (b) and (b″)). Also, in the repeating unit (b″), the side chain having at least one group selected from the group consisting of (x) to (z) and the side chain having at least either a fluorine atom or a silicon atom are preferably bonded to the same carbon atom in the main chain, that is, have a positional relationship as in the following formula (K1).

In the formula, B1 represents a partial structure having at least one group selected from the group consisting of (x) to (z), and B2 represents a partial structure having at least either a fluorine atom or a silicon atom.

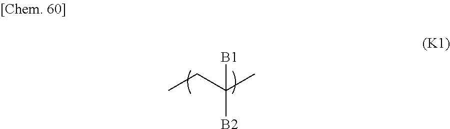

The group selected from the group consisting of (x) to (z) is preferably (x) an alkali-soluble group or (y) a polarity converting group, more preferably (y) a polarity converting group.

The alkali-soluble group (x) includes a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, a tris(alkylsulfonyl)methylene group, and the like.

Preferred alkali-soluble groups include a fluorinated alcohol group (preferably hexafluoroisopropanol), a sulfonimide group, and a bis(carbonyl)methylene group.

The repeating unit (bx) having (x) an alkali-soluble group includes a repeating unit where an alkali-soluble group is directly bonded to the main chain of the resin, such as repeating unit by an acrylic acid or a methacrylic acid; and a repeating unit where an alkali-soluble group is bonded to the main chain of the resin through a linking group. Furthermore, an alkali-soluble group may be introduced into the terminal of the polymer chain by using an alkali-soluble group-containing polymerization initiator or chain transfer agent at the polymerization. All of these cases are preferred.

In the case where the repeating unit (bx) is a repeating unit having at least either a fluorine atom or a silicon atom (that is, in the case of corresponding to the repeating unit (b′) or (b″)), examples of the fluorine atom-containing partial structure in the repeating unit (bx) are the same as those in the above-described repeating unit having at least either a fluorine atom or a silicon atom, and the groups represented by formula (F2) to (F4) are preferred. Also, examples of the silicon atom-containing partial structure in the repeating unit (bx) are the same as those in the above-described repeating unit having at least either a fluorine atom or a silicon atom, and the groups represented by formulae (CS-1) to (CS-3) are preferred.

The content of the repeating unit (bx) having (x) an alkali-soluble group is preferably from 1 to 50 mol %, more preferably from 3 to 35 mol %, still more preferably from 5 to 20 mol %, based on all repeating units in the hydrophobic resin.

Specific examples of the repeating unit (bx) having (x) an alkali-soluble group are illustrated below, but the present invention is not limited thereto. In specific examples, X₁ represents a hydrogen atom, —CH₃, —F or —CF₃.

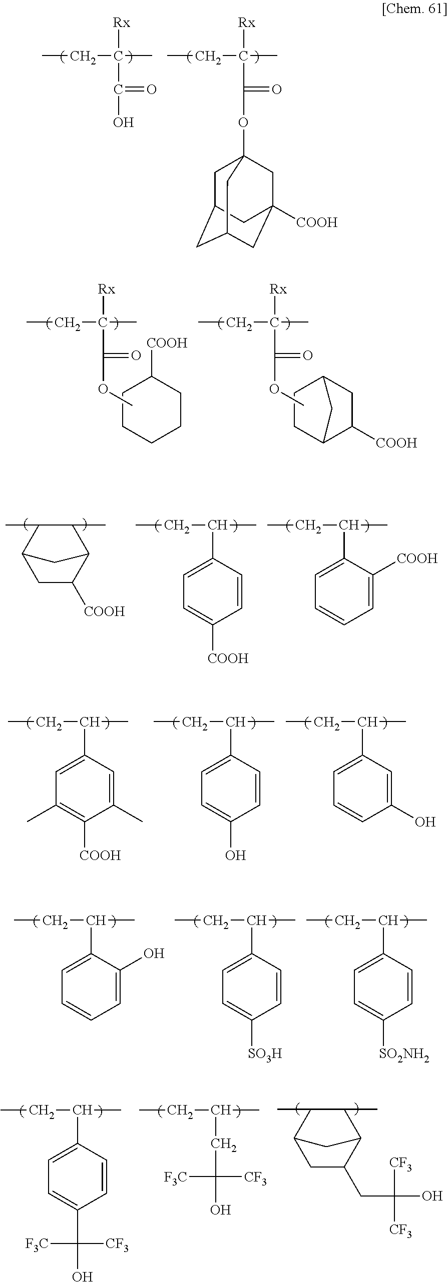

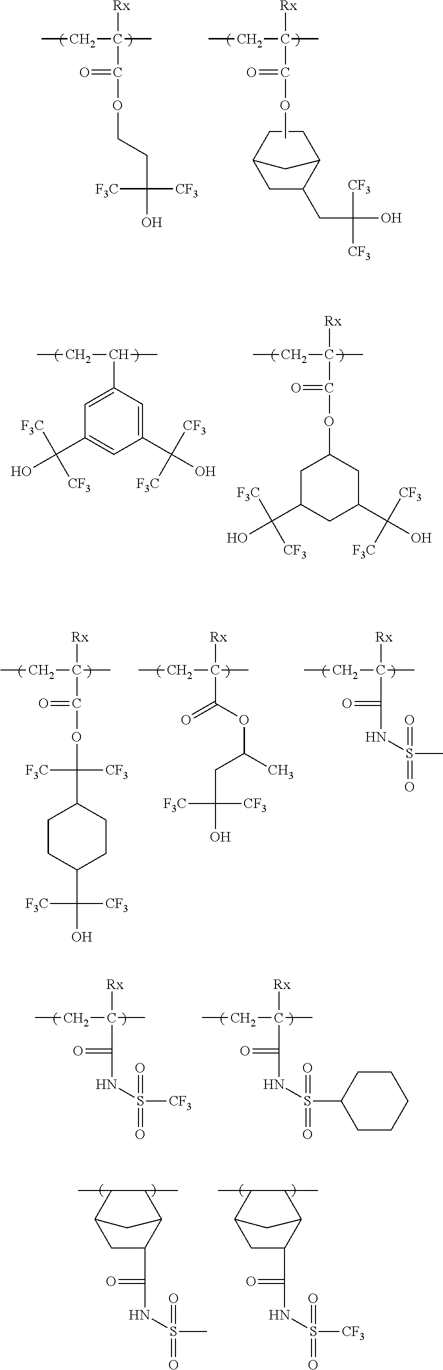

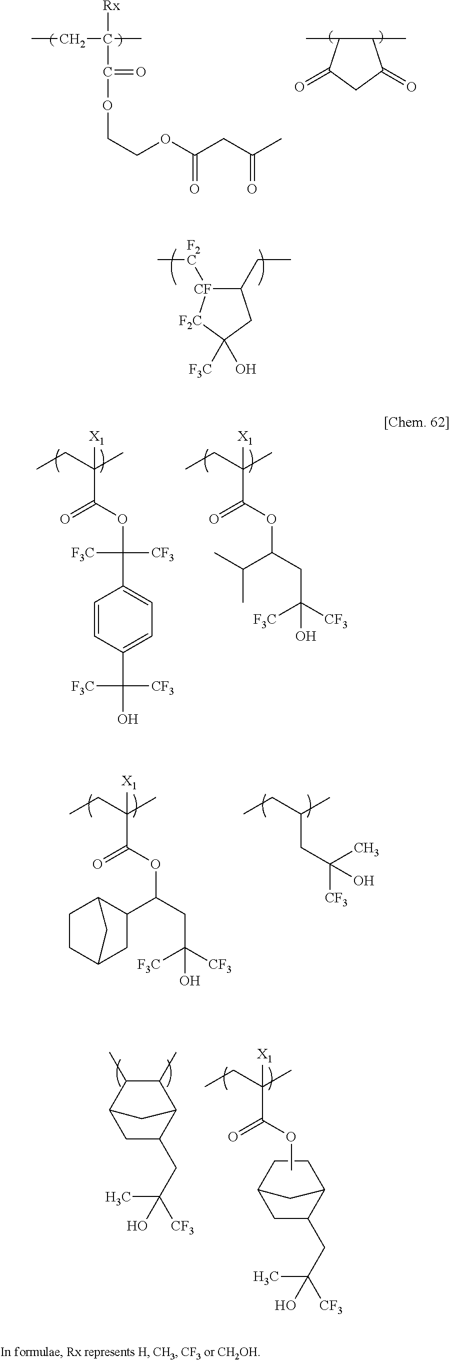

The polarity converting group (y) includes, for example, a lactone group, a carboxylic acid ester group (—COO—), an acid anhydride group (—C(O)OC(O)—), an acid imide group (—NHCONH—), a carboxylic acid thioester group (—COS—), a carbonic acid ester group (—OC(O)O—), a sulfuric acid ester group (—OSO₂O—), and a sulfonic acid ester group (—SO₂O—) and is preferably a lactone group.

Both an embodiment where the polarity converting group (y) is contained, for example, in a repeating unit composed of an acrylic acid ester or a methacrylic acid ester and thereby is introduced into the side chain of the resin, and an embodiment where the polarity converting group (y) is introduced into the terminal of the polymer chain by using a polymerization initiator or chain transfer agent containing the group, are preferred.

Specific examples of the repeating unit (by) having (y) a polarity converting group include repeating units having a lactone structure represented by formulae (KA-1-1) to (KA-1-17) described later.

The repeating unit (by) having (y) a polarity converting group is preferably a repeating unit having at least either a fluorine atom or a silicon atom (that is, in the case of a repeating unit corresponding to the repeating unit (b′) or (b″)). The resin containing the repeating unit (by) has hydrophobicity, and this is preferred particularly from the standpoint of reducing the development defect.

The repeating unit (by) includes, for example, a repeating unit represented by formula (K0):

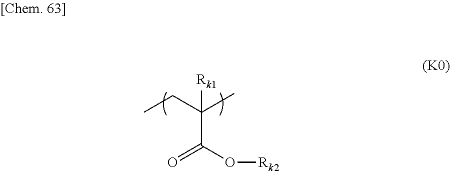

In the formula, Rₖ₁ represents a hydrogen atom, a halogen atom, a hydroxyl group, an alkyl group, a cycloalkyl group, an aryl group or a polarity converting group-containing group.

Rₖ₂ represents an alkyl group, a cycloalkyl group, an aryl group or a polarity converting group-containing group.

However, at least either one of Rₖ₁ and Rₖ₂ represents a polarity converting group-containing group.

The polarity converting group indicates, as described above, a group capable of decomposing by the action of an alkali developer to increase the solubility in an alkali developer. The polarity converting group is preferably a group X in a partial structure represented by formula (KA-1) or (KB-1):

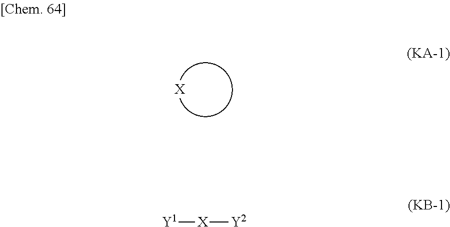

In formulae (KA-1) and (KB-1), X represents a carboxylic acid ester group: —COO—, an acid anhydride group: —C(O)OC(O)—, an acid imide group: —NHCONH—, a carboxylic acid thioester group: —COS—, a carbonic acid ester group: —OC(O)O—, a sulfuric acid ester group: —OSO₂O—, or a sulfonic acid ester group: —SO₂O—.

Each of Y¹ and Y², which may be the same or different, represents an electron-withdrawing group.

Incidentally, the repeating unit (by) has a preferred group capable of increasing the solubility in an alkali developer by containing a group having a partial structure represented by formula (KA-1) or (KB-1), but as in the case of the partial structure represented by formula (KA-1) or the partial structure represented by formula (KB-1) where Y¹ and Y² are monovalent, when the partial structure does not have a bond, the group having the partial structure is a group having a monovalent or higher valent group formed by removing at least one arbitrary hydrogen atom in the partial structure.

The partial structure represented by formula (KA-1) or (KB-1) is connected to the main chain of the hydrophobic resin at an arbitrary position through a substituent.

The partial structure represented by formula (KA-1) is a structure forming a ring structure together with the group as X.

In formula (KA-1), X is preferably a carboxylic acid ester group (that is, a case of forming a lactone ring structure as KA-1), an acid anhydride group or a carbonic acid ester group, more preferably a carboxylic acid ester group.

The ring structure represented by formula (KA-1) may have a substituent and, for example, may have nka substituents Zₖₐ₁.

Zₖₐ₁ represents, when a plurality of Zₖₐ₁ are present, each independently represents, a halogen atom, an alkyl group, a cycloalkyl group, an ether group, a hydroxyl group, an amide group, an aryl group, a lactone ring group or an electron-withdrawing group.

Zₖₐ₁ may combine with each other to form a ring. The ring formed by combining Zₖₐ₁ with each other includes, for example, a cycloalkyl ring and a heterocyclic ring (e.g., cyclic ether ring, lactone ring).

nka represents an integer of 0 to 10 and is preferably an integer of 0 to 8, more preferably an integer of 0 to 5, still more preferably an integer of 1 to 4, and most preferably an integer of 1 to 3.

The electron-withdrawing group as Zₖₐ₁ is the same as the electron-withdrawing group of Y¹ and Y² described later. Incidentally, this electron-withdrawing group may be substituted with another electron-withdrawing group.

Zₖₐ₁ is preferably an alkyl group, a cycloalkyl group, an ether group, a hydroxyl group or an electron-withdrawing group, more preferably an alkyl group, a cycloalkyl group or an electron-withdrawing group. The ether group is preferably an ether group substituted with an alkyl group, a cycloalkyl group or the like, that is, preferably an alkyl ether group or the like. The electron-withdrawing group has the same meaning as above.

The halogen atom of Zₖₐ₁ includes a fluorine atom, a chlorine atom, a bromine atom, an iodine atom, and the like and is preferably a fluorine atom.

The alkyl group as Zₖₐ₁ may have a substituent and may be either linear or branched. The linear alkyl group is preferably an alkyl group having a carbon number of 1 to 30, more preferably from 1 to 20, and examples thereof include a methyl group, an ethyl group, an n-propyl group, an n-butyl group, a sec-butyl group, a tert-butyl group, an n-pentyl group, an n-hexyl group, an n-heptyl group, an n-octyl group, an n-nonyl group, and an n-decanyl group. The branched alkyl group is preferably an alkyl group having a carbon number of 3 to 30, more preferably from 3 to 20, and examples thereof include an i-propyl group, an i-butyl group, a tert-butyl group, an i-pentyl group, a tert-pentyl group, an i-hexyl group, a tert-hexyl group, an i-heptyl group, a tert-heptyl group, an i-octyl group, a tert-octyl group, an i-nonyl group and a tert-decanoyl group. An alkyl group having a carbon number of 1 to 4, such as methyl group, ethyl group, n-propyl group, i-propyl group, n-butyl group, i-butyl group and tert-butyl group, is preferred.

The cycloalkyl group as Zₖₐ₁ may have a substituent and may be monocyclic or polycyclic. In the case of a polycyclic type, the cycloalkyl group may be crosslinked. That is, in this case, the cycloalkyl group may have a bridged structure. The monocyclic type is preferably a cycloalkyl group having a carbon number of 3 to 8, and examples thereof include a cyclopropyl group, a cyclopentyl group, a cyclohexyl group, a cyclobutyl group, and a cyclooctyl group. The polycyclic type includes a group having a bicyclo, tricyclo or tetracyclo structure or the like and having a carbon number of 5 or more. A cycloalkyl group having a carbon number of 6 to 20 is preferred, and examples thereof include an adamantyl group, a norbornyl group, an isoboronyl group, a camphanyl group, a dicyclopentyl group, an α-pinel group, a tricyclodecanyl group, a tetracyclododecyl group, and an androstanyl group. As the cycloalkyl group, the following structure is also preferred. Incidentally, a part of carbon atoms in the cycloalkyl group may be substituted with a heteroatom such as oxygen atom.

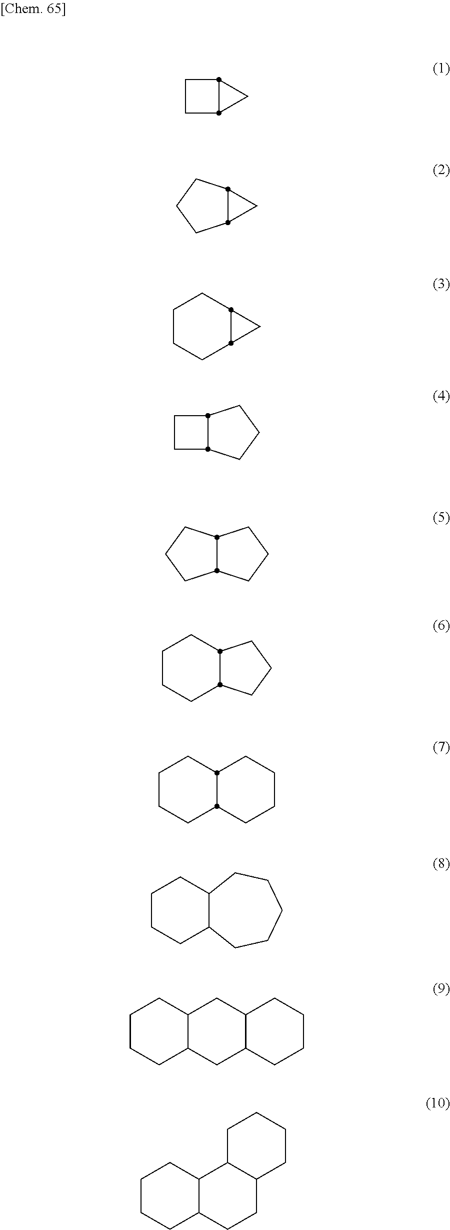

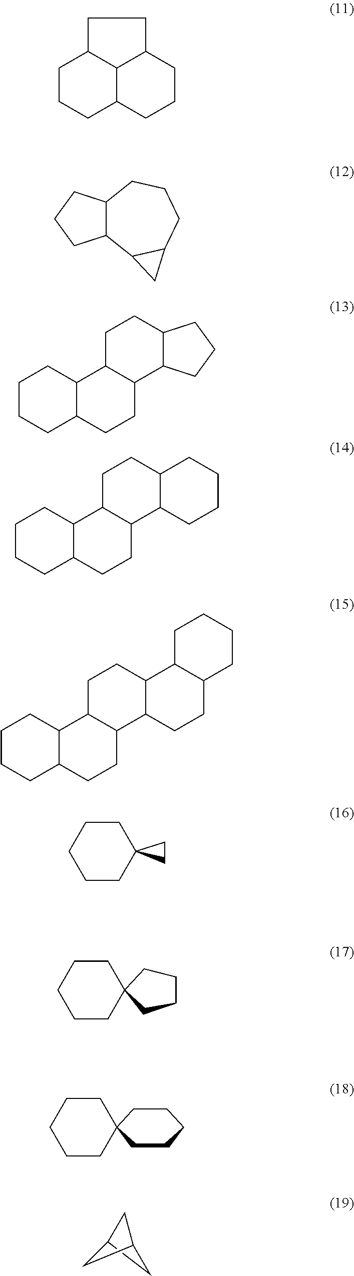

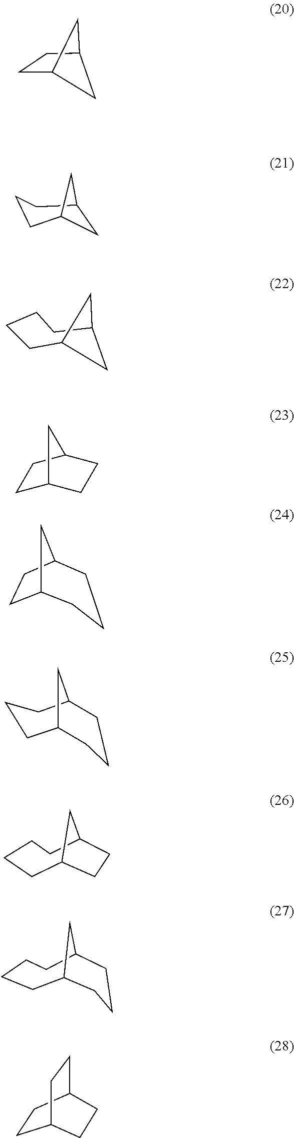

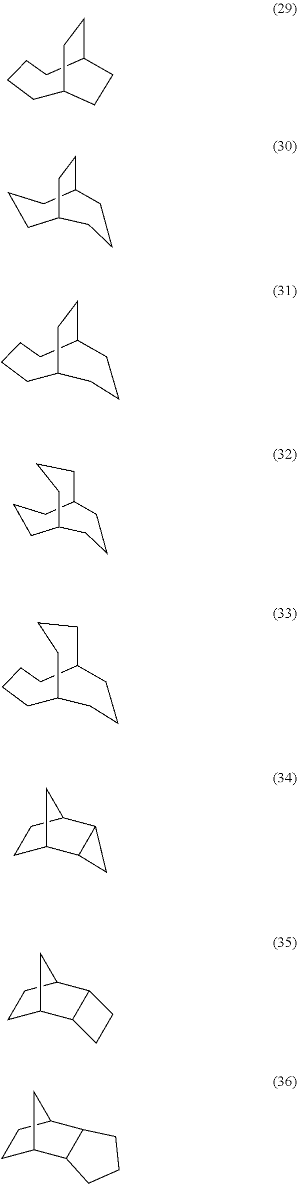

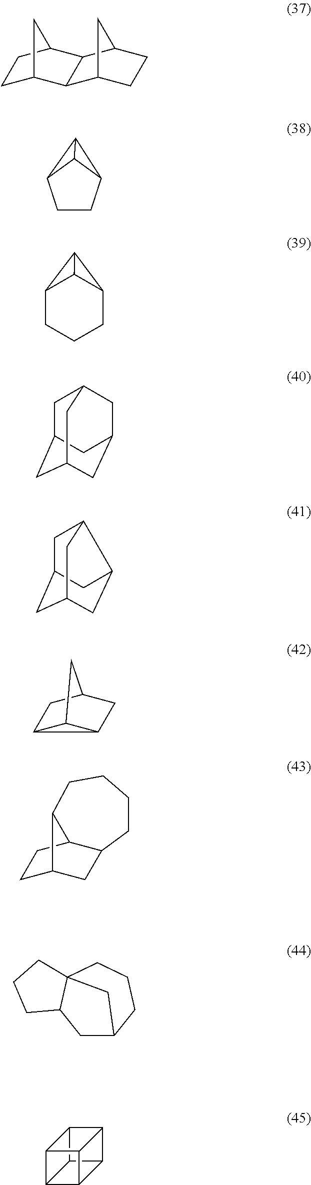

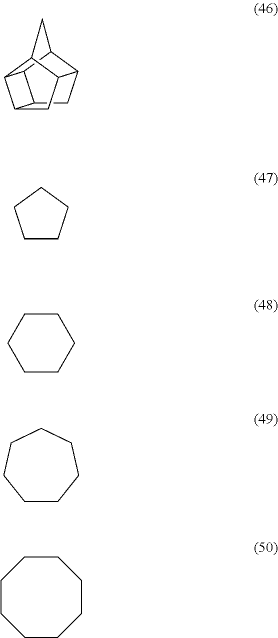 [SMILES: C1C2C3CC4C5CC3C1C5C24 ; C1CCCC1 ; C1CCCCC1 ; C1CCCCCC1 ; C1CCCCCCC1]

Preferred alicyclic moieties include an adamantyl group, a noradamantyl group, a decalin group, a tricyclodecanyl group, a tetracyclododecanyl group, a norbornyl group, a cedrol group, a cyclohexyl group, a cycloheptyl group, a cyclooctyl group, a cyclodecanyl group and a cyclododecanyl group, and an adamantyl group, a decalin group, a norbornyl group, a cedrol group, a cyclohexyl group, a cycloheptyl group, a cyclooctyl group, a cyclodecanyl group, a cyclododecanyl group and a tricyclodecanyl group are more preferred.

The substituent on these alicyclic structures includes an alkyl group, a halogen atom, a hydroxyl group, an alkoxy group, a carboxyl group, and an alkoxycarbonyl group. The alkyl group is preferably a lower alkyl group such as methyl group, ethyl group, propyl group, isopropyl group and butyl group, more preferably a methyl group, an ethyl group, a propyl group or an isopropyl group. The alkoxy group is preferably an alkoxy group having a carbon number of 1 to 4, such as methoxy group, ethoxy group, propoxy group and butoxy group. The substituent that may be substituted on the alkyl group and alkoxy group includes a hydroxyl group, a halogen atom, an alkoxy group (preferably having a carbon number of 1 to 4), and the like.

Also, these group may further have a substituent, and examples of the further substituent include a hydroxyl group, a halogen atom (e.g., fluorine, chlorine, bromine, iodine), a nitro group, a cyano group, the above-described alkyl group, an alkoxy group such as methoxy group, ethoxy group, hydroxyethoxy group, propoxy group, hydroxypropoxy group, n-butoxy group, isobutoxy group, sec-butoxy group and tert-butoxy group, an alkoxycarbonyl group such as methoxycarbonyl group and ethoxycarbonyl group, an aralkyl group such as benzyl group, phenethyl group and cumyl group, an aralkyloxy group, an acyl group such as formyl group, acetyl group, butyryl group, benzoyl group, cinnamyl group and valeryl group, an acyloxy group such as butyryloxy group, an alkenyl group such as vinyl group, propenyl group and allyl group, an alkenyloxy group such as vinyloxy group, propenyloxy group, allyloxy group and butenyloxy group, the above-described aryl group, an aryloxy group such as phenoxy group, and an aryloxycarbonyl group such as benzoyloxy group.

It is preferred that X in formula (KA-1) is a carboxylic acid ester group and the partial structure represented by formula (KA-1) is a lactone ring, and the lactone ring is preferably a 5- to 7-membered lactone ring.

In this connection, as in (KA-1-1) to (KA-1-17) shown below, another ring structure is preferably fused to a 5- to 7-membered lactone ring of the partial structure represented by formula (KA-1) in the form of forming a bicyclo or spiro structure.

The peripheral ring structure with which the ring structure represented by formula (KA-1) may combine includes, for example, those in (KA-1-1) to (KA-1-17) shown below and those based on these structures.

The structure containing the lactone ring structure represented by formula (KA-1) is more preferably a structure represented by any one of the following (KA-1-1) to (KA-1-17). The lactone structure may be bonded directly to the main chain. Preferred structures are (KA-1-1), (KA-1-4), (KA-1-5), (KA-1-6), (KA-1-13), (KA-1-14) and (KA-1-17).

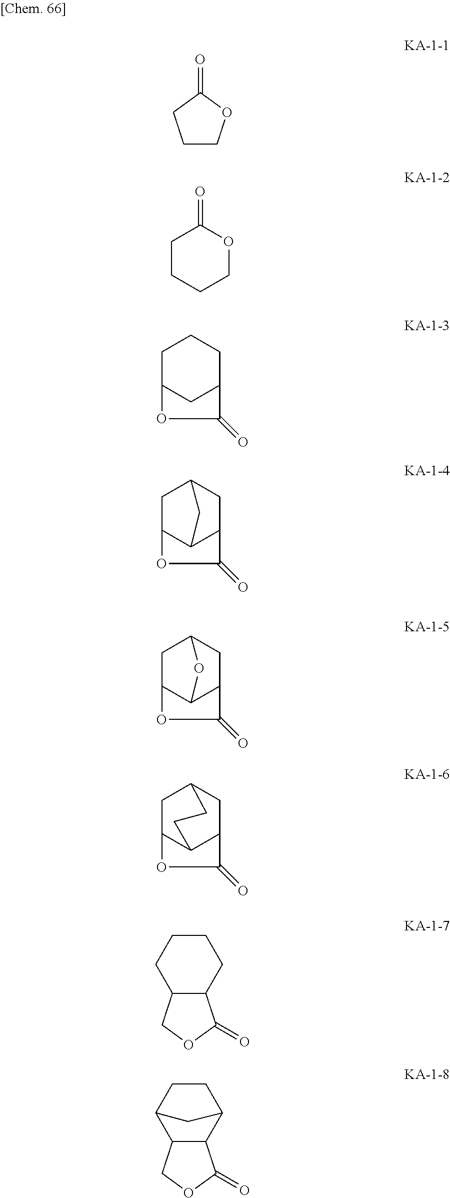

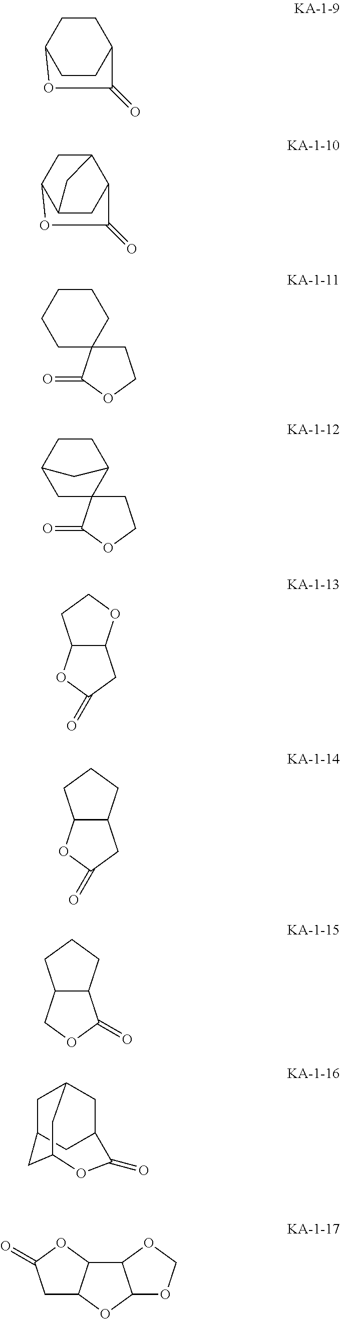

The structure containing the above-described lactone ring structure may or may not have a substituent. Preferred examples of the substituent are the same as those of the substituent Zₖₐ₁ that may be substituted on the ring structure represented by formula (KA-1).

In formula (KB-1), X is preferably a carboxylic acid ester group (—COO—).

In formula (KB-1), each of Y¹ and Y² independently represents an electron-withdrawing group.

The electron-withdrawing group is a partial structure represented by the following formula (EW), and * in formula (EW) indicates a direct bond to (KA-1) or a direct bond to X in (KB-1).

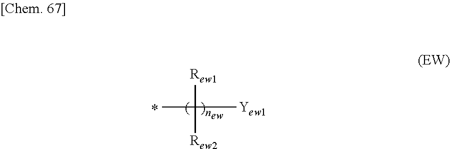

In formula (EW), n_{ew} is a repetition number of the linking group represented by —C(R_{ew1})(R_{ew2})— and represents an integer of 0 or 1. In the case where n_{ew} is 0, this indicates that the bond is a single bond and Y_{ew1} is directly bonded.

Y_{ew1} is a halogen atom, a cyano group, a nitrile group, a nitro group, a halo(cyclo)alkyl or haloaryl group represented by —C(R_{f1})(R_{f2})—R_{f3}, an oxy group, a carbonyl group, a sulfonyl group, a sulfinyl group, or a combination thereof; and the electron-withdrawing group may be, for example, the following structure. Incidentally, the “halo(cyclo)alkyl group” indicates an at least partially halogenated alkyl or cycloalkyl group, and the “haloaryl group” indicates an at least partially halogenated aryl group. In the following structural formulae, each of R_{ew3} and R_{ew4} independently represents an arbitrary structure. The partial structure represented by formula (EW) has an electron-withdrawing property regardless of the structure of R_{ew3} or R_{ew4}, and each of R_{ew3} and R_{ew4} may be connected, for example, to the main chain of the resin but is preferably an alkyl group, a cycloalkyl group or an alkyl fluoride group.

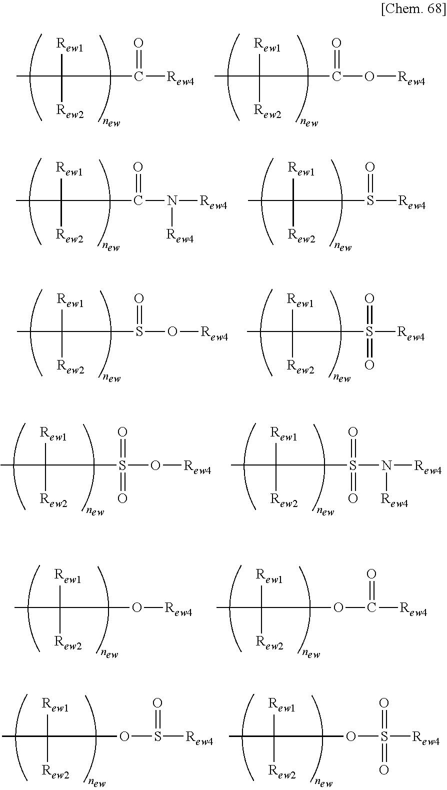

In the case where Y_{ew1} is a divalent or higher valent group, the remaining bond forms bonding to an arbitrary atom or substituent. At least any one group of Y_{ew1}, R_{ew1} and R_{ew2} may be connected to the main chain of the hydrophobic resin through a further substituent.

Y_{ew1} is preferably a halogen atom or a halo(cyclo)alkyl or haloaryl group represented by —C(R_{f1})(R_{f2})—R_{f3}.

Each of R_{ew1} and R_{ew2} independently represents an arbitrary substituent and, for example, represents a hydrogen atom, an alkyl group, a cycloalkyl group or an aryl group.

At least two members of R_{ew1}, R_{ew2} and Y_{ew1} may combine with each other to form a ring.

Here, R_{f1} represents a halogen atom, a perhaloalkyl group, a perhalocycloalkyl group or a perhaloaryl group and is preferably a fluorine atom, a perfluoroalkyl group or a perfluorocycloalkyl group, more preferably a fluorine atom or a trifluoromethyl group.

Each of R_{f2} and R_{f3} independently represents a hydrogen atom, a halogen atom or an organic group, and R_{f2} and R_{f3} may combine to form a ring. The organic group includes, for example, an alkyl group, a cycloalkyl group, and an alkoxy group. R_{f2} preferably represents the same group as R_{f1} or combines with R_{f3} to form a ring.

R_{f1} to R_{f3} may combine to form a ring, and the ring formed includes a (halo)cycloalkyl ring, a (halo)aryl group, and the like.

The (halo)alkyl group in R_{f1} to R_{f3} includes, for example, the alkyl group in Zₖₐ₁ and a structure formed by halogenation thereof.

The (per)halocycloalkyl group and (per)haloaryl group in R_{f1} to R_{f3} or in the ring formed by combining R_{f2} and R_{f3} includes, for example, a structure formed by halogenating the cycloalkyl group in Zₖₐ₁ and is preferably a fluorocycloalkyl group represented by —C₍ₙ₎F₂ₙ₋₂)H or a perfluoroaryl group represented by —C₍ₙ₎F₍ₙ₋₁₎, wherein the carbon number n is not particularly limited but is preferably from 5 to 13, more preferably 6.

The ring which may be formed by combining at least two members of R_{ew1}, R_{ew2} and Y_{ew1} with each other is preferably a cycloalkyl group or a heterocyclic group, and the heterocyclic group is preferably a lactone ring group. The lactone ring includes, for example, the structures represented by formula (KA-1-1) to (KA-1-17).

Incidentally, the repeating unit (by) may have a plurality of partial structures represented by formula (KA-1), a plurality of partial structures represented by formula (KB-1), or both a partial structure of formula (KA-1) and a partial structure of formula (KB-1).

In this connection, the partial structure of formula (KA-1) may partially or entirely serve also as an electron-withdrawing group of Y¹ or Y² in formula (KB-1). For example, in the case where X in formula (KA-1) is a carboxylic acid ester group, the carboxylic acid ester group may function as an electron-withdrawing group of Y¹ or Y² in formula (KB-1).

Also, in the case where the repeating unit (by) comes under the repeating unit (b*) or the repeating unit (b″) and has a partial structure represented by formula (KA-1), the partial structure represented by formula (KA-1) is more preferably a partial structure where the polarity converting group is —COO— in the structure represented by formula (KA-1).

The repeating unit (by) may be a repeating unit having a partial structure represented by formula (KY-0):

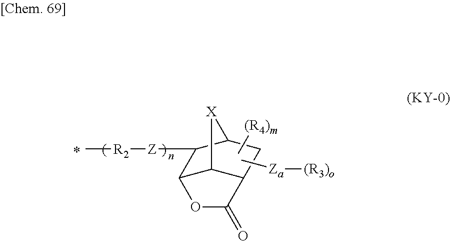

In formula (KY-0), each R₂ independently represents an alkylene group or a cycloalkylene group.

R₃ represents a hydrocarbon group where a part or all of hydrogen atoms on the constituent carbons are substituted for by a fluorine atom.

R₄ represents, when m≧22, each independently represents, a halogen atom, a cyano group, a hydroxy group, an amide group, an alkyl group, a cycloalkyl group, an alkoxy group, a phenyl group, an acyl group, an alkoxycarbonyl group or a group represented by R—C(═O)— or R—C(═O)O—, wherein R represents an alkyl group or a cycloalkyl group. When m2, two or more R₄ may combine with each other to form a ring.

X represents an alkylene group, a cycloalkylene group, an oxygen atom or a sulfur atom.

Each of Z and Za independently represents a single bond, an ether bond, an ester bond, an amide bond, a urethane bond or a urea bond.

* represents a bond to the main or side chain of the resin (D).

o represents an integer of 1 to 7.

m represents an integer of 0 to 7.

n represents an integer of 0 to 5.

The structure of —R₂—Z— is preferably a structure represented by —(CH₂)₁—COO— (wherein l represents an integer of 1 to 5).

The preferred carbon number and specific examples of the alkylene or cycloalkylene group as R₂ are the same as those described for the alkylene or cycloalkylene group in Z₂ of formula (bb).

The carbon number of the linear, branched or cyclic hydrocarbon group as R₃ is, in the case of a linear hydrocarbon group, preferably from 1 to 30, more preferably from 1 to 20; in the case of a branched hydrocarbon group, preferably from 3 to 30, more preferably from 3 to 20; and in the case of a cyclic hydrocarbon group, from 6 to 20. Specific examples of R₃ include specific examples of the alkyl group and cycloalkyl group as Z₁ above.

The preferred carbon numbers and specific examples of the alkyl group and cycloalkyl group as R₄ and R are the same as those described above for the alkyl group and cycloalkyl group as Zₖₐ₁.

The acyl group as R₄ is preferably an acyl group having a carbon number of 1 to 6, and examples thereof include a formyl group, an acetyl group, a propionyl group, a butyryl group, an isobutyryl group, a valeryl group, and a pivaloyl group.

The alkyl moiety in the alkoxy group and alkoxycarbonyl group as R₄ includes a linear, branched or cyclic alkyl moiety, and the preferred carbon number and specific examples of the alkyl moiety are the same as those described above for the alkyl group and cycloalkyl group as Zₖₐ₁.

The preferred carbon number and specific examples the alkylene group or cycloalkylene group as X are the same as those described for the alkylene group and cycloalkylene group as R₂.

Also, the repeating unit (by) is more preferably a repeating having at least two or more polarity converting groups.

In the case where the repeating unit (by) has at least two polarity converting groups, the repeating unit preferably has a group containing a partial structure having two polarity converting groups represented by the following formula (KY-1). Incidentally, when the structure represented by formula (KY-1) does not have a bond, this is a group containing a monovalent or higher valent group formed by removing at least one arbitrary hydrogen atom in the structure.

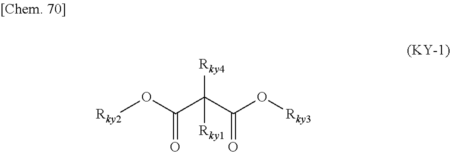

In formula (KY-1), each of R_{ky1} and R_{ky4} independently represents a hydrogen atom, a halogen atom, an alkyl group, a cycloalkyl group, a carbonyl group, a carbonyloxy group, an oxycarbonyl group, an ether group, a hydroxyl group, a cyano group, an amide group or an aryl group. Alternatively, R_{ky1} and R_{ky4} may be bonded to the same atom to form a double bond. For example, R_{ky1} and R_{ky4} may be bonded to the same oxygen atom to form a part (═O) of a carbonyl group.

Each of R_{ky2} and R_{ky3} is independently an electron-withdrawing group, or while R_{ky1} and R_{ky2} combine to form a lactone ring, R_{ky3} is an electron-withdrawing group. The lactone ring formed is preferably a structure of (KA-1-1) to (KA-1-17). Examples of the electron-withdrawing group are the same as those for Y₁ and Y₂ in formula (KB-1), and a halogen atom and a halo(cyclo)alkyl or haloaryl group represented by —C(R_{f1})(R_{f2})—R_{f3} are preferred. Preferably, R_{ky3} is a halogen atom or a halo(cyclo)alkyl or haloaryl group represented by —C(R_{f1})(R_{f2})—R_{f3} and R_{ky2} combines with R_{ky1} to form a lactone ring or is an electron-withdrawing group containing no halogen atom.

R_{ky1}, R_{ky2} and R_{ky4} may combine with each other to form a monocyclic or polycyclic structure.

R_{ky1} and R_{ky4} specifically include the same groups as those for Zₖₐ₁ in formula (KA-1).

The lactone ring formed by combining R_{ky1} and R_{ky2} is preferably a structure of (KA-1-1) to (KA-1-17). Examples of the electron-withdrawing group are the same as those for Y₁ and Y₂ in formula (KB-1).

The structure represented by formula (KY-1) is preferably a structure represented by the following formula (KY-2). Here, the structure represented by formula (KY-2) is a group having a monovalent or higher valent group formed by removing at least one arbitrary hydrogen atom in the structure.

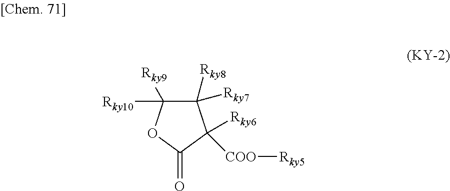

In formula (KY-2), each of R_{ky6} to R_{ky10} independently represents a hydrogen atom, a halogen atom, an alkyl group, a cycloalkyl group, a carbonyl group, a carbonyloxy group, an oxycarbonyl group, an ether group, a hydroxyl group, a cyano group, an amide group or an aryl group.

Two or more members of R_{ky6} to R_{ky10} may combine with each other to form a monocyclic or polycyclic structure.

R_{ky5} represents an electron-withdrawing group. Examples of the electron-withdrawing group are the same as those for Y₁ and Y₂ above, and a halogen atom and a halo(cyclo)alkyl or haloaryl group represented by —C(R_{f1})(R₂)—R_{f3} are preferred.

R_{ky5} to R_{ky10} specifically include the same groups as those for Zₖₐ₁ in formula (KA-1).

The structure represented by formula (KY-2) is more preferably a partial structure represented by the following formula (KY-3):

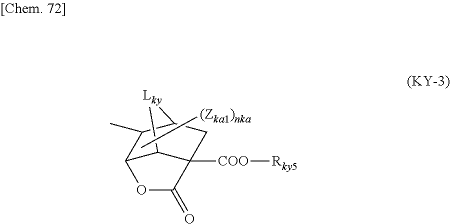

In formula (KY-3), each of Zₖₐ₁ and nka has the same meanings as in formula (KA-1), and R_{ky5} has the same meaning as in formula (KY-2).

L_{ky} represents an alkylene group, a cycloalkylene group, an oxygen atom or a sulfur atom. The alkylene group of L_{ky} includes a methylene group, an ethylene group, and the like. L_{ky} is preferably an oxygen atom or a methylene group, more preferably a methylene group.

The repeating unit (b) is not limited as long as it is a repeating unit obtained by polymerization such as addition polymerization, condensation polymerization and addition condensation, but this repeating unit is preferably a repeating unit obtained by addition polymerization of a carbon-carbon double bond. Examples thereof include an acrylate-based repeating unit (encompassing a system having a substituent on the α- or β-position), a styrene-based repeating unit (encompassing a system having a substituent on the α- or β-position), a vinyl ether-based repeating unit, a norbornene-based repeating unit, and a maleic acid derivative (such as maleic anhydride, its derivative, and maleimide) repeating unit. An acrylate-based repeating unit, a styrene-based repeating unit, a vinyl ether-based repeating unit and a norbornene-based repeating unit are preferred, an acrylate-based repeating unit, a vinyl ether-based repeating unit and a norbornene-based repeating unit are more preferred, and an acrylate-based repeating unit is most preferred.

In the case where the repeating unit (by) is a repeating unit having at least either a fluorine atom or a silicon atom (that is, in the case of a repeating unit corresponding to the repeating unit (b′) or (b″)), examples of the fluorine atom-containing partial structure in the repeating unit (by) are the same as those recited above in the repeating unit having at least either a fluorine atom or a silicon atom, and the groups represented by formula (F2) to (F4) are preferred. Also, in this case, examples of the silicon atom-containing partial structure in the repeating unit (by) are the same as those recited above in the repeating unit having at least either a fluorine atom or a silicon atom, and the groups represented by formulae (CS-1) to (CS-3) are preferred.

The monomer corresponding to the (by) repeating unit having a group capable of increasing the solubility in an alkali developer can be synthesized, for example, by the method described in US2010/0152400A, WO2010/067905A or WO2010/067898A.

In the hydrophobic resin, the content ratio of the repeating unit (by) is preferably from 10 to 100 mol %, more preferably from 20 to 99 mol %, still more preferably from 30 to 97 mol %, and most preferably from 40 to 95 mol %, based on all repeating units in the hydrophobic resin.

Specific examples of the (by) repeating unit having a group capable of increasing the solubility in an alkali developer are illustrated below, but the present invention is not limited thereto. Ra represents a hydrogen atom, a fluorine atom, a methyl group or a trifluoromethyl group.

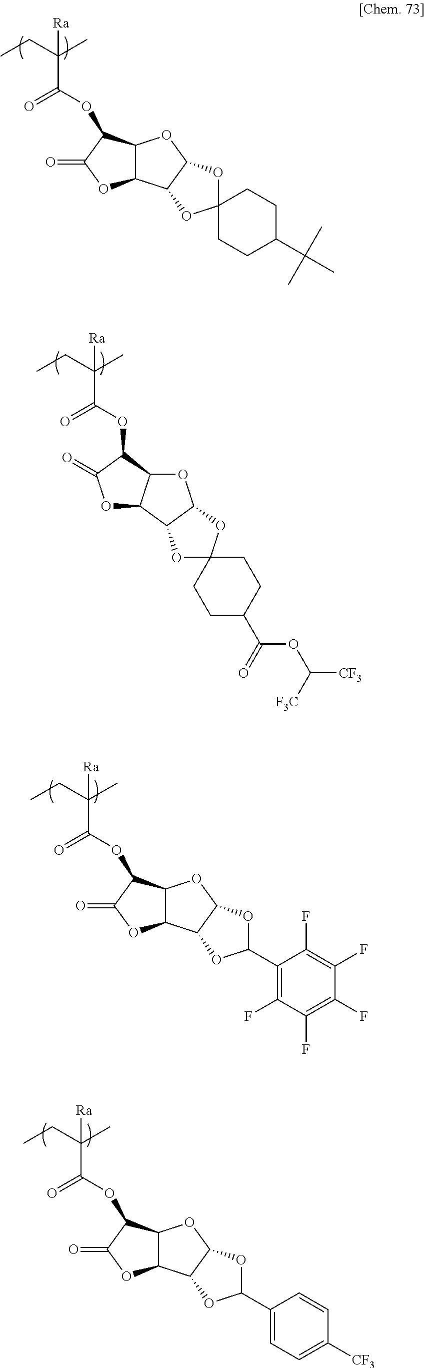

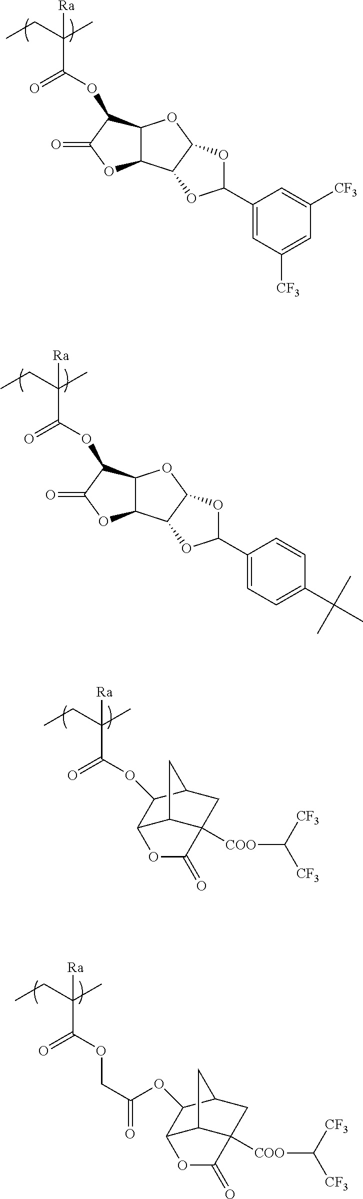

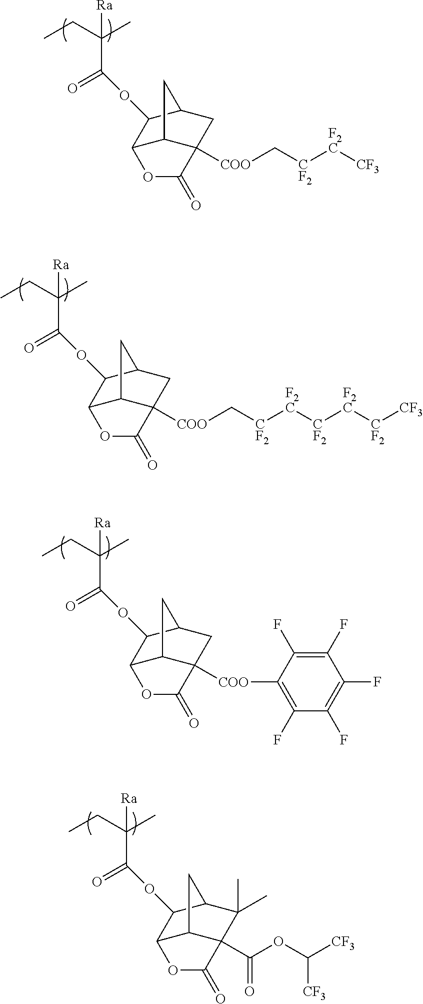

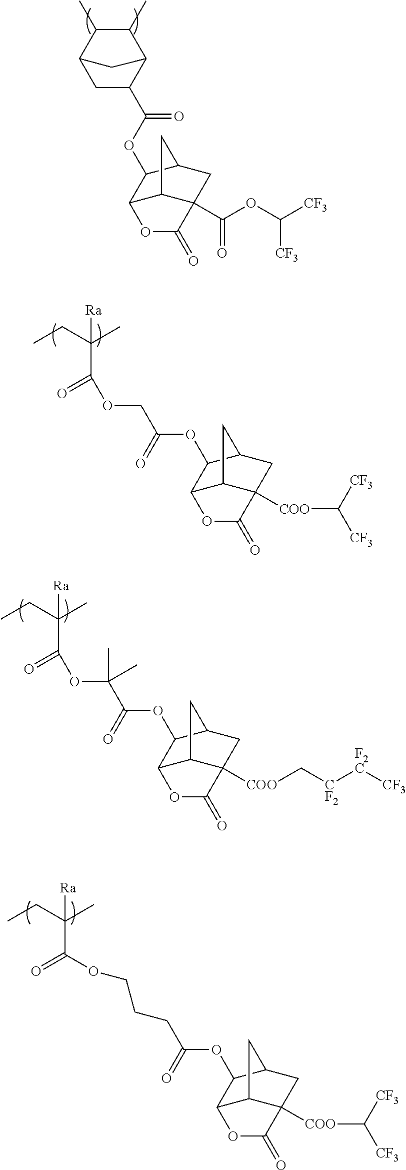

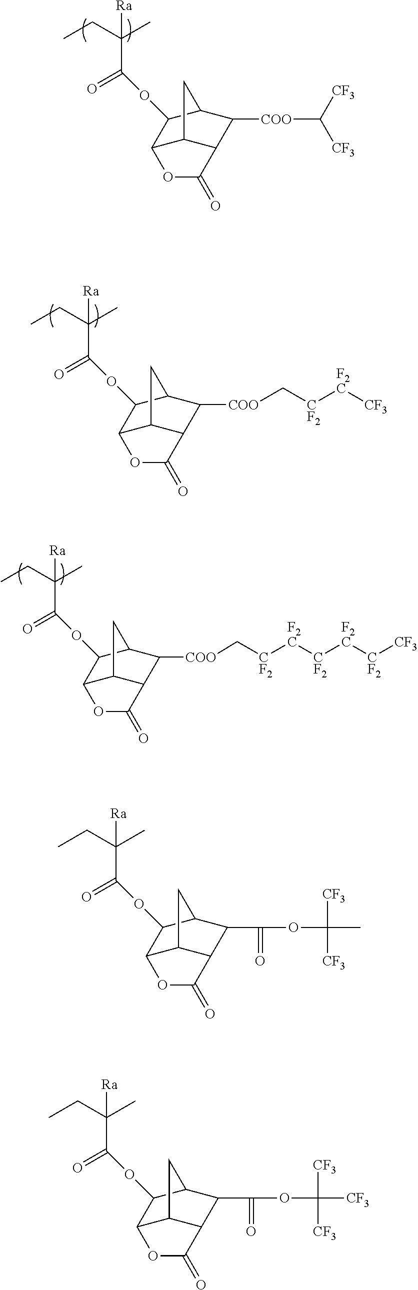

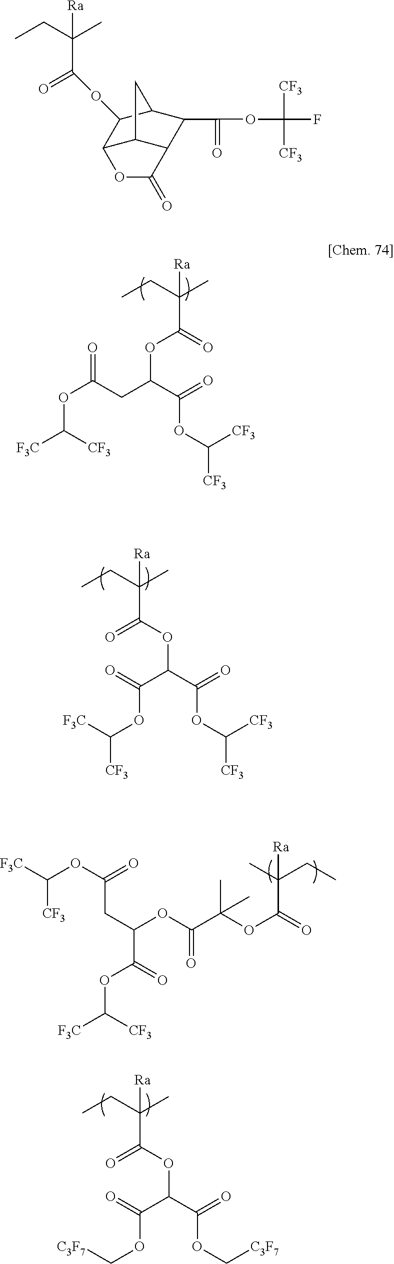

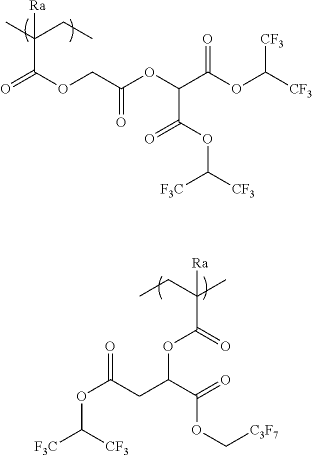

Examples of the repeating unit (bz) having (z) a group capable of decomposing by the action of an acid, which is contained in the hydrophobic group, are the same as those of the acid decomposable group-containing repeating unit described for the resin (B).

In the case where the repeating unit (bz) is a repeating unit having at least either a fluorine atom or a silicon atom (that is, in the case of a repeating unit corresponding to the repeating unit (b′) or (b″)), examples of the fluorine atom-containing partial structure in the repeating unit (bz) are the same as those recited above in the repeating unit having at least either a fluorine atom or a silicon atom, and the groups represented by formula (F2) to (F4) are preferred. Also, in this case, examples of the silicon atom-containing partial structure in the repeating unit (by) are the same as those recited above in the repeating unit having at least either a fluorine atom or a silicon atom, and the groups represented by formulae (CS-1) to (CS-3) are preferred.

In the hydrophobic resin, the content of the repeating unit (bz) having (z) a group capable of decomposing by the action of an acid is preferably from 1 to 80 mol %, more preferably from 10 to 80 mol %, still more preferably from 20 to 60 mol %, based on all repeating units in the hydrophobic resin.

While the repeating unit (b) having at least one group selected from the group consisting of (x) to (z) is described above, the content ratio of the repeating unit (b) in the hydrophobic resin is preferably from 1 to 98 mol %, more preferably from 3 to 98 mol %, still more preferably from 5 to 97 mol %, and most preferably from 10 to 95 mol %, based on all repeating units in the hydrophobic resin.

The content ratio of the repeating unit (b′) is preferably from 1 to 100 mol %, more preferably from 3 to 99 mol %, still more preferably from 5 to 97 mol %, and most preferably from 10 to 95 mol %, based on all repeating units in the hydrophobic resin.

The content ratio of the repeating unit (b*) is preferably from 1 to 90 mol %, more preferably from 3 to 80 mol %, still more preferably from 5 to 70 mol %, and most preferably from 10 to 60 mol %, based on all repeating units in the hydrophobic resin. The content ratio of the repeating unit having at least either a fluorine atom or a silicon atom, which is used together with the repeating unit (b*), is preferably from 10 to 99 mol %, more preferably from 20 to 97 mol %, still more preferably from 30 to 95 mol %, and most preferably from 40 to 90 mol %, based on all repeating units in the hydrophobic resin.

The content ratio of the repeating unit (b″) is preferably from 1 to 100 mol %, more preferably from 3 to 99 mol %, still more preferably from 5 to 97 mol %, and most preferably from 10 to 95 mol %, based on all repeating units in the hydrophobic resin.

The hydrophobic resin may further contain a repeating unit represented by the following formula (III):

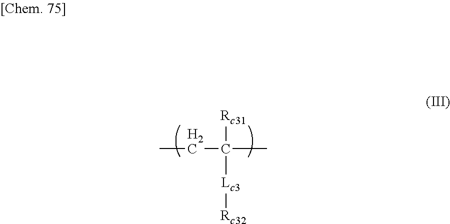

In formula (III), R_{c31} represents a hydrogen atom, an alkyl group (which may be substituted with a fluorine atom), a cyano group or a —CH₂—O—Rac₂ group, wherein Rac₂ represents a hydrogen atom, an alkyl group or an acyl group. R_{c31} is preferably a hydrogen atom, a methyl group, a hydroxymethyl group or a trifluoromethyl group, more preferably a hydrogen atom or a methyl group.

R_{c32} represents a group having an alkyl group, a cycloalkyl group, an alkenyl group, a cycloalkenyl group or an aryl group. These groups may be substituted with a fluorine atom- or silicon atom-containing group or the like.

L_{c3} represents a single bond or a divalent linking group.

In formula (III), the alkyl group of R_{c32} is preferably a linear or branched alkyl group having a carbon number of 3 to 20.

The cycloalkyl group is preferably a cycloalkyl group having a carbon number of 3 to 20.

The alkenyl group is preferably an alkenyl group having a carbon number of 3 to 20.

The cycloalkenyl group is preferably a cycloalkenyl group having a carbon number of 3 to 20.

The aryl group is preferably a phenyl group or a naphthyl group, which are an aryl group having a carbon number of 6 to 20, and these groups may have a substituent.

R_{c32} is preferably an unsubstituted alkyl group or a fluorine atom-substituted alkyl group.

The divalent linking group of L_{c3} is preferably an alkylene group (preferably having a carbon number of 1 to 5), an oxy group, a phenylene group or an ester bond (a group represented by —COO—).

It is also preferred that the hydrophobic resin further contains a repeating unit represented by the following formula (BII-AB):

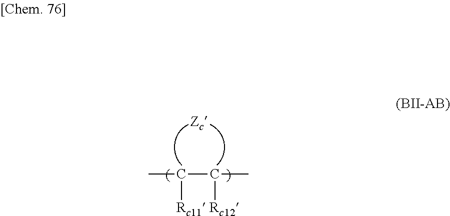

In formula (BII-AB), each of R_{c11}′ and R_{c12}′ independently represents a hydrogen atom, a cyano group, a halogen atom or an alkyl group.

Zc′ represents an atomic group for forming an alicyclic structure together with two carbon atoms (C—C) to which Zc′ is bonded.

In the case where each group in the repeating units represented by formulae (III) and (BII-AB) is substituted with a fluorine atom- or silicon atom-containing group, the repeating unit corresponds also to the above-described repeating unit having at least either a fluorine atom or a silicon atom.

Specific examples of the repeating units represented by formulae (III) and (BII-AB) are illustrated below, but the present invention is not limited thereto. In the formulae, Ra represents H, CH₃, CH₂OH, CF₃ or CN. Incidentally, the repeating unit where Ra is CF₃ corresponds also to the above-described repeating unit having at least either a fluorine atom or a silicon atom.

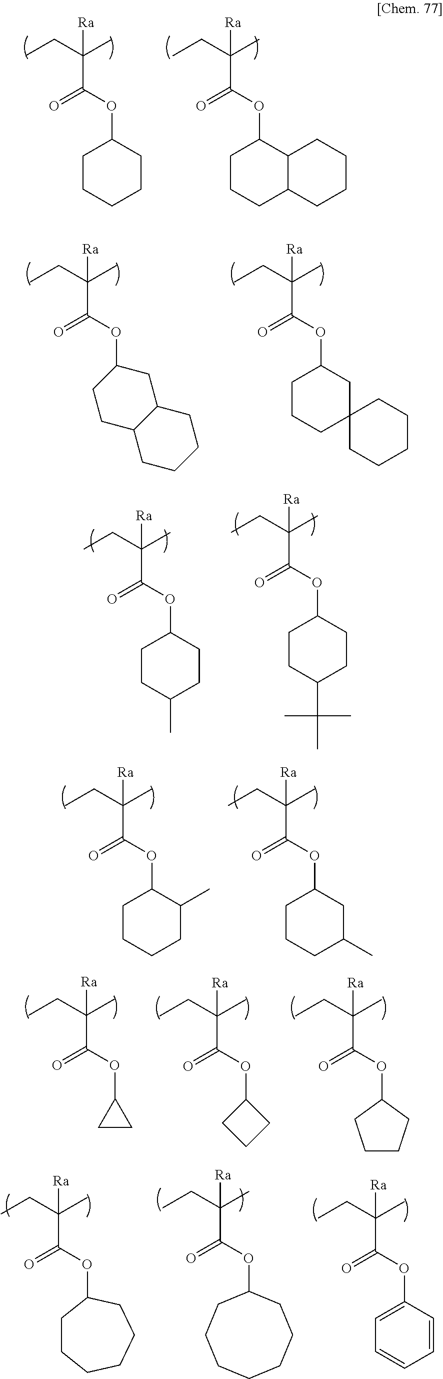

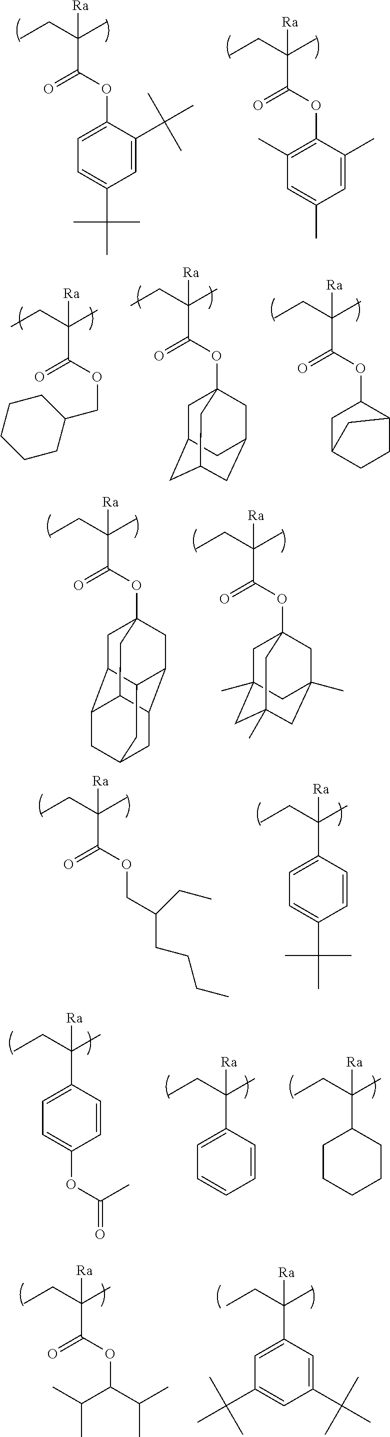

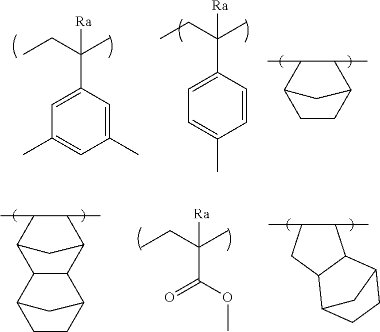

In the hydrophobic resin, similarly to the resin (A), it is of course preferred that the content of impurities such as metal is small, but also, the content of residual monomers or oligomer components is preferably from 0 to 10 mass %, more preferably from 0 to 5 mass %, still more preferably from 0 to 1 mass %. When these conditions are satisfied, a composition reduced in the change with aging of in-liquid extraneous substances, sensitivity or the like can be obtained. Furthermore, in view of resolution, resist profile, side wall of pattern, roughness and the like, the molecular weight distribution (Mw/Mn, sometimes referred to as “polydispersity”) is preferably from 1 to 3, more preferably from 1 to 2, still more preferably from 1 to 1.8, and most preferably from 1 to 1.5.

As the hydrophobic resin, various commercial products may also be used, or the resin may be synthesized by a conventional method (for example, radical polymerization). For example, the general synthesis method includes a batch polymerization method of dissolving monomer species and an initiator in a solvent and heating the solution, thereby effecting the polymerization, a dropping polymerization method of adding dropwise a solution containing monomer species and an initiator to a heated solvent over 1 to 10 hours, and the like. A dropping polymerization method is preferred.

The reaction solvent, polymerization initiator, reaction conditions (e.g., temperature, concentration) and purification method after reaction are the same as those described for the resin (B).

Specific examples of the hydrophobic resin are illustrated below. Also, the molar ratio of repeating units (corresponding to respective repeating units starting from the left), weight average molecular weight and polydispersity of each resin are shown in Table later.

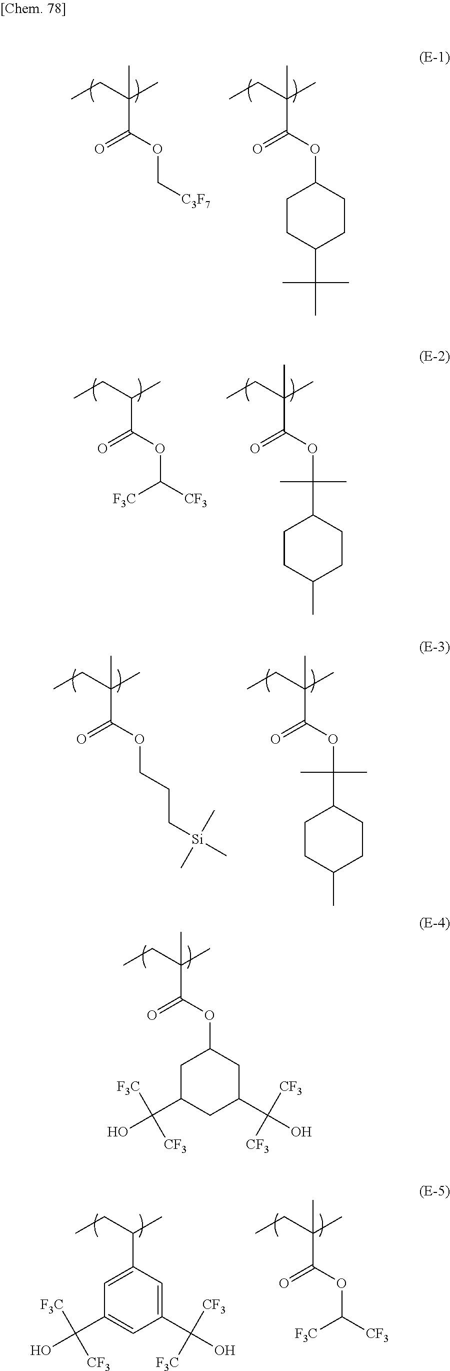

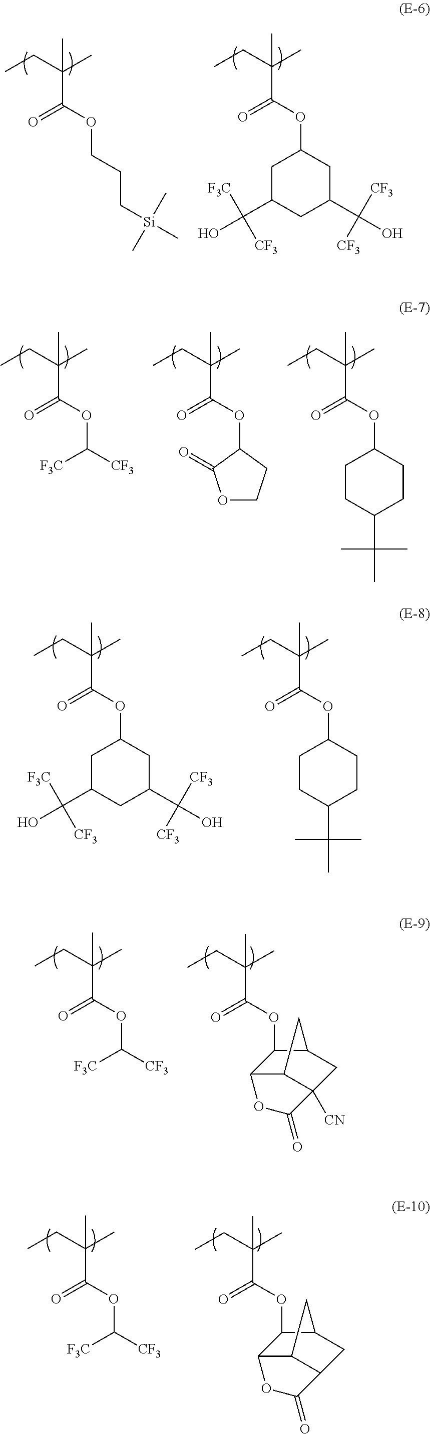

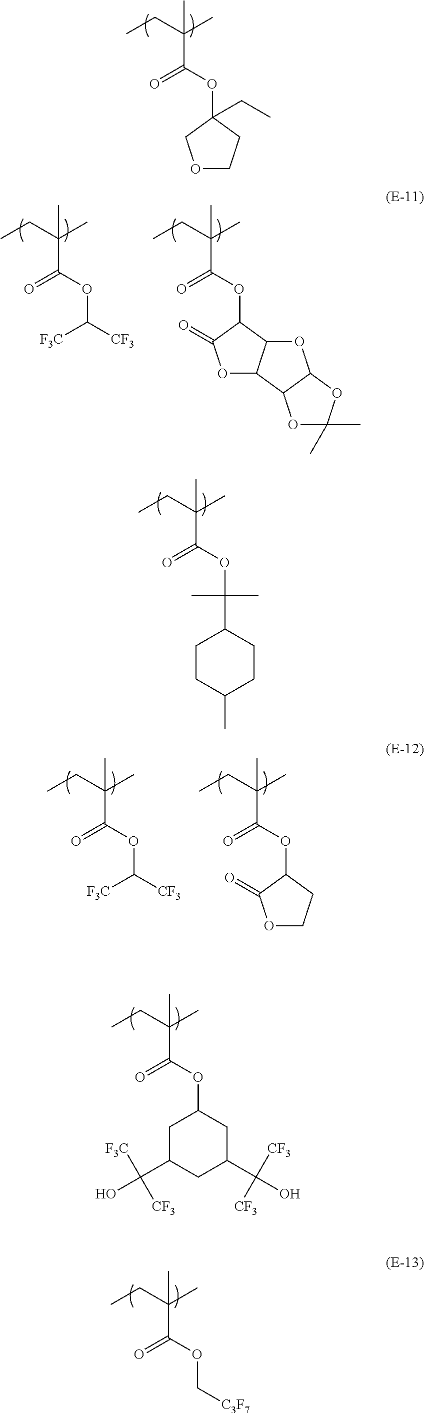

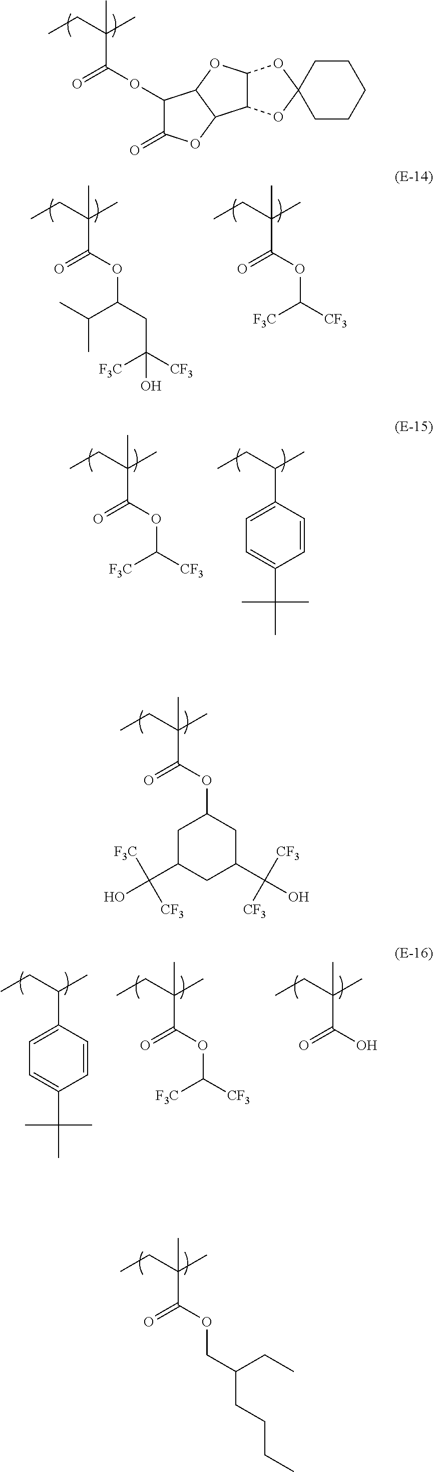

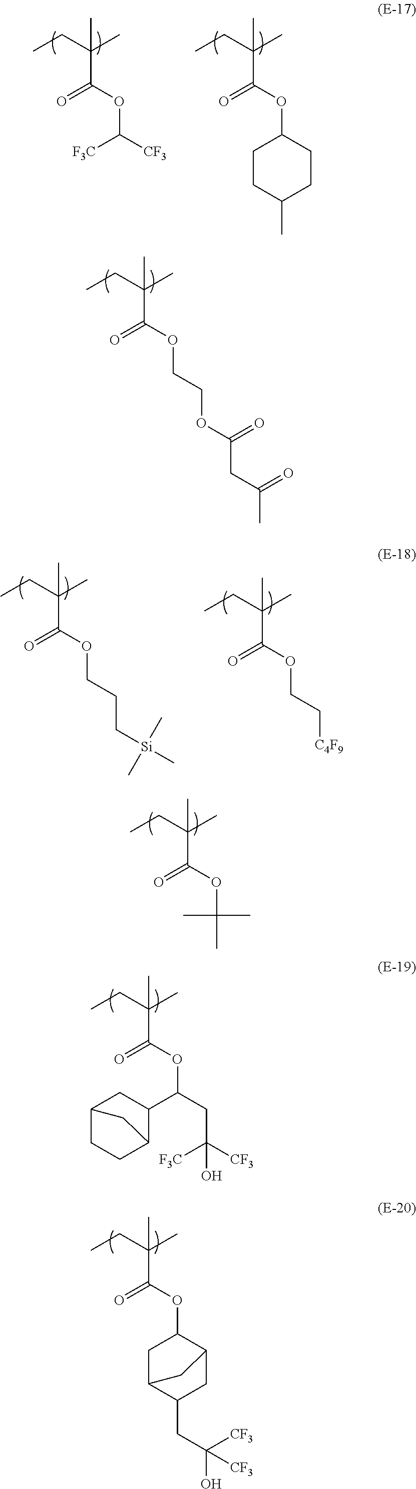

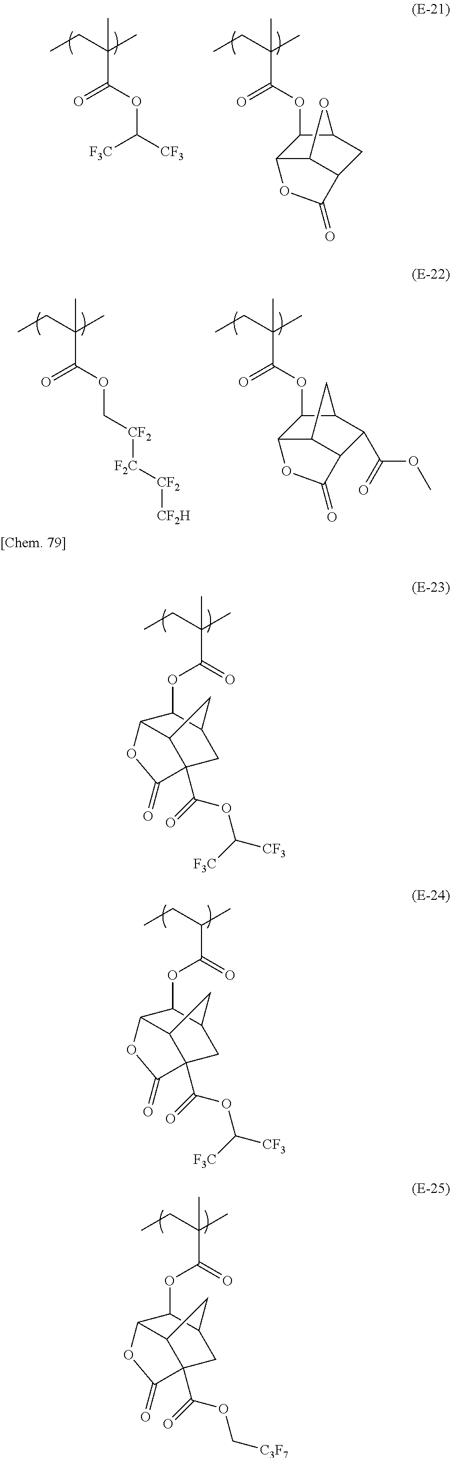

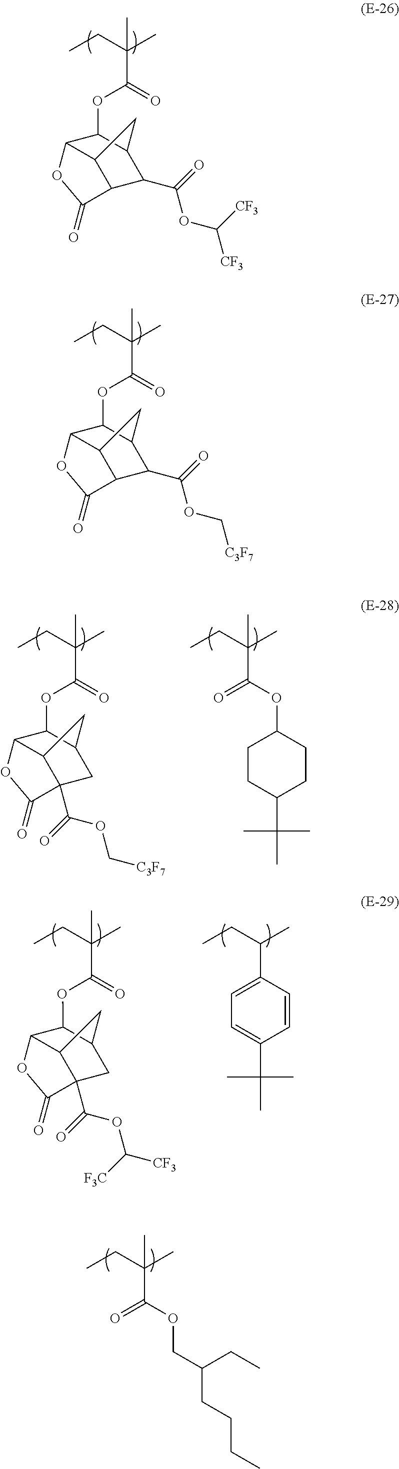

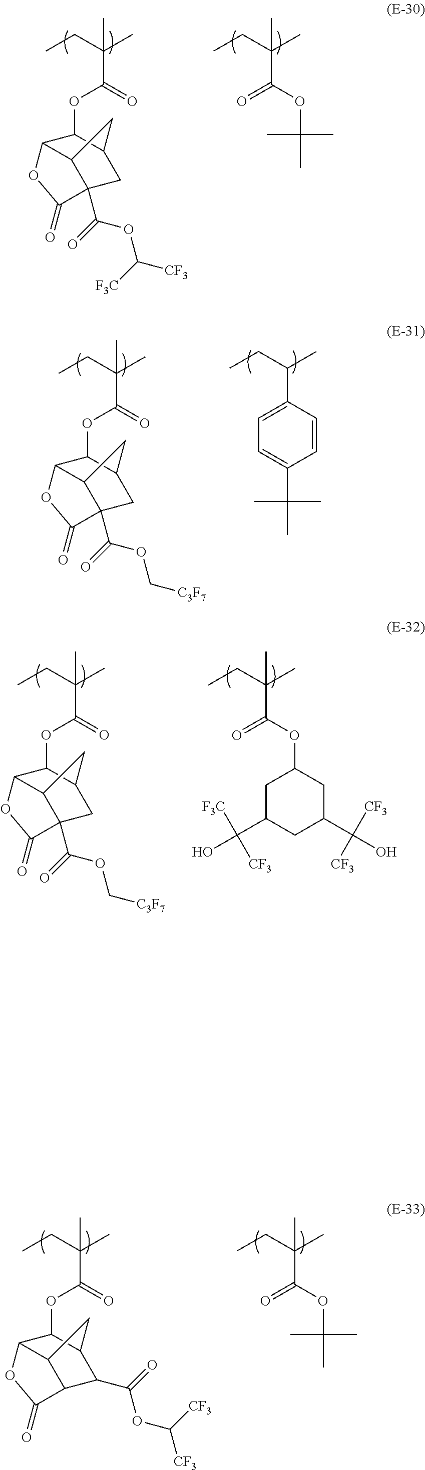

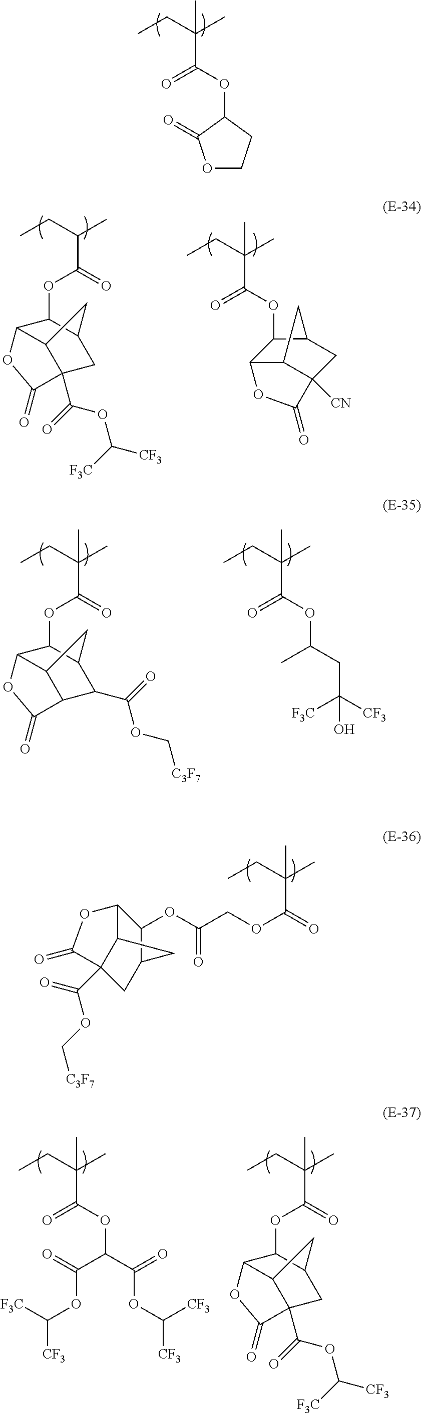

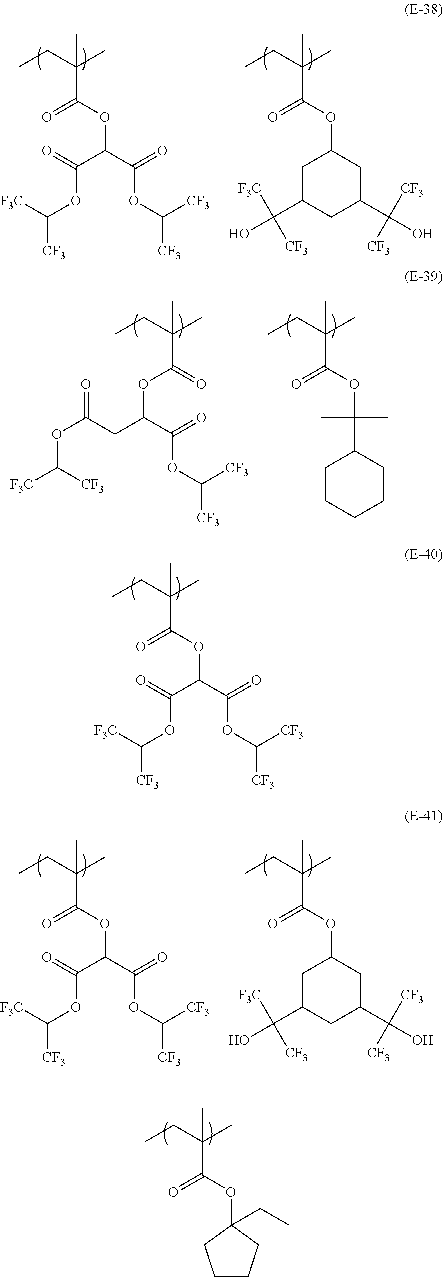

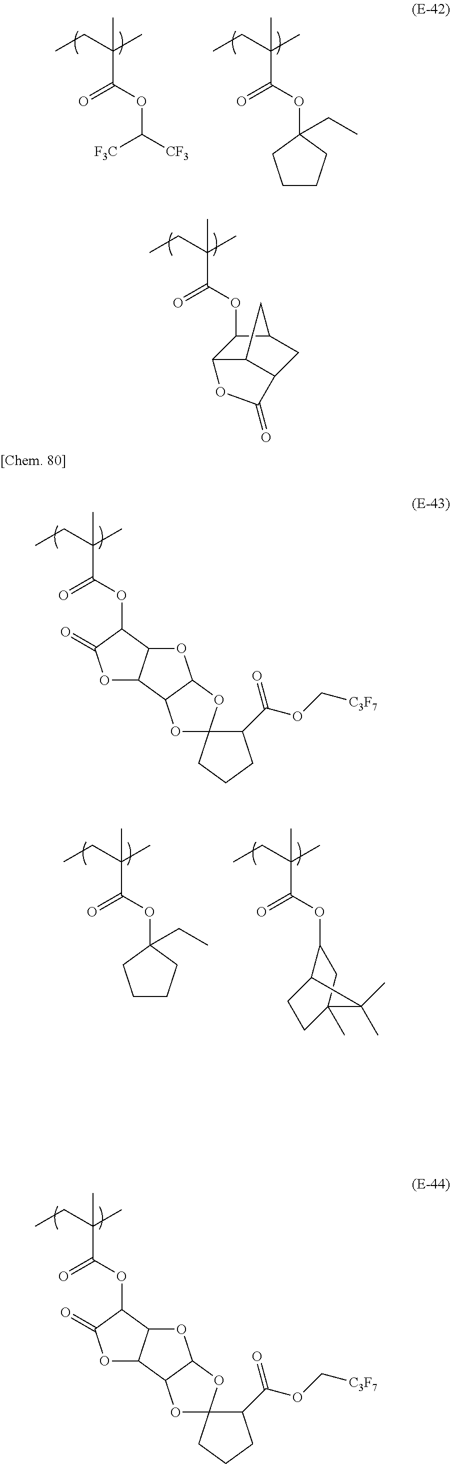

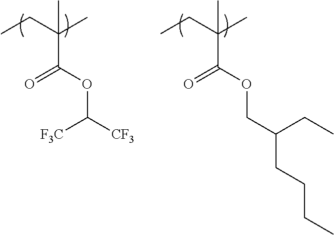

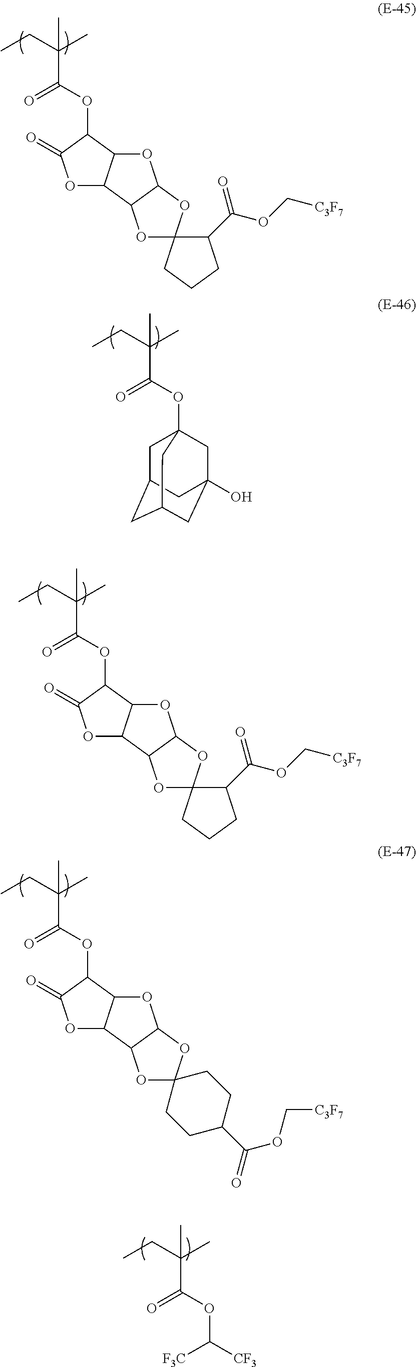

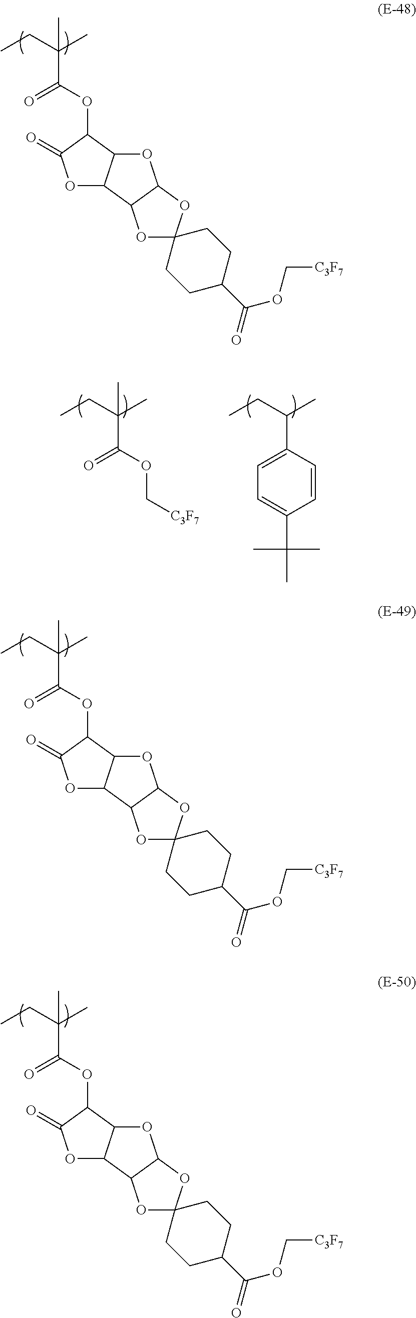

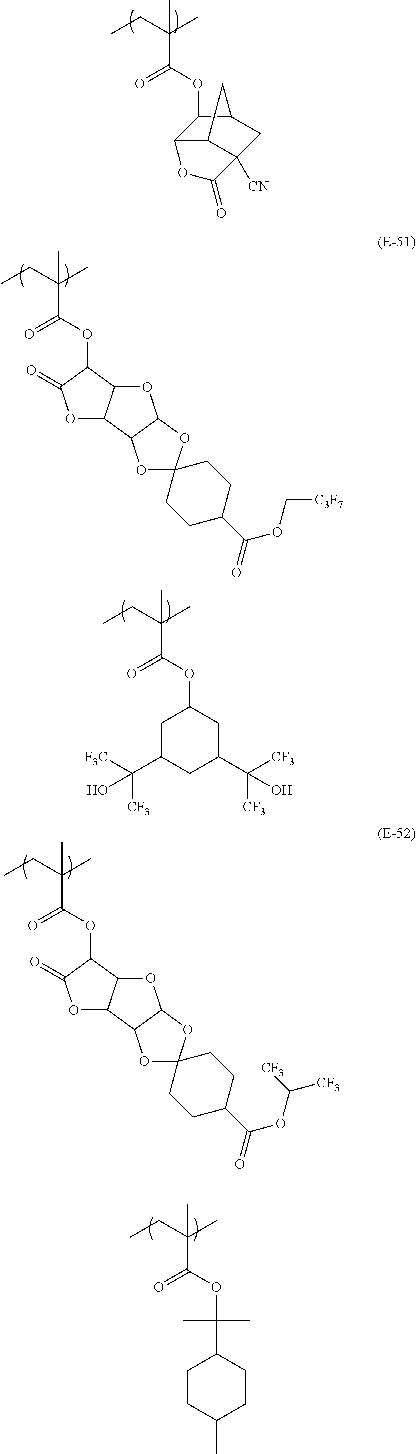

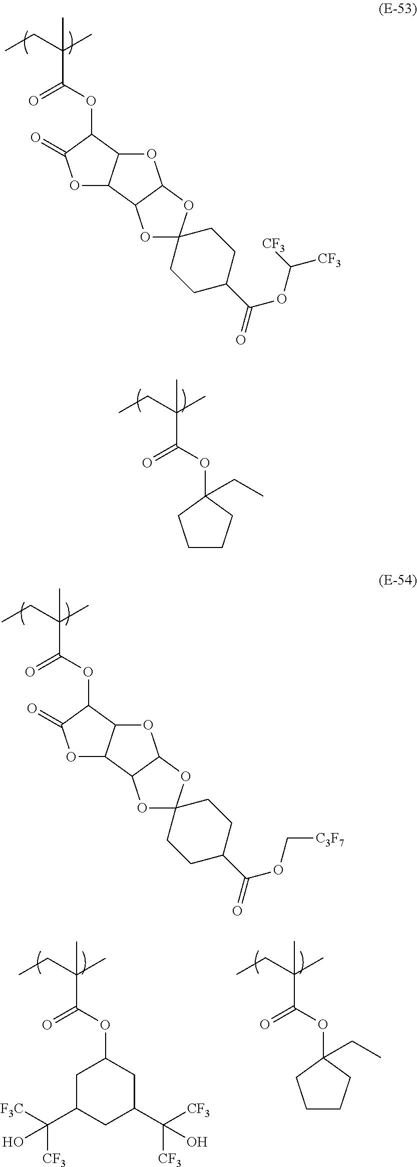

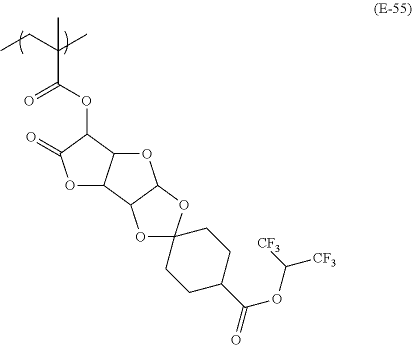

TABLE 1

| Polymer | C/R (mol %) | Mw | Mw/Mn |
|---|---|---|---|
| E-1 | 50/50 | 6000 | 1.5 |
| E-2 | 30/70 | 6500 | 1.4 |
| E-3 | 45/55 | 8000 | 1.4 |
| E-4 | 100 | 15000 | 1.7 |
| E-5 | 60/40 | 6000 | 1.4 |
| E-6 | 40/60 | 8000 | 1.4 |
| E-7 | 30/40/30 | 8000 | 1.4 |
| E-8 | 60/40 | 8000 | 1.3 |
| E-9 | 50/50 | 6000 | 1.4 |
| E-10 | 40/40/20 | 7000 | 1.4 |
| E-11 | 40/30/30 | 9000 | 1.6 |
| E-12 | 30/30/40 | 6000 | 1.4 |
| E-13 | 60/40 | 9500 | 1.4 |
| E-14 | 60/40 | 8000 | 1.4 |
| E-15 | 35/35/30 | 7000 | 1.4 |
| E-16 | 50/40/5/5 | 6800 | 1.3 |
| E-17 | 20/30/50 | 8000 | 1.4 |
| E-18 | 25/25/50 | 6000 | 1.4 |
| E-19 | 100 | 9500 | 1.5 |
| E-20 | 100 | 7000 | 1.5 |
| E-21 | 50/50 | 6000 | 1.6 |
| E-22 | 40/60 | 9600 | 1.3 |
| E-23 | 100 | 20000 | 1.7 |
| E-24 | 100 | 25000 | 1.4 |
| E-25 | 100 | 15000 | 1.7 |
| E-26 | 100 | 12000 | 1.8 |
| E-27 | 100 | 18000 | 1.3 |
| E-28 | 70/30 | 15000 | 2.0 |
| E-29 | 80/15/5 | 18000 | 1.8 |
| E-30 | 60/40 | 25000 | 1.8 |
| E-31 | 90/10 | 19000 | 1.6 |
| E-32 | 60/40 | 20000 | 1.8 |
| E-33 | 50/30/20 | 11000 | 1.6 |
| E-34 | 60/40 | 12000 | 1.8 |
| E-35 | 60/40 | 15000 | 1.6 |
| E-36 | 100 | 22000 | 1.8 |
| E-37 | 20/80 | 35000 | 1.6 |
| E-38 | 30/70 | 12000 | 1.7 |
| E-39 | 30/70 | 9000 | 1.5 |
| E-40 | 100 | 9000 | 1.5 |
| E-41 | 40/15/45 | 12000 | 1.9 |
| E-42 | 30/30/40 | 13000 | 2.0 |
| E-43 | 40/40/20 | 23000 | 2.1 |
| E-44 | 65/30/5 | 25000 | 1.6 |
| E-45 | 100 | 15000 | 1.7 |
| E-46 | 20/80 | 9000 | 1.7 |
| E-47 | 70/30 | 18000 | 1.5 |
| E-48 | 60/20/20 | 18000 | 1.8 |
| E-49 | 100 | 12000 | 1.4 |
| E-50 | 60/40 | 20000 | 1.6 |
| E-51 | 70/30 | 33000 | 2.0 |
| E-52 | 60/40 | 19000 | 1.8 |
| E-53 | 50/50 | 15000 | 1.5 |
| E-54 | 40/20/40 | 35000 | 1.9 |
| E-55 | 100 | 16000 | 1.4 |

C/R: Compositional Ratio

The actinic ray-sensitive or radiation-sensitive resin composition of the present invention contains a hydrophobic resin having at least either a fluorine atom or a silicon atom, and the hydrophobic resin is unevenly distributed to the surface layer of a film formed of the composition, so that when the immersion medium is water, the receding contact angle of the film surface for water as well as the followability of immersion liquid can be enhanced.

The receding contact angle of a film after baking a coating composed of the actinic ray-sensitive or radiation-sensitive resin composition of the present invention but before exposure is preferably from 60 to 90°, more preferably 65° or more, still more preferably 70° or more, yet still more preferably 75° or more, at the temperature during exposure, usually room temperature 23±3° C., and a humidity of 45±5%.

The hydrophobic resin is, as described above, unevenly distributed to the interface but unlike a surfactant, need not have necessarily a hydrophilic group in the molecule and may not contribute to uniform mixing of polar/nonpolar substances.

In the immersion exposure step, the immersion liquid must move on a wafer by conforming to the movement of an exposure head that is scanning the wafer at a high speed to form an exposure pattern. Therefore, the contact angle of the immersion liquid with the resist film in a dynamic state is important, and the resist is required to have a performance allowing the immersion liquid to follow the high-speed scanning of an exposure head with no remaining of a liquid droplet

The hydrophobic resin is hydrophobic and therefore, liable to increase the development residue (scum) and BLOB defect after alkali development, but by virtue of having three or more polymer chains through at least one branch part, the alkali dissolution rate is enhanced as compared with a linear chain-type resin and in turn, the performance in terms of development residue (scum) and the BLOB defect is improved.

In the case where the hydrophobic resin has a fluorine atom, the content ratio of fluorine atom is preferably from 5 to 80 mass %, more preferably from 10 to 80 mass %, based on the mass average molecular weight of the hydrophobic resin. Also, the fluorine atom-containing repeating unit preferably accounts for 10 to 100 mol %, more preferably from 30 to 100 mol %, based on all repeating units in the hydrophobic resin.

In the case where the hydrophobic resin has a silicon atom, the content ratio of silicon atom is preferably from 2 to 50 mass %, more preferably from 2 to 30 mass %, based on the mass average molecular weight of the hydrophobic resin. Also, the silicon atom-containing repeating unit preferably accounts for 10 to 90 mol %, more preferably from 20 to 80 mol %, based on all repeating units in the hydrophobic resin.

The weight average molecular weight of the hydrophobic resin is preferably from 1,000 to 100,000, more preferably from 2,000 to 50,000, still more preferably from 3,000 to 30,000. Here, the weight average molecular weight of the resin indicates a molecular weight in terms of polystyrene measured by GPC (carrier: tetrahydrofuran (THF)).

As for the hydrophobic resin, one kind may be used alone, or two or more kinds may be used in combination.

The content ratio of the hydrophobic resin in the actinic ray-sensitive or radiation-sensitive resin composition is preferably from 0.01 to 20 mass %, more preferably from 0.1 to 18 mass %, still more preferably from 0.5 to 15 mass %, based on the total solid content of the composition.

### [5](E) Solvent

The actinic ray-sensitive or radiation-sensitive resin composition according to the present invention usually further contains a solvent.

The solvent includes, for example, an organic solvent such as alkylene glycol monoalkyl ether carboxylate, alkylene glycol monoalkyl ether, alkyl lactate, alkyl alkoxypropionate, cyclic lactone (preferably having a carbon number of 4 to 10), monoketone compound (preferably having a carbon number of 4 to 10) which may contain a ring, alkylene carbonate, alkyl alkoxyacetate and alkyl pyruvate

Preferred examples of the alkylene glycol monoalkyl ether carboxylate include propylene glycol monomethyl ether acetate (PGMEA, another name: 1-methoxy-2-acetoxypropane), propylene glycol monoethyl ether acetate, propylene glycol monopropyl ether acetate, propylene glycol monobutyl ether acetate, propylene glycol monomethyl ether propionate, propylene glycol monoethyl ether propionate, ethylene glycol monomethyl ether acetate, and ethylene glycol monoethyl ether acetate.

Preferred examples of the alkylene glycol monoalkyl ether include propylene glycol monomethyl ether (PGME, another name: 1-methoxy-2-propanol), propylene glycol monoethyl ether, propylene glycol monopropyl ether, propylene glycol monobutyl ether, ethylene glycol monomethyl ether, and ethylene glycol monoethyl ether.

Preferred examples of the alkyl lactate include methyl lactate, ethyl lactate, propyl lactate, and butyl lactate.

Preferred examples of the alkyl alkoxypropionate include ethyl 3-ethoxypropionate, methyl 3-methoxypropionate, methyl 3-ethoxypropionate, and ethyl 3-methoxypropionate.

Preferred examples of the cyclic lactone include β-propiolactone, β-butyrolactone, γ-butyrolactone, α-methyl-γ-butyrolactone, β-methyl-γ-butyrolactone, γ-valerolactone, γ-caprolactone, γ-octanoic lactone, and α-hydroxy-γ-butyrolactone.

Preferred examples of the monoketone compound which may contain a ring include 2-butanone, 3-methylbutanone, pinacolone, 2-pentanone, 3-pentanone, 3-methyl-2-pentanone, 4-methyl-2-pentanone, 2-methyl-3-pentanone, 4,4-dimethyl-2-pentanone, 2,4-dimethyl-3-pentanone, 2,2,4,4-tetramethyl-3-pentanone, 2-hexanone, 3-hexanone, 5-methyl-3-hexanone, 2-heptanone, 3-heptanone, 4-heptanone, 2-methyl-3-heptanone, 5-methyl-3-heptanone, 2,6-dimethyl-4-heptanone, 2-octanone, 3-octanone, 2-nonanone, 3-nonanone, 5-nonanone, 2-decanone, 3-decanone, 4-decanone, 5-hexen-2-one, 3-penten-2-one, cyclopentanone, 2-methylcyclopentanone, 3-methylcyclopentanone, 2,2-dimethylcyclopentanone, 2,4,4-trimethylcyclopentanone, cyclohexanone, 3-methylcyclohexanone, 4-methylcyclohexanone, 4-ethylcyclohexanonc, 2,2-dimethylcyclohexanone, 2,6-dimethylcyclohexanone, 2,2,6-trimethylcyclohexanone, cycloheptanone, 2-methylcycloheptanone, and 3-methylcycloheptanone.

Preferred examples of the alkylene carbonate include propylene carbonate, vinylene carbonate, ethylene carbonate, and butylene carbonate.

Preferred examples of the alkyl alkoxyacetate include 2-methoxyethyl acetate, 2-ethoxyethyl acetate, 2-(2-ethoxyethoxy)ethyl acetate, 3-methoxy-3-methylbutyl acetate, and 1-methoxy-2-propyl acetate.

Preferred examples of the alkyl pyruvate include methyl pyruvate, ethyl pyruvate, and propyl pyruvate.

The solvent that can be preferably used includes a solvent having a boiling point of 130° C. or more at ordinary temperature under atmospheric pressure and specifically includes cyclopentanone, γ-butyrolactone, cyclohexanone, ethyl lactate, ethylene glycol monoethyl ether acetate, propylene glycol monomethyl ether acetate, ethyl 3-ethoxypropionate, ethyl pyruvate, 2-ethoxyethyl acetate, 2-(2-ethoxyethoxy)ethyl acetate, and propylene carbonate.

In the present invention, one of these solvents may be used alone, or two or more kinds thereof may be used in combination.

In the present invention, a mixed solvent prepared by mixing a solvent containing a hydroxyl group in the structure and a solvent not containing a hydroxyl group may be used as the organic solvent.

The solvent containing a hydroxyl group and the solvent not containing a hydroxyl group may be appropriately selected from the compounds recited above, but the solvent containing a hydroxyl group is preferably an alkylene glycol monoalkyl ether, an alkyl lactate or the like, more preferably propylene glycol monomethyl ether or ethyl acetate. The solvent not containing a hydroxyl group is preferably an alkylene glycol monoalkyl ether acetate, an alkyl alkoxypropionate, a monoketone compound that may contain a ring, a cyclic lactone, an alkyl acetate or the like, and among these, more preferably propylene glycol monomethyl ether acetate, ethyl ethoxypropionate, 2-heptanone, γ-butyrolactone, cyclohexanone or butyl acetate, most preferably propylene glycol monomethyl ether acetate, ethyl ethoxypropionate or 2-heptanone.

The mixing ratio (by mass) of the solvent containing a hydroxyl group and the solvent not containing a hydroxyl group is from 1/99 to 99/1, preferably from 10/90 to 90/10, more preferably from 20/80 to 60/40. A mixed solvent containing 50 mass % or more of a solvent not having a hydroxyl group is particularly preferred in view of coating uniformity.

The solvent is preferably a mixed solvent of two or more kinds of solvents containing propylene glycol monomethyl ether acetate.

### [6](F) Basic Compound

The actinic ray-sensitive or radiation-sensitive resin composition of the present invention may further contain a basic compound (hereinafter, sometimes referred to as compound (F)) so as to reduce the change in performance over time from exposure to heating.

Preferred basic compounds include a basic compound having a structure represented by the following formulae (A) to (E):

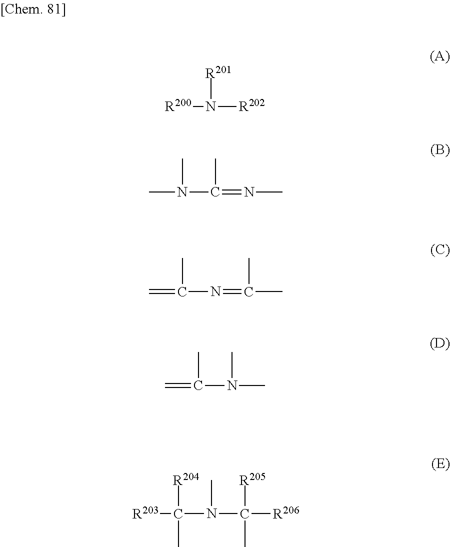

In formulae (A) and (E), each of R²⁰⁰, R²⁰¹ and R²⁰², which may be the same or different, represents a hydrogen atom, an alkyl group (preferably having a carbon number of 1 to 20), a cycloalkyl group (preferably having a carbon number of 3 to 20) or an aryl group (having a carbon number of 6 to 20), and R²⁰¹ and R²⁰² may combine with each other to form a ring. Each of R²⁰³, R²⁰⁴, R²⁰⁵ and R²⁰⁶, which may be the same or different, represents an alkyl group having a carbon number of 1 to 20.

As for the alkyl group, the alkyl group having a substituent is preferably an aminoalkyl group having a carbon number of 1 to 20, a hydroxyalkyl group having a carbon number of 1 to 20, or a cyanoalkyl group having a carbon number of 1 to 20.

The alkyl group in formulae (A) and (E) is more preferably unsubstituted.

Preferred compounds include guanidine, aminopyrrolidine, pyrazole, pyrazoline, piperazine, aminomorpholine, aminoalkylmorpholine, piperidine, and the like. More preferred compounds include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

The compound having an imidazole structure includes imidazole, 2,4,5-triphenylimidazole, benzimidazole, 2-phenylbenzimidazole, and the like. The compound having a diazabicyclo structure includes 1,4-diazabicyclo[2,2,2]octane, 1,5-diazabicyclo[4,3,0]non-5-ene, 1,8-diazabicyclo[5,4,0]undec-7-ene, and the like. The compound having an onium hydroxide structure includes a tetrabutylammonium hydroxide, a triarylsulfonium hydroxide, a phenacylsulfonium hydroxide, and a sulfonium hydroxide having a 2-oxoalkyl group, specifically, triphenylsulfonium hydroxide, tris(tert-butylphenyl)sulfonium hydroxide, bis(tert-butylphenyl)iodonium hydroxide, phenacylthiophenium hydroxide and 2-oxopropylthiophenium hydroxide. The compound having an onium carboxylate structure is a compound where the anion moiety of the compound having an onium hydroxide structure becomes a carboxylate, and examples thereof include an acetate, an adamantane-1-carboxylate, and a perfluoroalkyl carboxylate. The compound having a trialkylamine structure includes tri(n-butyl)amine, tri(n-octyl)amine, and the like. The aniline compound includes 2,6-diisopropylaniline, N,N-dimethylaniline, N,N-dibutylaniline, N,N-dihexylaniline, and the like. The alkylamine derivative having a hydroxyl group and/or an ether bond includes ethanolamine, diethanolamine, triethanolamine, N-phenyldiethanolamine, tris(methoxyethoxyethyl)amine, and the like. The aniline derivative having a hydroxyl group and/or an ether bond includes N,N-bis(hydroxyethyl)aniline and the like.

Other preferred basic compounds include a phenoxy group-containing amine compound, a phenoxy group-containing ammonium salt compound, a sulfonic acid ester group-containing amine compound, and a sulfonic acid ester group-containing ammonium salt compound.

In the phenoxy group-containing amine compound, phenoxy group-containing ammonium salt compound, sulfonic acid ester group-containing amine compound and sulfonic acid ester group-containing ammonium salt compound, at least one alkyl group is preferably bonded to the nitrogen atom. These compounds preferably contain an oxygen atom in the alkyl chain to form an oxyalkylene group. The number of oxyalkylene groups in molecule is 1 or more, preferably from 3 to 9, more preferably from 4 to 6. Among oxyalkylene groups, structures of —CH₂CH₂O—, —CH(CH₃)CH₂O— and —CH₂CH₂CH₂O— are preferred.

Specific examples of the phenoxy group-containing amine compound, phenoxy group-containing ammonium salt compound, sulfonic acid ester group-containing amine compound and sulfonic acid ester group-containing ammonium salt compound include, but are not limited to, Compounds (C1-1) to (C3-3) illustrated in paragraph [0066] of U.S. Patent Application Publication 2007/0224539.

One of these basic compounds may be used alone, or two or more thereof may be used in combination.

In the case where the composition according to the present invention contains the compound (F), the content ratio thereof is usually from 0.001 to 10 mass %, preferably from 0.01 to 5 mass %, based on the total solid content of the composition of the present invention.

The ratio of the acid generator and the compound (F) contained in the composition is preferably acid generator/compound (F) (by mol)=from 2.5 to 300. That is, the molar ratio is preferably 2.5 or more in view of sensitivity and resolution and is preferably 300 or less from the standpoint of suppressing the reduction in resolution due to thickening of the resist pattern over time after exposure until heat treatment. The ratio of acid generator/compound (F) (by mol) is more preferably from 3.5 to 200, still more preferably from 3.5 to 150. Incidentally, the amount of acid generator is the sum of the amount of compound (A) and the amount of compound (C).

### [7](O) Low Molecular Compound Having a Group Capable of Leaving by the Action of an Acid, and Increasing in the Basicity Upon Leaving of the Group

The actinic ray-sensitive or radiation-sensitive resin composition of the present invention preferably contains a low molecular compound having a group capable of leaving by the action of an acid, and increasing in the basicity upon leaving of the group (hereinafter, sometimes referred to as “low molecular compound (G)”).

The group capable of leaving by the action of an acid is not particularly limited but is preferably an acetal group, a carbonate group, a carbamate group, a tertiary ester group, a tertiary hydroxyl group or a hemiaminal ether group, more preferably a carbamate group or a hemiaminal ether group.

The molecular weight of the (G) low molecular compound having a group capable of leaving by the action of an acid is preferably from 100 to 1,000, more preferably from 100 to 700, still more preferably from 100 to 500.

The compound (G) is preferably an amine derivative having on the nitrogen atom a group capable of leaving by the action of an acid.

The compound (G) may have a protective group-containing carbamate group on the nitrogen atom. The protective group constituting the carbamate group is represented, for example, by the following formula (d-1):

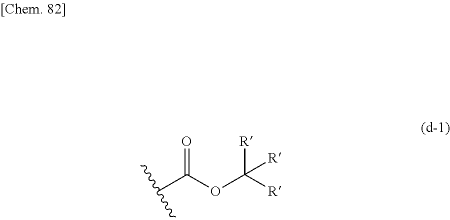

In formula (d-1), each R′ independently represents a hydrogen atom, a linear or branched alkyl group, a cycloalkyl group, an aryl group, an aralkyl group or an alkoxyalkyl group. R′ may combine with each other to form a ring.

R′ is more preferably a linear or branched alkyl group, a cycloalkyl group or an aryl group, more preferably a linear or branched alkyl group or a cycloalkyl group.

The low molecular compound (G) may also be composed by arbitrarily combining the above-described basic compound and the structure represented by formula (d-1).

The low molecular compound (G) is more preferably a compound having a structure represented by the following formula (A).

Incidentally, the low molecular compound (G) may be a compound corresponding to the above-described basic compound as long as it is a low molecular compound having a group capable of leaving by the action of an acid.

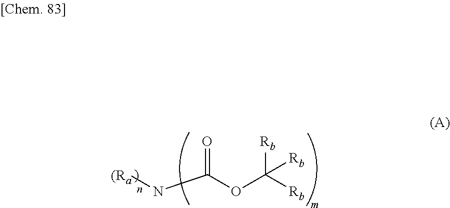

In formula (A), Ra represents a hydrogen atom, an alkyl group, a cycloalkyl group, an aryl group or an aralkyl group. Also, when n=2, two Ra may be the same or different, and two Ra may combine with each other to form a divalent heterocyclic group (preferably having a carbon number of 20 or less) or a derivative thereof.

Each Rb independently represents a hydrogen atom, an alkyl group, a cycloalkyl group, an aryl group or an aralkyl group, provided that in —C(Rb)(Rb)(Rb), when one or more Rb are a hydrogen atom, at least one of remaining R^{b} is a cyclopropyl group, a 1-alkoxyalkyl group or an aryl group.

At least two Rb may combine to form an alicyclic hydrocarbon group, an aromatic hydrocarbon group, a heterocyclic group, or a derivative thereof.

n represents an integer of 0 to 2, m represents an integer of 1 to 3, and n+m⁻³.

In formula (A), the alkyl group, cycloalkyl group, aryl group and aralkyl group represented by Ra and Rb may be substituted with a functional group such as hydroxyl group, cyano group, amino group, pyrrolidino group, piperidino group, morpholino group and oxo group, an alkoxy group or a halogen atom. The same applies to the alkoxyalkyl group represented by Rb.

The alkyl group, cycloalkyl group, aryl group and aralkyl group (these alkyl group, cycloalkyl group, aryl group and aralkyl group may be substituted with the above-described functional group, an alkoxy group or a halogen atom) of R^{a} and R^{b} include, for example,

a group derived from a linear or branched alkane such as methane, ethane, propane, butane, pentane, hexane, heptane, octane, nonane, decane, undecane and dodecane, or a group where the group derived from an alkane is substituted with one or more kinds of or one or more groups of cycloalkyl group such as cyclobutyl group, cyclopentyl group and cyclohexyl group;

a group derived from a cycloalkane such as cyclobutane, cyclopentane, cyclohexane, cycloheptane, cyclooctane, norbornane, adamantane and noradamantane, or a group where the group derived from a cycloalkane is substituted with one or more kinds of or one or more groups of linear or branched alkyl group such as methyl group, ethyl group, n-propyl group, i-propyl group, n-butyl group, 2-methylpropyl group, 1-methylpropyl group and tert-butyl group;

a group derived from an aromatic compound such as benzene, naphthalene and anthracene, or a group where the group derived from an aromatic compound is substituted with one or more kinds of or one or more groups of linear or branched alkyl group such as methyl group, ethyl group, n-propyl group, i-propyl group, n-butyl group, 2-methylpropyl group, 1-methylpropyl group and tert-butyl group;

a group derived from a heterocyclic compound such as pyrrolidine, piperidine, morpholine, tetrahydrofuran, tetrahydropyran, indole, indoline, quinoline, perhydroquinoline, indazole and benzimidazole, or a group where the group derived from a heterocyclic compound is substituted with one or more kinds of or one or more groups of linear or branched alkyl group or aromatic compound-derived group; a group where the group derived from a linear or branched alkane or the group derived from a cycloalkane is substituted with one or more kinds of or one or more groups of aromatic compound-derived group such as phenyl group, naphthyl group and anthracenyl group; and a group where the substituent above is substituted with a functional group such as hydroxyl group, cyano group, amino group, pyrrolidino group, piperidino group, morpholino group and oxo group.

Also, the divalent heterocyclic group (preferably having a carbon number of 1 to 20) formed by combining Ra with each other or a derivative thereof includes, for example, a group derived from a heterocyclic compound such as pyrrolidine, piperidine, morpholine, 1,4,5,6-tetrahydropyrimidine, 1,2,3,4-tetrahydroquinoline, 1,2,3,6-tetrahydropyridine, homopiperazine, 4-azabenzimidazole, benzotriazole, 5-azabenzotriazole, 1H-1,2,3-triazole, 1,4,7-triazacyclononane, tetrazole, 7-azaindole, indazole, benzimidazole, imidazo[1,2-a]pyridine, (1S,4S)-(+)-2,5-diazabicyclo[2.2.1]heptane, 1,5,7-triazabicyclo[4.4.0]dec-5-ene, indole, indoline, 1,2,3,4-tetrahydroquinoxaline, perhydroquinoline and 1,5,9-triazacyclododecane, and a group where the group derived from a heterocyclic compound is substituted with one or more kinds of or one or more groups of linear or branched alkane-derived group, cycloalkane-derived group, aromatic compound-derived group, heterocyclic compound-derived group, and functional group such as hydroxyl group, cyano group, amino group, pyrrolidino group, piperidino group, morpholino group and oxo group.

Specific examples of the low molecular compound (G) particularly preferred in the present invention are illustrated below, but the present invention is not limited thereto.

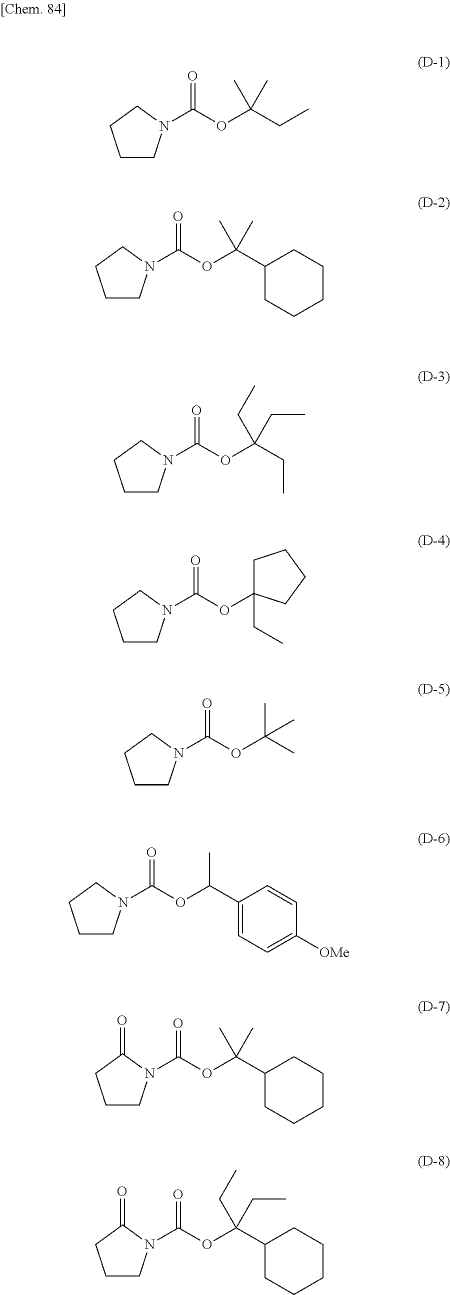

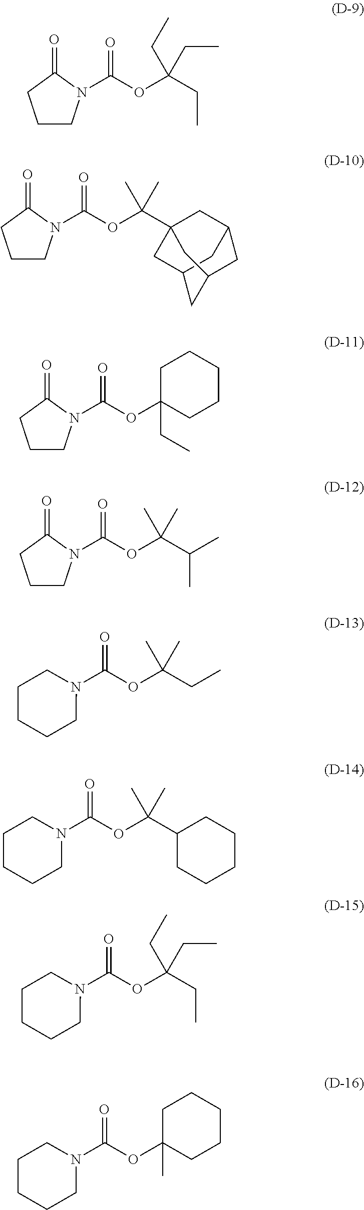

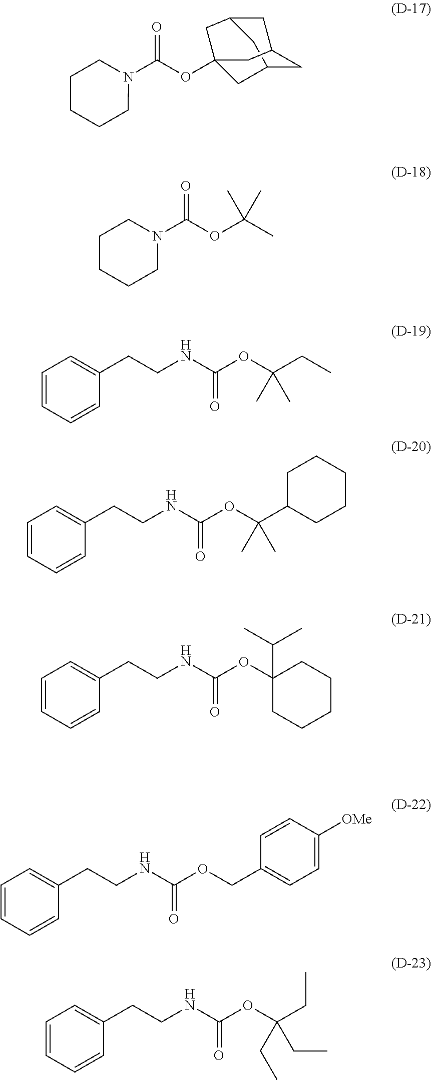

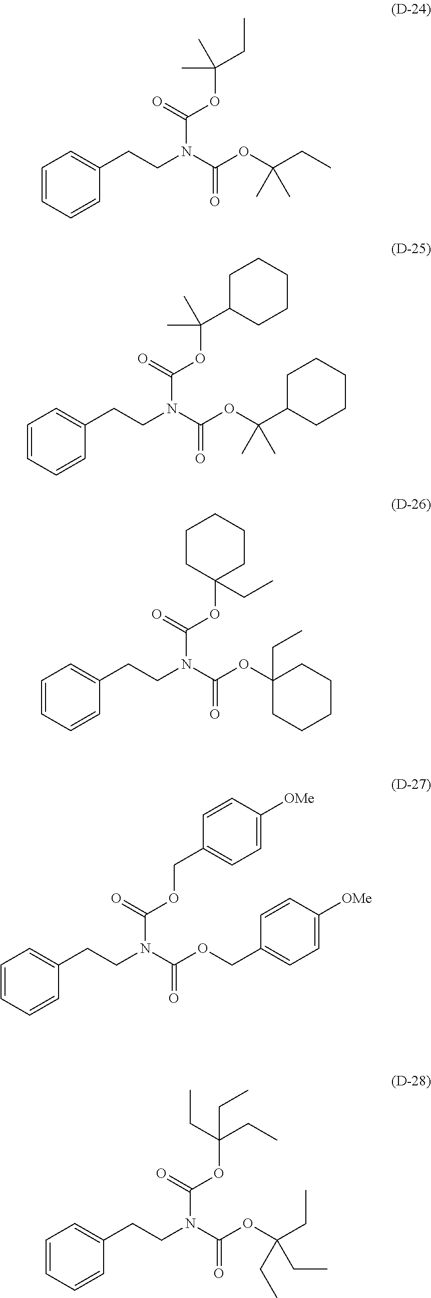 [SMILES: CCC(C)(C)OC(=O)N(CCc1ccccc1)C(=O)OC(C)(C)CC ; CC(C)(OC(=O)N(CCc1ccccc1)C(=O)OC(C)(C)C1CCCCC1)C1CCCCC1 ; CCC1(OC(=O)N(CCc2ccccc2)C(=O)OC2(CC)CCCCC2)CCCCC1 ; COc1ccc(COC(=O)N(CCc2ccccc2)C(=O)OCc2ccc(OC)cc2)cc1 ; CCC(CC)(CC)OC(=O)N(CCc1ccccc1)C(=O)OC(CC)(CC)CC]

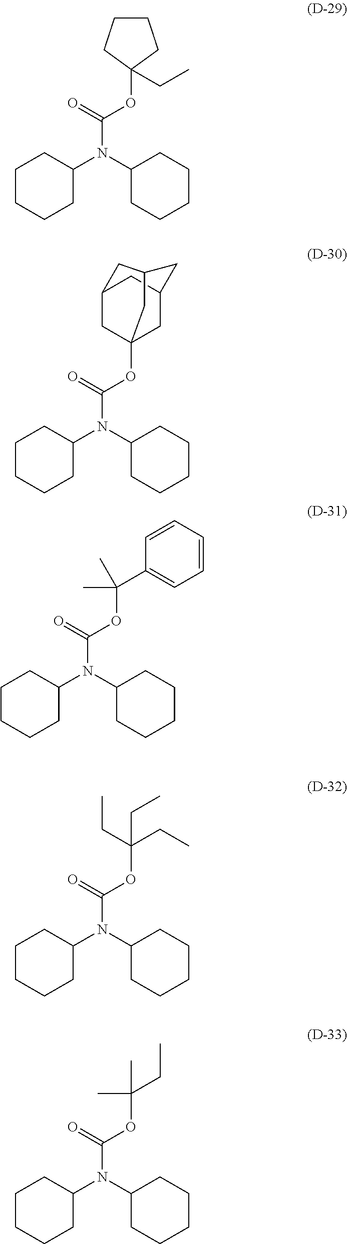

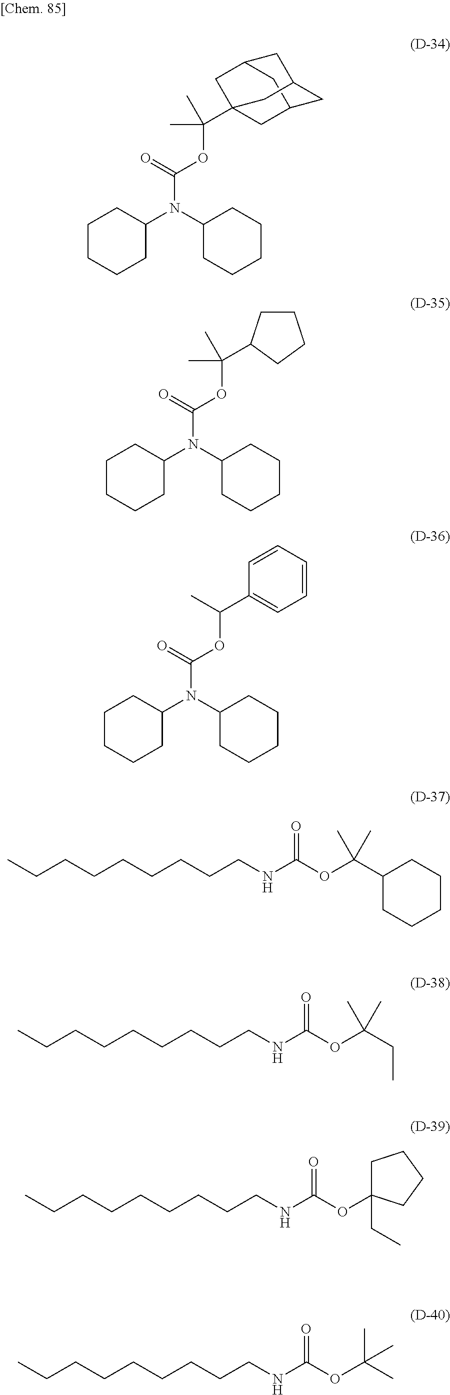

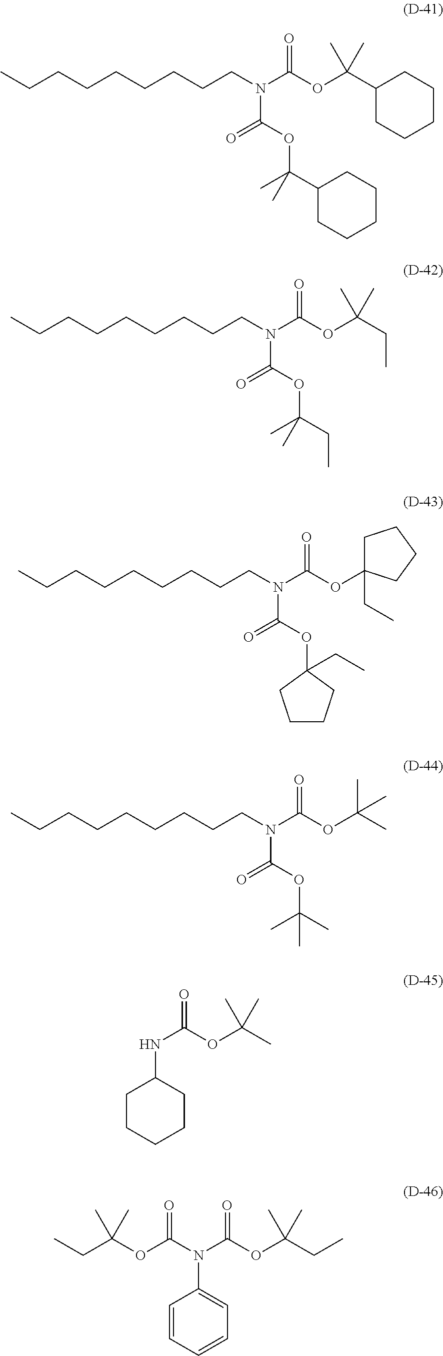

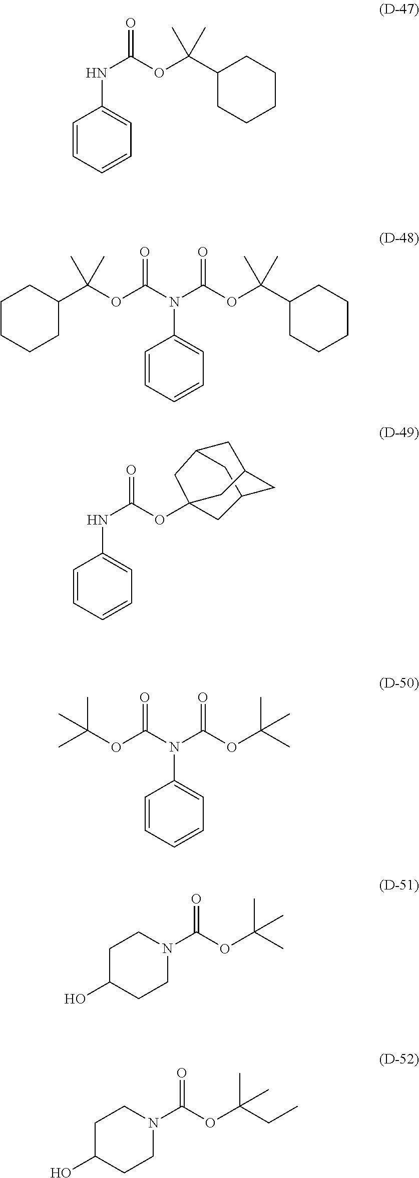 [SMILES: CC(C)(OC(=O)Nc1ccccc1)C1CCCCC1 ; CC(C)(OC(=O)N(C(=O)OC(C)(C)C1CCCCC1)c1ccccc1)C1CCCCC1 ; O=C(Nc1ccccc1)OC12CC3CC(CC(C3)C1)C2 ; CC(C)(C)OC(=O)N(C(=O)OC(C)(C)C)c1ccccc1 ; CC(C)(C)OC(=O)N1CCC(O)CC1 ; CCC(C)(C)OC(=O)N1CCC(O)CC1]

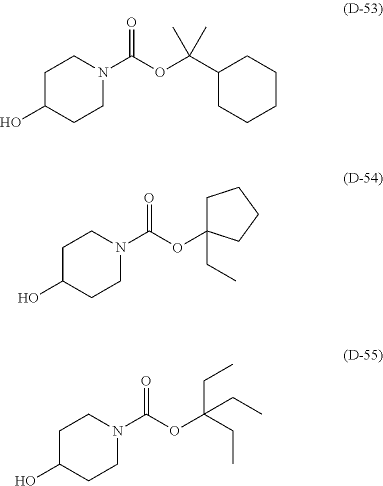 [SMILES: CC(C)(OC(=O)N1CCC(O)CC1)C1CCCCC1 ; CCC1(OC(=O)N2CCC(O)CC2)CCCC1 ; CCC(CC)(CC)OC(=O)N1CCC(O)CC1]

The compound represented by formula (A) can be synthesized by the method described, for example, in JP-A-2009-199021.

As for the low molecular compound (G), one compound may be used alone, or two or more compounds may be mixed and used.

In the present invention, the content ratio of the low molecular compound (G) is usually from 0.001 to 20 mass %, preferably from 0.001 to 10 mass %, more preferably from 0.01 to 5 mass %, based on the total solid compound of the composition.

The ratio of the acid generator and the low molecular compound (G) used in the composition is preferably acid generator/[low molecular compound (G)+basic compound (F)](by mol)=from 2.5 to 300. That is, the molar ratio is preferably 2.5 or more in view of sensitivity and resolution and is preferably 300 or less from the standpoint of suppressing the reduction in resolution due to thickening of the resist pattern over time after exposure until heat treatment. The ratio of acid generator/[low molecular compound (G)+basic compound (F)](by mol) is more preferably from 3.5 to 200, still more preferably from 3.5 to 150. Incidentally, the amount of acid generator is the sum of the amount of compound (A) and the amount of compound (C).

### [8](H) Surfactant

The actinic ray-sensitive or radiation-sensitive resin composition of the present invention may further contain a surfactant. In the case of containing a surfactant, it is preferred to contain any one of fluorine-containing and/or silicon-containing surfactants (a fluorine-containing surfactant, a silicon-containing surfactant and a surfactant containing both a fluorine atom and a silicon atom), or two or more thereof.

By containing the above-described surfactant, the composition of the present invention can give a resist pattern with good sensitivity and resolution and little adherence or development failure in using an exposure light source of 250 nm or less, particularly 220 nm or less.

The fluorine-containing and/or silicon-containing surfactants includes the surfactants described in paragraph [0276] of U.S. Patent Application Publication 2008/0248425, such as EFtop EF301 and EF303 (produced by Shin-Akita Kasci K.K.); Florad FC430, 431 and 4430 (produced by Sumitomo 3M Inc.); Megaface F171, F173, F176, F189, F113, F110, F177, F120 and R08 (produced by DIC Corporation); Surflon S-382, SC101, 102, 103, 104, 105 and 106 (produced by Asahi Glass Co., Ltd.); Troysol S-366 (produced by Troy Chemical); GF-300 and GF-150 (produced by Toagosei Chemical Industry Co., Ltd.); Surflon S-393 (produced by Seimi Chemical Co., Ltd.); EFtop EF121, EF122A, EF122B, RF122C, EF125M, EF135M, EF351, EF352, EF801, EF802 and EF601 (produced by JEMCO Inc.); PF636, PF656, PF6320 and PF6520 (produced by OMNOVA); and FIX-204G, 208G, 218G, 230G, 204D, 208D, 212D, 218D and 222D (produced by NEOS Co., Ltd.). In addition, Polysiloxane Polymer KP-341 (produced by Shin-Etsu Chemical Co., Ltd.) may also be used as the silicon-containing surfactant.

Other than those known surfactants, a surfactant using a polymer having a fluoroaliphatic group derived from a fluoroaliphatic compound which is produced by a telomerization process (also called a telomer process) or an oligomerization process (also called an oligomer process), may be used. The fluoroaliphatic compound can be synthesized by the method described in JP-A-2002-90991.

The polymer having a fluoroaliphatic group is preferably a copolymer of a fluoroaliphatic group-containing monomer with a (poly(oxyalkylene)) acrylate and/or a (poly(oxyalkylene)) methacrylate, and the copolymer may have an irregular distribution or may be a block copolymer. The poly(oxyalkylene) group includes a poly(oxyethylene) group, a poly(oxypropylene) group, a poly(oxybutylene) group, and the like and may also be a unit having alkylenes differing in the chain length within the same chain, such as block-linked poly(oxyethylene, oxypropylene and oxyethylene) and block-linked poly(oxyethylene and oxypropylene). Furthermore, the copolymer of a fluoroaliphatic group-containing monomer and a (poly(oxyalkylene)) acrylate (or methacrylate) is not limited only to a binary copolymer but may be also a ternary or higher copolymer obtained by simultaneously copolymerizing two or more different fluoroaliphatic group-containing monomers or two or more different (poly(oxyalkylene)) acrylates (or methacrylates).

Examples thereof include, as the commercially available surfactant, Megaface F178, F-470, F-473, F-475, F-476 and F-472 (produced by DIC Corporation) and further include a copolymer of a C₆F₁₃ group-containing acrylate (or methacrylate) with a (poly(oxyalkylene)) acrylate (or methacrylate), and a copolymer of a C₃F₇ group-containing acrylate (or methacrylate) with a (poly(oxyethylene)) acrylate (or methacrylate) and a (poly(oxypropylene)) acrylate (or methacrylate).

In the present invention, surfactants other than the fluorine-containing and/or silicon-containing surfactants, described in paragraph [0280] of U.S. Patent Application Publication No. 2008/0248425, may be also used.

One of these surfactants may be used alone, or some of them may be used in combination.

In the case where the composition of the present invention contains a surfactant, the content ratio of the surfactant is preferably from 0.1 to 2 mass %, more preferably from 0.1 to 1.5 mass %, still more preferably from 0.1 to 1 mass %/, based on the total solid content of the composition.

On the other hand, it is also preferred that the amount added of the surfactant is 10 ppm or less or the composition does not contain a surfactant. In this case, the hydrophobic resin is more unevenly distributed to the surface, so that the resist film surface can be made more hydrophobic and the followability of water at the immersion exposure can be enhanced.

### [9](I) Onium Carboxylate

The actinic ray-sensitive or radiation-sensitive resin composition of the present invention may contain an onium carboxylate. The onium carboxylate is preferably an iodonium salt or an ammonium salt. The anion moiety is preferably a linear or branched, monocyclic or polycyclic alkylcarboxylate anion having a carbon number of 1 to 30, more preferably the carboxylate anion in which the alkyl group is partially or entirely substituted with fluorine. The alkyl chain may contain an oxygen atom. Thanks to such a configuration, the transparency to light of 220 nm or less is ensured, the sensitivity and resolution are enhanced, and the iso/dense bias and exposure margin are improved.

The fluorine-substituted carboxylate anion includes fluoroacetate, difluoroacetate, trifluoroacetate, pentafluoropropionate, heptafluorobutyrate, nonafluoropentanoate, perfluorododecanoate, perfluorotridecanoate, perfluorocyclohexanecarboxylate and 2,2-bistrifluoromethylpropionate anions, and the like.

The content ratio of the onium carboxylate in the composition is generally from 0.1 to 20 mass %, preferably from 0.5 to 10 mass %, more preferably from 1 to 7 mass %, based on the total solid content of the composition.

### [10](J) Dissolution Inhibiting Compound

The actinic ray-sensitive or radiation-sensitive resin composition of the present invention may contain a dissolution inhibiting compound capable of decomposing by the action of an acid to increase the solubility in an alkali developer and having a molecular weight of 3,000 or less. In order to prevent reduction in the transparency to light of 220 nm or less, the dissolution inhibiting compound is preferably an alicyclic or aliphatic compound having an acid-decomposable group, such as acid-decomposable group-containing cholic acid derivatives described in Proceeding of SPIE. 2724, 355 (1996). Examples of the acid-decomposable group and the alicyclic structure are the same as those described above for the resin (B).

In the case where the composition of the present invention is exposed to a KrF excimer laser or irradiated with an electron beam, the dissolution inhibiting compound preferably contains a structure where a phenolic hydroxyl group of a phenol compound is substituted with an acid-decomposable group. The phenol compound preferably contains from 1 to 9 phenol frameworks, more preferably from 2 to 6 phenol frameworks.

The amount added of the dissolution inhibiting compound is preferably from 3 to 50 mass %, more preferably from 5 to 40 mass %, based on the total solid content of the actinic ray-sensitive or radiation-sensitive resin composition.

Specific examples of the dissolution inhibiting compound are illustrated below, but the present invention is not limited thereto.

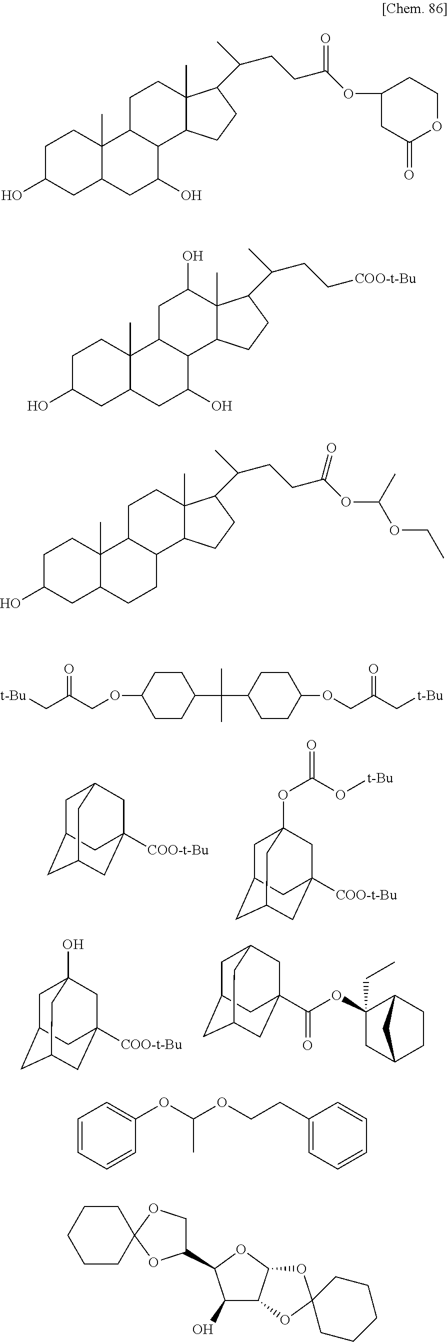

### [11](K) Other Additives

The actinic ray-sensitive or radiation-sensitive resin composition of the present invention may further contain, if desired, a dye, a plasticizer, a photosensitizer, a light absorber, a compound for accelerating dissolution in a developer (for example, a phenol compound having a molecular weight of 1,000 or less, or a carboxyl group-containing alicyclic or aliphatic compound), and the like.

The phenol compound having a molecular weight of 1,000 or less can be easily synthesized by one skilled in the art by referring to the method described, for example, in JP-A-4-122938, JP-A-2-28531, U.S. Pat. No. 4,916,210 and European Patent 219294.

Specific examples of the carboxyl group-containing alicyclic or aliphatic compound include, but are not limited to, a carboxylic acid derivative having a steroid structure, such as cholic acid, deoxycholic acid and lithocholic acid, an adamantanecarboxylic acid derivative, an adamantanedicarboxylic acid, a cyclohexanecarboxylic acid, and a cyclohexanedicarboxylic acid.

### [12] Pattern Forming Method

The pattern forming method of the present invention involves exposing an actinic ray-sensitive or radiation-sensitive film and developing the exposed film.

The actinic ray-sensitive or radiation-sensitive film is formed from the above-described actinic ray-sensitive or radiation-sensitive resin composition of the present invention and, more specifically, is preferably formed on a substrate. In the pattern forming method of the present invention, the step of forming an actinic ray-sensitive or radiation-sensitive film from an actinic ray-sensitive or radiation-sensitive resin composition on a substrate, the step of exposing the film, and the development step can be performed by generally known methods.

From the standpoint of enhancing the resolution, the actinic ray-sensitive or radiation-sensitive film of the present invention preferably has a thickness of 30 to 250 nm, more preferably from 30 to 200 nm. Such a film thickness can be achieved by setting the solid content concentration in the actinic ray-sensitive or radiation-sensitive resin composition to an appropriate range, thereby imparting an appropriate viscosity and enhancing the coatability and film-forming property.

The total solid content concentration in the actinic ray-sensitive or radiation-sensitive resin composition of the present invention is generally from 1 to 10 mass %, preferably from 1 to 8.0 mass %/, more preferably from 1.0 to 7.0 mass %.

The actinic ray-sensitive or radiation-sensitive resin composition of the present invention is used by dissolving the components above in a predetermined organic solvent, preferably in the above-described mixed solvent, filtering the solution through a filter, and coating the filtrate on a predetermined support. The filter used for filtration is preferably a polytetrafluoroethylene-, polyethylene- or nylon-made filter having a pore size of 0.1 μm or less, more preferably 0.05 μm or less, still more preferably 0.03 μm or less. A plurality of kinds of filters may be used by connecting the filters in series or in parallel. Also, the composition may be filtered a plurality of times. Furthermore, a deaeration treatment or the like may be applied to the composition before and after filtration through a filter.

For example, the actinic ray-sensitive or radiation-sensitive resin composition is coated on such a substrate (e.g., silicon/silicon dioxide-coated substrate) as used in the production of an integrated circuit device, by an appropriate coating method such as spinner and coater, and then dried to form a film.

Before forming the film, an antireflection film may be previously coated and provided on the substrate.

The antireflection film which can be used may be either an inorganic film type such as titanium, titanium dioxide, titanium nitride, chromium oxide, carbon and amorphous silicon, or an organic film type composed of a light absorber and a polymer material. As for the organic antireflection film, a commercially available organic antireflection film such as DUV30 Series and DUV-40 Series produced by Brewer Science, Inc. and AR-2, AR-3 and AR-5 produced by Shipley Co., Ltd., may also be used The film is irradiated with an actinic ray or radiation through a predetermined mask, preferably baked (heated), and then subjected to development and rinsing, whereby a good pattern can be obtained. Incidentally, in the irradiation with an electron beam, lithography without a mask (direct lithography) is general practice.

It is also preferred to involve a pre-baking step (PB; Prebake) after the film formation but before the exposure step.

In addition, it is also preferred to involve a post-exposure baking step (PEB; Post Exposure Bake) after the exposure step but before the development step.

As for the heating temperature, both PB and PEB are preferably performed at 70 to 120° C., more preferably at 80 to 110° C.

The heating time is preferably from 30 to 300 seconds, more preferably from 30 to 180 seconds, still more preferably from 30 to 90 seconds.

Heating can be performed using a device attached to an ordinary exposure/developing machine or may be performed using a hot plate or the like.

Thanks to baking, the reaction in the exposed area is accelerated, and the sensitivity and pattern profile are improved.

The actinic ray or radiation includes infrared light, visible light, ultraviolet light, far ultraviolet light, extreme-ultraviolet light, X-ray, electron beam, and the like, but the radiation is preferably far ultraviolet light having a wavelength of 250 nm or less, more preferably 220 nm or less, still more preferably from 1 to 200 nm. Specific examples thereof include KrF excimer laser (248 nm), ArF excimer laser (193 nm), F2 excimer laser (157 nm), X-ray, and electron beam, with ArF excimer laser, F2 excimer laser, EUV (13 nm) and electron beam being preferred.

As for the alkali developer in the development step, a quaternary ammonium salt typified by tetramethylammonium hydroxide is usually used, but in addition, an aqueous alkali solution of inorganic alkali, primary amine, secondary amine, tertiary amine, alcohol amine, cyclic amine or the like can also be used.

Furthermore, this alkali developer may be used after adding thereto alcohols and a surfactant each in an appropriate amount.

The alkali concentration of the alkali developer is usually from 0.1 to 20 mass %.

The pH of the alkali developer is usually from 10.0 to 15.0.

As for the rinsing solution, pure water is used, and an appropriate amount of a surfactant may be added thereto before use.

As the developing method, for example, a method of dipping the substrate in a bath filled with the developer for a fixed time (dipping method), a method of raising the developer on the substrate surface by the effect of a surface tension and keeping it still for a fixed time, thereby performing development (puddle method), a method of spraying the developer on the substrate surface (spraying method), and a method of continuously ejecting the developer on the substrate rotating at a constant speed while scanning the developer ejecting nozzle at a constant rate (dynamic dispense method) may be applied.

In the rinsing step, the wafer after development is rinsed using a rinsing solution. The method for rinsing treatment is not particularly limited but, for example, a method of continuously ejecting the rinsing solution on the substrate rotating at a constant speed (spin coating method), a method of dipping the substrate in a bath filled with the rinsing solution for a fixed time (dipping method), and a method of spraying the rinsing solution on the substrate surface (spraying method), may be applied. Above all, it is preferred to perform the rinsing treatment by the spin coating method and after the rinsing, remove the rinsing solution from the substrate surface by spinning the substrate at a rotational speed of 2,000 to 4,000 rpm. It is also preferred to involve a heating step (Post Bake) after the rinsing step. The developer and rinsing solution remaining between patterns and inside of the pattern are removed by the baking. The heating step after the rinsing step is performed at usually from 40 to 160° C., preferably from 70 to 95° C., for usually from 10 seconds to 3 minutes, preferably from 30 to 90 seconds.

After the development or rinsing, a treatment for removing the developer or rinsing solution adhering on the pattern by a supercritical fluid may be performed.

The film formed using the actinic ray-sensitive or radiation-sensitive resin composition of the present invention may be subjected to immersion exposure. That is, the film may be irradiated with an actinic ray or radiation in the state of filling the gap between the film and the lens with a liquid having a refractive index higher than that of air. By this exposure, the resolution can be more enhanced.

The immersion liquid used when performing immersion exposure is described below.

The immersion liquid is preferably a liquid being transparent to light of the exposure wavelength and having as small a temperature coefficient of refractive index as possible so as to minimize the distortion of an optical image projected on the resist film. Particularly, when the exposure light source is ArF excimer laser (wavelength: 193 nm), water is preferably used in view of availability and ease of handling in addition to the above-described aspects.

Furthermore, a medium having a refractive index of 1.5 or more may also be used with an attempt to more shorten the wavelength. This medium may be either an aqueous solution or an organic solvent.

In the case of using water as the immersion liquid, for the purpose of decreasing the surface tension of water and increasing the surface activity, an additive (liquid) incapable of dissolving the resist layer on the wafer and at the same time, capable of giving only a negligible effect on the optical coat at the undersurface of the lens element may be added in a small ratio.

The additive is preferably an aliphatic alcohol having a refractive index substantially equal to that of water, and specific examples thereof include methyl alcohol, ethyl alcohol, and isopropyl alcohol. By virtue of adding an alcohol having a refractive index substantially equal to that of water, even when the alcohol component in water is evaporated and its content concentration is changed, the change in the refractive index of the liquid as a whole can be made very small. On the other hand, when a substance opaque to light of 193 nm or an impurity greatly differing in the refractive index from water is mingled, this incurs distortion of the optical image projected on the resist, and therefore, water used is preferably distilled water. Pure water obtained by further filtering the distilled water through an ion exchange filter or the like may be also used.

The electrical resistance of water used as the immersion liquid is preferably 18.3 MQcm or more, and TOC (total organic carbon) is preferably 20 ppb or less. Also, the water is preferably subjected to a deaeration treatment.

The lithography performance can be enhanced by elevating the refractive index of the immersion liquid. From such a standpoint, an additive for elevating the refractive index may be added to water, or heavy water (D₂O) may be used in place of water.

In order to prevent the resist film from contacting with the immersion liquid, a film (hereinafter, sometimes referred to as a “topcoat”) sparingly soluble in the immersion liquid may be provided between the resist film and the immersion liquid. The functions required of the topcoat are suitability for coating on the resist film, transparency to radiation, particularly radiation having a wavelength of 193 nm, and sparing solubility in the immersion liquid. As the topcoat, a film unmixable with the resist film and capable of being uniformly coated on the resist film is preferably used.

In view of transparency to light of 193 nm, the topcoat is preferably an aromatic-free polymer. Such a polymer includes, for example, a hydrocarbon polymer, an acrylic acid ester polymer, a polymethacrylic acid, a polyacrylic acid, a polyvinyl ether, a silicon-containing polymer, and a fluorine-containing polymer. The above-described hydrophobic resin is suitable also as the topcoat. If impurities are dissolved out into the immersion liquid from the topcoat, the optical lens is contaminated. For this reason, the amount of residual monomer components of the polymer contained in the topcoat is smaller.

On removing the topcoat, a developer may be used, or a releasing agent may be separately used. The releasing agent is preferably a solvent less permeating the resist film. From the standpoint that the removing step can be performed simultaneously with the development step of the resist, the topcoat is preferably capable of being removed with an alkali developer and from the standpoint of removing the film with an alkali developer, the topcoat is preferably acidic, but in view of non-intermixing with the resist, the topcoat may be neutral or alkaline.

The difference in the refractive index between the topcoat and the immersion liquid is preferably null or small. In this case, the resolution can be enhanced. In the case where the exposure light source is an ArF excimer laser (wavelength: 193 nm), water is preferably used as the immersion liquid and therefore, the topcoat for ArF immersion exposure preferably has a refractive index close to the refractive index (1.44) of water.

Also, in view of transparency and refractive index, the topcoat is preferably a thin film. The topcoat is preferably unmixable with the resist film and furthermore, unmixable also with the immersion liquid. From this standpoint, when the immersion liquid is water, the solvent used for the topcoat is preferably a medium that is sparingly soluble in the solvent used for the actinic ray-sensitive or radiation-sensitive resin composition of the present invention resin and insoluble in water. In the case where the immersion liquid is an organic solvent, the topcoat may be either water-soluble or water-insoluble.

### EXAMPLES

The embodiments of the present invention are described in greater detail by referring to Examples, but the scope of the present invention is not limited to these Examples.

### <Acid Generator (1)>

Compounds (A-1) to (A-16) show below were synthesized as the compound (A). Also, for reference, Compound (A-17) and (A-18) shown below were prepared.

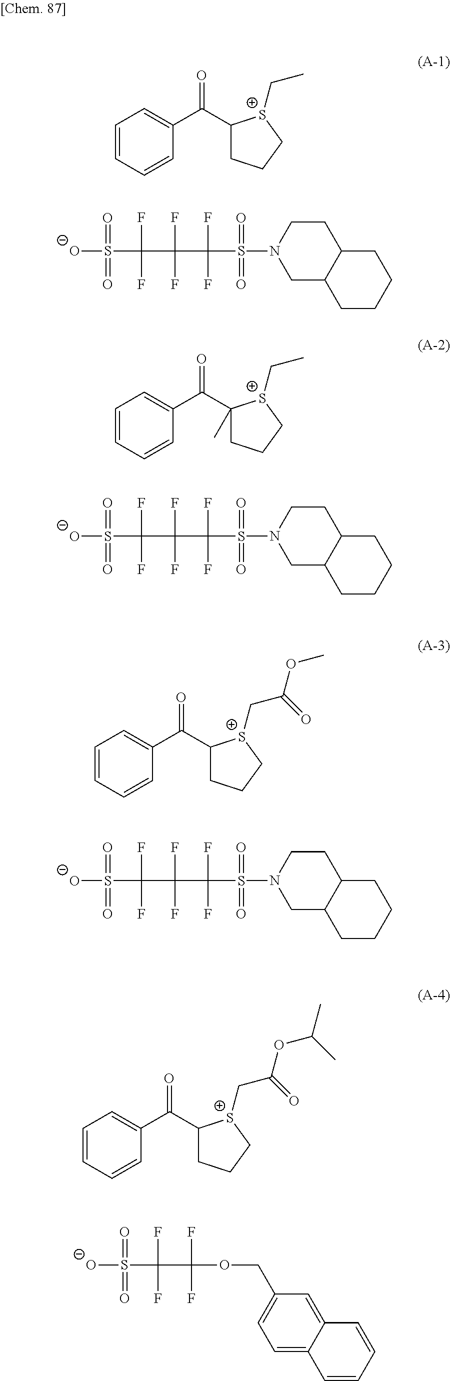

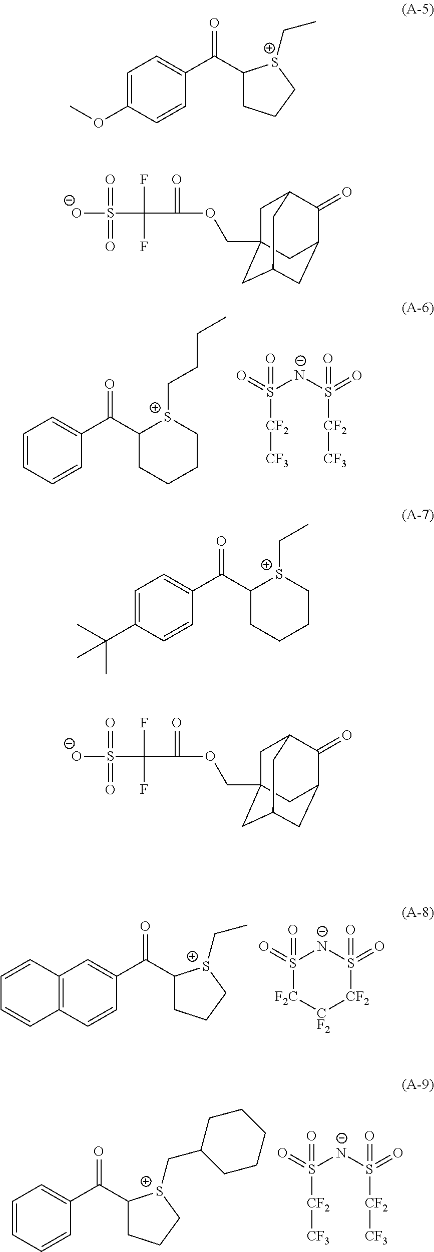

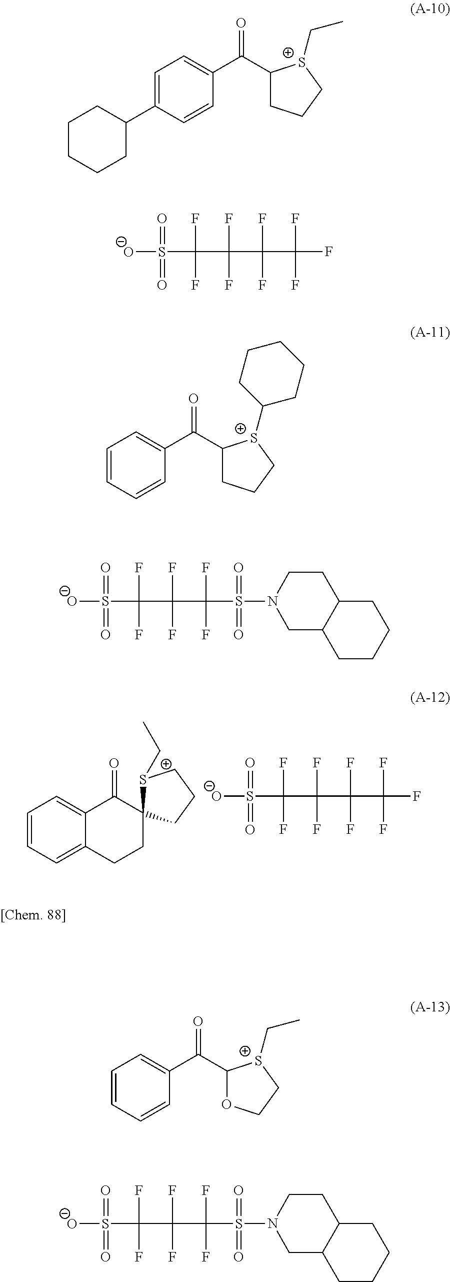

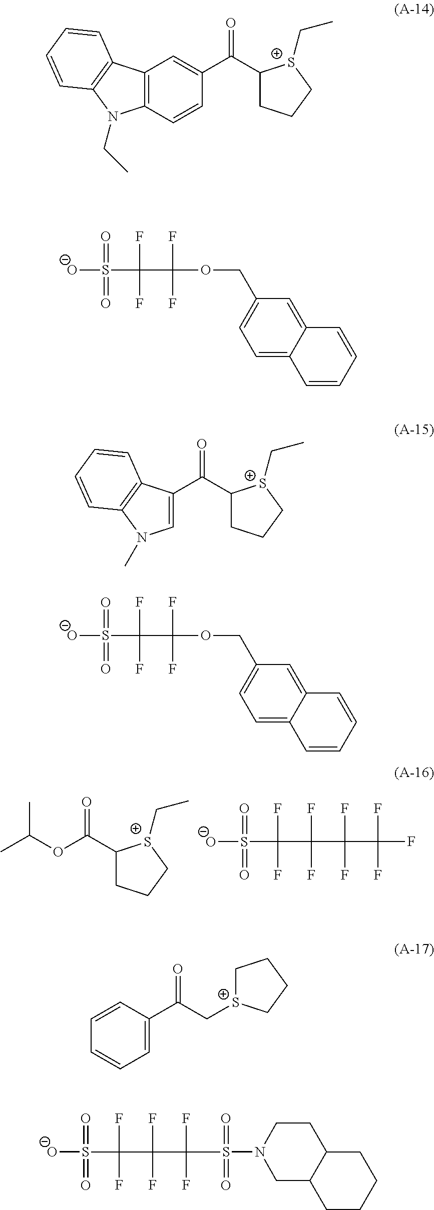

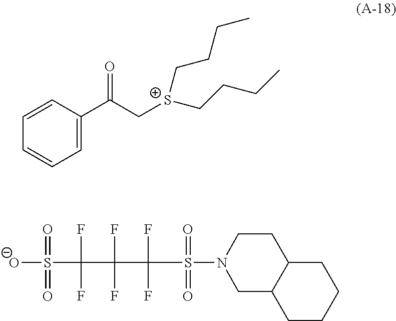 [SMILES: CCCC[S+](CCCC)CC(=O)c1ccccc1 ; O=S(=O)([O-])C(F)(F)C(F)(F)C(F)(F)S(=O)(=O)N1CCC2CCCCC2C1]

### Synthesis Example 1

### Synthesis of Compound (A-1)

In a 1-L three-neck flask, 20 g of phenacyl bromide and 15.5 g of triethylamine were dissolved in 200 g of tetrahydrofuran (THF). The resulting solution was stirred under ice cooling, and 9.3 g of 3-mercapto 1-propanol was added over 10 minutes. After the dropwise addition, the ice bath was removed. The reaction solution was stirred at room temperature for 1 hour, and 200 g of ethyl acetate was added thereto. The organic layer was washed in sequence with saturated sodium bicarbonate water, water and saturated brine, and the solvent was removed to obtain 20.5 g of Compound (A-1-1) shown below in a transparent liquid form.

In a 1-L three-neck flask, 20.5 g of Compound (A-1-1) and 19.5 g of triethylamine were dissolved in 200 g of THF. The resulting solution was stirred under ice cooling, and 14.2 g of methanesulfonyl chloride was added over 10 minutes. After the dropwise addition, the ice bath was removed. The reaction solution was stirred at room temperature for 30 minutes, and 200 g of ethyl acetate was added thereto. The organic layer was washed in sequence with saturated sodium bicarbonate water, water and saturated brine, and the solvent was removed to obtain 21.0 g of Compound (A-1-2) shown below in a transparent liquid form.

In a 1-L three-neck flask, 21.0 g of Compound (A-1-2) was dissolved in 160 g of THF and 40 g of N,N-dimethylformamide (DMF). The resulting solution was stirred under ice cooling, and 7.6 g of NaH was added, followed by stirring at room temperature for 1 hour. The reaction solution was neutralized with hydrochloric acid, and 200 g of ethyl acetate was added thereto. The organic layer was washed in sequence with saturated sodium bicarbonate water, water and saturated brine, and the solvent was removed to obtain 15.0 of Compound (A-1-3) in a brown liquid form.

In a 50-mL one-neck flask, 1.0 g of Compound (A-1-3) and 1.6 g of ethyl iodide were dissolved in 5 g of acetonitrile, and 1.1 g of AgBF₄ was added thereto, followed by stirring at 60° C. for 3 hours. The reaction solution was filtered to remove silver iodide, and 30 g of chloroform and 30 g of water were added thereto. Furthermore, 2.5 g of Compound (A-1-4) was added, and the solution was stirred for 1 hour. The organic layer was washed with water three times to remove the solvent, and the precipitated crystal was washed with 50 g of diisopropyl ether to obtain 2.0 g of Compound (A-1) as a white solid. The chemical shifts in ¹H-NMR of Compound (A-1) are shown below.

¹H-NMR (300 MHz, CDCl₃): 8.13 (d, 2H), 7.69 (t, 1H), 7.53 (t, 1H), 6.33 (dd, 1H), 3.95 (d, 1H), 3.79 (d, 1H), 3.72 (m, 1H), 3.66 (q, 2H), 3.51 (m, 1H), 3.22-3.05 (m, 2H), 2.78-2.65 (m, 2H), 2.40 (m, 1H), 2.25 (m, 1H), 1.78-1.60 (m, 6H), 1.55 (t, 3H), 1.40-1.20 (m, 4H), 1.15-0.90 (m, 2H).

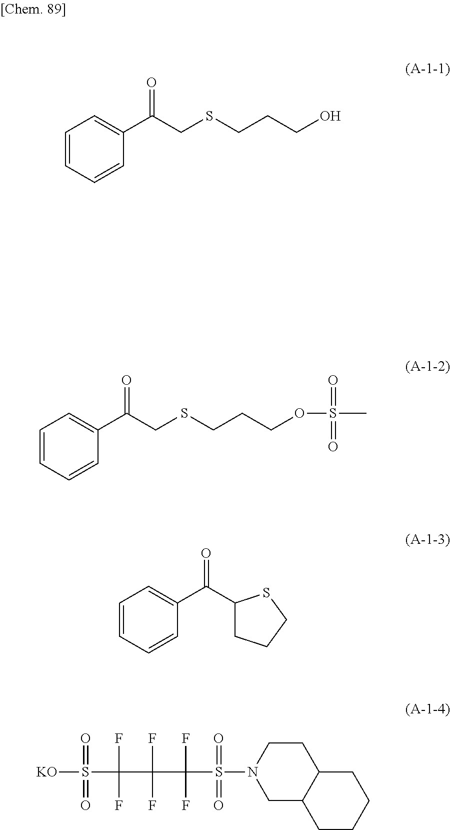

### Synthesis Example 2

### Synthesis of Compound (A-2)

In a 300-mL three-neck flask, 2.3 g of 3-mercapto 1-propanol was dissolved in 50 g of THF and 10 g of ethanol (EtOH), and 2.8 g of potassium tert-butoxide (tBuOK) was added thereto. The resulting solution was stirred under ice cooling, and 5.0 g of 2-bromopropiophenone was added over 10 minutes. After the dropwise addition, the ice bath was removed. The reaction solution was stirred at room temperature for 1 hour and then neutralized with 1 N hydrochloric acid, and 100 g of ethyl acetate was added thereto. The organic layer was washed in sequence with saturated sodium bicarbonate water, water and saturated brine, and the solvent was removed to obtain 5.1 g of Compound (A-2-1) shown below in a transparent liquid form.

In a 200-mL three-neck flask, 4.2 g of Compound (A-2-1) and 3.8 g of triethylamine were dissolved in 40 g of THF. The resulting solution was stirred under ice cooling, and 2.8 g of methanesulfonyl chloride was added dropwise over 10 minutes. After the dropwise addition, the ice bath was removed. The reaction solution was stirred at room temperature for 30 minutes, and 100 g of ethyl acetate was added thereto. The organic layer was washed in sequence with saturated sodium bicarbonate water, water and saturated brine, and the solvent was removed to obtain 5.0 g of Compound (A-2-2) shown below in a transparent liquid form.

In a 200-mL three-neck flask, 5.0 g of Compound (A-2-2) was dissolved in 40 g of THF and 10 g of DMF. The resulting solution was stirred under ice cooling, and 1.5 g of sodium hydride (NaH) was added, followed by stirring at room temperature for 1 hour. The reaction solution was neutralized with 1 N hydrochloric acid, and 100 g of ethyl acetate was added thereto. The organic layer was washed in sequence with saturated sodium bicarbonate water, water and saturated brine, and the solvent was removed to obtain Compound (A-2-3) shown below in a transparent liquid form.

In a 50-mL one-neck flask, 1.0 g of Compound (A-2-3) was dissolved in 5 g of methylene chloride. The resulting solution was stirred under ice cooling, and 1.5 g of triethyloxonium tetrafluoroborate (Et₃OBF₄) was added thereto, and after stirring at room temperature for 3 hours, 30 g of chloroform and 50 g of water were added thereto. Furthermore, 3.9 g of Compound (A-1-4) was added, and the solution was stirred for 1 hour. The organic layer was washed with water three times to remove the solvent, and the precipitated crystal was washed with 50 g of diisopropyl ether to obtain 2.1 g of Compound (A-2, dr=3:2) as a white solid. The chemical shifts in ¹H-NMR of Compound (A-2) are shown below.

¹H-NMR (300 MHz, CDCl₃): 8.0 (m, 2H), 7.75 (m, 1H), 7.60 (m, 2H), 3.95 (d, 1H), 3.85 (m, 0.4H), 3.79 (d, 1H), 3.65 (m, 1H), 3.45 (m, 1H), 3.18 (m, 0.6H), 3.05 (t, 1H), 2.90 (m, 0.4H), 2.80 (m, 1H), 2.65 (t, 1H), 2.60 (m, 1.4H), 2.50 (m, 1.6H), 2.10 (m, 0.4H), 2.0 (s, 3H), 1.78-1.60 (m, 6H), 1.55 (t, 3H), 1.40-1.20 (m, 7H), 1.15-0.90 (m, 2H).

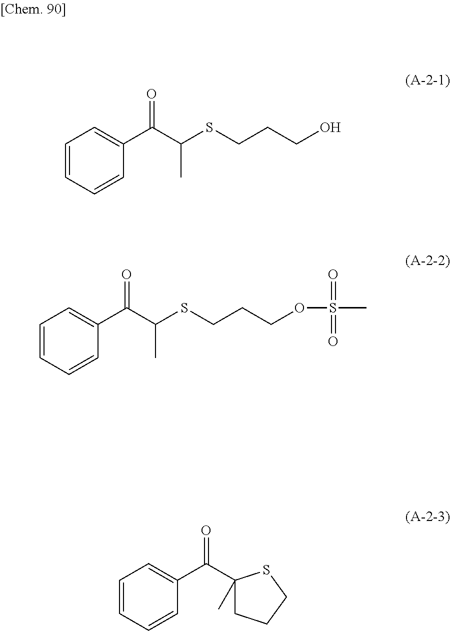 [SMILES: CC(SCCCO)C(=O)c1ccccc1 ; CC(SCCCOS(C)(=O)=O)C(=O)c1ccccc1 ; CC1(C(=O)c2ccccc2)CCCS1]

Other compounds (A) were synthesized in the same manner as Compound (A-1) or (A-2).

### <Acid Generator (2)>

Compounds (C-1) to (C-7) shown below were prepared as the compound (C).

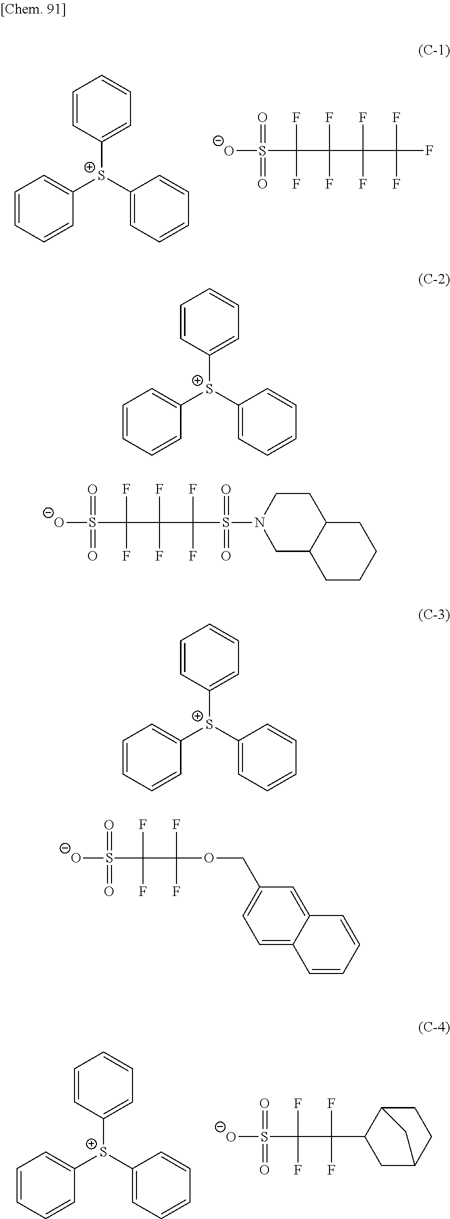

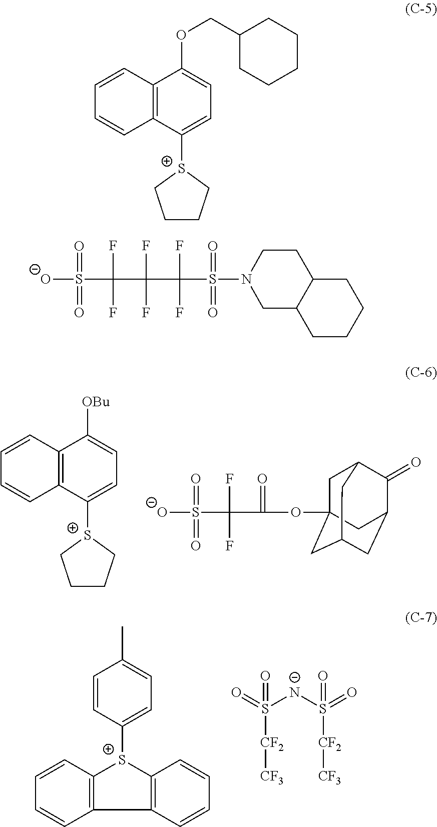

### <Resin (B)>

Resins (B-1) to (B-11) shown below were prepared as the resin (B).

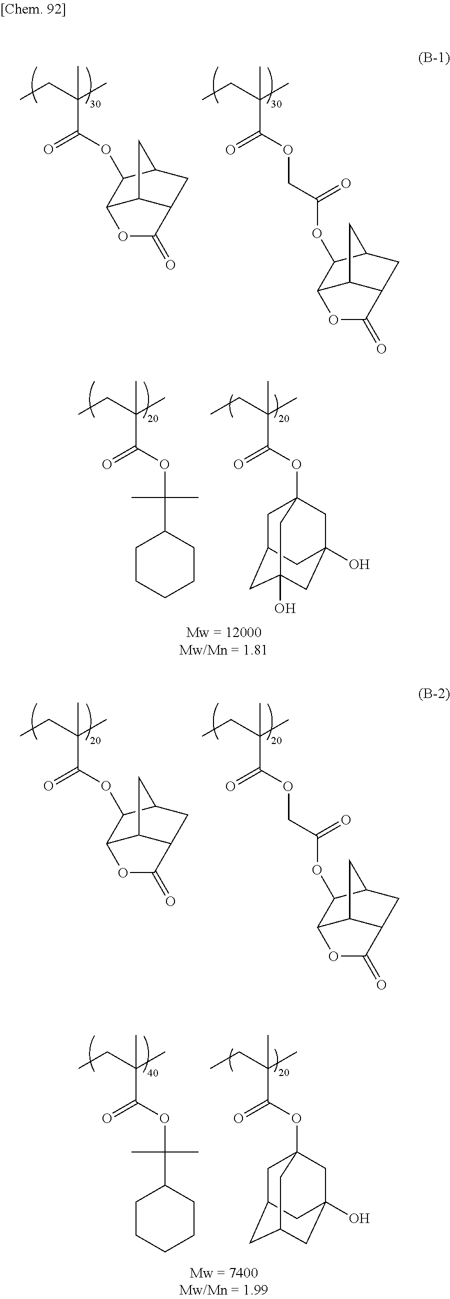

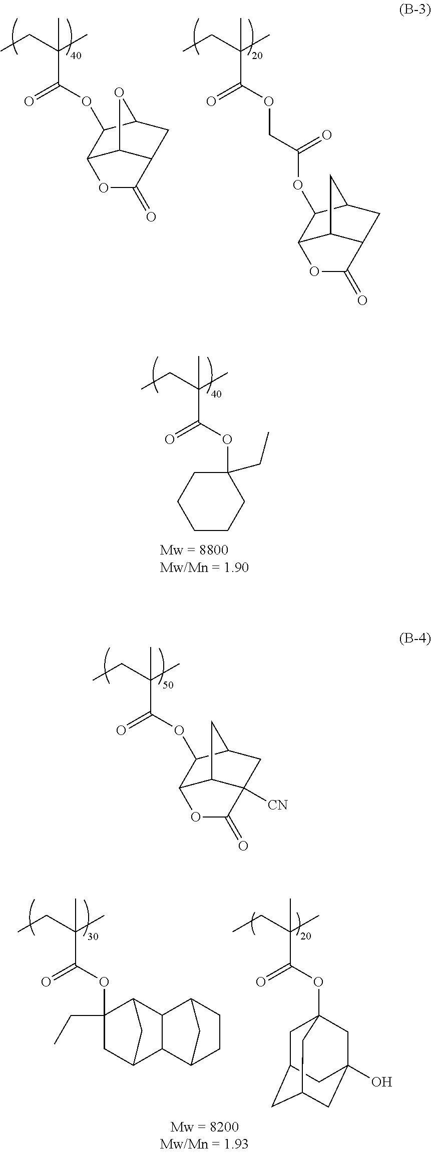

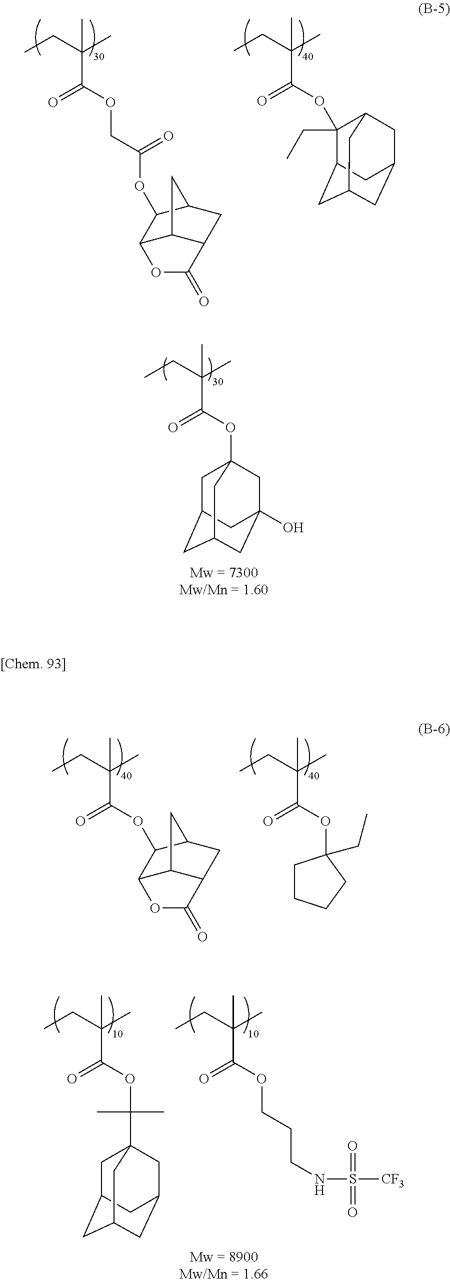

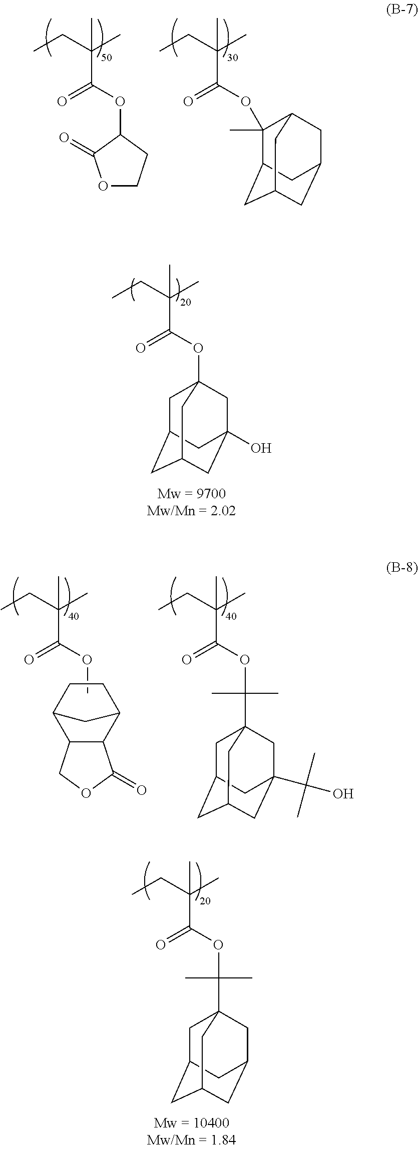

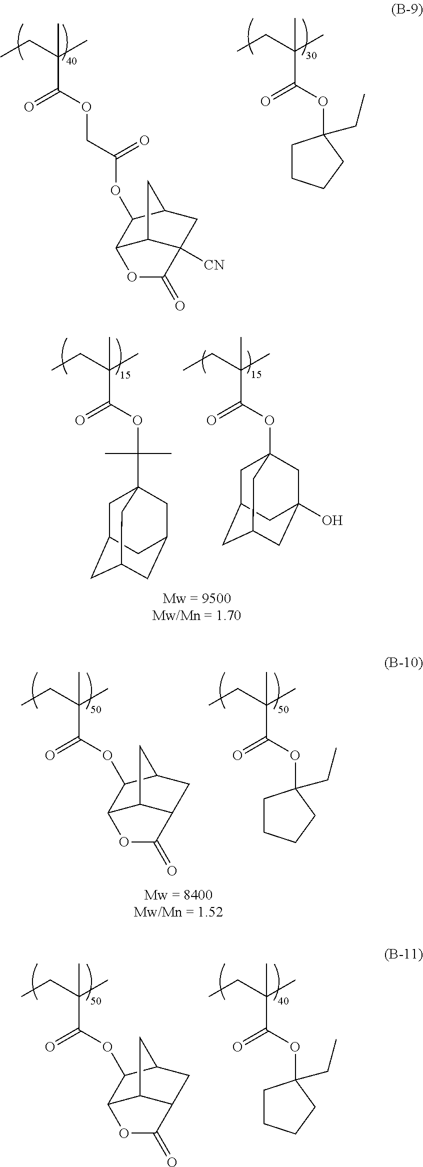

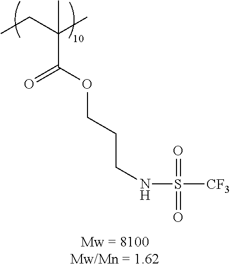

### Hydrobobic Resin

Resins (D-1) to (D-8) shown below were prepared as the hydrophobic resin (D).

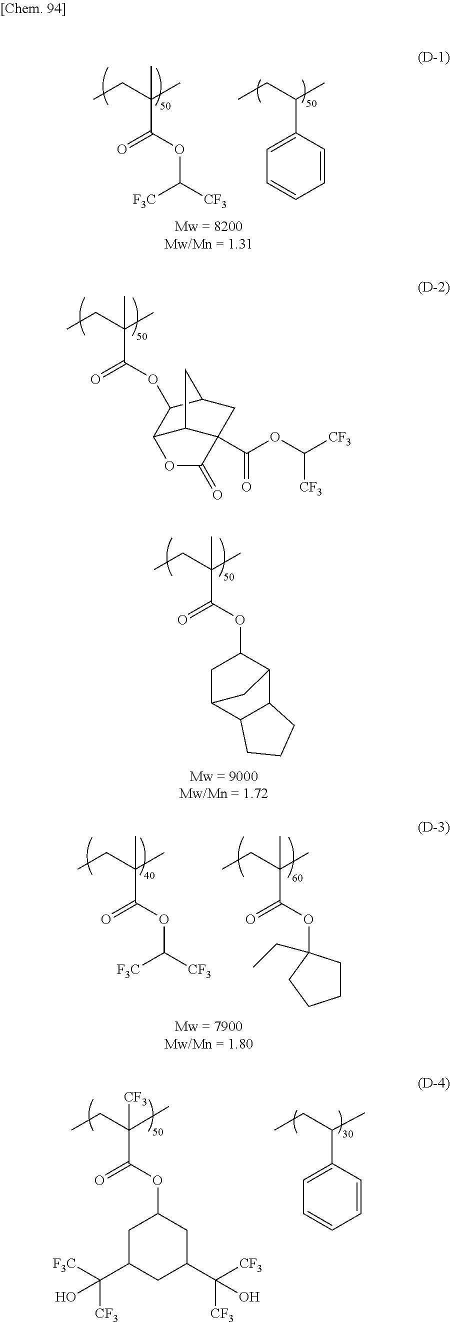

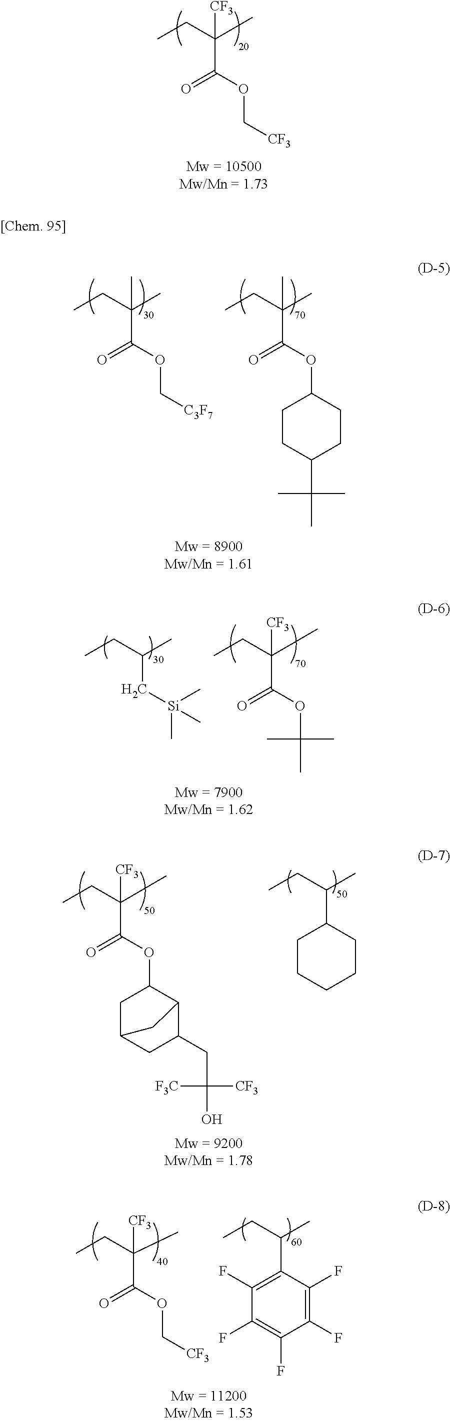

### <Basic Compound (F) or Low Molecular Compound (O)>

Compounds (F-1) to (F-6) shown below were prepared as the basic compound (F) or low molecular compound (G).

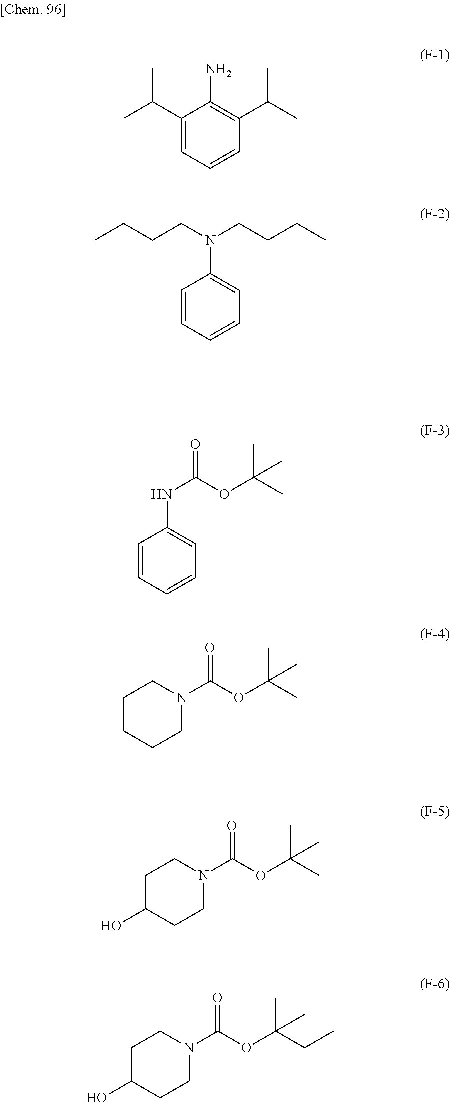

### <Solvent>

The following S-1 to S-5 were prepared as the solvent.

S-1: Propylene glycol monomethyl ether acetate
S-2: Propylene glycol monomethyl ether

### S-3: γ-Butyrolactone

### S-4: Cyclohexanone

S-5: Propylene carbonate

### <Surfactant>

The following W-1 to W-5 were prepared as the surfactant.

W-1: Megaface F176 (produced by DIC Corp.)
W-2: Megaface R08 (produced by DIC Corp.)
W-3: Polysiloxane Polymer KP-341 (produced by Shin-Etsu Chemical Co., Ltd.)
W-4: Troysol S366 (produced by Troy Chemical)
W-5: PF6320 (produced by OMNOVA Solutions Inc.)

### Examples 1 to 25 and Comparative Examples 1 to 4

### Preparation of Resist Composition

The components shown in Tables 2 and 3 below were dissolved in the solvent shown in the same Tables to prepare a solution having a solid content concentration of 4.4 mass %, and the obtained solution was filtered through a polyethylene filter having a pore size of 0.03 μm to prepare an actinic ray-sensitive or radiation-sensitive resin composition (positive resist composition).

### <Exposure Condition (1): Evaluation of ArF Immersion)

An organic antireflection film, ARC29SR (produced by Nissan Chemical Industries, Ltd.), was coated on a silicon wafer and baked at 205° C. for 60 seconds to form an antireflection film having a thickness of 78 nm, and the actinic ray-sensitive or radiation-sensitive resin composition prepared was coated thereon and baked at 130° C. for 60 seconds to form a resist film having a thickness of 110 nm. The resulting wafer was exposed through a 6% halftone mask having a line width of 45 nm (a 1:1 line-and-space pattern) by using an ArF excimer laser immersion scanner (XT1700i, manufactured by ASML, NA: 1.35). As the immersion liquid, pure water was used.

Thereafter, the wafer was heated at 90° C. for 60 seconds, developed with an aqueous tetramethylammonium hydroxide solution (2.38 mass %) for 30 seconds, rinsed with pure water, and then spin-dried to obtain a resist pattern.

### <Exposure Condition (2): Evaluation of ArF Dry>

An organic antireflection film, ARC29A (produced by Nissan Chemical Industries, Ltd.), was coated on a silicon wafer and baked at 205° C. for 60 seconds to form an antireflection film having a thickness of 78 nm, and the actinic ray-sensitive or radiation-sensitive resin composition prepared was coated thereon and baked at 130° C. for 60 seconds to form a film having a thickness of 120 nm. The obtained wafer was exposed through a 6% halftone mask having a line width of 75 nm (a 1:1 line-and-space pattern) by using an ArF excimer laser scanner (PAS5500/1100, manufactured by ASML, NA: 0.75), then heated at 90° C. for 60 seconds, developed with an aqueous tetramethylammonium hydroxide solution (2.38 mass %) for 30 seconds, rinsed with pure water, and spin-dried to obtain a pattern.

### <Evaluation of Resist>

### [Sensitivity: Exposure Condition (1)]

The cross-sectional profile of the pattern obtained was observed using a scanning electron microscope (S-9220, manufactured by Hitachi, Ltd.). The minimum irradiation energy below which a line of 45 nm in width (line:space=1:1) is not resolved, was taken as the sensitivity.

### [Sensitivity: Exposure Condition (2)]

The cross-sectional profile of the pattern obtained was observed using a scanning electron microscope (S-9220, manufactured by Hitachi, Ltd.). The minimum irradiation energy below which a line of 75 nm in width (line:space=1:1) is not resolved, was taken as the sensitivity.

### [Exposure Latitude: Exposure Condition (1)]

The exposure dose for reproducing a line-and-space (1:1) mask pattern with a line width of 45 nm was defined as an optimal exposure dose. The exposure dose range allowing a 45 nm±10% tolerance for the pattern size was determined by changing the exposure dose, and this value was divided by the optimal exposure dose and expressed in percentage. As the value is larger, the fluctuation of performance due to change in the exposure dose is smaller and the exposure latitude (EL) is better.

### [Exposure Latitude: Exposure Condition (2)]

The exposure dose for reproducing a line-and-space (1:1) mask pattern with a line width of 75 nm was defined as an optimal exposure dose. The exposure dose range allowing a 75 nm±110% tolerance for the pattern size was determined by changing the exposure dose, and this value was divided by the optimal exposure dose and expressed in percentage. As the value is larger, the fluctuation of performance due to change in the exposure dose is smaller and the exposure latitude (EL) is better.

### [LER: Exposure Condition (1)]

The line pattern finished to a line width of 45 nm was observed by a scanning microscope (S9260, manufactured by Hitachi, Ltd.), and with respect to a longitudinal edge region in 2 μm of the line pattern, the distance from a reference line where the edge should be present was measured at 50 points. The standard deviation thereof was determined, and 3a was computed. A smaller value indicates better performance.

### [LER: Exposure Condition (2)]

The line pattern finished to a line width of 75 nm was observed by a scanning microscope (S9260, manufactured by Hitachi, Ltd.), and with respect to a longitudinal edge region in 2 μm of the line pattern, the distance from a reference line where the edge should be present was measured at 50 points. The standard deviation thereof was determined, and 3σ was computed. A smaller value indicates better performance.

These measurement results are shown in Table 2 and Table 3 below.

TABLE 2

| | | | | | | Hydrophobic | | Basic | |
|---|---|---|---|---|---|---|---|---|---|
| | Resin (B) | Acid Generator | | Acid Generator | | Resin | | Compound or | |
| Example | (10 g) | (compound (A)) | (g) | (compound (C)) | (g) | (resin (D)) | (g) | Compound (G) | (g) |
| 1 | B-10 | A-1 | 1.5 | — | — | D-1 | 1.5 | F-6 | 0.01 |
| 2 | B-10 | A-1/A-9 | 1.0/0.5 | — | — | D-1/D-4 | 1.0/0.5 | F-4 | 0.01 |
| 3 | B-11 | A-2 | 1.5 | — | — | D-1 | 1.5 | F-4 | 0.01 |
| 4 | B-3 | A-3 | 1.5 | — | — | D-2 | 1.5 | F-5 | 0.01 |
| 5 | B-2 | A-4 | 1.5 | — | — | D-3 | 1.5 | F-4 | 0.01 |
| 6 | B-5 | A-5 | 1.7 | — | — | D-4 | 1.5 | F-2 | 0.01 |
| 7 | B-6 | A-6 | 0.7 | C-4 | 0.3 | D-5 | 1.5 | F-3 | 0.01 |
| 8 | B-6 | A-6/A-8 | 0.5/1.0 | — | — | D-5 | 1.5 | F-1 | 0.01 |
| 9 | B-7 | A-7 | 0.8 | C-1 | 0.3 | D-6 | 1.5 | F-4 | 0.01 |
| 10 | B-8 | A-8 | 1.5 | — | — | D-7 | 1.5 | F-6 | 0.01 |
| 11 | B-9 | A-9 | 1.5 | — | — | D-8 | 1.5 | F-6 | 0.01 |
| 12 | B-10 | A-10 | 1.0 | C-2 | 0.3 | D-1 | 1.5 | F-3 | 0.01 |
| 13 | B-10/B-11 | A-11 | 1.5 | — | — | D-1 | 1.5 | F-4 | 0.01 |
| | (5 g/5 g) | | | | | | | | |
| 14 | B-1 | A-12 | 1.1 | — | — | D-2 | 1.5 | F-3 | 0.01 |
| 15 | B-1 | A-13 | 0.5 | C-5 | 0.5 | D-4 | 1.5 | F-3 | 0.01 |
| 16 | B-4 | A-14 | 0.5 | C-6 | 0.7 | D-2 | 1.5 | F-4 | 0.01 |
| 17 | B-5 | A-15 | 0.5 | C-7/C-3 | 0.5/0.3 | D-3 | 1.5 | F-5 | 0.01 |
| 18 | B-2 | A-16 | 0.3 | C-7 | 0.8 | D-6 | 1.5 | F-4 | 0.01 |

| | | | | | | Hydrophobic | | Basic | |
|---|---|---|---|---|---|---|---|---|---|
| Comparative | Resin (B) | | | | | Resin | | Compound or | |
| Example | (10 g) | Acid Generator | (g) | Acid Generator | (g) | (resin (D)) | (g) | Compound (G) | (g) |
| 1 | B-10 | A-17 | 1.5 | — | — | D-1 | 1.5 | F-6 | 0.01 |
| 2 | B-10 | A-18 | 1.5 | — | — | D-1 | 1.5 | F-6 | 0.01 |

| | Surfactant | | | | Sensitivity | EL | LER |
|---|---|---|---|---|---|---|---|
| Example | (0.03 g) | Solvent | (mass ratio) | Exposure Condition | (mJ/cm²) | (%) | (nm) |
| 1 | W-1 | S-1/S-2 | (70/30) | (1) | 21.0 | 18.0 | 3.3 |
| 2 | W-1 | S-1/S-2/S-5 | (70/25/5) | (1) | 22.0 | 17.2 | 3.4 |
| 3 | W-2 | S-2/S-3 | (60/40) | (1) | 21.4 | 16.9 | 3.5 |
| 4 | W-3 | S-2/S-3 | (70/30) | (1) | 21.2 | 17.0 | 3.7 |
| 5 | W-4 | S-1/S-4 | (95/5) | (1) | 22.1 | 17.5 | 3.6 |
| 6 | W-5 | S-1 | (100) | (1) | 21.2 | 17.0 | 3.5 |
| 7 | W-5 | S-2 | (100) | (1) | 22.0 | 17.0 | 3.6 |
| 8 | W-1 | S-1/S-2/S-4 | (60/35/5) | (1) | 22.5 | 17.0 | 3.6 |
| 9 | W-2 | S-1/S-3 | (55/45) | (1) | 22.0 | 16.8 | 3.5 |
| 10 | W-3 | S-1/S-3 | (60/40) | (1) | 21.4 | 17.0 | 3.4 |
| 11 | W-4 | S-1/S-3 | (80/20) | (1) | 22.3 | 17.3 | 3.4 |
| 12 | W-5 | S-1/S-2 | (70/30) | (1) | 21.8 | 16.9 | 3.5 |
| 13 | W-1 | S-2/S-3 | (70/30) | (1) | 21.5 | 17.2 | 3.6 |
| 14 | W-2 | S-2/S-3 | (60/40) | (1) | 22.7 | 17.6 | 3.6 |
| 15 | W-3 | S-1/S-2 | (75/25) | (1) | 25.7 | 16.5 | 4.5 |
| 16 | W-5 | S-1/S-3 | (70/30) | (1) | 27.0 | 15.9 | 4.7 |
| 17 | W-5 | S-1/S-3 | (70/30) | (1) | 28.0 | 15.8 | 5.0 |
| 18 | W-2 | S-1/S-3 | (70/30) | (1) | 29.4 | 14.9 | 5.7 |

| Comparative | Surfactant | | | | Sensitivity | EL | LWR |
|---|---|---|---|---|---|---|---|
| Example | (0.03 g) | Solvent | (mass ratio) | Exposure Condition | (mJ/cm²) | (%) | (nm) |
| 1 | W-2 | S-2/S-3 | (60/40) | (1) | 31.8 | 13.2 | 6.2 |
| 2 | W-3 | S-2/S-3 | (60/40) | (1) | 34.2 | 14.0 | 6.4 |

TABLE 3

| | Resin (B) | Acid Generator | | Acid Generator | | Basic Compound or | |
|---|---|---|---|---|---|---|---|
| Example | (10 g) | (compound (A)) | (g) | (compound (C)) | (g) | Compound (G) | (g) |
| 19 | B-10 | A-1 | 1.5 | — | — | F-6 | 0.01 |
| 20 | B-11 | A-2 | 1.5 | — | — | F-3 | 0.01 |
| 21 | B-9/B-10 (5 g/5 g) | A-3 | 1.5 | — | — | F-1 | 0.01 |
| 22 | B-6 | A-4/A-5 | 0.5/1.0 | — | — | F-1 | 0.01 |
| 23 | B-1 | A-13 | 0.5 | C-5 | 0.5 | F-3 | 0.01 |
| 24 | B-5 | A-15 | 0.5 | C-7/C-3 | 0.5/0.3 | F-2 | 0.01 |
| 25 | B-2 | A-16 | 0.3 | C-7 | 0.8 | F-6 | 0.01 |

| Comparative | Resin (B) | | | | | Basic Compound or | |
|---|---|---|---|---|---|---|---|
| Example | (10 g) | Acid Generator | (g) | Acid Generator | (g) | Compound (G) | (g) |
| 3 | B-10 | A-17 | 1.5 | — | — | F-6 | 0.01 |
| 4 | B-10 | A-18 | 1.5 | — | — | F-6 | 0.01 |

| | Surfactant | | | | Sensitivity | EL | LER |
|---|---|---|---|---|---|---|---|
| Example | (0.03 g) | Solvent | (mass ratio) | Exposure Condition | (mJ/cm²) | (%) | (nm) |
| 19 | W-1 | S-1/S-2 | (70/30) | (2) | 19.4 | 18.2 | 5.0 |
| 20 | W-2 | S-1/S-2 | (70/30) | (2) | 20.1 | 17.3 | 5.2 |
| 21 | W-3 | S-2/S-3 | (70/30) | (2) | 19.7 | 17.8 | 5.4 |
| 22 | W-1 | S-1/S-2/S-4 | (60/35/5) | (2) | 20.5 | 17.7 | 5.4 |
| 23 | W-4 | S-2/S-3 | (60/40) | (2) | 24.0 | 17.0 | 5.7 |
| 24 | W-4 | S-1/S-5 | (95/5) | (2) | 25.1 | 16.6 | 5.7 |
| 25 | W-2 | S-1/S-3 | (70/30) | (2) | 26.2 | 16.0 | 6.2 |

| Comparative | Surfactant | | | | Sensitivity | EL | LWR |
|---|---|---|---|---|---|---|---|
| Example | (0.03 g) | Solvent | (mass ratio) | Exposure Condition | (mJ/cm²) | (%) | (nm) |
| 3 | W-1 | S-1/S-2 | (70/30) | (2) | 29.8 | 14.9 | 7.8 |
| 4 | W-1 | S-1/S-2 | (70/30) | (2) | 31.4 | 13.6 | 7.6 |

It is seen from Table 2 and Table 3 that according to the actinic ray-sensitive or radiation-sensitive resin composition of the present invention, all of high sensitivity, excellent exposure latitude and excellent line edge roughness performance can be achieved at a high level, as compared with the compositions of Comparative Examples where the compound represented by formula (1-1) is not contained as an acid generator.

Also, it is seen that in Examples using the compound where in formula (1-1), R1 is an aromatic hydrocarbon group or an aromatic heterocyclic group, all of high sensitivity, excellent exposure latitude and excellent line edge roughness performance can be achieved at a higher level.

### INDUSTRIAL APPLICABILITY

According to the present invention, an actinic ray-sensitive or radiation-sensitive resin composition capable of satisfying all of high sensitivity, excellent exposure latitude and excellent line edge roughness performance at a high level, an actinic ray-sensitive or radiation-sensitive film using the composition, and a pattern forming method can be provided.

While the invention has been described in detail and with reference to specific embodiments thereof, it will be apparent to one skilled in the art that various changes and modifications can be made therein without departing from the spirit and scope of the invention.

This application is based on Japanese Patent Application (Patent Application No. 2011-180895) filed on Aug. 22, 2011, the contents of which are incorporated herein by way of reference.

1. An actinic ray-sensitive or radiation-sensitive resin composition containing (A) a compound represented by the following formula (1-1): 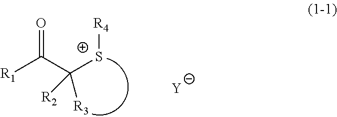
wherein R₁ represents an alkyl group, an alkenyl group, an alkoxy group, an aliphatic cyclic group, an aromatic hydrocarbon group or a heterocyclic group,
R₂ represents a hydrogen atom, an alkyl group, an alkoxy group, an alkenyl group, an aliphatic cyclic group, an aromatic hydrocarbon group, a heterocyclic group, a cyano group or an alkoxycarbonyl group,
R₃ represents an alkylene group where one or more —CH₂— groups may be substituted with an ether group, a carbonyl group, an ester group, an amide group, a methane group or a urea group,
R₄ represents an alkyl group, an alkenyl group, an aliphatic cyclic group, an arylcarbonylalkyl group, an aryloxycarbonylalkyl group or an alkoxycarbonylalkyl group,
R₁ and R₂ may combine with each other to form a ring, and
Y⁻ represents an anion.

2. The actinic ray-sensitive or radiation-sensitive resin composition as claimed in claim 1,
wherein in formula (1-1), R₁ is an aromatic hydrocarbon group or an aromatic heterocyclic group.

3. The actinic ray-sensitive or radiation-sensitive resin composition as claimed in claim 2,
wherein in formula (1-1), R₁ is an aromatic hydrocarbon group.

4. The actinic ray-sensitive or radiation-sensitive resin composition as claimed in claim 1,
wherein in formula (1-1), R₃ is an unsubstituted alkylene group.

5. The actinic ray-sensitive or radiation-sensitive resin composition as claimed in claim 1,
wherein Y⁻ represents an organic acid anion.

6. The actinic ray-sensitive or radiation-sensitive resin composition as claimed in claim 1,
wherein Y⁻ represents a sulfonate anion, an imidate anion or a methidate anion.

7. The actinic ray-sensitive or radiation-sensitive resin composition as claimed in claim 1, containing (B) a resin capable of decomposing by an action of an acid to increase the solubility for an alkali developer.

8. The actinic ray-sensitive or radiation-sensitive resin composition as claimed in claim 1, further containing a hydrophobic resin.

9. The actinic ray-sensitive or radiation-sensitive resin composition as claimed in claim 1, further containing (F) a basic compound or (G) a low molecular compound having a group capable of leaving by an action of an acid, and increasing in the basicity upon leaving of the group.

10. An actinic ray-sensitive or radiation-sensitive film formed using the actinic ray-sensitive or radiation-sensitive resin composition claimed in claim 1.

11. A pattern forming method comprising exposing the actinic ray-sensitive or radiation-sensitive film claimed in claim 10 and developing the exposed film.

12. The pattern forming method as claimed in claim 11, wherein the exposure is performed through an immersion liquid.
